(19) United States
(12) Patent Application Publication
(10) Pub. No.: US 2025/0204164 A1
(43) Pub. Date: Jun. 19, 2025

(54) DISPLAY DEVICE AND PHOTOSENSITIVE COMPOSITION

(71) Applicant: TORAY Industries, Inc., Tokyo (JP)

(72) Inventors: Yugo TANIGAKI, Otsu-shi, Shiga (JP); Hiroki NISHIOKA, Otsu-shi, Shiga (JP); Takashi HONMA, Otsu-shi, Shiga (JP)

(73) Assignee: TORAY Industries, Inc., Tokyo (JP)

(21) Appl. No.: 18/852,292

(22) PCT Filed: Mar. 24, 2023
(86) PCT No.: PCT/JP2023/011950

§ 371 Date: Sep. 27, 2024

(30) Foreign Application Priority Data
Mar. 30, 2022 (JP) 2022-055753
Mar. 30, 2022 (JP) 2022-055754

(51) Int. Cl. H10K 59/122; G02B 5/22; G03F 7/004; G03F 7/039; H10K 59/80; H10K 77/10; H10K 102/00; H10K 102/10

(52) U.S. Cl. CPC H10K 59/122; G02B 5/223; G03F 7/0045; G03F 7/0392; H10K 59/80517; H10K 59/8792; H10K 77/111; H10K 2102/103; H10K 2102/311; H10K 2102/351

(57) ABSTRACT

The main object of the present invention is to provide an organic EL display that has excellent light emission characteristics to enable low voltage driving and has light emitting elements with high reliability, thereby serving to realize a desired current density. Provided is a display device including a substrate, a first electrode, a second electrode, a pixel separation layer, and an organic layer containing a light emitting layer, wherein the pixel separation layer contains a colorant (D-DL), has an optical density of 0.5 to 3.0 in the visible light wavelength range per μm of the thickness of the pixel separation layer, and has a plurality of pixel parts in a plan view. The detection intensity of the sulfur ion (S⁻), the detection intensity of the chlorine ion (Cl⁻), the detection intensity of the bromine ion (Br⁻), and the sum of the detection intensity of the chlorine ion (Cl⁻) and the detection intensity of the bromine ion (Br⁻), all measured by time-of-flight secondary ion mass spectrometry at a position 3 nm deep in each pixel part from the surface of the first electrode, the surface being in contact with the organic layer containing a light emitting layer, satisfy relationships represented by specific general formulas.

### TECHNICAL FIELD

The present invention relates to a display device and a photosensitive composition. More specifically, it relates to such display devices as organic electroluminescence (hereinafter abbreviated as organic EL) displays, quantum dot displays, and micro-light emitting diode (micro-LED) displays. It particularly relates to organic EL displays.

### BACKGROUND ART

In recent years, technologies related to organic EL displays, quantum dot displays, and micro-LED displays have been actively researched as components for display devices having thin displays including smartphones, tablet C's, and televisions, and many products containing these displays have been developed.

To improve the light emission characteristics of organic EL displays, highly heat resistant photosensitive compositions are now used in the pixel separation layers, thin film transistor (hereinafter referred to as TFT) planarization layers, and TFT protection layers included in organic EL displays, as well as in the interlayer insulation layers and gate insulation layers in TFT arrays. For example, the pixel separation layer disposed on the first electrode requires an opening part that is designed for exposing the first electrode, which acts as anode. Thus, the pixel separation layer is formed by photolithography. An organic EL display contains a self-luminous element and accordingly, if external light such as sunlight enters in an outdoor environment, reflection of the external light causes a decrease in the visibility and contrast. Thus, as a common technique for blocking external light to reduce its reflection, a polarizing film is disposed on the light extraction side. Furthermore, there is another good technique that is designed to enhance the light blocking efficiency by incorporating colorants in the photosensitive composition used to form the pixel separation layer.

In regard to improvement in light emission characteristics of organic EL displays, low voltage driving can serve to realize a higher emission luminance and smaller power consumption because a high current flow can be achieved at a desired voltage. Furthermore, an improvement in the reliability of a light emitting element can lead to an increase in the durability of organic EL displays. Accordingly, to achieve a desired current density, it is necessary to both realize improved light emission characteristics that enable low voltage driving and adopt light emitting elements with improved reliability.

Examples of good organic EL displays include those organic EL displays in which the total content of metal elements and/or halogen elements in the pixel separation layer and/or planarization layer is controlled within a specific range (see Patent document 1). Examples of good photosensitive compositions include negative type photosensitive compositions that contain a first resin such as polyimide and a second resin such as cardo based resin (see Patent document 2).

### PRIOR ART DOCUMENTS

### Patent Documents

Patent document 1: International Publication WO 2018/123853
Patent document 2: International Publication WO 2017/159876

### SUMMARY OF INVENTION

### Problems to be Solved by the Invention

In an organic EL display, the formation of a polarizing film on the light extraction side results in partial blocking of the light emission from the light emitting element as well. Therefore, there occurs the problem of a decrease in light emission luminance although such a polarizing film is effective for suppressing external light reflection.

On the other hand, if a colorant is included in the photosensitive composition used to form the pixel separation layer for suppression of external light reflection, ultraviolet light etc. will be also blocked during light exposure for patterning. Accordingly, if there occur deteriorated pattern processability and development residues attributed to the solubility of colorants, they can lead to higher voltage driving affecting the light emission characteristics of the organic EL display. Furthermore, there is another problem of a decrease in reliability of light emitting elements due to foreign substances that can come from development residues etc.

Therefore, an organic EL display to work as a display device is required to possess excellent light emission characteristics that enable low voltage driving and has a light emitting element with high reliability in order to realize a desired current density. However, the display device proposed in Patent document 1 given above is inferior in some of the above characteristics. In addition, in order to achieve a desired current density, the photosensitive composition to use is required not only to have good light emission characteristics that enable low voltage driving, but also to be able to provide a cured film that allows the light emitting element to have high reliability. However, the photosensitive composition proposed in Patent document 2 given above is inferior in some of the above characteristics.

### Means of Solving the Problems

To solve the above problems, the display device and photosensitive composition according to the present invention are configured to have the aspects [1] to [20] described below.

[1] A display device comprising a substrate, a first electrode, a second electrode, a pixel separation layer, and an organic layer containing a light emitting layer,
wherein the pixel separation layer contains a colorant (D-DL) and has an optical density of 0.5 to 3.0 in the visible light wavelength range per μm of the thickness of the pixel separation layer,
has a plurality of pixel parts in a plan view, and
satisfies the relationship represented by the general formula (SA-1) and/or the relationship represented by the general formula (XA-1):

$$2 \leq ( {S}_{Dep / Anode} ) \leq 200 , and \qquad ( SA - 1 )$$

$$2 \leq ( {X}_{Dep / Anode} ) \leq 200 , \qquad ( XA - 1 )$$

wherein:
(S_{Dep/Anode}) counts represents the detection intensity of the sulfur ion (S⁻); (X_{Dep/Anode}) counts represents the sum of (Cl_{Dep/Anode}) and (Br_{Dep/Anode});
(Cl_{Dep/Anode}) counts represents the detection intensity of the chlorine ion (Cl⁻); and (Br_{Dep/Anode}) counts represents the detection intensity of the bromine ion (Br⁻);
all measured by time-of-flight secondary ion mass spectrometry at a position 3 nm deep in each pixel part from the surface of the first electrode, the surface being in contact with the organic layer containing a light emitting layer.

[2] The display device according to [1], satisfying the relationships represented by the general formula (SA-1) and the general formula (XA-1).

[3] The display device according to either [1] or [2], wherein:
the first electrode is a non-transparent electrode having a multilayer structure;
the first electrode has a non-transparent conductive metal layer; and
at least one of the layers other than the outermost layer of the first electrode that faces the light emitting layer includes a non-transparent conductive metal layer containing silver or copper as the main constituent element.

[4] The display device according to [3], wherein the first electrode has a transparent conductive oxide film layer and a non-transparent conductive metal layer and has, as the outermost layer of the first electrode that faces the light emitting layer, a transparent conductive oxide film layer containing indium as the main constituent element.

[5] The display device according to [4], satisfying the relationship represented by the general formula (SA-1) given above and further satisfying the relationships represented by the general formula (SA-2) and the general formula (InSA-1); and/or
satisfying the relationship represented by the general formula (XA-1) given above and further satisfying the relationships represented by the general formula (XA-2) and the general formula (InXA-1); wherein:
(InO_{Dep/Anode}) counts is the detection intensity of the indium oxide ion (InO₂⁻), measured by time-of-flight secondary ion mass spectrometry at a position 3 nm deep in each pixel part from the surface of the transparent conductive oxide film layer, the surface being in contact with the organic layer containing a light emitting layer:

$$0.0001 \leq ( {S}_{Dep / Anode} ) / ( ln {O}_{Dep / Anode} ) \leq 0.1 , \qquad ( SA - 2 )$$

$$1 , 000 \leq ( ln {O}_{Dep / Anode} ) \leq 40 , 000 , \qquad ( lnSA - 1 )$$

$$0.0001 \leq ( {X}_{Dep / Anode} ) / ( ln {O}_{Dep / Anode} ) \leq 0.1 , and \qquad ( XA - 2 )$$

$$1 , 000 \leq ( ln {O}_{Dep / Anode} ) \leq 40 , 0. \qquad ( lnXA - 1 )$$

[6] The display device according to any one of [1] to [5], further satisfying the relationship represented by the general formula (SA-1a) and/or the relationship represented by the general formula (XA-1a):

$$2 \leq ( {S}_{Dep / Anode} ) \leq 100 , and \qquad ( SA - 1 a )$$

$$2 \leq ( {X}_{Dep / Anode} ) \leq 100. \qquad ( XA - 1 a )$$

[7] The display device according to any one of [1] to [6], satisfying the relationship represented by the general formula (SD-1) and/or the relationship represented by the general formula (XD-1):

$$0.1 \leq ( {S}_{Anode} ) / ( {S}_{PDL} ) \leq 20 , and \qquad ( SD - 1 )$$

$$0.1 \leq ( {X}_{Anode} ) / ( {X}_{PDL} ) \leq 20 , \qquad ( XD - 1 )$$

wherein:
(SP_{DL}) is the ratio of the ion detection intensity of the sulfur ion (S⁻);
(X_{PDL}) is the total of (Cl_{PDL}) and (Br_{PDL});
(Cl_{PDL}) is the ratio of the ion detection intensity of the chlorine ion (Cl⁻);
(Br_{PDL}) is the ratio of the ion detection intensity of the bromine ion (Br⁻);
the ratios being relative to the total anion detection intensities measured by time-of-flight secondary ion mass spectrometry on the surface of the pixel separation layer part that is in contact with the second electrode part or is exposed in the opening part in the second electrode part, in the region not overlapping with the region including the organic layer part containing a light emitting layer on the pixel separation layer part;
(S_{Anode}) is the ratio of the ion detection intensity of the sulfur ion (S⁻);
(X_{Anode}) is the total of (Cl_{Anode}) and (Br_{Anode});
(Cl_{Anode}) is the ratio of the ion detection intensity of the chlorine ion (Cl⁻); and
(Br_{Anode}) is the ratio of the ion detection intensity of the bromine ion (Br⁻);
the ratios being relative to the total anion detection intensities measured by time-of-flight secondary ion mass spectrometry on the surface of the first electrode part that is in contact with the organic layer containing a light emitting layer in the pixel part.

[8] The display device according to any one of [1] to [7], wherein:
the pixel separation layer contains an organic black pigment and/or a mixture of two or more color pigments,
the organic black pigment containing one or more selected from the group consisting of benzofuranone based black pigments, perylene based black pigments, and azo based black pigments, and
the mixture of two or more color pigments containing two or more pigments selected from the group consisting of red, orange, yellow, green, blue, and purple.

[9] The display device according to any one of [1] to [8], wherein the pixel separation layer contains a resin (A1-DL) and/or a resin (A3-DL) as specified below:
resin (A1-DL): a resin having one or more structural units selected from the group consisting of imide structure, amide structure, oxazole structure, and siloxane structure, and
resin (A3-DL): a resin having a structural unit containing a phenolic hydroxyl group.

[10] The display device according to any one of [1] to [9], wherein the pixel separation layer contains a compound (C1x-DL) and/or a compound (C2x-DL) as specified below:
compound (C1x-DL): a compound having a fluorene structure, benzofluorene structure, dibenzofluorene structure, carbazole structure, benzocarbazole structure, indole structure, benzoinole structure, or diphenyl sulfide structure and having a structure including an imino group bonded to these structures and/or a structure including a carbonyl group bonded to these structures, and
compound (C2x-DL): a compound having a carboxylate structure containing an indene structure and/or an aryl sulfonate structure containing an indene structure.

[11] The display device according to any one of [1] to [10], wherein the non-transparent conductive metal layer containing silver or copper as the main constituent element in the first electrode further contains one or more selected from the group consisting of In, Sn, Zn, Al, Ga, Bi, Nd, Ni, Mn, Na, K, Mg, Ca, C, and Si, as elements different from the main constituent element.

[12] The display device according to any one of [1] to [11], in the form of a flexible display device further comprising:
a flexible substrate,
a structure in which the pixel separation layer is disposed on the flexible substrate, none of linear polarizing plates, quarter wave plates, or circular polarizing plates on the light extraction side of the organic layer containing a light emitting layer, and
a curved display part, a display part having a plane bending outward, or a display part having a plane bending inward.

[13] The display device according to any one of [1] to [12], wherein:
the pixel separation layer has a step shaped cured pattern, and
the thickness difference of (ΔT_{FT-HT}) μm between the thickness of (T_{FT}) μm and the thickness of (T_{HT}) μm is 0.5 to 10.0 μm where (T_{FT}) μm is the thickness of the thick parts and (T_{HT}) μm is the thickness of the thin parts in the step shaped cured pattern of the pixel separation layer.

[14] The display device according to [13], wherein:
the thick parts and the thin parts in the step shaped cured pattern of the pixel separation layer contain the same colorant (D-DL), and
the optical density per μm of the thickness of the thick parts and the thin parts is 0.5 to 3.0 in the visible light wavelength range.

[15] The display device according to any one of [1] to [12], wherein the pixel separation layer has a cured pattern and has a spacer layer disposed on a part of the pixel separation layer,
the spacer layer having a thickness (T_{SP}) μm of 0.5 to 10.0 μm, and
the spacer layer satisfying at least one of the requirements (1) to (3) given below:
(1) the spacer layer does not contain the colorant (D-DL),
(2) the spacer layer contains the colorant (D-DL) and has an optical density in the visible light wavelength of 0.0 to 0.3 per μm of the thickness of the spacer layer, and
(3) the spacer layer includes a compound (C2x-DL) having a carboxylate structure containing an indene structure and/or an aryl sulfonate structure containing an indene structure.

[16] A display device including a substrate, a first electrode, a second electrode, a pixel separation layer, and an organic layer containing a light emitting layer, wherein:
the pixel separation layer contains a colorant (D-DL) and has an optical density of 0.5 to 3.0 in the visible light wavelength range per μm of the thickness of the pixel separation layer;
the pixel separation layer contains one or more selected from the group consisting of a compound (I1a-DL), compound (I1b-DL), compound (I2a-DL), and compound (I2b-DL) as specified below;
the compound (I1a-DL) and the compound (I2a-DL) have structures (I-Ia) as specified below;
the compound (I1b-DL) and the compound (I2b-DL) have structures (I-Ib) as specified below; and
one or more of the requirements (1a-DL) and (1b-DL) or one or more of the requirements (2a-DL) and (2b-DL) specified below are satisfied:
compound (I1a-DL): one or more compounds selected from the group consisting of thiol structure-containing compounds, sulfide structure-containing compounds, disulfide structure-containing compounds, sulfoxide structure-containing compounds, sulfone structure-containing compounds, sultone structure-containing compounds, thiophene structure-containing compounds, and sulfonic acid structure-containing compounds,
compound (I1b-DL): a compound having, as anion species, one or more selected from the group consisting of sulfide ion structures, hydrogen sulfide ion structures, sulfate ion structures, and hydrogen sulfate ion structures and also having, as cation species, an ammonium ion structure, primary ammonium ion structure, secondary ammonium ion structure, tertiary ammonium ion structure, or quaternary ammonium ion structure,
compound (I2a-DL): one or more compounds selected from the group consisting of alkyl chloride structure-containing compounds, cycloalkyl chloride structure-containing compounds, aryl chloride structure-containing compounds, alkyl bromide structure-containing compounds, cycloalkyl bromide structure-containing compounds, and aryl bromide structure-containing compounds,
compound (I2b-DL): a compound having, as anion species, a chloride ion structure and/or a bromide ion structure, and also having, as cation species, an ammonium ion structure, primary ammonium ion structure, secondary ammonium ion structure, tertiary ammonium ion structure, or quaternary ammonium ion structure,
structure (I-Ia): a structure containing one or more selected from the group consisting of monovalent or divalent aliphatic groups having 4 to 30 carbon atoms, alkylaryl groups having 10 to 30 carbon atoms, arylalkyl groups having 10 to 30 carbon atoms, and aryl groups having 7 to 15 carbon atoms,
structure (I-Ib): a structure containing one or more selected from the group consisting of monovalent or divalent aliphatic groups having 1 to 6 carbon atoms, alkylaryl groups having 10 to 30 carbon atoms, arylalkyl groups having 10 to 30 carbon atoms, and aryl group having 7 to 15 carbon atoms,
(1a-DL) the content of the sulfur element in the pixel separation layer is 0.01 to 500 mass ppm,
(1b-DL) the total content of the sulfide ion, hydrogen sulfide ion, sulfate ion, and hydrogen sulfate ion in the pixel separation layer is 0.01 to 1,000 mass ppm,
(2a-DL) the total content of the chlorine element and the bromine element in the pixel separation layer is 0.01 to 500 mass ppm, and (2b-DL) the total content of chloride ions and bromide ions in the pixel separation layer is 0.01 to 1,000 mass ppm.

[17] A photosensitive composition including an alkali soluble resin (A), a photosensitizer (C), and a colorant (D) and satisfying the requirement (I) and/or the requirement (II) given below: (I) further including one or more selected from the group consisting of components containing the sulfur element, components containing the chlorine element, and components containing the bromine element and satisfying the requirement (1a) and/or the requirement (2a) given below,
(1a) the content of the sulfur element in the photosensitive composition is 0.01 to 100 mass ppm, and
(2a) the total content of the chlorine element and the bromine element in the photosensitive composition is 0.01 to 100 mass ppm,
(II) further including one or more selected from the group consisting of components containing a sulfur based anion as given below and components containing a halogen anion as given below and satisfying the requirement (1b) and/or the requirement (2b) given below, sulfur based anion: one or more ions selected from the group consisting of sulfide ions, hydrogen sulfide ions, sulfate ions, and hydrogen sulfate ions, halogen anion: a chloride ion and/or a bromide ion,
(1b) the total content of sulfide ions, hydrogen sulfide ions, sulfate ions, and hydrogen sulfate ions in the photosensitive composition is 0.01 to 500 mass ppm, and
(2b) the total content of chloride ions and bromide ions in the photosensitive composition is 0.01 to 500 mass ppm.

[18] The photosensitive composition according to [17], comprising the component containing the sulfur element and also satisfying the requirement (1a) and/or comprising the component containing a sulfur based anion and also satisfying the requirement (1b).

[19] The photosensitive composition according to either [17] or [18], comprising the component containing the sulfur element and also satisfying the requirement (1a) and/or comprising the component containing a sulfur based anion and also satisfying the requirement (1b), and further
comprising one or more selected from the group consisting of components containing the chlorine element and components containing the bromine element and also satisfying the requirement (2a) and/or comprising the component containing a halogen anion and also satisfying the requirement (2b).

[20] The photosensitive composition according to any one of [17] to [19], further comprising water and satisfying the requirement (3) given below:
(3) the content of water in the photosensitive composition is 0.01 to 2.0 mass %.

### Advantageous Effects of the Invention

The present invention provides an organic EL display having excellent light emission characteristics that enable low voltage driving and allowing the light emitting element to have high reliability, thereby serving to realize a desired current density.

### BRIEF DESCRIPTION OF THE DRAWINGS

FIG. 1 This gives a schematic cross-sectional view and plan view illustrating an example of a display device that includes a pixel separation layer having a step shape.

FIG. 2 This gives a schematic cross-sectional view and plan view illustrating an example of a display device that includes a pixel separation layer and a spacer layer.

FIG. 3 This gives a schematic cross-sectional view and plan view illustrating an example of a display device that includes a pixel separation layer having a step shape and a pixel size control layer.

FIG. 4 This gives a plan view illustrating examples of the shape of a pixel part, the shape of a color filter layer part, and the shape of the opening part of a black matrix layer part.

FIG. 5 This gives a schematic cross-sectional view and plan view illustrating an example of a display device that has a structure in which the black matrix layer part overlaps with the color filter layer part.

FIG. 6 This gives a schematic cross-sectional view illustrating an example of a display device that includes a pixel separation layer having a step shape and a polarizing film.

FIG. 7 This gives a plan view illustrating an example of a display device that is designed to include pixel parts of a first color, pixel parts of a second color, and pixel parts of a third color.

FIG. 8 This gives a schematic cross-sectional view illustrating an example of a cross-section of a cured pattern having a step shape.

FIG. 9 This gives a schematic cross-sectional view illustrating an example of steps 1 to 6 of a manufacturing process for a display device that includes a pixel separation layer having a step shape.

FIG. 10 This gives a plan view illustrating an example of steps 1 to 4 of a manufacturing process for the substrate of an organic EL display used for evaluation of light emission characteristics.

FIG. 11 This gives a plan view illustrating an example of arrangement and sizes of translucent parts, light-shielding parts, and semi-translucent parts in a halftone photomask used for evaluation of halftone characteristics.

FIG. 12 This gives a plan view illustrating an example of arrangement and sizes of thick parts, opening parts, and thin parts in an organic EL display device used for evaluation of light emission characteristics.

### DESCRIPTION OF PREFERRED EMBODIMENTS

Display devices according to the first and second aspects of the present invention are described below. Hereinafter, the term “the display device according to the present invention” refers to any of the display device according to the first aspect or the second aspect of the present invention and the display device including a cured product prepared by curing a photosensitive composition according to the third aspect of the present invention which will be described later. As compared with this, the term “the display device according to the first aspect”, for example, is used to refer to a display device according to a particular aspect.

For the display device according to the present invention, a “plane” in a plan view means a plane parallel to the substrate described later. In addition, for the display device according to the present invention, the “plan view” means a view of a plane on the light extraction side in the display device, which is an xy-plane looking from the z-axis direction, wherein the xy-plane is a plane parallel to the substrate while the z-axis direction is perpendicular to the xy-plane. When focusing on a specific member in a plan view, it is looked at through another member overlapping with the specific member, if any. If the substrate is not flat, the xy-plane is a plane parallel to an appropriate pixel part described later. For the display device according to the present invention, “overlapping” means direct or indirect overlapping in the z-axis direction. For the display device according to the present invention, the average value of a pattern dimension can be determined by measuring the pattern dimension at 30 points using an optical microscope or scanning electron microscope (SEM), followed by calculating the average. The maximum and minimum values of a pattern dimension can be calculated as the maximum and minimum values of the 30 measurements of the pattern dimension taken as described above using an optical microscope or SEM. The main chain of a resin refers to the longest of the chains that form the resin including structural units. Of the chains that form the resin including structural units, a side chain is one that is branched from or bonded to the main chain and is shorter than the main chain. The chain end of a resin refers to the structure that cap an end of the main chain, such as a structure derived from an end capping agent. In addition, a hydrocarbon group or an alkylene group containing a “-bond” or a “-group” refers to a hydrocarbon group or an alkylene group to which the “-bond” or “-group” is connected or at least two hydrocarbon groups or at least two alkylene groups that are connected to each other via the “-bond” or the “-group”.

### <Display Device>

The display device according to the first aspect of the present invention is a display device including a substrate, a first electrode, a second electrode, a pixel separation layer, and an organic layer containing a light emitting layer, wherein the pixel separation layer contains a colorant (D-DL) and has an optical density of 0.5 to 3.0 in the visible light wavelength range per μm of the thickness of the pixel separation layer, has a plurality of pixel parts in plan view, and satisfies the relationship represented by the general formula (SA-1) and/or the relationship represented by the general formula (XA-1):

$$2 \leq ( {S}_{Dep / Anode} ) \leq 200 \qquad ( SA - 1 )$$

$$2 \leq ( {X}_{Dep / Anode} ) \leq 200 , \qquad ( XA - 1 )$$

wherein:
(S_{Dep/Anode}) counts represents the detection intensity of the sulfur ion (S⁻),
(X_{Dep/Anode}) counts represents the total of (Cl_{Dep/Anode}) and (Br_{Dep/Anode}),
(Cl_{Dep/Anode}) counts represents the detection intensity of the chlorine ion (Cl⁻),
(Br_{Dep/Anode}) counts represents the detection intensity of the bromine ion (Br⁻),
all measured by time-of-flight secondary ion mass spectrometry at a position 3 nm deep in the pixel parts from the surface of the first electrode, the surface being in contact with the organic layer containing a light emitting layer.

If configured in this way, the display device according to the present invention can have excellent light emission characteristics that enable low voltage driving and allow the light emitting element to have high reliability. Larger detection intensities of the sulfur ion, chlorine ion, or bromine ion on the surface of the first electrode in contact with the organic layer containing a light emitting layer in a pixel part means that larger proportions of the surface of the first electrode are modified by these elements. If the detection intensities of the sulfur ion, chlorine ion, and bromine ion are adjusted as described above, it serves to realize excellent light emission characteristics to allow low voltage driving to be achieved by controlling the difference in the work function. In addition, it is considered that a higher light emission luminance can be achieved at the same driving voltage. It is also expected that for example, the polarization structure and charge balance on the first electrode in an organic EL display can be controlled by intentional adjustment of the detection intensities of these ions on the first electrode serves. It is inferred from this that the suppression of ion migration and electromigration attributed to metal impurities and ion impurities that can adversely affect the light emission characteristics can significantly enhance the effect of improving the reliability of the light emitting element. In addition, it is inferred that the suppression of migration and aggregation of metal in the first electrode can significantly enhance the effect of improving the reliability of the light emitting element.

This in turn enhances the effect of improving the reliability of the light emitting element.

The display device according to the second aspect of the present invention is a display device including a substrate, a first electrode, a second electrode, a pixel separation layer, and an organic layer containing a light emitting layer, wherein:
the pixel separation layer contains a colorant (D-DL) and has an optical density of 0.5 to 3.0 in the visible light wavelength range per μm of the thickness of the pixel separation layer;
the pixel separation layer contains one or more selected from the group consisting of the compound (I1a-DL), compound (I1b-DL), compound (I2a-DL), and compound (I2b-DL) specified below;
the compound (I1a-DL) and the compound (I2a-DL) have structures (I-Ia) as specified below;
the compound (I1b-DL) and the compound (I2b-DL) have structures (I-Ib) as specified below;
compound (I1a-DL): one or more compounds selected from the group consisting of thiol structure-containing compounds, sulfide structure-containing compounds, disulfide structure-containing compounds, sulfoxide structure-containing compounds, sulfone structure-containing compounds, sultone structure-containing compounds, thiophene structure-containing compounds, and sulfonic acid structure-containing compounds,
compound (I1b-DL): a compound having, as anion species, one or more selected from the group consisting of sulfide ion structures, hydrogen sulfide ion structures, sulfate ion structures, and hydrogen sulfate ion structures, and also having, as cation species, an ammonium ion structure, primary ammonium ion structure, secondary ammonium ion structure, tertiary ammonium ion structure, or quaternary ammonium ion structure,
compound (I2a-DL): one or more compounds selected from the group consisting of alkyl chloride structure-containing compounds, cycloalkyl chloride structure-containing compounds, aryl chloride structure-containing compounds, alkyl bromide structure-containing compounds, cycloalkyl bromide structure-containing compounds, and aryl bromide structure-containing compounds,
compound (I2b-DL): a compound having, as anion species, a chloride ion structure and/or a bromide ion structure, and also having, as cation species, an ammonium ion structure, primary ammonium ion structure, secondary ammonium ion structure, tertiary ammonium ion structure, or quaternary ammonium ion structure,
structure (I-Ia): a structure containing one or more selected from the group consisting of monovalent or divalent aliphatic groups having 4 to 30 carbon atoms, alkylaryl groups having 10 to 30 carbon atoms, arylalkyl groups having 10 to 30 carbon atoms, and aryl groups having 7 to 15 carbon atoms,
structure (I-Ib): a structure containing one or more selected from the group consisting of monovalent or divalent aliphatic groups having 1 to 6 carbon atoms, alkylaryl groups having 10 to 30 carbon atoms, arylalkyl groups having 10 to 30 carbon atoms, and aryl group having 7 to 15 carbon atoms:
(1a-DL) the content of the sulfur element in the pixel separation layer is 0.01 to 500 mass ppm,
(1b-DL) the total content of sulfide ions, hydrogen sulfide ions, sulfate ions, and hydrogen sulfate ions in the pixel separation layer is 0.01 to 1,000 mass ppm,
(2a-DL) the total content of the chlorine element and the bromine element in the pixel separation layer is 0.01 to 500 mass ppm, and
(2b-DL) the total content of chloride ions and bromide ions in the pixel separation layer is 0.01 to 1,000 mass ppm.

If configured in this way, the display device according to the present invention can have excellent emission characteristics that enable low voltage driving and contain a light emitting element with high reliability. In the case where a compound having a structure containing the sulfur element, a compound having a structure containing a sulfur based anion as described above, a compound having a structure containing the chlorine element, a compound having a structure containing the bromine element, or a compound having a structure containing a halogen anion as described above is included in the pixel separation layer, it is inferred that when forming such a pixel separation layer on the first electrode described later, the surface of the first electrode that faces the light emitting layer and corresponds to the opening part in the pixel separation layer part or the opening part in the pixel size control layer part is surface-modified by these elements or ions. It is considered that after forming the pixel separation layer, there occurs the transition of these elements or ions contained in the pixel separation layer, and then this causes the modification of the surface of the first electrode with these elements or ions. It is inferred that as a result, the adjustment of the difference in the work function works for realizing excellent light emission characteristics that enable low voltage driving. In addition, it is considered that this also allows a higher light emission luminance to be achieved at the same driving voltage. It is also considered that for example, the polarization structure and charge balance in the pixel separation layer in an organic EL display can be controlled by intentionally adding these compounds. It is inferred from this that the suppression of ion migration and electromigration attributed to metal impurities and ion impurities that can adversely affect the light emission characteristics can enhance the effect of improving the reliability of the light emitting element. In addition. it is inferred that the suppression of migration and aggregation of metal in the first electrode can enhance the effect of improving the reliability of the light emitting element.

### <Substrate>

The display device according to the present invention has a substrate. From the perspective of improving the impact resistance, it is preferable for the substrate to include silicon dioxide or aluminum trioxide, and more preferably, it should be a glass substrate, quartz substrate, crystal substrate, or sapphire substrate.

The substrate is preferably a flexible substrate in order to ensure enhanced flexibility and enhanced bending property and to allow the display device to have an increased degree of freedom in shape (curved surface shape, bent shape, etc.). From the perspective of improving the adhesion between the cured film and the substrate according to the present invention and also enhancing their bending properties, it is preferable for the flexible substrate to contain carbon as the main constituent elemental. For such a flexible substrate, the term “main constituent element” refers to the element that accounts for the largest proportion among the constituent elements of the flexible substrate. Preferable flexible substrates include polyimide substrates, polyethylene terephthalate substrates, cycloolefin polymer substrates, polycarbonate substrates, and cellulose triacetate substrates, of which polyimide substrates are more preferable from the perspective of improving bending properties. It is preferable for the display device according to the present invention to have a structure in which the pixel separation layer described later is disposed on a flexible substrate.

The display device according to the present invention is preferably a display device with flexibility and it preferably includes a curved display part, a display part having a plane bending outward, or a display part having a plane bending inward. It is preferable for the display device with flexibility to be an organic EL display with flexibility, a quantum dot display with flexibility, or a micro-LED display with flexibility, of which the use of an organic EL display with flexibility is more preferable.

### <First Electrode and Second Electrode; First Electrode Part and Second Electrode Part in Plan View>

The display device according to the present invention has a first electrode and a second electrode. As the first electrode and the second electrode, the combination of a transparent electrode and a non-transparent electrode may be used in order to allow light emission to be extracted from one side of the organic layer containing a light emitting layer which will be described later. The transparent electrode and the non-transparent electrode are required to have excellent electrical characteristics. If a transparent electrode or a non-transparent electrode is used as an anode, it is required to inject holes efficiently, whereas if used as a cathode, it is required to inject electrons efficiently, thereby ensuring various characteristics in an integrated manner.

A display device with a bottom emission configuration has a transparent electrode as the first electrode and a non-transparent electrode as the second electrode. On the other hand, a display device with a top emission configuration has a non-transparent electrode as the first electrode and a transparent electrode as the second electrode. The display device with a bottom emission configuration is preferably an organic EL display with a bottom emission configuration. The display device with a top emission configuration is preferably an organic EL display with a top emission configuration. A transparent electrode as referred to herein is an electrode having a transmittance of 30% or more at a wavelength of 550 nm. A non-transparent electrode as referred to herein is an electrode having a transmittance of less than 30% at a wavelength of 550 nm. In the case of an electrode having a multilayer structure, it is classified as transparent or non-transparent based on the overall transmittance of the multilayer electrode measured at a wavelength of 550 nm. To realize various characteristics in an integrated manner, it is also preferable that the first electrode is a non-transparent electrode having a multilayer structure. For example, it may be a good method to use a non-transparent electrode having a multilayer structure as the first electrode wherein the surface of the first electrode that faces the substrate is provided with a base layer designed to improve adhesion or corrosion resistance or a reflection adjustment layer designed to adjust reflection. In the case of an electrode having a single layer structure, the terms “transparent” and “non-transparent” used for the transparent conductive oxide film layer, non-transparent conductive layer, non-transparent conductive metal layer, transparent conductive layer, and transparent conductive metal layer, which will be described later, means whether they have a transmittance of 30% or more or a transmittance of less than 30% at a wavelength of 550 nm, respectively, as described above. On the other hand, in the case of an electrode having a multilayer structure, “being transparent” means that the overall transmittance at a wavelength of 550 nm is 30% or more, and “being non-transparent” means that at least one of the layers constituting the multilayer structure has a transmittance of less than 30%. In other words, if the multilayer structure includes at least one non-transparent conductive layer or non-transparent conductive metal layer, any electrode having this multilayer structure is a non-transparent electrode. In the case of an electrode having a multilayer structure that is classified as transparent, it is preferable that each layer constituting the multilayer structure has a transmittance of 70% or more at a wavelength of 550 nm.

It is preferable for the display device according to the present invention to have a plurality of first electrode parts in a plan view. The first electrode described above, when seen in a plan view, corresponds to a first electrode part. It is preferable for the display device according to the present invention to have a second electrode part in a plan view. The second electrode described above, when seen in the plan view, corresponds to a second electrode part. It is more preferable for the display device according to the present invention to have a plurality of second electrode parts. In the case where the display device according to the present invention has a plurality of first electrode parts and in the case where the display device according to the present invention has a plurality of second electrode parts, it is preferable for the first electrode parts and the second electrode parts, respectively, to have a closed polygon shape, a shape of a closed polygon in which at least a side and/or an apex is replaced with an arc, or a closed shape formed of arcs. Preferable examples and preferable features related to such a closed polygon shape, a shape of a closed polygon in which at least a side and/or an apex is replaced with an arc, and a closed shape formed of arcs will be described later.

### <Transparent Conductive Oxide Film Layer, Non-Transparent Conductive Layer, Non-Transparent Conductive Metal Layer, Transparent Conductive Layer, and Transparent Conductive Metal Layer>

It is preferable for the display device according to the present invention to have, as the outermost layer of the first electrode that faces the light emitting layer, a transparent conductive oxide film layer, more preferably a transparent conductive oxide film layer containing In, Sn, Zn, Al, or Ga as the main constituent element, and still more preferably a transparent conductive oxide film layer containing indium as the main constituent element. For a transparent conductive oxide film layer, the term “main constituent element” refers to the element other than oxygen that accounts for the largest proportion among the constituent elements of the transparent conductive oxide film layer. The transparent conductive oxide film layer containing In, Sn, Zn, Al, or Ga as the main constituent element is preferably of an ITO type or an IZO type, of which ITO type is more preferable, from the perspective of realizing lower voltage driving of the light emission characteristics and improved light emission luminance. From the perspective of realizing lower voltage driving of the light emission characteristics and improved reliability of the light emitting element, the transparent conductive oxide film layer is preferably an amorphous transparent conductive oxide film layer, more preferably an amorphous transparent conductive oxide film layer containing indium as the main constituent element. On the other hand, from the perspective of improving the light emission luminance, the transparent conductive oxide film layer is preferably a polycrystalline transparent conductive oxide film layer, more preferably a polycrystalline transparent conductive oxide film layer containing indium as the main constituent element. It is preferable for the display device according to the present invention to have a first electrode having a multilayer structure and have such a transparent conductive oxide film layer as the outermost layer of the first electrode that faces the light emitting layer, regardless of whether it is a transparent electrode or a non-transparent electrode. The first electrode has a single layer structure or a multilayer structure. When the first electrode has a single layer structure, it is preferable for the first electrode to be a transparent electrode. When the first electrode has a multilayer structure, it is preferable for the first electrode to be a transparent electrode or a non-transparent electrode. When the first electrode is used as an anode, it is preferable for the first electrode to be of an ITO type or an IZO type, of which ITO type is more preferable, from the perspective of realizing lower voltage driving of the light emission characteristics and improved light emission luminance. When the first electrode is a transparent electrode, it is preferable for the transmittance at a wavelength of 550 nm to be adjusted by changing the thickness of the first electrode.

When the first electrode is a non-transparent electrode having a single layer structure, the first electrode is a non-transparent conductive layer. When the first electrode is a non-transparent electrode having a multilayer structure, the first electrode has a non-transparent conductive layer. In the first electrode, it is preferable that at least one layer other than the outermost layer that faces the light emitting layer is a non-transparent conductive layer. When the first electrode is a non-transparent electrode, it is preferable for the non-transparent conductive layer to be a non-transparent conductive metal layer containing a metal element regardless of whether it has a single layer structure or a multilayer structure. In the case where the first electrode is used as an anode, furthermore, it is preferable for the non-transparent conductive metal layer to contain Ag, Cu, Au, Ti, Al, Ni, Mo, or Cr as the main constituent element from the perspective of realizing lower voltage driving of the light emission characteristics, improved light emission luminance, improved reliability of the light emitting element, and improved corrosion resistance, and it more preferably contains Ag, Cu, Au, Ti, or Al as the main constituent element, and still more preferably contains silver or copper as the main constituent element. The non-transparent conductive metal layer preferably further contains one or more selected from the group consisting of In, Sn, Zn, Al, Ga, Pd, Cu, Bi, Nd, Ni, Mn, Na, K, Mg, Ca, C, and Si as elements different from the main constituent element, and more preferably contains one or more selected from the group consisting of In, Sn, Al, Pd, Cu, Na, K, Mg, Ca, and Si. For the non-transparent conductive metal layer, the term “main constituent element” refers to the element that accounts for the largest proportion among the constituent elements of the non-transparent conductive metal layer. In the case where the first electrode is a non-transparent electrode, it is preferable for the transmittance at a wavelength of 550 nm to be adjusted by changing the thickness of the first electrode.

It is preferable for the display device according to the present invention to have a transparent conductive metal layer as the outermost layer of the second electrode that faces the light emitting layer, and it is more preferably a transparent conductive metal layer containing Li, Mg, Ag, Cu, Au, Ti, or Al as the main constituent element, and still more preferably a transparent conductive metal layer containing magnesium or silver as the main constituent element. For the transparent conductive metal layer, the term “main constituent element” refers to the element that accounts for the largest proportion among the constituent elements of the transparent conductive metal layer. The transparent conductive metal layer containing Li, Mg, Ag, Cu, Au, Ti, or Al as the main constituent element is preferably of a LiAg type or a MgAg type, more preferably a MgAg type, from the perspective of realizing improved light emission luminance. It is preferable for the display device according to the present invention to have a second electrode having a multilayer structure and have such a transparent conductive metal layer as the outermost layer of the second electrode that faces the light emitting layer, regardless of whether it is a transparent electrode or a non-transparent electrode. In the case where the second electrode is used as a cathode, it is preferable for the transparent conductive metal layer or the non-transparent conductive metal layer to contain Li, Mg, Ag, Cu, Au, Ti, or Al as the main constituent element from the perspective of realizing improved light emission luminance and improved reliability of the light emitting element. From the perspective of realizing improved light emission luminance, it is preferable for the transparent conductive metal layer is of a LiAg type or a MgAg type, more preferably of a MgAg type. In the case where the second electrode is a transparent electrode or a non-transparent electrode, it is preferable for the transmittance at a wavelength of 550 nm to be adjusted by changing the thickness of the second electrode.

### <Amorphous Transparent Conductive Oxide Film Layer; Non-Transparent Conductive Metal Layer Containing Specific Metals>

From the perspective of realizing lower voltage driving of the light emission characteristics and improved light emission luminance, the first electrode is a non-transparent electrode having a multilayer structure and the first electrode has a non-transparent conductive metal layer and preferably has a non-transparent conductive metal layer in which at least one of the layers other than the outermost layer of the first electrode that faces the light emitting layer contains silver or copper as the main constituent element. If it has a non-transparent conductive metal layer containing silver or copper as the main constituent element, it significantly enhances the effect of realizing lower voltage driving of the light emission characteristics and improved light emission luminance because silver and copper have good low resistance characteristics.

If the display device according to the present invention is configured in this way, it is preferable, from the perspective of realizing lower voltage driving of the light emission characteristics and improved light emission reliability, that in the display device according to the present invention, the first electrode has a transparent conductive oxide film layer and a non-transparent conductive metal layer and has, as the outermost layer of the first electrode that faces the light emitting layer, a transparent conductive oxide film layer containing indium as the main constituent element. It is inferred that if it has, as the outermost layer of the first electrode that faces the light emitting layer, a transparent conductive oxide film layer containing indium as the main constituent element, the adjustment of the difference in the work function can significantly enhance the effect of realizing lower voltage driving of the light emission characteristics and improved reliability of the light emitting element.

From the perspective of realizing lower voltage driving of the light emission characteristics, improved light emission luminance, and improved reliability of the light emitting element, it is preferable that the display device according to the present invention has a top emission configuration and that the first electrode is a non-transparent electrode having a multilayer structure wherein the first electrode has a transparent conductive oxide film layer and a non-transparent conductive metal layer, has, as the outermost layer of the first electrode that faces the light emitting layer, an amorphous transparent conductive oxide film layer containing indium as the main constituent element, and has, as at least one of the layers other than the outermost layer of the first electrode that faces the light emitting layer, a non-transparent conductive metal layer containing silver or copper as the main constituent element. As described above, this significantly enhances the effect of realizing lower voltage driving of the light emission characteristics and improved light emission luminance because the silver or copper component contained in the non-transparent conductive metal layer have good low resistance characteristics. In addition, it is inferred that the adjustment of the difference in the work function by the indium component contained in the transparent conductive oxide film layer can significantly enhance the effect of realizing lower voltage driving of the light emission characteristics and improved reliability of the light emitting element. Furthermore, the amorphous transparent conductive oxide film layer serves to suppress the occurrence of defects while the top emission configuration serves to reduce stray light and scattered light within the element. It is inferred that this enables the suppression of increase in driving voltage required to ensure light emission luminance, thus significantly enhancing the effect of improving reliability of the light emitting element.

It is inferred that if an amorphous transparent conductive oxide film layer is present as the outermost layer of the first electrode, occurrence of defects and formation of protrusions on the surface of the first electrode are suppressed to significantly enhance the effect of realizing improved reliability of the light emitting element. In addition, it is inferred that surface modification with the sulfur, chlorine, and bromine elements occurs easily in the amorphous conductive oxide film layer present as the outermost layer, and the adjustment of the difference in the work function can significantly enhance the effect of realizing lower voltage driving of the light emission characteristics and improved reliability of the light emitting element. It is also inferred that if it has a non-transparent conductive metal layer containing silver or copper as the main constituent element, the light extraction efficiency is increased due to the high reflectance characteristics of these metals, significantly enhancing the effect of realizing lower voltage driving of the light emission characteristics and improved light emission luminance. It is also inferred that the conductivity is increased due to the low resistance characteristics of these metals, significantly enhancing the effect of realizing lower voltage driving of the light emission characteristics and improved light emission luminance. The presence of an amorphous transparent conductive oxide film layer and a non-transparent conductive metal layer containing silver or copper as the main constituent element significantly enhances the effect of realizing lower voltage driving of the light emission characteristics, improved reliability of the light emitting element, improved light emission luminance, and improved light extraction efficiency. This is particularly desirable for display devices with top emission configurations.

For the first electrode, the total content of the silver element and the copper element in the non-transparent conductive metal layer containing silver or copper as the main constituent element is preferably 95 mass % or more, more preferably 96 mass % or more, and still more preferably 97 mass % or more, from the perspective of realizing lower voltage driving of the light emission characteristics and improved light emission luminance due to increased reflectance and decreased resistivity. On the other hand, the total content of the silver element and the copper element is preferably 99.5 mass % or less, more preferably 99 mass % or less, and still more preferably 98.5 mass % or less, from the perspective of realizing lower voltage driving of the light emission characteristics and improved light emission luminance due to increased reflectance and decreased resistivity.

Such a non-transparent conductive metal layer containing silver as the main constituent element present in the first electrode preferably further contains copper and/or palladium, more preferably copper and palladium, as elements different from the main constituent element. Similarly, such a non-transparent conductive metal layer containing copper as the main constituent element present in the first electrode preferably further contains silver and/or palladium, more preferably silver and palladium, as elements different from the main constituent element. It is inferred that the inclusion of these elements serves to increase the conductivity of the first electrode to enhance more significantly the effect of realizing lower voltage driving of the light emission characteristics and improved light emission luminance. It is also inferred that the heat resistance and oxidation resistance of the first electrode are increased very largely, thereby significantly enhancing the effect of improving the reliability of the light emitting element.

In the first electrode, the total content of the copper element and the palladium element in the non-transparent conductive metal layer containing silver as the main constituent element is preferably 0.1 mass % or more, more preferably 0.5 mass % or more, and still more preferably 1.0 mass % or more, from the perspective of realizing lower voltage driving of the light emission characteristics, improved light emission luminance, and improved reliability of the light emitting element. On the other hand, the total content of the copper element and the palladium element is preferably 5 mass % or less, more preferably 4 mass % or less, and still more preferably 3 mass % or less, from the perspective of realizing lower voltage driving of the light emission characteristics, improved light emission luminance, and improved reliability of the light emitting element. In the first electrode, furthermore, the total content of the silver element and the palladium element in the non-transparent conductive metal layer containing copper as the main constituent element is preferably 0.1 mass % or more, more preferably 0.5 mass % or more, and still more preferably 1.0 mass % or more, from the perspective of realizing lower voltage driving of the light emission characteristics, improved light emission luminance, and improved reliability of the light emitting element. On the other hand, the total content of the silver element and the palladium element is preferably 5 mass % or less, more preferably 4 mass % or less, and still more preferably 3 mass % or less, from the perspective of realizing lower voltage driving of the light emission characteristics, improved light emission luminance, and improved reliability of the light emitting element.

In the case where the display device according to the present invention includes a first electrode that is a non-transparent electrode having a multilayer structure wherein the first electrode has a transparent conductive oxide film layer and a non-transparent conductive metal layer, has, as the outermost layer of the first electrode that faces the light emitting layer, an amorphous transparent conductive oxide film layer containing indium as the main constituent element and has, as at least one of the layers other than the outermost layer of the first electrode that faces the light emitting layer, a non-transparent conductive metal layer containing silver or copper as the main constituent element, thereby forming a top emission configuration, it is preferable that in the display device according to the present invention, the non-transparent conductive metal layer containing silver or copper as the main constituent element further contains one or more selected from the group consisting of In, Sn, Zn, Al, Ga, Bi, Nd, Ni, Mn, Na, K, Mg, Ca, C, and Si as elements different from the main constituent element, more preferably contains one or more selected from the group consisting of In, Sn, Al, Na, K, Mg, Ca, and Si, and still more preferably contains one or more selected from the group consisting of Na, K, Mg, and Ca. It is inferred that the inclusion of these elements serves to increase the conductivity of the first electrode to enhance more significantly the effect of realizing lower voltage driving of the light emission characteristics and improved light emission luminance. Such a non-transparent conductive metal layer containing silver as the main constituent element in the first electrode preferably contains copper and/or palladium and further contains these elements. Similarly, such a non-transparent conductive metal layer containing copper as the main constituent element in the first electrode preferably contains silver and/or palladium and further contains these elements.

In the first electrode, the total content of the elements of In, Sn, Zn, Al, Ga, Bi, Nd, Ni, Mn, Na, K, Mg, Ca, C, and Si in the non-transparent conductive metal layer containing silver or copper as the main constituent element is preferably 0.1 mass % or more, more preferably 0.5 mass % or more, from the perspective of realizing lower voltage driving of the light emission characteristics and improved light emission luminance. On the other hand, the total content of the elements of In, Sn, Zn, Al, Ga, Bi, Nd, Ni, Mn, Na, K, Mg, Ca, C, and Si is preferably 3 mass % or less, more preferably 2 mass % or less, from the perspective of realizing lower voltage driving of the light emission characteristics and improved light emission luminance.

### <Pixel Separation Layer; Pixel Separation Layer Part in Plan View>

The display device according to the present invention has a pixel separation layer. The pixel separation layer is a layer that separates adjacent pixel parts and defines the region of each pixel part. It is preferable that the pixel separation layer is a layer that is designed to separate regions on the first electrode. It should be noted that when the display device according to the present invention includes a pixel size control layer which will be described later, the pixel size control layer also acts to separate adjacent pixel parts and serves as a layer that defines the regions and dimensions of each pixel part. It is preferable that the pixel separation layer is a cured film of a photosensitive composition, more preferably a cured film of a photosensitive composition containing a colorant, and still more preferably a cured film of a photosensitive composition containing a black colorant. It is preferable that the pixel separation layer is a layer that is designed to overlap partly with the first electrode which is described above. If they are configured in this way, it is possible to realize insulation between the first electrode and the second electrode in any desired pixel, thereby preventing non-lighting of the pixel from occurring due to short-circuiting between the first electrode and the second electrode. It also serves to realize insulation between the first electrode in any desired pixel and the first electrode in an adjacent pixel, thereby preventing non-lighting of the pixels from occurring due to short-circuiting between the first electrodes.

The pixel separation layer is preferably black in the visible light wavelength range due to coloring by a component such as resin in the photosensitive composition, and more preferably it is black due to coloring by a thermal color developer and/or oxidative color developer etc. in addition to coloring by a component such as resin. The pixel separation layer is black more preferably due to coloring by a plurality of colorants, and it is black still more preferably due to coloring by a thermal color developer and/or oxidative color developer etc. in addition to coloring by a plurality of colorants. It is particularly preferable that the pixel separation layer is black due to black colorant. Here, the term “coloring” refers to having a color of red, orange, yellow, green, blue, or purple.

It is preferable that the display device according to the present invention includes a pixel separation layer part having a plurality of opening parts in a plan view. The pixel separation layer described above corresponds to a pixel separation layer part when seen in a plan view. For the display device according to the present invention, it is preferable that the shape of a pixel part which will be described later is analogous or similar to the shape of the opening part in the pixel separation layer part and it is more preferably identical to the shape of the opening part in the pixel separation layer part. In the case where the display device according to the present invention has a pixel size control layer part which will be described later in a plan view, it is preferable that the shape of the pixel part which will be described later is analogous or similar to the shape of the opening part in the pixel size control layer part and it is more preferable that it is identical to the shape of the opening part in the pixel size control layer part.

It is preferable that the pixel part has a closed polygon shape, a shape of a closed polygon in which at least a side and/or an apex is replaced with an arc, or a closed shape formed of arcs. Examples of a closed polygon include a triangle, equilateral triangle, isosceles triangle, right angled triangle, quadrilateral, square, rhombus, rectangle, trapezoid, right trapezoid, and parallelogram. Examples of a shape of a closed polygon in which at least a side and/or an apex is replaced with an arc include a triangle, equilateral triangle, isosceles triangle, right angled triangle, quadrilateral, square, rhombus, rectangle, trapezoid, right trapezoid, or parallelogram in which at least a side and/or an apex is replaced with an arc. Examples of a closed shape formed of arcs include a circle, perfect circle, and ellipse. It is preferable that the pixel part has one of the following shapes: quadrilateral, square, rhombus, and rectangle; a shape of a quadrilateral, square, rhombus, or rectangle in which at least a side and/or an apex is replaced with an arc; and a circle and perfect circle. From the perspective of realizing suppressed external light reflection, lower voltage driving of the light emission characteristics, and improved light emission luminance, it is preferable that the pixel part has a shape of a closed polygon in which at least a side and/or an apex is replaced with an arc. It is inferred that as the shape of the pixel part is changed from a perfect circle by partial replacement with a straight line, the emission, in the form of surface emission, of light from the light emitting element becomes asymmetric and strengthened by the reflection and interference that occurs between the first electrode and the second electrode, thereby significantly enhancing the effect of lower voltage driving of the light emission characteristics and improved light emission luminance. Furthermore, It is inferred that as the shape of the pixel part is changed from a perfect circle by partial replacement with a straight line, the scattering of the incident external light on the surface of the pixel separation layer part becomes asymmetric and weakened by the reflection and interference that occur between the first electrode and the second electrode, thereby significantly enhancing the effect of realizing the suppression of external light reflection.

It is preferable that the shape of the undermentioned color filter layer part that overlaps with a pixel part, the shape of the opening part in the undermentioned black matrix layer part that overlaps with a pixel part, the shape of the undermentioned spacer layer part, the shape of the undermentioned overcoat layer part, and the shape of the opening part in the undermentioned overcoat layer part are a shape of a closed polygon, a shape of a closed polygon in which at least a side and/or an apex is replaced with an arc, or a closed shape formed of arcs. Preferable examples and preferable features related to such a closed polygon shape, a shape of a closed polygon in which at least a side and/or an apex is replaced with an arc, and a closed shape formed of arcs are as described above.

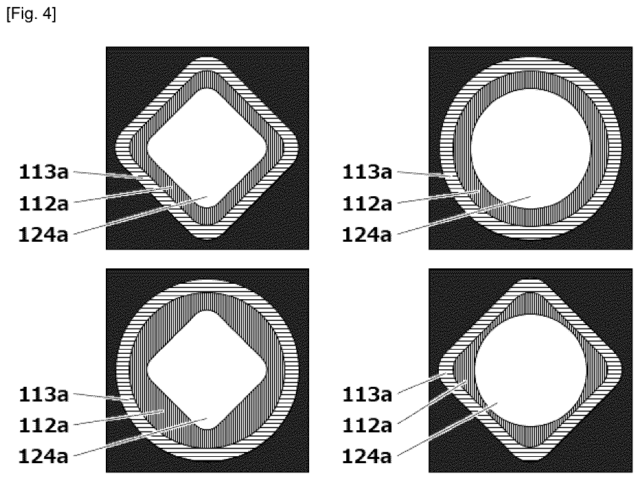

It is preferable that the shape of the undermentioned color filter layer part that overlaps with a pixel part is analogous or similar to the shape of the pixel part. It is preferable that the shape of the opening part in the undermentioned black matrix layer part that overlaps with a pixel part is analogous or similar to the shape of the pixel part. It is preferable that the shape of the color filter layer part is analogous or similar to the shape of the opening part in the black matrix layer part. It is more preferable that the shape of the pixel part, the shape of the color filter layer part, and the shape of the opening part in the black matrix layer part are analogous or similar to each other. Any one of the shape of the pixel part, the shape of the color filter layer part, and the shape of the opening part in the black matrix layer part may not be analogous or similar to the others. The shape of the pixel part, the shape of the color filter layer part, and the shape of the opening part in the black matrix layer part may be neither analogous nor similar to each other. Examples of the shape of the pixel part, the shape of the color filter layer part, and the shape of the opening part in the black matrix layer part are shown in FIG. 4.

For the shape of the pixel part, the shape of the opening part in the pixel separation layer part, the shape of the opening part in the undermentioned pixel size control layer part, the shape of the undermentioned spacer layer part, the shape of the undermentioned color filter layer part, the shape of the opening part in the undermentioned black matrix layer part, the shape of the undermentioned overcoat layer part, and the shape of the opening part in the undermentioned overcoat layer part, the pattern dimensions in the long axis direction and the pattern dimensions in the short axis direction are described below.

In the case of a closed polygon, the pattern dimension in the long axis direction refers to the length of the longest straight line among the straight lines that divide the closed polygon into two halves with line symmetry. On the other hand, the pattern dimension in the short axis direction refers to the length of the longest straight line among the straight lines that are orthogonal to the long axis direction. In the case of a shape of a closed polygon in which at least a side and/or an apex is replaced with an arc, the pattern dimension in the long axis direction refers to the length of the longest straight line among the straight lines that divide the shape of a closed polygon in which at least a side and/or an apex is replaced with an arc into two halves with line symmetry. On the other hand, the pattern dimension in the short axis direction refers to the length of the longest straight line among the straight lines that are orthogonal to the long axis direction. In the case of a closed shape formed of arcs, the pattern dimension in the long axis direction refers to the length of the longest straight line among the straight lines that divide the closed shape formed of arcs into two halves with line symmetry. On the other hand, the pattern dimension in the short axis direction refers to the length of the longest straight line among the straight lines that are orthogonal to the long axis direction. In the case of a circle, perfect circle, or ellipse, the pattern dimension in the long axis direction refers to the length of the longest diameter. On the other hand, the pattern dimension in the short axis direction refers to the diameter of the circle in the direction orthogonal to the long axis direction.

The pattern dimension of the opening parts in the pixel separation layer part and the pixel size control layer part which will be described later refer to the bottom-to-bottom length of the opening parts. The average value of the pattern dimension in the long axis direction of the opening part in the pixel separation layer part or the opening part in the pixel size control layer part is preferably 5.0 μm or more, more preferably 6.0 μm or more, still more preferably 7.0 μm or more, still more preferably 8.0 μm or more, and particularly preferably 10.0 μm or more, from the perspective of realizing suppressed external light reflection, lower voltage driving of the light emission characteristics, improved light emission luminance, and improved reliability of the light emitting element. On the other hand, the average value of the pattern dimension in the long axis direction of the opening part in the pixel separation layer part or the opening part in the pixel size control layer part which will be described later is preferably 50.0 μm or less, more preferably 40.0 μm or less, and still more preferably 35.0 μm or less, from the perspective of realizing suppressed external light reflection and improved light emission luminance. Furthermore, the average value of the pattern dimension in the long axis direction of the opening part in the pixel separation layer part or the opening part in the pixel size control layer part is preferably 30.0 μm or less, more preferably 25.0 μm or less, still more preferably 20.0 μm or less, still more preferably 17.0 μm or less, and particularly preferably 15.0 μm or less, from the perspective of realizing suppressed external light reflection, lower voltage driving of the light emission characteristics, improved light emission luminance, and improved reliability of the light emitting element.

The pattern dimension in the long axis direction of the pixel parts refers to the bottom-to-bottom length of the pixel parts. When the pattern dimension in the long axis direction of the pixel part is denoted by (CD) μm while the pattern dimension in the long axis direction of the opening part in the pixel separation layer part or the opening part in the pixel size control layer part that corresponds to the pixel part is denoted by (DL) μm, the dimension difference (ΔCD-DL) μm between (CD) μm and (DL) μm is preferably-2.0 μm or more, more preferably −1.5 μm or more, still more preferably-0.5 μm or more, and particularly preferably-0.2 μm or more. On the other hand, it is preferable that the dimension difference (ΔCD-DL) μm between (CD) μm and (DL) μm is 1.5 μm or less, more preferably 1.0 μm or less, still more preferably 0.5 μm or less, and particularly preferably 0.2 μm or less. The pattern dimension in the long axis direction of the pixel part is most preferably equal to the pattern dimension in the long axis direction of the opening part in the pixel separation layer part or the opening part in the pixel size control layer part that corresponds to the pixel part.

### <Pixel Size Control Layer; Pixel Size Control Layer Part in Plan View>

It is preferable for the display device according to the present invention to further include a pixel size control layer. The pixel size control layer is a layer that is in contact with both the pixel separation layer and the pixel part and acts to adjust the dimension of the region of each pixel part. It is preferable that the pixel size control layer is a layer designed to adjust the sizes of the regions on the first electrode that are divided by the pixel separation layer. It is preferable that the pixel size control layer is a cured film of a photosensitive composition. It is preferable that the pixel size control layer is configured to overlap with a part of the first electrode which is described above. If they are configured in this way, it allows the pattern dimensions of the opening parts that act as pixel parts to be controlled with high precision, thereby significantly enhancing the effect of improving the uniformity of pattern dimension. As a result, it serves for highly accurate control of the pattern dimension of the pixel part, the pattern dimension of the color filter layer part, and the pattern dimension of the opening part in the black matrix layer part, thereby significantly enhancing the effect of realizing suppressed external light reflection, lower voltage driving of the light emission characteristics, improved light emission luminance, and improved reliability of the light emitting element.

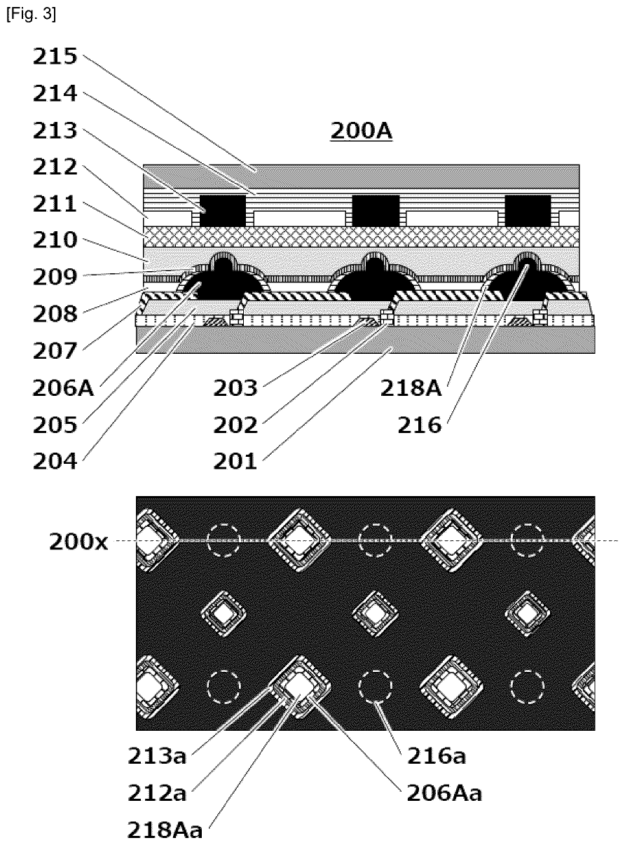

It is preferable that the display device according to the present invention further includes a pixel size control layer having a plurality of opening parts in the plan view. For the display device according to the present invention, the term “covering” refers to directly overlapping with at least partly in the z-axis direction. The pixel size control layer described above corresponds to the pixel size control layer part when seen in the plan view. FIG. 3 gives a schematic cross-sectional view and a plan view illustrating examples of a pixel separation layer having a step shape and a pixel size control layer.

### <Spacer Layer; Spacer Layer Part in Plan View>

It is preferable for the display device according to the present invention to further include a spacer layer. The spacer layer is a layer disposed above and/or below the pixel separation layer. Even when the pixel separation layer does not have a step shape, the presence of a spacer layer makes it possible to impart the function for fitting to the film parts of the pixel separation layer having a step shape. The spacer layer preferably contains a spacer layer disposed above the pixel separation layer and/or a lower spacer layer disposed below the pixel separation layer. It is preferable that the spacer layer is a cured film of a photosensitive composition. It is preferable that the spacer layer is disposed in a part of the pixel separation layer. If they are configured in this way, it allows the contact area between the pixel separation layer and the deposition mask to be reduced when forming the organic layer containing a light emitting layer. Consequently, damage to the pixel separation layer is suppressed, thereby significantly enhancing the effect of preventing a decrease in panel yield and improving the reliability of the light emitting element.

It is preferable for the display device according to the present invention to further include a spacer layer part in the plan view. The spacer layer described above corresponds to the spacer layer part when seen in the plan view. From the perspective of realizing suppressed external light reflection, it is preferable for the spacer layer part to have a shape of a closed polygon or a shape of a closed polygon in which at least a side and/or an apex is replaced with an arc. It is inferred that as the shape of the spacer layer part is changed from a perfect circle by partial replacement with a straight line, the scattering of the incident external light on the surface of the spacer layer part becomes asymmetric and weakened by the reflection and interference that occur between the first electrode and the second electrode, thereby significantly enhancing the effect of suppressing external light reflection.

### <Colorants in Pixel Separation Layer, Pixel Size Control Layer, and Spacer Layer>

In the display device according to the present invention, the pixel separation layer includes a colorant (D-DL). If it is configured in this way, it allows the pixel separation layer to act to block the incident external light, thereby significantly enhancing the effect of suppressing external light reflection. In addition, due to increased light blocking efficiency of the pixel separation layer in the visible light wavelength region and the ultraviolet region, the outgassing from the pixel separation layer etc. is suppressed and the degradation of the light emitting element is prevented, thereby significantly enhancing the effect of improving the reliability of the light emitting element. The colorant (D-DL) in the pixel separation layer is preferably a black colorant and/or a mixture of two or more colorants. The colorant (D-DL) in the pixel separation layer preferably contains a pigment and/or a dye, more preferably both a pigment and a dye.

For the display device according to the present invention, it is preferable that the pixel separation layer contains the colorant (D-DL) while the spacer layer satisfies at least one of the requirements (1) to (3) given below. For the display device according to the present invention, the spacer layer more preferably satisfies at least one of the requirements (1) and (3) given below and still more preferably satisfies at least the requirement (1) given below.
(1) The spacer layer does not contain the colorant (D-DL).
(2) The spacer layer includes the colorant (D-DL) and has an optical density of 0.0 to 0.3 per μm of the thickness of the spacer layer in the visible light wavelength.
(3) The spacer layer includes a compound (C2x-DL) having a carboxylate structure containing an indene structure and/or an aryl sulfonate structure containing an indene structure.

If they are configured in this way, it allows the pixel separation layer and the spacer layer to have a structure that is produced by a two layered film formation method using photosensitive compositions of different components or have a structure in which the spacer layer is one produced from a positive photosensitive composition. In the case where the two layered film formation method is used, it is inferred that the opening part in the first layer is to come into contact with the alkaline developer liquid again, and accordingly, this serves for the suppression of residue generation in the opening part in the pixel separation layer part or in the opening part in the pixel size control layer part, thereby significantly enhancing the effect of realizing lower voltage driving of the light emission characteristics and enhanced light emission luminance. In addition, when a negative type composition is used, the first layer, i.e. the pixel separation layer, undergoes sufficient photocuring by full-tone exposure, instead of half-tone exposure using a half-tone photomask, and accordingly, the solubility in the alkaline developer liquid is reduced significantly. Therefore, it is inferred that the first layer, i.e. the pixel separation layer, has a smooth surface with little roughness to suppress the scattering of the incident external light, significantly enhancing the effect of suppressing external light reflection. On the other hand, when the spacer layer is made of a positive photosensitive composition, the dissolution in the opening part in the alkaline solution is promoted by light exposure to suppress the generation of development residues, thereby significantly enhancing the effect of realizing lower voltage driving of the light emission characteristics and enhanced light emission luminance. Furthermore, the portion that is to become a pixel separation layer decreases significantly in solubility to the alkaline developer liquid due to the interaction between the first layer, i.e. the pixel separation layer, and the positive photosensitive composition. Therefore, it is inferred that the first layer, i.e. the pixel separation layer, has a smooth surface with little roughness to suppress the scattering of the incident external light, significantly enhancing the effect of suppressing external light reflection. In addition, the presence of the spacer layer serves to avoid damage to the pixel separation layer, thereby significantly enhancing the effect of preventing a decrease in panel yield and improving the reliability of the light emitting element. The colorant (D-DL) in the spacer layer is preferably a black colorant and/or a mixture of two or more colorants. The colorant (D-DL) in the spacer layer preferably contains a pigment and/or a dye, more preferably both a pigment and a dye.

Next, colorants that can be contained in one or more layers selected from the group consisting of the pixel separation layer, the pixel size control layer, and the spacer layer (hereinafter referred to as “pixel separation layer etc.”) are described collectively. From the perspective of realizing suppressed external light reflection and improved reliability of the light emitting element, it is preferable that the colorant (D-DL) in the pixel separation layer etc. contains a black pigment and/or a mixture of two or more color pigment. From the perspective of realizing suppressed external light reflection and improved reliability of the light emitting element, it is preferable that the colorant (D-DL) in the pixel separation layer etc. contains a black dye and/or a mixture of two or more coloring dyes. It is preferable that the colorant (D-DL) in the pixel separation layer etc. is the colorant (D) which will be described later.

It is preferable that the pixel separation layer etc. contain a black pigment. If they are configured in this way, it allows the pixel separation layer etc. to act to block the incident external light, thereby significantly enhancing the effect of suppressing external light reflection. In addition, due to increased light blocking efficiency of the pixel separation layer etc. in the visible light wavelength region and the ultraviolet region, the outgassing from the pixel separation layer etc. is suppressed and the degradation of the light emitting element is prevented, thereby significantly enhancing the effect of improving the reliability of the light emitting element.

The pixel separation layer etc. preferably contain an organic black pigment and/or a mixture of two or more color pigments, wherein the organic black pigment contains one or more selected from the group consisting of benzofuranone based black pigments, perylene based black pigments, and azo based black pigments and the mixture of two or more color pigments contains two or more pigments selected from the group consisting of red, orange, yellow, green, blue, and purple pigments.

The organic black pigment preferably contains a benzofuranone based black pigment and/or a perylene based black pigment, more preferably a benzofuranone based black pigment. The mixture of two or more color pigments preferably contains one or more pigments selected from the group consisting of anthraquinone based pigments, diketopyrrolopyrrole based pigments, perylene based pigments, isoindoline based pigments, isoindolinone based pigments, imidazolone based pigments, quinacridone based pigments, pyranthrone based pigments, phthalocyanine based pigments, and indanthrone based pigments, and dioxazine based pigments, and more preferably contains one or more pigments selected from the group consisting of perylene based pigments, imidazolone based pigments, and indanthrone based pigments. If they are configured in this way, it significantly enhances the effect of realizing suppressed external light reflection, lower voltage driving of the light emission characteristics, and improved reliability of the light emitting element. It is inferred that these pigments in the pixel separation layer etc. act to increase the conductivity on the surface of the first electrode that faces the light emitting layer and corresponds to the opening part in the pixel separation layer part or the opening part in the pixel size control layer part. Accordingly, this is considered to promote lower voltage driving of the light emission characteristics. It is inferred that as a result, this ensures that a highly enhanced light emission luminance is achieved at the same driving voltage.

The benzofuranone based black pigment preferably contains at least two benzofuran-2(3H)-one structures that may share a benzene ring or at least two benzofuran-3 (2H)-one structures that may share a benzene ring, and more preferably contains a compound having a structure as represented by the general formula (161) or the general formula (162), a geometric isomer thereof, a salt thereof, or a salt of a geometric isomer thereof.

In the case where the pixel separation layer etc. in the display device according to the present invention contain an organic black pigment and/or a mixture of two or more color pigments, it is preferable that the pixel separation layer etc. contain a benzofuranone based black pigment, with the benzofuranone based black pigment preferably containing a compound having a structure as represented by the general formula (161) or the general formula (162), a geometric isomer thereof, a salt thereof, or a salt of a geometric isomer thereof. It is preferable that the benzofuranone based black pigment present in the pixel separation layer etc. is a benzofuranone based black pigment as described later. If they are configured in this way, it significantly enhancing the effect of realizing suppressed external light reflection, lower voltage driving of the light emission characteristics, and improved reliability of the light emitting element. It is inferred that the benzofuranone based black pigment present in the pixel separation layer etc. acts to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. Furthermore, as compared with common organic pigments, benzofuranone based black pigments are high in light blocking efficiency per unit mass of the pigment, significantly enhancing the effect of realizing suppressed external light reflection and improved reliability of the light emitting element. In addition, as compared with common organic pigments and inorganic pigments, benzofuranone based black pigments have higher insulating efficiency and lower dielectricity, significantly enhancing the effect of realizing improved reliability of the light emitting element.

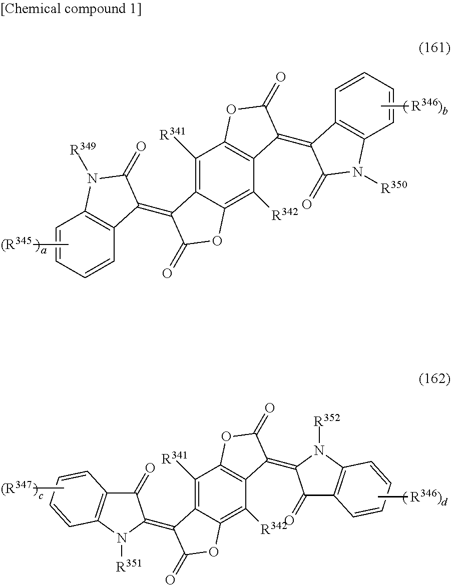

In general formulas (161) and (162), R³⁴¹ to R³⁴⁴ each independently represent a hydrogen atom, a halogen atom, or an alkyl group having 1 to 10 carbon atoms. R³⁴⁵ to R³⁴⁸ each independently represent a halogen atom, R³⁵³, COOH, COOR³⁵³, COO⁻, CONH₂, CONHR³⁵³, CONR³⁵³R³⁵⁴, CN, OH, OR³⁵³, OCOR³⁵³, OCONH₂, OCONHR³⁵³, OCONR³⁵³R³⁵⁴, NO₂, NH₂, NHR³⁵³, NR³⁵³R³⁵⁴, NHCOR³⁵³, NR³⁵³COR³⁵⁴, N═CH2, N═CHR³⁵³, N═CR353R³⁵⁴, SH, SR³⁵³, SOR³⁵³, SO₂R³⁵³, SO₃R³⁵³, SO₃H, SO₃, SO₂NH₂, SO₂NHR³⁵³, or SO₂NR³⁵³R³⁵⁴R³⁵³ and R³⁵⁴ each independently represent an alkyl group having 1 to 10 carbon atoms, a cycloalkyl group having 4 to 10 carbon atoms, an alkenyl group having 2 to 10 carbon atoms, a cycloalkenyl group having 4 to 10 carbon atoms, or an alkynyl group having 2 to 10 carbon atoms. The plurality of R³⁴⁵'s to R³⁴⁸'s may be bonded directly or form a ring through oxygen atom bridging, sulfur atom bridging, NH bridging, or NR³⁵³ bridging. R³⁴⁹ to R³⁵² each independently represent a hydrogen atom, an alkyl group having 1 to 10 carbon atoms, or an aryl group having 6 to 15 carbon atoms. Here, a, b, c, and d are each independently an integer of 0 to 4. The alkyl groups, cycloalkyl groups, alkenyl groups, cycloalkenyl groups, alkynyl groups, and aryl groups mentioned above may each have a heteroatom and may each be either a non-substitution product or a substitution product.

The perylene based black pigment preferably has a perylene structure, more preferably contains a compound having a structure as represented by any of the general formulas (164) to (166) or a salt thereof, and still more preferably contains a compound having a 3,4,9,10-perylenetetracarboxylic acid bisbenzimidazole structure, a geometric isomer thereof, a salt thereof, or a salt of a geometric isomer thereof. It is preferable that the perylene based black pigment present in the pixel separation layer etc. is a perylene based black pigment which will be described later.

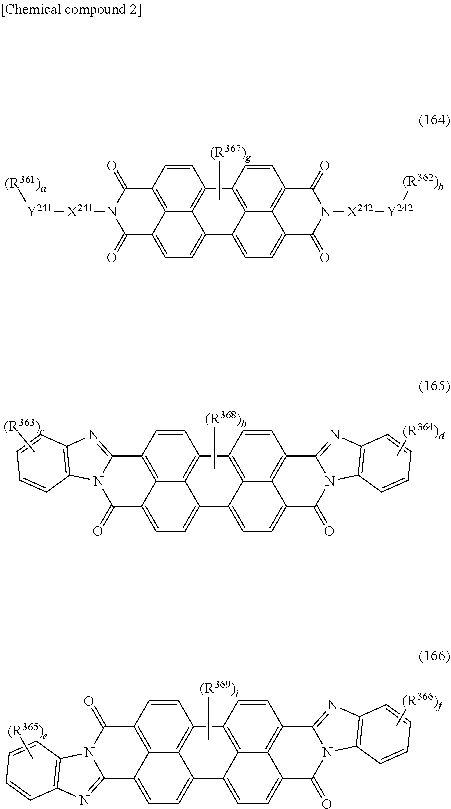

In general formulas (164) to (166), X²⁴¹ and X²⁴² each independently represent a direct bond or an alkylene group having 1 to 10 carbon atoms. Y²⁴¹ and Y²⁴² are each independently a direct bond or an arylene group having 6 to 15 carbon atoms. R³⁶¹ and R³⁶² are each independently a hydrogen atom, a hydroxyl group, an alkyl group having 1 to 10 carbon atoms, an alkoxy group having 1 to 6 carbon atoms, or an acyl group having 2 to 6 carbon atoms. R³⁶³ to R³⁶⁹ each independently represent a hydroxyl group, an alkyl group having 1 to 10 carbon atoms, an alkoxy group having 1 to 6 carbon atoms, an acyl group having 2 to 6 carbon atoms, a halogen atom, R³⁷⁰, COOH, COOR³⁷⁰, COO⁻, CONH₂, CONHR³⁷⁰, CONR³⁷⁰R³⁷¹, CN, OH, OR³⁷⁰, OCOR³⁷⁰, OCONH₂, OCONHR³⁷⁰, OCONR³⁷⁰R³⁷¹, NO₂, NH₂, NHR³⁷⁰, NR³⁷⁰R³⁷¹, NHCOR³⁷⁰, NR³⁷⁰COR³⁷¹, N═CH₂, N═CHR³⁷⁰, N═CR370R³⁷¹, SH, SR³⁷⁰, SOR³⁷⁰, SO₂R³⁷⁰, SO₃R³⁷⁰, SO₃H, SO₃⁻, SO₂NH₂, SO₂NHR³⁷⁰, or SO₂NR³⁷⁰R³⁷¹. R³⁷⁰ and R³⁷¹ each independently represent an alkyl group having 1 to 10 carbon atoms, a cycloalkyl group having 4 to 10 carbon atoms, an alkenyl group having 2 to 10 carbon atoms, a cycloalkenyl group having 4 to 10 carbon atoms, or an alkynyl group having 2 to 10 carbon atoms. The plurality of R³⁶⁷'s to R³⁶⁹'s may be bonded directly or form a ring through oxygen atom bridging, sulfur atom bridging, NH bridging, or NR³⁷⁰ bridging. Here, a and b are each independently an integer of 0 to 5. In addition, c, d, e, and f are each independently an integer of 0 to 4. Furthermore, g, h, and i are each independently an integer of 0 to 8. In the case where X²⁴¹ and X²⁴² are direct bonds and Y²⁴¹ and Y²⁴² are direct bonds, it is preferable that R³⁶¹ and R³⁶² each independently represent a hydrogen atom or an alkyl group having 1 to 10 carbon atoms, and a and b are 1. In the case where X²⁴¹ and X²⁴² are alkylene groups having 1 to 10 carbon atoms and Y²⁴¹ and Y²⁴² are direct bonds, it is preferable that R³⁶¹ and R³⁶² each independently represent a hydrogen atom, and a and b are 1. In the case where X²⁴¹ and X²⁴² are alkylene groups having 1 to 10 carbon atoms and Y²⁴¹ and Y²⁴² are arylene groups having 6 to 15 carbon atoms, it is preferable that R³⁶¹ and R³⁶² each independently represent a hydroxyl group, an alkoxy group having 1 to 6 carbon atoms, or an acyl group having 2 to 6 carbon atoms, and a and b each independently represent an integer of 0 to 5. The alkylene groups, arylene groups, alkyl groups, alkoxy groups, and acyl groups mentioned above may each have a heteroatom and may each be a non-substitution product or a substitution product.

The azo based black pigment preferably has an azo group, more preferably contains a compound having an azomethine structure and a carbazole structure or a salt thereof, and still more preferably contains a compound having a structure as represented by the general formula (168) or a salt thereof. The azo based black pigment present in the pixel separation layer etc. is preferably an azo based black pigment as described later.

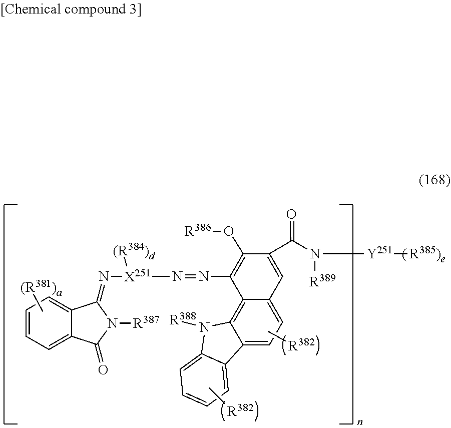

In general formula (168), X²⁵¹ is an arylene group having 6 to 15 carbon atoms. Y²⁵¹ is an arylene group having 6 to 15 carbon atoms. R³⁸¹ to R³⁸³ each independently represent a halogen atom, R³⁹⁰, COOH, COOR³⁹⁰, COO⁻, CONH₂, CONHR³⁹⁰, CONR³⁹⁰R³⁹¹, CN, OH, OR³⁹⁰, OCOR³⁹⁰, OCONH₂, OCONHR³⁹⁰, OCONR³⁹⁰R³⁹¹, NO₂, NH₂, NHR³⁹⁰, NR³⁹⁰R³⁹¹, NHCOR³⁹⁰, NR³⁹⁰COR³⁹¹, N═CH₂, N═CHR³⁹⁰, N═CR³⁹⁰R³⁹¹, SH, SR³⁹⁰, SOR³⁹⁰, SO₂R³⁹⁰, SO₃R³⁹⁰, SO₃H, SO₃⁻, SO₂NH₂, SO₂NHR³⁹⁰, or SO₂NR³⁹⁰R³⁹¹. R³⁹⁰ and R³⁹¹ each independently represent an alkyl group having 1 to 10 carbon atoms, a cycloalkyl group having 4 to 10 carbon atoms, an alkenyl group having 2 to 10 carbon atoms, a cycloalkenyl group having 4 to 10 carbon atoms, or an alkynyl group having 2 to 10 carbon atoms. The plurality of R³⁸¹'s to R³⁸³'s may be bonded directly or form a ring through oxygen atom bridging, sulfur atom bridging, NH bridging, or NR³⁹⁰ bridging. R³⁸⁴ is a halogen atom, an alkyl group having 1 to 10 carbon atoms, an alkoxy group having 1 to 6 carbon atoms, or a nitro group. R³⁸⁵ is a halogen atom, an alkyl group having 1 to 10 carbon atoms, an alkoxy group having 1 to 6 carbon atoms, an acylamino group having 2 to 10 carbon atoms, or a nitro group. R³⁸⁶ to R³⁸⁹ are each independently a hydrogen atom or an alkyl group having 1 to 10 carbon atoms. Here, a is an integer of 0 to 4; b is an integer of 0 to 2; c is an integer of 0 to 4; d and e are each independently an integer of 0 to 8; and n is an integer of 1 to 4. The arylene groups, alkyl groups, alkoxy groups, and acylamino groups mentioned above may each have a heteroatom and may each be a non-substitution product or a substitution product. It is preferable that the primary particle diameter and the average primary particle diameter of the pigment present in the pixel separation layer etc. are 20 to 150 nm. From the perspective of improving the reliability of the light emitting element, the primary particle diameters and the average primary particle diameter of the pigment present in the pixel separation layer etc. are preferably 20 nm or more, more preferably 30 nm or more, still more preferably 40 nm or more, still more preferably 50 nm or more, and particularly preferably 60 nm or more. On the other hand, from the perspective of realizing suppressed external light reflection and improved reliability of the light emitting element, the primary particle diameters and the average primary particle diameter of the pigment present in the pixel separation layer etc. are preferably 150 nm or less, more preferably 120 nm or less, still more preferably 100 nm or less, still more preferably 90 nm or less, and particularly preferably 80 nm or less. The primary particle diameters of a pigment are defined as the long axis diameter of the primary particles of the pigment.

The primary particle diameters of the pigment in the pixel separation layer etc. can be measured by slicing the pixel separation layer etc. to prepare a thin specimen for measurement, polishing it by ion milling treatment to create a cross section with enhanced smoothness, observing and photographing positions in the depth range of 0.2 to 0.8 μm from the surface of the pixel separation layer etc. using a transmission electron microscope (hereinafter TEM) at a magnification of 50,000 times, and analyzing the image with image analysis software for particle size distribution (Mac-View, manufactured by MOUNTECH Co., Ltd.). Then, the average primary particle diameter of the pigment present in the pixel separation layer etc. can be determined by photographing and analyzing the cross section of the specimen, and calculating the average of measured diameters of 30 primary particles in the pixel separation layer etc. Furthermore, observation by a transmission electron microscopy-energy dispersive X-ray spectroscopy (hereinafter TEM-EDX) serves to identify the elements constituting the particles.

It is preferable that the pixel separation layer etc. contains an organic black dye and/or a mixture of two or more coloring dyes, wherein the black dye contains an azo based black dye, and the mixture of two or more coloring dyes contains two or more selected from the group consisting of red, orange, yellow, green, blue, and purple dyes.

The black dye is preferably an azo based black dye. Preferable examples of the black dye include Solvent Blacks 27-47, of which Solvent Blacks 27, 29, and 34 are still more preferred (all numbers show C. I. numbers). Examples of black dye products include VALIFAST (registered trademark) Black 3804 (Solvent Black 34), 3810 (Solvent Black 29), 3820 (Solvent Black 27), 3830 (Solvent Black 27), and NUBIAN (registered trademark) Black TN-870 (Solvent Black 7) (all manufactured by Orient Chemical Industries, Co., Ltd.). The mixture of two or more coloring dyes preferably includes one or more dyes selected from the group consisting of squarylium dyes, xanthene dyes, triarylmethane dyes, and phthalocyanine dyes, more preferably includes xanthene dyes and/or triarylmethane dyes, and still more preferably includes xanthene dyes. If they are configured in this way, it significantly enhancing the effect of realizing suppressed external light reflection, lower voltage driving of the light emission characteristics, and improved reliability of the light emitting element. It is inferred that these dyes present in the pixel separation layer etc. act to increase the conductivity on the surface of the first electrode that faces the light emitting layer and corresponds to the opening part in the pixel separation layer part or the opening part in the pixel size control layer part. Accordingly, this is considered to promote lower voltage driving of the light emission characteristics. It is inferred that as a result, this ensures that a highly enhanced light emission luminance is achieved at the same driving voltage.

For the display device according to the present invention, it is preferable that the pixel separation layer etc. include the colorant (D-DL) and further includes a compound having a structure derived from a thermal color developer and/or a compound having a structure derived from an oxidative color developer. If they are configured in this way, it serves significantly for ensuring suppressed external light reflection and improved reliability of the light emitting element.

Such a compound having a structure derived from a thermal color developer is preferably a compound having a structure resulting from structural change or decomposition of a thermal color developer caused by heating in an inert atmosphere, and more preferably it is a compound having a quinone structure and/or a quinoid structure. It is still more preferable that such a compound having a quinone structure and/or a quinoid structure contains a compound (Q1) and/or a compound (Q2) as specified below. The inert atmosphere is preferably a nitrogen, helium, neon, argon, krypton, or xenon atmosphere, a gas atmosphere containing 1 to less than 10,000 ppm (0.0001 to 1 mass %) of oxygen, or vacuum.

(Q1) a compound having a quinone structure and/or a quinoid structure and also having an aromatic structure

(Q2) a compound having two or more quinone structures and/or two or more quinoid structures

Such a compound having a structure derived from an oxidative color developer is preferably a compound having a structure resulting from structural change or decomposition of an oxidative color developer caused by heating in a gas atmosphere containing oxygen, and more preferably it is a compound having a quinone structure and/or a quinoid structure. It is still more preferable that such a compound having a quinone structure and/or a quinoid structure contains a compound (Q1) and/or a compound (Q2) as specified above. The gas atmosphere containing oxygen is preferably air, an oxygen atmosphere, or a gas atmosphere containing 10,000 ppm (1 mass %) or more of oxygen.

### <Inorganic Particles in Pixel Separation Layer, Pixel Size Control Layer, and Spacer Layer; Silica Particles>

Inorganic particles and silica particles in the pixel separation layer etc. are described collectively below. It is preferable that the pixel separation layer etc. contain inorganic particles. If they are configured in this way, the robust structure of the inorganic particles in the pixel separation layer etc. acts to significantly improve the heat resistance of the inorganic particles in the pixel separation layer etc. and serves to suppress the outgassing from the pixel separation layer etc. As a result, the degradation of the light emitting element is suppressed, accordingly significantly enhancing the effect of realizing improved reliability of the light emitting element. The inorganic particles present in the pixel separation layer etc. is preferably the inorganic particles (H) which will be described later.

The inorganic particles present in the pixel separation layer etc. preferably contain Si, Al, Ti, V, Zn, Zr, Nb, Sn, Li, Cr, Mn, Fe, Co, Ni, Cu, Sr, Ag, Ba, La, Ce, Ta, W, or Re as the main constituent element, more preferably contain silicon, aluminum, titanium, vanadium, chromium, iron, cobalt, copper, zinc, zirconium, niobium, tin, or cerium as the main constituent element, and still more preferably contain silicon as the main constituent element. The term “the main constituent element in the inorganic particles” refers to the element that accounts for the largest proportion among the constituent elements of the inorganic particles. Among the elements listed above, the mass of any one of them is focused on in making a decision. If any of these elements is present as the main constituent element, the outgassing from the pixel separation layer etc. is suppressed, accordingly significantly enhancing the effect of realizing improved reliability of the light emitting element. The inorganic particles present in the pixel separation layer etc. are preferably silica particles, alumina particles, titania particles, vanadium oxide particles, chromium oxide particles, iron oxide particles, cobalt oxide particles, copper oxide particles, zinc oxide particles, zirconium oxide particles, niobium oxide particles, tin oxide particles, or cerium oxide particles, of which silica particles are more preferable.

It is more preferable that the pixel separation layer etc. contain silica particles. If they are configured in this way, the degradation of the light emitting element is suppressed, accordingly significantly enhancing the effect of realizing improved reliability of the light emitting element, as in the case of the inorganic particles present in the pixel separation layer etc. It is inferred that this also acts to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. Furthermore, the silica particles present in the pixel separation layer etc. work to reduce the reflection and scattering of the incident external light on the surface of the pixel separation layer etc., accordingly significantly enhancing the effect of realizing suppressed external light reflection. The silica particles present in the pixel separation layer etc. are preferably the silica particles (H1) which will be described later.

It is preferable that the primary particle diameters and the average primary particle diameter of the silica particles present in the pixel separation layer etc. are 5 to 50 nm. From the perspective of improving the reliability of the light emitting element, the primary particle diameters and the average primary particle diameter of the silica particles present in the pixel separation layer etc. are preferably 5 nm or more, more preferably 7 nm or more, and still more preferably 10 nm or more. On the other hand, from the perspective of realizing suppressed external light reflection and improved reliability of the light emitting element, the primary particle diameters and the average primary particle diameter of the silica particles present in the pixel separation layer etc. are preferably 50 nm or less, more preferably 40 nm or less, still more preferably 30 nm or less, still more preferably 25 nm or less, particularly preferably 20 nm or less, and most preferably 15 nm or less. The primary particle diameter of a silica particle is defined as the long axis diameter of a primary particle of silica. It should be noted that silicon dioxide contained in surface treatment agents or cover layers present in an organic pigment or inorganic pigment is not regarded as silica particles regardless of their primary particle diameter and aspect ratio.

The primary particle diameter and the aspect ratio of a silica particle in the pixel separation layer etc. can be measured by slicing the pixel separation layer etc. to prepare a thin specimen for measurement, polishing it by ion milling treatment to create a cross section with enhanced smoothness, observing and photographing positions in the depth range of 0.2 to 0.8 μm from the surface of the pixel separation layer etc. using a TEM at a magnification of 50,000 times, and analyzing the image with image analysis software for particle size distribution (Mac-View, manufactured by MOUNTECH Co., Ltd.). Then, the average primary particle diameter of the silica particle present in the pixel separation layer etc. can be determined by photographing and analyzing the cross section of the specimen, and calculating the average of measured diameters of 30 primary particles of silica in the pixel separation layer etc. In addition, the elements constituting the particles can be analyzed based on observations made by TEM-EDX, making it possible to identify the silica particles in the pixel separation layer, etc.

The pixel separation layer etc. may not only contain silica particles having primary particle diameters or average primary particle diameter of 5 to 50 nm, but also contain silica particles having primary particle diameters or average primary particle diameter of less than 5 nm and/or silica particles having primary particle diameters or average primary particle diameter of more than 50 nm.

It is preferable that the silica particles in the pixel separation layer etc. have functional groups on their surfaces. Preferable examples of the functional groups present on the surfaces of the silica particles include reaction residues of surface modifying groups containing radical polymerizable groups, reaction residues of surface modifying groups containing thermal reactive groups, silanol groups, alkoxysilyl groups, alkylsilyl groups, dialkylsilyl groups, trialkylsilyl groups, phenylsilyl groups, and diphenylsilyl groups, of which reaction residues of surface modifying groups containing radical polymerizable groups and reaction residues of surface modifying groups containing thermal reactive groups are more preferable from the perspective of suppressing external light reflection, enabling lower voltage driving of the light emission characteristics, improving the light emission luminance, and improving the reliability of the light emitting elements.

Preferable examples of the radical polymerizable groups include styryl group, cinnamoyl group, maleimide group, nadimide group, (meth)acryloyl group, vinyl group, and allyl group. Preferable examples of the thermal reactive groups include alkoxymethyl group, methylol group, epoxy group, oxetanyl group, and blocked isocyanate group.

From the perspective of improving the reliability of the light emitting element, the silica particles present in the pixel separation layer etc. preferably contain silica particles containing the sodium element. The sodium element may exist in the form of, for example, ion (Na+) or salt with a silanol group (Si—ONa). The content of the sodium element in all silica particles present in the pixel separation layer etc. is preferably 1 ppm or more, more preferably 5 mass ppm or more, still more preferably 10 mass ppm or more, and particularly preferably 50 mass ppm or more. Furthermore, from the perspective of improving the reliability of the light emitting element, it is preferably 100 mass ppm or more, more preferably 300 mass ppm or more, and still more preferably 500 mass ppm or more. On the other hand, the content of the sodium element in all silica particles present in the pixel separation layer etc. is preferably 10,000 mass ppm or less, more preferably 7,000 mass ppm or less, still more preferably 5,000 mass ppm or less, still more preferably 3,000 mass ppm or less, and particularly preferably 1,000 mass ppm or less. Silica particles containing the sodium element can be produced by reacting sodium silicate, which is a strong alkali, as source of silicon with a mineral acid, which is a strong acid, under alkaline conditions. If a cross section of a primary particle of silica is observed and analyzed by the aforementioned TEM-EDX, the sodium element present in a silica particle can be detected in the central part, which corresponds to the intersection of the long axis and the short axis.

### <Resin in Pixel Separation Layer, Pixel Size Control Layer, and Spacer Layer>

Resin in the pixel separation layer etc. are described collectively below. It is preferable that the pixel separation layer etc. contain the resin (A1-DL) and/or the resin (A3-DL) which are specified below.

Resin (A1-DL): a resin having a structural unit containing one or more selected from the group consisting of imide structure, amide structure, oxazole structure, and siloxane structure Resin (A3-DL): a resin having a structural unit containing a phenolic hydroxyl group

If they are configured in this way, it significantly enhances the effect of realizing suppressed external light reflection, lower voltage driving of the light emission characteristics, improved light emission luminance, and improved reliability of the light emitting element. This is inferred to be because the resin (A1-DL) and (A3-DL) resin in the pixel separation layer etc. absorb light in the visible wavelength range, thereby significantly enhancing the effect of suppressing the external light reflection. Furthermore, it is inferred that the resin (A1-DL) and (A3-DL) resin in the pixel separation layer etc. enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. In addition, it is inferred that the high heat resistance of the imide structure, amide structure, oxazole structure, or siloxane structure in the resin (A1-DL) or the aromatic skeleton in the resin (A3-DL) serves to suppress the outgassing from the pixel separation layer etc., accordingly significantly enhancing the effect of improving the reliability of the light emitting element. It is preferable that the resin (A1-DL) present in the pixel separation layer etc. contains a structure derived from the resin (A1) which will be described later or a structure derived from the resin (A2) which will be described later. It is preferable that the resin (A3-DL) in the pixel separation layer etc. is a resin having one or more selected from the group consisting of structures derived from the (A3) resin which will be described later, structures derived from the resin (A1) which will be described later, and structures derived from the resin (A2) which will be described later.

The pixel separation layer etc. preferably contains the resin (A2-DL) specified below. The pixel separation layer etc. preferably contains the resin (A1-DL) and/or the (A3-DL) and further contains the resin (A2-DL). The pixel separation layer etc. more preferably contains the resin (A1-DL) and resin (A2-DL), and particularly preferably contains the resin (A1-DL), resin (A2-DL), and (A3-DL) resin.

Resin (A2-DL): a resin having a structural unit as represented by the general formula (24)

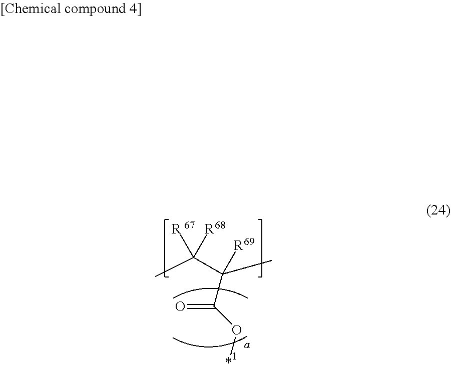

In the general formula (24), R⁶⁷ to R⁶⁹ are each independently a hydrogen atom or an alkyl group containing 1 to 6 carbon atoms. Here, a is 0 or 1. In addition, *¹ denotes a bonding point in the resin.

The structural unit represented by the general formula (24) preferably contains a reaction residue of an ethylenically unsaturated double bond group. The reaction residue of an ethylenically unsaturated double bond group is a residue left after radical polymerization of an ethylenically unsaturated double bond group exposed to light and/or heat. The reaction residue of an ethylenically unsaturated double bond group is preferably a residue left after radical polymerization of an ethylenically unsaturated double bond group in the resin (A2) which will be described later, more preferably a residue left after radical polymerization of an ethylenically unsaturated double bond group in the resin (A2) which will be described later with the radical polymerizable compound (B) which will be described later.

If they are configured in this way, it significantly enhances the effect of improving the reliability of the light emitting element. The resin (A2-DL) present in the pixel separation layer etc. is a resin in which the crosslink density is increased by radical polymerization with a radical polymerizable group such as (meth)acryloyl group. It is inferred that the outgassing from the pixel separation layer etc. is suppressed by the high heat resistance of crosslinked structure of the resin (A2-DL), accordingly significantly enhancing the effect of improving the reliability of the light emitting element. It is preferable that the resin (A2-DL) present in the pixel separation layer etc. is a resin that has a structure derived from the resin (A2) which will be described later and/or a structure derived from the (A3) resin which will be described later.

The resin (A1-DL) present in the pixel separation layer etc. preferably contains one or more structural units selected from those represented by the general formula (1), (2), (3), (4), (5), (6), (9), or (10) which will be described later.

The resin (A3-DL) present in the pixel separation layer etc. preferably contains one or more structural units selected from those represented by the general formula (31), (32), (33), (34), (35), (36), (38), (39), or (40) which will be described later. These resins preferably have a phenolic hydroxyl group as an acidic group in at least one of the main chain of the resin, side chain of the resin, and chain end of the resin and contain an aromatic skeleton in a structural unit of the resin, and they more preferably have a phenolic hydroxyl group as an acidic group in a structural unit of the resin and contain an aromatic skeleton. It is also preferable that part of the phenolic hydroxyl groups present in the resin form a crosslinked structure after reacting with another resin or compound.

The resin (A2-DL) present in the pixel separation layer etc. preferably contains one or more structural units selected from those represented by the general formula (1), (2), (3), (4), (5), (6), (9), or (10) which will be described later. The resin (A2-DL) present in the pixel separation layer etc. preferably contains one or more selected from the group consisting of a structural unit having a condensed polycyclic structure, a structural unit having a condensed polycyclic heterocyclic structure, a structural unit having structure containing an aromatic skeleton and an alicyclic skeleton directly connected to each other, and a structural unit having structure containing at least two aromatic skeletons directly connected to each other. Examples of the condensed polycyclic structure include the naphthalene structure, fluorene structure, and indan structure. Examples of the condensed polycyclic heterocyclic structure include the xanthene structure, indolinone structure, and isoindolinone structure. The alicyclic skeleton is preferably a tricyclo[5.2.1.0^{2,6}]decane structure. The structure having at least two aromatic skeletons directly connected to each other is preferably the biphenyl structure. The resin (A2-DL) present in the pixel separation layer etc. preferably has one or more selected from the group consisting of novolac structures, cresol novolac structures, triphenylalkane structures, diphenyl-phenylalkylphenylalkane structures, and diphenylalkane structures.

### <Compounds in Pixel Separation Layer, Pixel Size Control Layer, and Spacer Layer>

Compounds in the pixel separation layer etc. are described collectively below. The pixel separation layer etc. preferably contains a compound (C1-DL) having a structure derived from a photopolymerization initiator (hereinafter referred to as compound (C1-DL)) and/or a compound (C2-DL) having a structure derived from a naphthoquinone diazide compound (hereinafter referred to as compound (C2-DL)). The compound (C1-DL) present in the pixel separation layer etc. is preferably a compound having a structure derived from a photopolymerization initiator containing an oxime ester structure and/or a compound having a structure derived from a photopolymerization initiator containing an oxime ester carbonyl structure. The compound (C2-DL) present in the pixel separation layer etc. is preferably a compound having a structure derived from 1,2-naphthoquinone diazide-5-sulfonic acid ester compound and/or a compound having a structure derived from 1,2-naphthoquinone diazide-4-sulfonic acid ester compound. It is preferable that the pixel separation layer includes a compound having a carboxylate structure containing an indene structure and/or an aryl sulfonate structure containing an indene structure.

If it is configured in this way, it significantly enhances the effect of realizing suppressed external light reflection and improved reliability of the light emitting element. This is inferred to be because the compound (C1-DL) and compound (C2-DL) present in the pixel separation layer etc. absorb light in the visible wavelength range, thereby significantly enhancing the effect of suppressing the external light reflection. The compound (C1-DL) present in the pixel separation layer etc. is a compound having a residue contained in the pixel separation layer etc. left after increasing the crosslink density in the film by radical polymerization with a radical polymerizable compound having a (meth)acryloyl group etc. The compound (C2-DL) present in the pixel separation layer etc. is a compound having a residue contained in the pixel separation layer etc. left after increasing the crosslink density in the film by forming a crosslinked structure during heat curing, etc. It is inferred that therefore, the compound (C1-DL) and the compound (C2-DL) present in the pixel separation layer etc. are incorporated as part of the crosslinked structure in the pixel separation layer etc., to cause an increase in the crosslink density of the film and suppression of the outgassing from the pixel separation layer etc., thereby significantly enhancing the effect of improving the reliability of the light emitting element.

It is more preferable that the pixel separation layer etc. contain the compound (C1x-DL) and/or the compound (C2x-DL) which are specified below.

Compound (C1x-DL): a compound having a fluorene structure, benzofluorene structure, dibenzofluorene structure, carbazole structure, benzocarbazole structure, indole structure, benzoinole structure, or diphenyl sulfide structure and having a structure formed by bonding an imino group to these structures and/or a structure formed by bonding a carbonyl group bonded to these structures

Compound (C2x-DL): a compound having a carboxylate structure containing an indene structure and/or an aryl sulfonate structure containing an indene structure

The compound (C1x-DL) present in the pixel separation layer etc. is preferably a compound having a fluorene structure, benzofluorene structure, dibenzofluorene structure, carbazole structure, or benzocarbazole structure, and more preferably a compound formed by bonding an imino group to these structures.

The compound (C2x-DL) present in the pixel separation layer etc. is preferably a compound having a 1H-indene-3-carboxylate-7-arylsulfonate structure and/or a compound having a 1H-indene-1-arylsulfonate-3-carboxylate structure.

If they are configured in this way, it significantly enhancing the effect of realizing suppressed external light reflection, lower voltage driving of the light emission characteristics, and improved reliability of the light emitting element. This is inferred to be because in the pixel separation layer etc., the condensed polycyclic structure, condensed polycyclic heterocyclic structure, or aromatic skeleton of the compound (C1x-DL) and the carboxylate structure containing the indene structure and the aryl sulfonate structure containing the indene structure of the compound (C2x-DL) absorb light in the visible wavelength range, thereby significantly enhancing the effect of suppressing the external light reflection. Furthermore, it is inferred that the compound (C1x-DL) and the compound (C2x-DL) in the pixel separation layer etc. act to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. In addition, the compound (C1x-DL) present in the pixel separation layer etc. is a compound having a residue contained in the pixel separation layer etc. left after increasing the crosslink density in the film by radical polymerization with a radical polymerizable compound having a (meth)acryloyl group etc. The compound (C2x-DL) present in the pixel separation layer etc. is a compound having a residue contained in the pixel separation layer etc. left after increasing the crosslink density in the film by forming a crosslinked structure during heat curing, etc. It is inferred that therefore, the compound (C1x-DL) and the compound (C2x-DL) present in the pixel separation layer etc. are incorporated as part of the crosslinked structure in the pixel separation layer etc., to cause an increase in the crosslink density of the film and suppression of the outgassing from the pixel separation layer etc., thereby significantly enhancing the effect of improving the reliability of the light emitting element. The compound (C1-DL) and the compound (C1x-DL) present in the pixel separation layer etc. are each preferably a compound having a structure derived from the compound (C1) which will be described later and more preferably a compound having a structure derived from the compound (C1-1) which will be described later. The compound (C2-DL) and the compound (C2x-DL) present in the pixel separation layer etc. are each preferably a compound derived from the compound (C2) which will be described later.

The display device according to the second aspect of the present invention includes a pixel separation layer containing one or more selected from the group consisting of the compound (11a-DL), compound (I1b-DL), compound (I2a-DL), and compound (I2b-DL) specified below, wherein:
the compound (I1a-DL) and the compound (I2a-DL) have structures (I-Ia) as specified below;
the compound (I1b-DL) and the compound (I2b-DL) have structures (I-Ib) as specified below; and
one or more of the (1a-DL) and (1b-DL) requirements or one or more of the (2a-DL) and (2b-DL) requirements specified below are satisfied:
compound (I1a-DL): one or more compounds selected from the group consisting of thiol structure-containing compounds, sulfide structure-containing compounds, disulfide structure-containing compounds, sulfoxide structure-containing compounds, sulfone structure-containing compounds, sultone structure-containing compounds, thiophene structure-containing compounds, and sulfonic acid structure-containing compounds,
compound (I1b-DL): a compound having, as anion species, one or more selected from the group consisting of sulfide ion structures, hydrogen sulfide ion structures, sulfate ion structures, and hydrogen sulfate ion structures, and also having, as cation species, an ammonium ion structure, primary ammonium ion structure, secondary ammonium ion structure, tertiary ammonium ion structure, or quaternary ammonium ion structure,
compound (I2a-DL): one or more compounds selected from the group consisting of alkyl chloride structure-containing compounds, cycloalkyl chloride structure-containing compounds, aryl chloride structure-containing compounds, alkyl bromide structure-containing compounds, cycloalkyl bromide structure-containing compounds, and aryl bromide structure-containing compounds,
compound (I2b-DL): a compound having, as anion species, a chloride ion structure and/or a bromide ion structure, and also having, as cation species, an ammonium ion structure, primary ammonium ion structure, secondary ammonium ion structure, tertiary ammonium ion structure, or quaternary ammonium ion structure,
structure (I-Ia): a structure containing one or more selected from the group consisting of monovalent or divalent aliphatic groups having 4 to 30 carbon atoms, alkylaryl groups having 10 to 30 carbon atoms, arylalkyl groups having 10 to 30 carbon atoms, and aryl groups having 7 to 15 carbon atoms,
structure (I-Ib): a structure containing one or more selected from the group consisting of monovalent or divalent aliphatic groups having 1 to 6 carbon atoms, alkylaryl groups having 10 to 30 carbon atoms, arylalkyl groups having 10 to 30 carbon atoms, and aryl group having 7 to 15 carbon atoms,
(1a-DL) the content of the sulfur element in the pixel separation layer is 0.01 to 500 mass ppm,
(1b-DL) the total content of sulfide ions, hydrogen sulfide ions, sulfate ions, and hydrogen sulfate ions in the pixel separation layer is 0.01 to 1,000 mass ppm,
(2a-DL) the total content of the chlorine element and the bromine element in the pixel separation layer is 0.01 to 500 mass ppm, and
(2b-DL) the total content of chloride ions and bromide ions in the pixel separation layer is 0.01 to 1,000 mass ppm.

If a compound having a structure containing the sulfur element, a compound having a structure containing a sulfur based anion as described above, a compound having a structure containing the chlorine element, a compound having a structure containing the bromine element, or a compound having a structure containing a halogen anion as described above is included in the pixel separation layer, it is inferred that enhanced light emission characteristics that enable low voltage driving can be realized by adjusting the difference in the work function. It is considered that as a result, this also allows a higher light emission luminance to be achieved at the same driving voltage. It is also considered that for example, appropriate control of the polarization structure and charge balance in the pixel separation layer in an organic EL display can serve to enhance the reliability of the light emitting element. In addition, it is inferred that the suppression of migration and aggregation of metal in the first electrode enhances the effect of improving the reliability of the light emitting element.

The display device according to the present invention preferably includes a pixel separation layer etc. that contain one or more selected from the group consisting of the compound (I1a-DL), compound (I1b-DL), compound (I2a-DL), and compound (I2b-DL) specified below:
compound (I1a-DL): one or more compounds selected from the group consisting of thiol structure-containing compounds, sulfide structure-containing compounds, disulfide structure-containing compounds, sulfoxide structure-containing compounds, sulfone structure-containing compounds, sultone structure-containing compounds, thiophene structure-containing compounds, and sulfonic acid structure-containing compounds,
compound (I1b-DL): a compound having, as anion species, one or more selected from the group consisting of sulfide ion structures, hydrogen sulfide ion structures, sulfate ion structures, and hydrogen sulfate ion structures, and also having, as cation species, an ammonium ion structure, primary ammonium ion structure, secondary ammonium ion structure, tertiary ammonium ion structure, or quaternary ammonium ion structure,
compound (I2a-DL): one or more compounds selected from the group consisting of alkyl chloride structure-containing compounds, cycloalkyl chloride structure-containing compounds, aryl chloride structure-containing compounds, alkyl bromide structure-containing compounds, cycloalkyl bromide structure-containing compounds, and aryl bromide structure-containing compounds,
compound (I2b-DL): a compound having, as anion species, a chloride ion structure and/or a bromide ion structure, and also having, as cation species, an ammonium ion structure, primary ammonium ion structure, secondary ammonium ion structure, tertiary ammonium ion structure, or quaternary ammonium ion structure.

If they are configured in this way, it significantly enhances the effect of realizing lower voltage driving of the light emission characteristics, improved light emission luminance, and improved reliability of the light emitting element. It is inferred that the compound having the sulfur element and the compound having the chlorine element or the bromine element that are present in the pixel separation layer etc. act to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. In addition, it is considered that while the surface of the first electrode undergoes surface modification by the sulfur element, chlorine element, or bromine element, a dense film is formed due to self-assembly of the substituent groups on sulfur atoms, chlorine atoms, or bromine atoms. It is also inferred that the heat resistance and oxidation resistance of the first electrode are increased, thereby significantly enhancing the effect of improving the reliability of the light emitting element. Hereinafter, the compound (11a-DL), compound (I1b-DL), compound (I2a-DL), and compound (I2b-DL) are occasionally referred to collectively as the compounds (I-DL).

If they are configured in this way, from the perspective of realizing lower voltage driving of the light emission characteristics, improved light emission luminance, and improved reliability of the light emitting element,
it is preferable that in the case where the pixel separation layer etc. contain the compound (11a-DL), the compound (I1a-DL) includes one or more selected from the group consisting of thiol structure-containing compounds, sulfide structure-containing compounds, disulfide structure-containing compounds, and sulfonic acid structure-containing compounds,
in the case where the pixel separation layer etc. contain the compound (I1b-DL), the compound (I1b-DL) includes a composition having, as anion species, one or more selected from the group consisting of sulfide ion structures, hydrogen sulfide ion structures, sulfate ion structures, and hydrogen sulfate ion structures, and also having, as cation species, a quaternary ammonium ion structure,
in the case where the pixel separation layer etc. contain the compound (I2a-DL), the compound (I2a-DL) includes one or more selected from the group consisting of alkyl chloride structure-containing compounds, cycloalkyl chloride structure-containing compounds, alkyl bromide structure-containing compounds, and cycloalkyl bromide structure-containing compounds, and
in the case where the pixel separation layer etc. contain the compound (I2b-DL), the compound (I2b-DL) includes a composition having, as anion species, a chloride ion structure and/or a bromide ion structure, and also having, as cation species, a quaternary ammonium ion structure.

It is inferred that if configured in this way, it serves to further promote the surface modification action on the surface of the first electrode that faces the light emitting layer, thereby significantly enhancing the effect of realizing lower voltage driving of the light emission characteristics and improved light emission luminance. Here, a dense film is considered to be formed on the surface of the first electrode due to self-assembly of the substituent groups on sulfur atoms, chlorine atoms, or bromine atoms, and it is inferred that this significantly enhances the effect of improving the reliability of the light emitting element.

It is more preferable that the pixel separation layer etc. contain the compound (I1a-DL) and/or the compound (I1b-DL). It is still more preferable that the pixel separation layer etc. contain the compound (I1a-DL) and/or the compound (I1b-DL) and also contain the compound (I2a-DL) and/or the compound (I2b-DL). It is also more preferable that the pixel separation layer etc. contain the compound (I1a-DL) and the compound (I1b-DL). It is also more preferable that the pixel separation layer etc. contain the compound (I2a-DL) and the compound (I2b-DL). It is also preferable that the compound (I1a-DL), compound (I1b-DL), compound (I2a-DL), and compound (I2b-DL) each contain two or more compounds.

From the perspective of realizing lower voltage driving of the light emission characteristics, improved light emission luminance, and improved reliability of the light emitting element, it is preferable, for the pixel separation layer etc., that the compound (I1a-DL) and the (I2a-DL) compound have structures (I-Ia) as specified below while the compound (I1b-DL) and the compound (I2b-DL) have structures (I-Ib) as specified below:
structure (I-Ia): a structure containing one or more selected from the group consisting of monovalent or divalent aliphatic groups having 4 to 30 carbon atoms, alkylaryl groups having 10 to 30 carbon atoms, arylalkyl groups having 10 to 30 carbon atoms, and aryl groups having 7 to 15 carbon atoms, and
structure (I-Ib): a structure containing one or more selected from the group consisting of monovalent or divalent aliphatic groups having 1 to 6 carbon atoms, alkylaryl groups having 10 to 30 carbon atoms, arylalkyl groups having 10 to 30 carbon atoms, and aryl group having 7 to 15 carbon atoms.

It is inferred that if they are configured in this way, it serves to further promote the surface modification action on the surface of the first electrode that faces the light emitting layer, thereby significantly enhancing the effect of realizing lower voltage driving of the light emission characteristics and improved light emission luminance. Here, a dense film is considered to be formed on the surface of the first electrode due to self-assembly of the substituent groups on sulfur atoms, chlorine atoms, or bromine atoms, and it is inferred that this significantly enhances the effect of improving the reliability of the light emitting element.

The compound (I1a-DL) and the compound (I2a-DL) preferably have structures (II-Ia) and/or structures (III-Ia) as specified below:
structure (II-Ia): a structure containing one or more groups selected from the group consisting of monovalent aliphatic groups having 4 to 30 carbon atoms, divalent aliphatic groups having 6 to 30 carbon atoms, alkylaryl groups having 10 to 30 carbon atoms, and alkylaryl groups having 10 to 30 carbon atoms,
structure (III-Ia): a structure containing one or more groups selected from the group consisting of oxyalkylene group bonded to a monovalent aliphatic group having 4 to 30 carbon atoms, oxyalkylene group bonded to an alkylaryl group having 10 to 30 carbon atoms, oxyalkylene group bonded to an alkylaryl group having 10 to 30 carbon atoms, and oxyalkylene group bonded to an aryl group having 7 to 15 carbon atoms.

The compound (I1a-DL) has a substituent bonded to a sulfur atom wherein the substituent preferably has the structure (I-Ia), and the substituent more preferably has the structure (II-Ia) and/or the structure (III-Ia).

The compound (I2a-DL) has a substituent bonded to a chlorine atom or a bromine atom wherein the substituent preferably has the structure (I-Ia), and the substituent more preferably has the structure (II-Ia) and/or the structure (III-Ia).

The structure (II-Ia) is preferably the structure (II-Iax) specified below:
structure (II-Iax): a structure containing one or more groups selected from the group consisting of monovalent aliphatic groups having 6 to 12 carbon atoms, divalent aliphatic groups having 6 to 12 carbon atoms, alkylaryl groups having 14 to 26 carbon atoms, and alkylaryl groups having 14 to 26 carbon atoms.

The structure (III-Ia) is preferably the structure (III-Iax) specified below:
structure (III-Iax): a structure containing one or more groups selected from the group consisting of oxyalkylene group bonded to a monovalent aliphatic group having 6 to 12 carbon atoms, oxyalkylene group bonded to an alkylaryl group having 14 to 26 carbon atoms, oxyalkylene group bonded to an alkylaryl group having 14 to 26 carbon atoms, and oxyalkylene group bonded to an aryl group having 7 to 10 carbon atoms.

In the structure (I-Ia), structure (II-Ia), and structure (III-Ia), the monovalent aliphatic groups are preferably alkyl groups, alkenyl groups, or alkynyl groups, of which alkyl groups are more preferable. The divalent aliphatic groups are preferably alkylene groups, alkenylene groups, or alkynylene groups, of which alkylene groups are more preferable. Furthermore, the monovalent or divalent aliphatic groups are preferably straight-chain structures or branched structures, of which straight-chain structures are more preferable.

It is preferable that the compound (I1b-DL) and the compound (I2b-DL) have a substituent bonded to a nitrogen atom in the ammonium ion structure etc. that are listed above as cation species, wherein the substituent has the structure (I-Ib).

The structure (I-Ib) is preferably the structure (I-Ibx) specified below:
structure (I-Ibx): a structure containing one or more selected from the group consisting of monovalent aliphatic groups having 1 to 4 carbon atoms, alkylaryl groups having 10 to 26 carbon atoms, arylalkyl groups having 10 to 26 carbon atoms, and aryl group having 7 to 10 carbon atoms.

In the structure (I-Ib), the monovalent aliphatic groups are preferably alkyl groups, alkenyl groups, or alkynyl groups, of which alkyl groups are more preferable. The divalent aliphatic groups are preferably alkylene groups, alkenylene groups, or alkynylene groups, of which alkylene groups are more preferable. Furthermore, the monovalent or divalent aliphatic groups are preferably straight-chain structures or branched structures, of which straight-chain structures are more preferable. The monovalent or divalent aliphatic groups may have, as substituents, alkyl groups having 1 to 6 carbon atoms, alkoxy groups having 1 to 6 carbon atoms, carboxyl groups, hydroxyl groups, or amino groups.

In the structure (I-Ib), the aforementioned ammonium ion structure etc. are preferably an ammonium ion structure, primary ammonium ion structure, secondary ammonium ion structure, tertiary ammonium ion structure, or quaternary ammonium ion structure, of which a quaternary ammonium ion structures is more preferable. The quaternary ammonium ion structure preferably has 4 alkyl groups having 1 to 6 carbon atoms and more preferably has 4 alkyl groups having 1 to 4 carbon atoms. The 4 alkyl groups are each independently an alkyl group having 1 to 6 carbon atoms, wherein their numbers of carbon atoms may be identical to or different from each other.

The display device according to the present invention satisfies one or more of the requirements (1a-DL) and (1b-DL) specified below or satisfies one or more of the requirements (2a-DL) and (2b-DL) specified below:
(1a-DL) the content of the sulfur element in the pixel separation layer is 0.01 to 500 mass ppm,
(1b-DL) the total content of sulfide ions, hydrogen sulfide ions, sulfate ions, and hydrogen sulfate ions in the pixel separation layer is 0.01 to 1,000 mass ppm,
(2a-DL) the total content of the chlorine element and the bromine element in the pixel separation layer is 0.01 to 500 mass ppm, and
(2b-DL) the total content of chloride ions and bromide ions in the pixel separation layer is 0.01 to 1,000 mass ppm.

In the case where the pixel separation layer contains the compound (I1a-DL) and/or the compound (I1b-DL) as specified above, the display device according to the present invention preferably satisfies one or more of the requirements (1a-DL) and (1b-DL) specified above, and more preferably satisfies the requirements (1a-DL) and (1b-DL) specified above. Furthermore, in the case where the pixel separation layer contains the compound (I2a-DL) and/or the compound (I2b-DL) as specified above, the display device according to the present invention preferably satisfies one or more of the requirements (2a-DL) and (2b-DL) specified above, and more preferably satisfies the requirements (2a-DL) and (2b-DL) specified above. Furthermore, in the case where the pixel separation layer contains the compound (I1a-DL) and/or the compound (I1b-DL) specified above and also contains the compound (I2a-DL) and/or the compound (I2b-DL) specified above,
the display device according to the present invention preferably satisfies one or more of the requirements (1a-DL) and (1b-DL) specified above and satisfies one or more of the requirements (2a-DL) and (2b-DL) specified above, and
more preferably satisfies the requirements (1a-DL) and (1b-DL) specified above and further satisfies the requirements (2a-DL) and (2b-DL) specified above.

The content of the sulfur element in the pixel separation layer is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the content of the sulfur element is preferably 700 mass ppm or less, more preferably 500 mass ppm or less, and still more preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The total content of the chlorine element and the bromine element in the pixel separation layer is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of the chlorine element and the bromine element is preferably 700 mass ppm or less, more preferably 500 mass ppm or less, and still more preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The content of the sulfur element in the pixel separation layer refers to the total quantity of the sulfur element present in the form of isolated atoms, ions, compounds, or compound ions. Similarly, the content of the chlorine element in the pixel separation layer refers to the total quantity of the chlorine element present in the form of isolated atoms, ions, compounds, or compound ions. Similarly, the content of the bromine element in the pixel separation layer refers to the total quantity of the bromine element present in the form of isolated atoms, ions, compounds, or compound ions.

The total content of sulfide ions, hydrogen sulfide ions, sulfate ions, and hydrogen sulfate ions in the pixel separation layer is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of sulfide ions, hydrogen sulfide ions, sulfate ions, and hydrogen sulfate ions is preferably 1,000 mass ppm or less, more preferably 700 mass ppm or less, still more preferably 500 mass ppm or less, and particularly preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The total content of chloride ions and bromide ions in the pixel separation layer is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of chloride ions and bromide ions is preferably 1,000 mass ppm or less, more preferably 700 mass ppm or less, still more preferably 500 mass ppm or less, and particularly preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The compound (I1a-DL) present in the pixel separation layer etc. is preferably a compound having a structure derived from the compound (I1a) which will be described later. The compound (I1b-DL) present in the pixel separation layer etc. is preferably a compound having a structure derived from the compound (I1b) which will be described later. The compound (I2a-DL) present in the pixel separation layer etc. is preferably a compound having a structure derived from the compound (I2a) which will be described later. The compound (I2b-DL) present in the pixel separation layer etc. is preferably a compound having a structure derived from the compound (I2b) which will be described later.

The contents of the sulfur element, chlorine element, and bromine element present in the pixel separation layer can be measured by means of combustion ion chromatography. For example, a typical measuring procedure includes burning and decomposing a sample of the photosensitive composition in a combustion tube of an analytical device, absorbing the generated gas in an absorption solution, and analyzing a part of the absorption solution by ion chromatography.

Furthermore, the contents of sulfide ions, hydrogen sulfide ions, sulfate ions, hydrogen sulfate ions, chloride ions, and bromide ions can be measured by means of ion chromatography. For example, a typical measuring procedure includes scraping off a sample from the pixel separation layer, adding the scraped sample of the pixel separation layer to a 10 mmol/L potassium hydroxide aqueous solution, and shaking it for 2 hours to extract ion components. Then, the extract is filtered, and the anion components are analyzed by ion chromatography.

It is preferable for the display device according to the present invention to include a pixel separation layer containing a compound (C1-DL) and/or a compound (C2-DL) and further include a pixel size control layer and a spacer layer containing a compound (C1-DL) that is different from the compound (C1-DL) present in the pixel separation layer and/or containing a compound (C2-DL) that is different from the compound (C2-DL) present in the pixel separation layer, and it is more preferable to include a pixel separation layer containing a compound (C1x-DL) and/or a compound (C2x-DL) and further include a pixel size control layer and a spacer layer containing a compound (C1x-DL) that is different from the compound (C1x-DL) present in the pixel separation layer and/or containing a compound (C2x-DL) that is different from the compound (C2x-DL) present in the pixel separation layer.

### <Maximum Value of Surface Roughness of Surface of Pixel Separation Layer and Spacer Layer>

It is preferable that in the display device according to the present invention, the pixel separation layer includes a cured pattern having a step shape which will be described later, wherein in the step shape of the cured pattern of the pixel separation layer, the thin parts of the pixel separation layer have a maximum surface roughness of 0.1 to 50.0 nm. On the other hand, it is preferable that in the step shape of the cured pattern of the pixel separation layer, the thick parts of the pixel separation layer have a maximum surface roughness of 0.1 to 50.0 nm. If they are configured in this way, it significantly enhances the effect of realizing increased adhesion between the pixel separation layer and the second electrode, lower voltage driving of the light emission characteristics, improved light emission luminance, and improved reliability of the light emitting element. From the perspective of increasing the adhesion between the pixel separation layer and the second electrode, the maximum surface roughness of the surface of the pixel separation layer is preferably 0.1 nm or more, more preferably 0.3 nm or more, still more preferably 0.5 nm or more, still more preferably 0.7 nm or more, and particularly preferably 1.0 nm or more. In addition, from the perspective of suppressing the external light reflection, the maximum surface roughness of the surface of the pixel separation layer is more preferably 3.0 nm or more, more preferably 5.0 nm or more, still more preferably 7.0 nm or more, and particularly preferably 10.0 nm or more. On the other hand, from the perspective of realizing lower voltage driving of the light emission characteristics, improved light emission luminance, and improved reliability of the light emitting element, the maximum surface roughness of the surface of the pixel separation layer is preferably 50.0 nm or less, more preferably 40.0 nm or less, still more preferably 30.0 nm or less, and particularly preferably 20.0 nm or less. Here, it is also preferable that the arithmetic average roughness of the surface of the thick parts of the pixel separation layer is 1.0 nm or more. It is also preferable that the maximum surface roughness of the surface of the thick parts of the pixel separation layer is 1.0 nm or more.

It is preferable that in the display device according to the present invention, the pixel separation layer is in contact with the second electrode which lies thereon. However, if the adhesion between the pixel separation layer and the second electrode is insufficient, interfacial delamination is likely to occur, which can lead to a reduced panel yield and decreased reliability of the light emitting element. In particular, when the display device according to the present invention is a flexible display device, the occurrence of interfacial delamination becomes more likely as the adhesion between the pixel separation layer and the second electrode becomes more insufficient. In the case where the display device according to the present invention is a flexible display device, as described above, it preferably has a structure in which the pixel separation layer is disposed on a flexible substrate. However, it is inferred that the occurrence of interfacial delamination will increase significantly if stress is generated at the interface between the pixel separation layer and the second electrode as they move along with the flexible substrate. If the maximum surface roughness of the surface of the pixel separation layer is in the aforementioned range, it can significantly enhance the effect of realizing increased adhesion between the pixel separation layer and the second electrode.

As described above, in the display device according to the present invention, it is preferable that the pixel separation layer is a cured film formed by curing a photosensitive composition. Here, after the formation of the pixel separation layer part, it is common to clean the surface of the first electrode by plasma treatment or the like in order to decompose and remove the residues remaining in slight amounts on the surface of the first electrode in the opening parts in the pixel separation layer part or in the opening parts in the pixel size control layer part. However, even the surface of the pixel separation layer can also be decomposed and removed if the plasma treatment is intensified or extended to decompose and remove the residues etc. remaining on the surface of the first electrode. Accordingly, in some cases, low molecular weight components remaining on the surface of the pixel separation layer after plasma treatment or decomposed and degraded parts of the surface of the pixel separation layer can act as a factor in reducing the reliability of the light emitting element. The degree of decomposition and degradation of the surface of the pixel separation layer caused by plasma treatment can be determined from measurements of the maximum surface roughness of the surface of the pixel separation layer. A larger maximum surface roughness of the surface of the pixel separation layer suggests a higher degree of decomposition and degradation of the surface of the pixel separation layer. If the maximum surface roughness of the surface of the pixel separation layer is in the aforementioned range, it significantly enhances the effect of realizing lower voltage driving of the light emission characteristics, improved light emission luminance, and improved reliability of the light emitting element.

For the display device according to the present invention, the effect of suppressing external light reflection is enhanced significantly if the maximum surface roughness of the surface of the pixel separation layer is in the aforementioned range and the diffuse reflected light on the surface of the pixel separation layer is increased. In general, when incident external light comes, two types of reflected light, namely, specular reflected light and diffuse reflected light, occur on the surface. Reflected light is the combination of these, of which specular reflected light has a greater impact on glariness and reflected glare that define visibility. Therefore, it is considered that increasing the diffuse reflected light while reducing the specular reflected light is effective for suppressing external light reflection. Accordingly, it is inferred that if the maximum surface roughness of the surface of the pixel separation layer is in the aforementioned range, it significantly enhances the effect of suppressing external light reflection.

In the case where the pixel separation layer present in the display device according to the present invention includes a cured pattern having a step shape, it is preferable that the difference between (Ra_{HT/max}) and (Ra_{FT/max}), i.e., |Δ(Ra_{HT/max}−Ra_{FT/max})| is 1.0 to 50.0 nm wherein (Ra_{HT/max}) is the maximum surface roughness of the thin parts of the surface of the pixel separation layer while (Ra_{FT/max}) is the maximum surface roughness of the thick parts of the surface of the pixel separation layer.

The difference between (Ra_{HT/max}) and (Ra_{FT/max}), i.e., |Δ(Ra_{HT/max}−Ra_{FT/max})|, is preferably 0.1 to 50.0 nm, wherein (Ra_{HT/max}) is the maximum surface roughness of the thin parts of the surface of the pixel separation layer while (Ra_{FT/max}) is the maximum surface roughness of the thick parts of the surface of the pixel separation layer. From the perspective of increasing the adhesion between the pixel separation layer and the second electrode and suppressing external light reflection, the difference between (Ra_{HT/max}) and (Ra_{FT/max}), i.e., |Δ(Ra_{HT/max}-Ra_{FT/max})|, is preferably 1.0 nm or more, more preferably 3.0 nm or more, still more preferably 5.0 nm or more, still more preferably 7.0 nm or more, and particularly preferably 10.0 nm or more. On the other hand, from the perspective of realizing lower voltage driving of the light emission characteristics, improved light emission luminance, and improved reliability of the light emitting element, the difference between (Ra_{HT/max}) and (Ra_{FT/max}), i.e., |Δ(Ra_{HT/max}-Ra_{FT/max})|, is preferably 50.0 nm or less, more preferably 40.0 nm or less, still more preferably 30.0 nm or less, and particularly preferably 20.0 nm or less.

In the case where the pixel separation layer has a cured pattern and part of the pixel separation layer has a spacer layer disposed thereon in the display device according to the present invention, the difference between (Ra_{DL/max}) and (Ra_{SP/max}), i.e., |Δ(Ra_{DL/max}-Ra_{SP/max})|, is preferably 1.0 to 50.0 nm, wherein (Ra_{DL/max}) is the maximum surface roughness of the surface of the pixel separation layer while (Ra_{SP/max}) is the maximum surface roughness of the surface of spacer layer. If they are configured in this way, it significantly enhances the effect of realizing increased adhesion between the pixel separation layer and the second electrode, suppressed external light reflection, lower voltage driving of the light emission characteristics, improved light emission luminance, and improved reliability of the light emitting element.

The difference between (Ra_{DL/max}) and (Ra_{SP/max}), i.e., |Δ(Ra_{DL/max}−Ra_{SP/max})|, is preferably 0.1 to 50.0 nm, wherein (Ra_{DL/max}) is the maximum surface roughness of the surface of the pixel separation layer while (Ra_{SP/max}) is the maximum surface roughness of the surface of the spacer layer. Examples and preferable features related to the difference between (Ra_{DL/max}) and (Ra_{SP/max}), i.e., |Δ(Ra_{DL/max}−Ra_{SP/max})|, are the same as the examples and preferable features related to the (Ra_{HT/max}) and (Ra_{FT/max}), i.e., |Δ(Ra_{HT/max}−Ra_{FT/max})|.

For the display device according to the present invention, the arithmetic average roughness and maximum surface roughness can be measured using an atomic force microscope (hereinafter AFM). In general, when measurement is performed by AFM, the display device placed on a horizontal plane and the surface of the pixel separation layer etc. present therein is observed from vertically above.

For the display device according to the present invention, the arithmetic average roughness and maximum surface roughness are determined based on measurement on the surface of the pixel separation layer etc. that is observable by AFM, i.e., a plane substantially parallel to the substrate.

<Optical Density of Pixel Dividing Layer, Pixel Size Control Layer, and Spacer Layer; Display Device with Flexibility>

It is preferable that the display device according to the present invention has an optical density of 0.5 to 3.0 per μm of the thickness of the pixel separation layer in the visible light wavelength range. If it is configured in this way, it allows the pixel separation layer to act for blocking the incident external light, thereby significantly enhancing the effect of suppressing external light reflection. In addition, due to increased light blocking efficiency of the pixel separation layer in the visible light wavelength region and the ultraviolet region, the outgassing from the pixel separation layer etc. is suppressed and the degradation of the light emitting element is prevented, thereby significantly enhancing the effect of improving the reliability of the light emitting element. It is preferable that the pixel separation layer is black. From the perspective of suppressing external light reflection and improving the reliability of the light emitting element, the optical density per μm of the thickness of the pixel separation layer in the visible wavelength region is preferably 0.7 or more, more preferably 1.0 or more, still more preferably 1.2 or more, and particularly preferably 1.5 or more. On the other hand, from the perspective of realizing lower voltage driving of the light emission characteristics, improved light emission luminance, and improved reliability of the light emitting element, the optical density per μm of the thickness of the pixel separation layer in the visible wavelength region is preferably 2.7 or less, more preferably 2.5 or less, still more preferably 2.2 or less, and particularly preferably 2.0 or less. Here, the term “optical density” refers to the optical density of a cured product prepared by curing the photosensitive composition by heating at 250° C. for 60 minutes. The thermal curing conditions to use include heating to 250° C. at a heating rate of 3.5° C./min in a nitrogen atmosphere with an oxygen concentration of 20 mass ppm or less, subsequent heat treatment at 250° C. for 60 minutes, and cooling to 50° C. However, in the case where the photosensitive composition contains a dye or a thermal color developer or where the photosensitive composition has positive type photosensitivity, the thermal curing conditions used included heating to 200° C. at a heating rate of 3.5° C./min in a nitrogen atmosphere with an oxygen concentration of 20 mass ppm or less, subsequent heat treatment at 200° C. for 60 minutes, and cooling to 50° C. Furthermore, in the case where the photosensitive composition contains an oxidative color developer, the thermal curing conditions used included heating to 200° C. at a heating rate of 3.5° C./min in a nitrogen atmosphere, subsequent heat treatment at 200° C. for 60 minutes, and cooling to 50° C. Unless otherwise specified, these thermal curing conditions are adopted throughout the present Description.

It is also preferable that the display device according to the present invention has an optical density of 0.5 to 3.0 per μm of the thickness of the pixel size control layer and/or the spacer layer in the visible light wavelength range. If they are configured in this way, it allows the pixel size control layer or the spacer layer to act to block the incident external light, thereby significantly enhancing the effect of suppressing external light reflection. In addition, due to increased light blocking efficiency of these layers in the visible light wavelength region and the ultraviolet region, the outgassing from these layers etc. is suppressed and the degradation of the light emitting element is prevented, thereby significantly enhancing the effect of improving the reliability of the light emitting element. It is preferable that the pixel size control layer and/or the spacer layer is black. Examples and preferable features related to the optical density per μm of the thickness of the pixel size control layer and the spacer layer in the visible light wavelength range are the same as the examples and preferable features related to the optical density of the pixel separation layer described above.

Here, for a structure in which at least two of the pixel separation layer, pixel size control layer, and spacer layer are stacked, the optical density of each layer can be determined by the following method. First, the thickness of the optical density (OD_{TOTAL}) of the structure in which at least two layers are stacked and the thickness of each layer are measured. Then, the optical density of a region devoid of a laminate structure such as a region containing only the pixel separation layer is measured, in addition to measuring the thickness of the pixel separation layer. From the measurements taken, the optical density (OD_{PDL}) per μm of the thickness of the pixel separation layer, for example, is calculated. Then, for example, the optical density of the pixel size control layer or the spacer layer is calculated from the optical density (OD_{TOTAL}) of the laminate structure, the thickness of each layer, and the difference in optical density from the optical density (OD_{PDL}).

For the display device according to the present invention, it is preferable that no linear polarizing plate, quarter wave plate, or circular polarizing plate exist on the light extraction side of the organic layer containing a light emitting layer. If it is configured in this way, the display device according to the present invention is devoid of a polarizing film that is poor in flexibility or bendability, and it significantly enhances the effect of improving flexibility and bendability.

The display device according to the present invention is preferably a flexible display device that further includes a flexible substrate, having a structure in which the pixel separation layer is disposed on the flexible substrate, having no linear polarizing plate, quarter wave plate, or circular polarizing plate on the light extraction side of the organic layer containing a light emitting layer, and having a curved display part, a display part having a plane bending outward, or a display part having a plane bending inward.

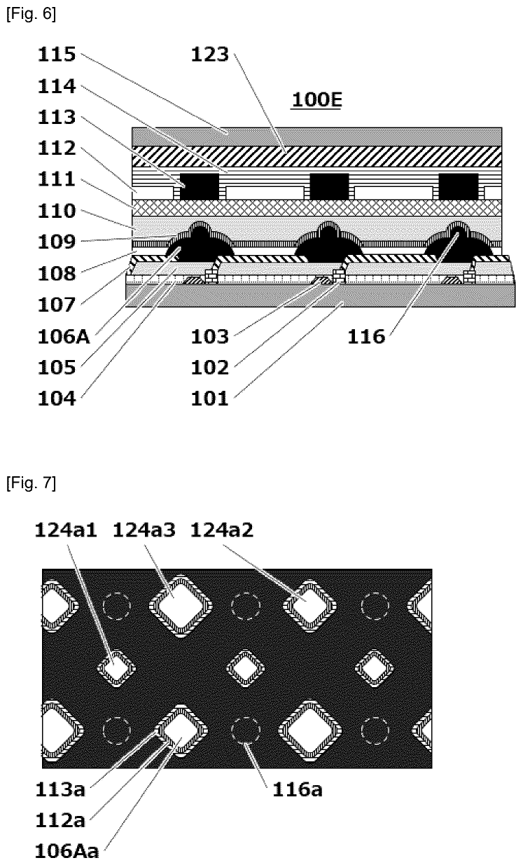

If they are configured in this way, the light blocking capability of the pixel separation layer enhances significantly the effect of preventing the electrode wiring from becoming visible and suppressing external light reflection even when the display device according to the present invention has no polarizing films such as linear polarizing plates, quarter wave plates, and circular polarizing plates on the light extraction side of the organic layer containing a light emitting layer. Thus, the absence a polarizing film that is poor in flexibility or bendability in the display device according to the present invention serves to significantly enhance the effect of improving flexibility and bendability. Therefore, the display device according to the present invention is suitable for displays with flexibility, particularly for organic EL displays with flexibility, that have a structure in which the pixel separation layer is disposed on a flexible substrate and have no polarizing films on the light extraction side of the organic layer containing a light emitting layer. Furthermore, the fact that it has no polarizing films enhances significantly the effect of reducing the cost required for manufacturing the display device. FIG. 6 gives a schematic cross section illustrating an example of a display device that includes a pixel separation layer of a step shape and a polarizing film.

It is preferable that the display device according to the present invention has a structure in which the pixel size control layer and/or the spacer layer are disposed on a flexible substrate. If they are configured in this way, the light blocking capability of the pixel size control layer or the spacer layer serve to enhance significantly the effect of preventing the electrode wiring from becoming visible and suppressing external light reflection even when the display device according to the present invention has no polarizing films such as linear polarizing plates, quarter wave plates, and circular polarizing plates on the light extraction side of the organic layer containing a light emitting layer.

It is also preferable that the display device according to the present invention further include one or more selected from the group consisting of linear polarizing plates, quarter wave plates, and circular polarizing plates disposed on the light extraction side of the organic layer containing a light emitting layer. If they are configured in this way, the light blocking capability of the pixel separation layer and the light blocking capability of the polarizing films serve to significantly enhance the effect of preventing the electrode wiring from becoming visible and suppressing external light reflection. Furthermore, in the case where the display device according to the present invention has a pixel size control layer and/or a spacer layer, the light blocking capability of these layers and the light blocking capability of polarizing films serve to enhance significantly the effect of preventing the electrode wiring from becoming visible and suppressing external light reflection. Therefore, the display device according to the present invention is particularly suitable for use as a display device that is required to have high external light reflection suppression capability, and particularly suitable for use as an organic EL display that is required to have high external light reflection suppression capability.

### <Cured Pattern of Pixel Separation Layer Having Step Shape>

It is preferable that in the display device according to the present invention, the pixel separation layer has a step shaped cured pattern wherein the step shaped cured pattern of the pixel separation layer has thick parts with a thickness of (T_{FT}) μm and thin parts with a thickness of (T_{HT}) μm, with the thickness difference of (ΔT_{FT-HT}) μm between the thickness of (T_{FT}) μm and the thickness of (T_{HT}) μm being 0.5 to 10.0 μm.

If they are configured in this way, it significantly enhances the effect of realizing lower voltage driving of the light emission characteristics, improved light emission luminance, and improved reliability of the light emitting element. If the pixel separation layer has a step shaped cured pattern with a thickness difference of 0.5 μm or more, it serves to decrease the contact area between the pixel separation layer and the deposition mask during the step for forming the organic layer containing a light emitting layer. Consequently, damage to the pixel separation layer is suppressed and this serves to enhance significantly the effect of preventing a decrease in panel yield and improving the reliability of the light emitting element. Common methods for forming a step shaped pixel separation layer include (1) the method of forming a step shape in a batch process using a halftone photomask and (2) the method of forming a pixel separation layer by means of a two layered film formation process. When using the method of (1), the region around the opening part in the pixel separation layer part is a thin part in the step shape of the pixel separation layer. Therefore, it is designed so that the alkali solubility there is higher than in the thick parts. Accordingly, this serves for the suppression of residue generation in the opening part in the pixel separation layer part, thereby enhancing the effect of realizing lower voltage driving of the light emission characteristics and improved light emission luminance. On the other hand, when using the method of (2), the region around the opening part in the pixel separation layer part is a thin part forming the first layer in the step shape of the pixel separation layer. Therefore, when forming the second layer, which produces thick parts, the opening part in the first layer comes into contact with the alkali developer again. Accordingly, this serves for the suppression of residue generation in the opening part in the pixel separation layer part, thereby significantly enhancing the effect of realizing lower voltage driving of the light emission characteristics and improved light emission luminance. If a step shape is formed in a batch process using a halftone photomask, it significantly enhances the effect of reducing the process time and improving the productivity in addition to the above effects.

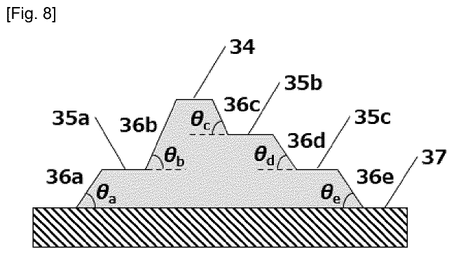

FIG. 8 gives a schematic cross section illustrating an example of a cross section of a cured pattern having a step shape in the pixel separation layer of the display device according to the present invention. The thick part 34 in the step shape represents a part that is cured in the light exposure step in the case of a negative type while it represents a part that is left unexposed in the light exposure step in the case of a positive type, and this part has the maximum thickness in the cured pattern. The thin parts 35a, 35b, and 35c in the step shape represent parts that are halftone-exposed in the light exposure step and are smaller in thicknesses than the thick part 34. It is preferable that the taper angles θa, θb, θc, θd, and θe of the inclined sides 36a, 36b, 36c, 36d, and 36e, respectively, in the cross section of the step shaped cured pattern are all forward taper angles, and they are more preferably small. Here, as shown in FIG. 8, the taper angles θa, θb, θc, θd, and θe referred to herein are the angles in the cross section of the step shaped cured pattern that is formed by the horizontal side 37 of the underlying substrate on which the cured pattern is disposed or the horizontal sides of the thin parts 35a, 35b, and 35c with the slopes 36a, 36b, 36c, 36d, and 36e in the cross section of the step shaped cured pattern that cross the horizontal sides of the thin parts 35a, 35b, and 35c. Forward taper as referred to herein has a taper angle in the range of more than 0° and less than 90° whereas a reverse taper has a taper angle in the range of more than 90° and less than 180°. The term “rectangular” means having a taper angle of 90°, and the term “small taper” means having a taper angle in the range of more than 0° and 60° or less.

In the display device according to the present invention, the thick part 34 is the region having the maximum thickness between the plane of the lower surface of the step shaped cured pattern (that faces the horizontal side 37 of the underlying substrate) and the plane of a upper surface whereas the thin parts 35a, 35b, and 35c are the regions having smaller thickness than the thick part. When the thickness of the thick part 34 is denoted by (T_{FT}) μm and the thickness of the thin parts 35a, 35b, and 35c located at least one step away from the thick part 34 is denoted by (T_{HT}) μm, the thickness difference between (T_{FT}) μm and (T_{HT}) μm, which is denoted by (ΔT_{FT-HT}) μm, is preferably 0.5 μm or more, more preferably 1.0 μm or more, still more preferably 1.5 μm or more, still more preferably 2.0 μm or more, particularly preferably 2.5 μm or more, and most preferably 3.0 μm or more, for each part. On the other hand, it is preferably 0.5 μm or more, more preferably 1.0 μm or more, still more preferably 1.5 μm or more, still more preferably 2.0 μm or more, particularly preferably 2.5 μm or more, and most preferably 3.0 μm or more, for all parts. Here, it is more preferable that the thickness difference (ΔT_{FT-HT}) μm between (T_{FT}) μm and the thickness (T_{HT}) μm of the thin part 35a or 35b is in the above range, and it is still more preferable that the thickness difference (ΔT_{FT-HT}) μm between (T_{FT}) μm and the thickness (T_{HT}) μm of the thin part 35a is in the above range. On the other hand, it is preferable that the thickness difference (ΔT_{FT-HT}) μm between (T_{FT}) μm and (T_{HT}) μm is 10.0 μm or less, more preferably 9.5 μm or less, still more preferably 9.0 μm or less, still more preferably 8.5 μm or less, and particularly preferably 8.0 μm or less.

The display device according to the present invention preferably satisfies all the relationships represented by the formulas (α) to (γ) and more preferably further satisfies all the relationships represented by the formulas (δ) to (ζ).

$$2. \leq ( {T}_{FT} ) \leq 10. \qquad ( α )$$

$$0.2 \leq ( {T}_{HT} ) \leq 7.5 \qquad ( β )$$

$$0.1 \times ( {T}_{FT} ) \leq ( {T}_{HT} ) \leq 0.75 \times ( {T}_{FT} ) \qquad ( γ )$$

$$2. \leq ( {T}_{FT} ) \leq 10. \qquad ( δ )$$

$$0.3 \leq ( {T}_{HT} ) \leq 7. \qquad ( ε )$$

$$0.15 \times ( {T}_{FT} ) \leq ( {T}_{HT} ) \leq 0.7 \times ( {T}_{FT} ) \qquad ( ζ )$$

If they are configured in this way, it significantly enhances the effect of suppressing the decrease in panel yield and improving the reliability of the light emitting element. If a step shape is formed in a batch process using a halftone photomask, it significantly enhances the effect of reducing the process time and improving the productivity in addition to the above effects.

It is preferable that in the display device according to the present invention, the thick parts and the thin parts in the step shape of the cured pattern of the pixel separation layer contain the same colorant (D-DL). It is more preferable that the thick parts and the thin parts contain the same compound (C1-DL) and/or the same compound (C2-DL). If they are configured in this way, it significantly enhances the effect of realizing lower voltage driving of the light emission characteristics, improved light emission luminance, and improved reliability of the light emitting element.

In the case where the display device according to the present invention includes a pixel separation layer having a step shaped cured pattern and having a thickness difference (ΔT_{FT-HT}) μm of 0.5 to 10.0 μm between (T_{FT}) μm and (T_{HT}) μm wherein (T_{HT}) μm is the thickness of the thick parts while (T_{HT}) μm is the thickness of the thin parts in the step shaped cured pattern of the pixel separation layer, it is preferable that in the display device according to the present invention, the thick parts and the thin parts in the step shaped cured pattern of the pixel separation layer contain the same colorant (D-DL) and that the optical densities per μm of the thickness of the thick parts and the thin parts in the visible light wavelength range are 0.5 to 3.0. It is more preferable that the thick parts and the thin parts contain the same compound (C1-DL) and/or the same compound (C2-DL).

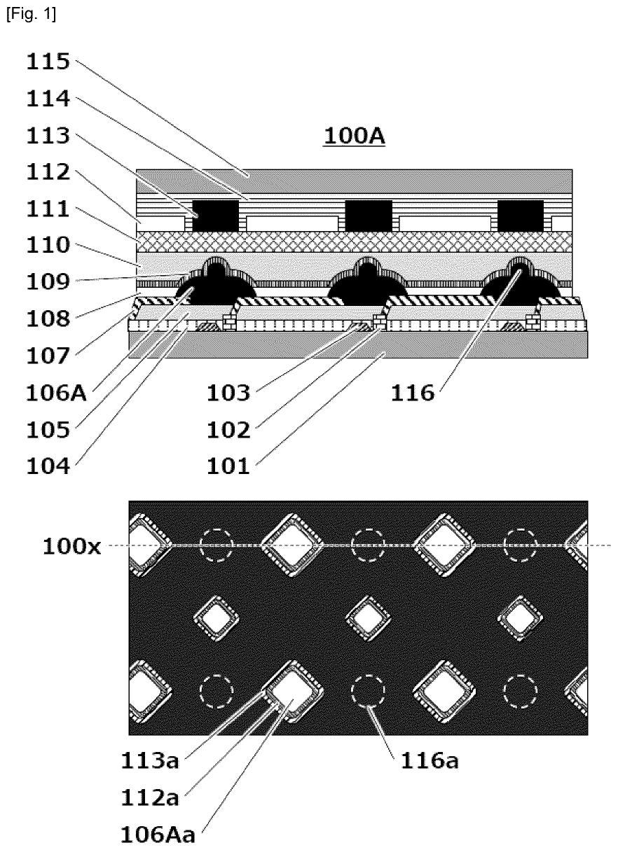

If they are configured in this way, it significantly enhances the effect of realizing lower voltage driving of the light emission characteristics, improved light emission luminance, and improved reliability of the light emitting element. Thus, the thick parts and the thin parts in the step shape of the pixel separation layer contain the same colorant, have optical densities in the same range, and contain the same photosensitizer, and this means that the pixel separation layer having a step shape is a product of a batch process designed for producing the step shape using a single photosensitive composite and halftone photomask. Accordingly, since it is designed so that the alkali solubility in the thin parts is higher than in the thick parts as described above, it is inferred that this serves to realize suppression of residue generation in the opening part in the pixel separation layer part, thereby significantly enhancing the effect of realizing lower voltage driving of the light emission characteristics and improved light emission luminance. It also enhances significantly the effect of reducing the process time and improving the productivity in addition to the above effects. In addition, the presence of a step shape serves to avoid damage to the pixel separation layer, thereby significantly enhancing the effect of preventing a decrease in panel yield and improving the reliability of the light emitting element. The “same compound (C1-DL)” is preferably one of those listed above as compound (C1x-DL). The “same compound (C2-DL)” is preferably one of those listed above as compound (C2x-DL). FIG. 1 gives a schematic cross-sectional view and a plan view illustrating an example of a display device that includes a pixel separation layer having a step shape.

<Spacer layer on pixel separation layer>

The display device according the present invention preferably includes a pixel separation layer that has a cured pattern and has a spacer layer disposed on a part of the pixel separation layer, wherein the spacer layer has a thickness (T_{SP}) μm of 0.5 to 10.0 μm.

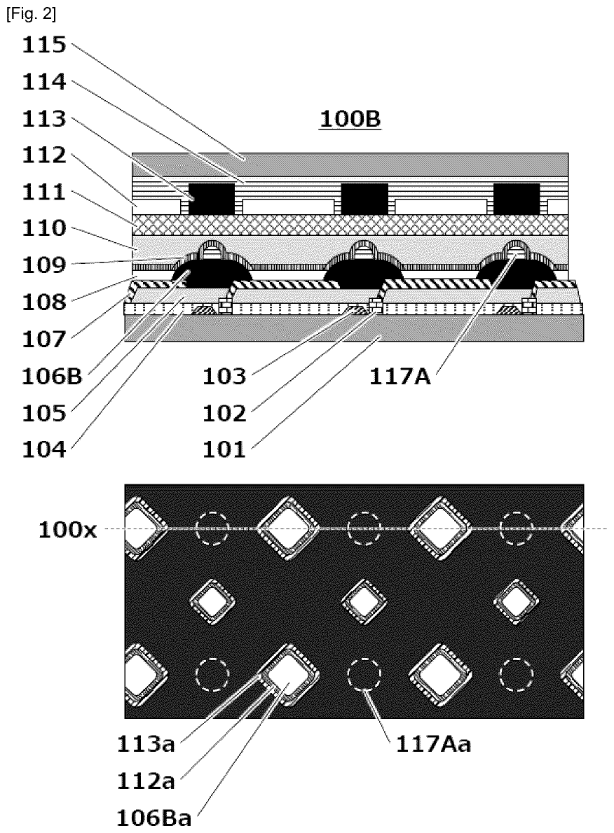

If they are configured in this way, a spacer layer with a sufficient height can be formed by photolithography. The presence of the spacer layer serves to avoid damage to the pixel separation layer, thereby significantly enhancing the effect of preventing a decrease in panel yield and improving the reliability of the light emitting element. FIG. 2 gives a schematic cross-sectional view and a plan view illustrating an example of a display device that includes a pixel separation layer and a spacer layer.

In the display device according the present invention, the spacer layer preferably has a thickness (T_{SP}) μm of 0.5 μm or more, more preferably 1.0 μm or more, still more preferably 1.5 μm or more, still more preferably 2.0 μm or more, particularly preferably 2.5 μm or more, and most preferably 3.0 μm or more. On the other hand, the thickness (T_{SP}) μm of the spacer layer is preferably 10.0 μm or less, more preferably 9.5 μm or less, still more preferably 9.0 μm or less, still more preferably 8.5 μm or less, and particularly preferably 8.0 μm or less.

It is preferable that the display device according the present invention includes a pixel separation layer that has a cured pattern and further has a spacer layer disposed on a part of the pixel separation layer, wherein the spacer layer has a thickness (T_{SP}) μm of 0.5 to 10.0 μm, and the spacer layer preferably satisfies at least one of the requirements (1) to (3) given below, more preferably satisfies at least one of the requirements (1) and (3) given below, and still more preferably satisfies the requirement (1) given below.
(1) The spacer layer does not contain the colorant (D-DL).
(2) The spacer layer includes the colorant (D-DL) and has an optical density of 0.0 to 0.3 per μm of the thickness of the spacer layer in the visible light wavelength.
(3) The spacer layer includes a compound (C2x-DL) having a carboxylate structure containing an indene structure and/or an aryl sulfonate structure containing an indene structure.

The spacer layer in the display device according to the present invention preferably does not include the colorant (D-DL). The absence of the colorant (D-DL) in the spacer layer serves to produce a spacer layer having a sufficient height and reduce damage to the pixel separation layer, thereby significantly enhancing the effect of preventing a decrease in panel yield and improving the reliability of the light emitting element.

### <Organic Layer Containing Light Emitting Layer; Organic Layer Part Containing Light Emitting Layer and Pixel Part in Plan View>

The display device according to the present invention has an organic layer containing a light emitting layer. The organic layer containing a light emitting layer preferably has an organic EL layer containing a light emitting layer and/or a light extraction layer containing a light emitting layer. It is preferable that the organic layer containing a light emitting layer is disposed on the aforementioned first electrode and between the aforementioned first electrode and second electrode to form a laminate structure. If they are configured in this way, it enables the production of a region that corresponds to a pixel part which will be described later. The region that corresponds to a pixel part which will be described later corresponds to a region where the organic layer containing a light emitting layer is in contact with the aforementioned first electrode.

The organic EL layer preferably further includes a hole transport layer and/or an electron transport layer, and the organic EL layer is preferably produced in such a manner that it forms a laminate structure with the light emitting layer.

The display device according to the present invention can serve for the production of an organic EL display that can work as a display device by using a laminate structure that includes an organic EL layer containing a light emitting layer. On the other hand, the display device according to the present invention can serve for the production of a quantum dot display or a micro-LED display, which can work as display devices, by using a laminate structure that includes a light extraction layer containing a light emitting layer.

It is also preferable that the display device according to the present invention is in the form of a quantum dot display that has a structure in which the light extraction layer containing a light emitting layer includes quantum dots. Such a quantum dot display is a display device having a first electrode, a second electrode, a pixel separation layer, and a light extraction layer containing a light emitting layer, all disposed on a substrate, in which the pixel separation layer is disposed so as to overlap with a part of the first electrode while the light extraction layer containing a light emitting layer is disposed on the first electrode and between the first electrode and second electrode, wherein the light extraction layer containing a light emitting layer includes quantum dots.

It is also preferable that the display device according to the present invention is in the form of a micro-LED display that having a structure in which the light extraction layer containing a light emitting layer includes an inorganic semiconductor. The micro-LED display is a display device having a first electrode, a second electrode, a pixel separation layer, and a light extraction layer containing a light emitting layer, all disposed on a substrate, in which the pixel separation layer is disposed so as to overlap with a part of the first electrode while the light extraction layer containing a light emitting layer is disposed on the first electrode and between the first electrode and second electrode, wherein the light extraction layer containing light emitting layer includes an inorganic semiconductor.

The display device according to the present invention can also be applied to the production of a display device having a laminate structure that includes both an organic EL layer containing a light emitting layer and a light extraction layer containing a light emitting layer. For example, the display devices (1) and (2) described below can be cited.
(1) A display device having a light emitting element that is disposed on the first electrode and that includes, as light sources, both an organic EL layer containing a light emitting layer and a light extraction layer containing a light emitting layer (e.g., a layer containing self-luminous type quantum dots)
(2) A display device having a light emitting element that is disposed on the first electrode and configured in such a manner that light coming from a light emitting element (organic EL emitting element) including an organic EL layer containing a light emitting layer is emitted after undergoing color conversion by a light extraction layer containing a light emitting layer (e.g., a layer containing quantum dots) disposed on an organic EL layer containing a light emitting layer

From the perspective of realizing lower voltage driving of the light emission characteristics, improved light emission luminance, and improved luminescent color purity, the display device according to the present invention is preferably a display device that has an organic EL layer containing a light emitting layer and a light extraction layer containing a light emitting layer. For the display device according to the present invention, it is preferable that the light extraction layer containing a light emitting layer preferably includes quantum dots while the organic EL layer containing a light emitting layer and the light extraction layer containing a light emitting layer are disposed on the first electrode in the order of the organic EL layer containing a light emitting layer and the light extraction layer containing a light emitting layer.

On the other hand, the display device according to the present invention may have a laminate structure that includes both an organic EL layer containing a light emitting layer and a light extraction layer containing a light emitting layer wherein the light extraction layer containing a light emitting layer is located at a position other than on the first electrode. For example, the display devices (3) to (5) described below can be cited.
(3) A display device that has two light sources, namely, light 1 coming from a light emitting element including an organic EL layer containing a light emitting layer (organic EL emitting element) disposed on the first electrode and light 2 produced by subjecting light coming from back-lights such as LED to color conversion by a light extraction layer containing a light emitting layer (e.g., a layer containing quantum dots) located at a position other than on the first electrode
(4) A display device in which light coming from a light emitting element including an organic EL layer containing a light emitting layer (organic EL emitting element) disposed on the first electrode is subjected to color conversion by a light extraction layer containing a light emitting layer (e.g., a layer containing quantum dots) located at a position other than on the first electrode, thereby providing light
(5) A display device that has two light sources, namely, light 1 coming from a light emitting element including an organic EL layer containing a light emitting layer (organic EL emitting element) disposed on the first electrode and light 2 produced by subjecting light coming from a light emitting element including an organic EL layer containing a light emitting layer (organic EL emitting element) disposed on the first electrode to color conversion by a light extraction layer containing a light emitting layer (e.g., a layer containing quantum dots) located at a position other than on the first electrode

From the perspective of realizing lower voltage driving of the light emission characteristics, improved light emission luminance, and improved luminescent color purity, the display device according to the present invention preferably further includes a color filter containing quantum dots. In the case of adopting a laminate structure having a color filter containing quantum dots, the light emitting element that overlaps with the color filter containing quantum dots in a plan view and is located at a position lower than the color filter containing quantum dots is preferably one of the following: an organic EL emitting element that emits blue light, an organic EL emitting element that emits white light, an LED element that emits blue light, and an LED element that emits white light.

It is preferable for the display device according to the present invention to include an organic layer part containing a light emitting layer in a plan view. The aforementioned organic layer containing a light emitting layer seen in a plan view corresponds to the organic layer part containing a light emitting layer. The display device according to the present invention has a plurality of pixel parts in a plan view. In the plan view of the display device according to the present invention, each pixel part is preferably defined as an area that is located on the aforementioned first electrode and includes a part of the organic layer containing a light emitting layer in an opening part in the pixel separation layer part or an opening part in the pixel size control layer part. The region that corresponds to a pixel part corresponds to a region where the organic layer part containing a light emitting layer is in contact with the aforementioned first electrode. In the plan view of the display device according to the present invention, the pixel part preferably overlaps with opening parts in the color filter layer part and the black matrix layer part.

### <Sealing Layer>

It is preferable for the display device according to the present invention to include a sealing layer. The sealing layer is a layer that acts to seal the laminate structure that includes the organic layer containing a light emitting layer to isolate it from the external environment in order to prevent the entry of water, gas, etc. It is preferable that the sealing layer is a cured film formed by curing a non-photosensitive composition or a photosensitive composition. The sealing layer is also preferably an inorganic layer containing a metal element or silicon. It is preferable that the sealing layer is formed in such a manner that it overlaps with display areas of the display device such as the first electrode, second electrode, opening part in the pixel separation layer part or opening part in the pixel size control layer part, organic layer containing a light emitting layer, and pixel parts, in order to seal the display areas of the display device. If they are configured in this way, the display areas of the display device are isolated from the external environment and it prevents the light emitting element from being degraded by entry of water, gas, etc., thereby significantly enhancing the effect of improving the reliability of the light emitting element. It is more preferable for the sealing layer to have a structure that serves to suppress the entry of water and oxygen.

In the case where the sealing layer is a cured film formed by curing of a non-photosensitive composition or a photosensitive composition, it is preferable that the water vapor transmission rate and gas transmission rate are decreased by adopting appropriate resin and other components in the composition, and it is more preferable that the water vapor transmission rate and gas transmission rate are decreased by forming a crosslink structure through photoreaction and/or by forming a crosslink structure through thermal reaction. In the case of a sealing layer in the form of an inorganic layer containing a metal element or silicon, it is preferable, from the perspective of decreasing the water vapor transmission rate and gas transmission rate, to use silicon oxide, silicon nitride, or silicon oxynitride, and it is more preferable to use silicon dioxide, trisilicon tetranitride, or silicon oxynitride.

### <Color Filter Layer; Color Filter Layer Part in Plan View>

It is preferable for the display device according to the present invention to include a color filter layer. The color filter layer is a layer disposed on the light extraction side to adjust the light emission spectrum. The color filter layer is preferably a layer disposed on the light extraction side and isolated from the pixel separation layer and the pixel part to adjust the light emission spectrum coming from the pixel part. The color filter layer is preferably a cured film formed by curing a photosensitive composition, more preferably a cured film formed by curing a photosensitive composition containing a colorant. The color filter layer is preferably a layer that is designed to overlap at least with a part of the aforementioned pixel part. If they are configured in this way, it serves to enhance significantly the effect of realizing suppressed external light reflection, lower voltage driving of the light emission characteristics, improved light emission luminance, and improved luminescent color purity.

The color filter layer is preferably colored in the visible light wavelength range due to a resin component etc. in the photosensitive composition, and more preferably it is colored due to a thermal color developer and/or oxidative color developer etc. in addition to a resin component etc. Here, the term “being colored” refers to having a color of red, orange, yellow, green, blue, or purple. The color filter layer preferably contains a color pigment and/or a color dye, more preferably both a color pigment and a color dye.

It is preferable for the display device according to the present invention to include a plurality of color filter layer parts in a plan view. The color filter layer described above corresponds to a color filter layer part in the plan view. From the perspective of realizing suppression of external light reflection, lower voltage driving of the light emission characteristics, and improved light emission luminance, it is preferable that the color filter layer part has a shape of a closed polygon or a shape of a closed polygon in which at least a side and/or an apex is replaced with an arc. It is inferred that as the shape of the color filter layer part is changed from a perfect circle by partial replacement with a straight line, the emission, in the form of surface emission, of light from the light emitting element becomes asymmetric and strengthened by interference of the light coming from the color filter layer part, thereby significantly enhancing the effect of realizing lower voltage driving of the light emission characteristics and improved light emission luminance. It is also inferred that as the shape of the color filter layer part is changed from a perfect circle by partial replacement with a straight line, the scattering of the incident external light coming from the color filter layer part on the surface of the pixel separation layer part becomes asymmetric and weakened by reflection and interference that occur between the first electrode and the second electrode, thereby significantly enhancing the effect of suppressing external light reflection.

### <Black Matrix Layer; Black Matrix Layer Part in Plan View>

It is preferable for the display device according to the present invention to include a black matrix layer. The black matrix layer is a layer disposed on the light extraction side to adjust the light emission region. The black matrix layer is preferably a layer disposed on the light extraction side and isolated from the pixel separation layer and the pixel part to adjust the region of light emission from the pixel part. The black matrix layer is preferably a cured film formed by curing a photosensitive composition, more preferably a cured film formed by curing a photosensitive composition containing a plurality of colorants, and still more preferably a cured film formed by curing a photosensitive composition containing a black colorant. The opening part in the black matrix layer is preferably designed to overlap with the aforementioned pixel part. If they are configured in this way, it significantly enhances the effect of realizing suppressed external light reflection, lower voltage driving of the light emission characteristics, and improved light emission luminance.

The black matrix layer is preferably black in the visible light wavelength range due to coloring by a component such as resin in the photosensitive composition, and more preferably it is black due to coloring by a thermal color developer and/or oxidative color developer etc. in addition to coloring by a component such as resin. Here, the term “coloring” refers to having a color of red, orange, yellow, green, blue, or purple. The black matrix layer preferably contains a black pigment and/or a mixture of two or more color pigments and more preferably contains an organic black pigment and/or an inorganic black pigment. The organic black pigment preferably contains one or more selected from the group consisting of carbon black, benzofuranone based black pigments, perylene based black pigments, and azo based black pigments. The inorganic black pigment preferably contains fine particles, oxides, complex oxides, sulfides, sulfates, nitrates, carbonates, nitrides, carbides, or oxynitrides of metal elements. Preferable metal elements include Ti, Zr, V, Cr, Mn, Co, Ni, Y, Nb, Hf, Ta, W, Re, Fe, Cu, Zn, and Ag.

It is preferable that the black matrix layer has an optical density of 0.5 to 4.0 per μm thickness in the visible light wavelength range. If it is configured in this way, it allows the black matrix layer to act to block the incident external light, thereby significantly enhancing the effect of suppressing external light reflection. In addition, due to increased light blocking efficiency of the black matrix layer in the visible light wavelength region and the ultraviolet region, the entry of external light into the pixel separation layer is decreased to suppress the outgassing from the pixel separation layer and prevent the degradation of the light emitting element, thereby significantly enhancing the effect of improving the reliability of the light emitting element. It is preferable that the black matrix layer is black. Here, the features of the optical density of the black matrix layer are as described above in relation to the optical density of the pixel separation layer.

It is preferable that the display device according to the present invention includes a black matrix layer part having a plurality of opening parts in a plan view. The aforementioned black matrix layer corresponds to each black matrix layer part in the plan view. From the perspective of realizing suppressed external light reflection, lower voltage driving of the light emission characteristics, and improved light emission luminance, it is preferable that each opening part in the black matrix layer part has a shape of a closed polygon or a closed polygon in which at least a side and/or an apex is replaced with an arc. It is inferred that as the shape of the opening part in the black matrix layer part is changed from a perfect circle by partial replacement with a straight line, the emission, in the form of surface emission, of light from the light emitting element becomes asymmetric and strengthened by interference of the light coming from the opening part in the black matrix layer part, thereby significantly enhancing the effect of realizing lower voltage driving of the light emission characteristics and improved light emission luminance. Furthermore, it is inferred that as the shape of the opening part in the black matrix layer part is changed from a perfect circle by partial replacement with a straight line, the scattering of the incident external light coming from the opening part in the black matrix layer part on the surface of the pixel separation layer part becomes asymmetric and weakened by reflection and interference that occur between the first electrode and the second electrode, thereby significantly enhancing the effect of suppressing external light reflection.

In the display device according to the present invention, it is preferable that the black matrix layer part does not overlap with the color filter layer part in the plan view and further satisfies the relationship represented by the general formula (CF/BM).

(CF_{L})≤(BM_{L}) (CF/BM)

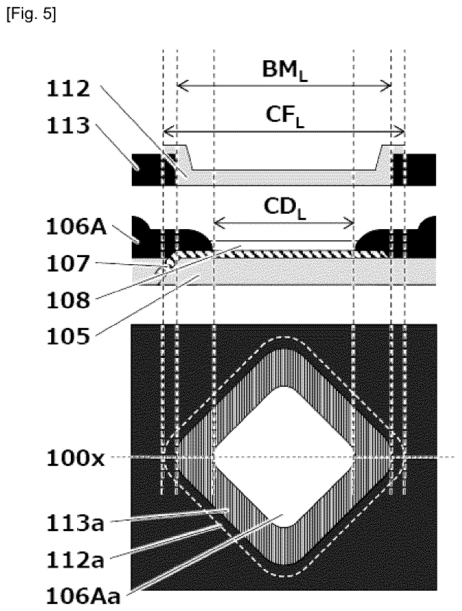

If the color filter layer part overlaps on top of the black matrix layer part, the color filter layer part will have thick areas near the layered part. In such cases, the light emission coming from the light emitting element can pass through the thick areas in the color filter layer part. On the other hand, if the black matrix layer part overlaps on top of the color filter layer part, some edge portions of the color filter layer part will be covered by the black matrix layer part. In such cases, the light emission coming from the light emitting element cannot pass through the areas covered by the black matrix layer part. If they are configured as described above, it serves to avoid the formation of a layered area where the color filter layer part overlaps on top of the black matrix layer part and the formation of a layered area where the black matrix layer part overlaps on top of the color filter layer part, thereby significantly enhancing the effect of realizing lower voltage driving of the light emission characteristics and improved light emission luminance. In addition, this enhances the effect of improving the light emission luminance in a wide angular field of view. FIG. 5 gives a schematic cross-sectional view and a plan view illustrating an example of a display device that has a structure in which the black matrix layer part overlaps with the color filter layer part.

### <Overcoat Layer; Overcoat Layer Part in Plan View>

It is preferable for the display device according to the present invention to further include an overcoat layer that isolates the black matrix layer and the color filter layer. The overcoat layer is a layer that is in contact with both the black matrix layer and the color filter layer and serves to planarize the surface of the laminate structure. It is preferable that the overcoat layer is a cured film formed by curing a non-photosensitive composition or a photosensitive composition, more preferably a cured film formed by curing a photosensitive composition, and still more preferably a cured film formed by curing a photosensitive composition containing a colorant. It is preferable that the overcoat layer overlaps with each pixel part described above. On the other hand, it is more preferable that the overcoat layer does not overlap with the aforementioned pixel parts. If they are configured in this way, it significantly enhances the effect of realizing suppressed external light reflection, lower voltage driving of the light emission characteristics, and improved light emission luminance. In addition, this enhances the effect of improving the light emission luminance in a wide angular field of view.

<TFT element layer>

It is preferable that the display device according to the present invention further includes a TFT element layer. For the display device according to the present invention, it is more preferable that the TFT element layer includes a semiconductor layer, source electrode, drain electrode, gate electrode, and gate insulation layer. When including a TFT element layer, it is preferable for the display device according to the present invention to further include an interlayer insulation layer that insulates the conductive layer located thereon.

Examples of the semiconductor layer disposed in the TFT element layer include silicon semiconductor layers such as of amorphous silicon (a-Si; amorphous silicon), polycrystalline silicon (p-Si; polycrystalline silicon), microcrystalline silicon, and nanocrystalline silicon, oxide semiconductor layers such as of indium gallium zinc oxide (IGZO; In—Ga—Zn—O), and LTPO (low temperature polycrystalline oxide) layers that contain both polycrystalline silicon and oxide semiconductors.

In the case where the display device according to the present invention has an active drive type top emission configuration, it preferably includes a TFT element layer on a substrate, with the TFT element layer being connected to a patterned island type first electrode.

<TFT planarization layer and TFT protection layer>

It is preferable for the display device according to the present invention to further include a TFT planarization layer and/or a TFT protection layer, and it is more preferable to include at least two TFT planarization layers and/or at least two TFT protection layers. Such a TFT planarization layer and/or a TFT protection layer are layers designed for planarization and/or protection of the surface of a laminate structure containing a TFT element.

The TFT planarization layer and the TFT protection layer are preferably black in the visible light wavelength range due to coloring by a component such as resin in the photosensitive composition, and more preferably it is black due to coloring by a thermal color developer and/or oxidative color developer etc. in addition to coloring by a component such as resin. Here, the term “coloring” refers to having a color of red, orange, yellow, green, blue, or purple.

<Interlayer insulation layer>

The display device according to the present invention preferably further includes an interlayer insulation layer and more preferably includes at least two interlayer insulation layers. Each interlayer insulation layer is a layer designed to insulate a conductive layer such as wiring and electrodes in the laminate structure. The interlayer insulation layer is preferably a layer designed to insulate a conductive layer disposed below the TFT planarization layer and/or the TFT protection layer. Furthermore, the interlayer insulation layer is preferably an interlayer insulation layer acting to insulate the touch panel wiring and/or the touch panel electrode which will be described later.

The interlayer insulation layer is preferably black in the visible light wavelength range due to coloring by a component such as resin in the photosensitive composition, and more preferably it is black due to coloring by a thermal color developer and/or oxidative color developer etc. in addition to coloring by a component such as resin. Here, the term “coloring” refers to having a color of red, orange, yellow, green, blue, or purple.

### <Touch Panel Wiring and Touch Panel Electrode>

The display device according to the present invention preferably further includes touch panel wiring and/or touch panel electrodes, and more preferably includes at least two touch panel wiring layers and/or at least two touch panel electrode layers. Touch panel wiring refers to wiring designed for conduction between a member having a position detection function and an external circuit. The touch panel wiring is preferably lead-out wiring designed for conduction between a touch panel electrode and an external circuit. A touch panel electrode is an electrode having a position detection function. The touch panel electrode is preferably an electrode that performs position detection based on changes in capacitance.

A transparent electrode or a non-transparent electrode can be used in touch panel wiring. It is preferable for the touch panel wiring to have a transparent electrode from the perspective of expanding the pixel part area, increasing the opening ratio in the display device, and realizing a narrow bezel display device. If they are configured in this way, it significantly enhances the effect of realizing suppressed external light reflection, lower voltage driving of the light emission characteristics, and improved light emission luminance. It is preferable for the touch panel electrode to be a transparent electrode from the perspective of realizing lower voltage driving of the light emission characteristics, improved light emission luminance, and suppressed visibility of the touch panel electrode.

When the display device according to the present invention includes touch panel wiring, a touch panel electrode, and an interlayer insulation layer below the aforementioned first electrode on the substrate, it will have an in-cell type touch panel. If they are configured in this way, it significantly enhances the effect of improving the light emission luminance. When the display device according to the present invention includes touch panel wiring, a touch panel electrode, and an interlayer insulation layer below the aforementioned sealing layer on the second electrode, it will have an in-cell type touch panel. If they are configured in this way, it significantly enhances the effect of improving the light emission luminance. When the display device according to the present invention includes touch panel wiring, a touch panel electrode, and an interlayer insulation layer below the aforementioned color filter layer and black matrix layer on the sealing layer, it will have an on-cell type touch panel. If they are configured in this way, it significantly enhances the effect of improving the light emission luminance and decreasing the number of production steps.

When the display device according to the present invention includes touch panel wiring, a touch panel electrode, and an interlayer insulation layer on top of a color filter layer, black matrix layer, or overcoat layer (hereinafter referred to as color filter layer etc.) disposed on the same substrate, it will have an on-cell type touch panel. If they are configured in this way, it significantly enhances the effect of improving the light emission luminance and decreasing the number of production steps. On the other hand, when the display device according to the present invention includes, above the color filter layer etc., touch panel wiring, a touch panel electrode, and an interlayer insulation layer disposed on another substrate adhered thereto, it will have an out-cell type touch panel. If they are configured in this way, it significantly enhances the effect of decreasing the number of production steps.

When the display device according to the present invention includes one or more selected from the group consisting of linear polarizing plate, quarter wave plate, and circular polarizing plate above the color filter layer etc. disposed on the same substrate, it will have a build-up type polarizing film. If they are configured in this way, it significantly enhances the effect of suppressing external light reflection. On the other hand, when the display device according to the present invention includes one or more selected from the group consisting of linear polarizing plate, quarter wave plate, and circular polarizing plate disposed on another substrate and adhered on top of the color filter layer etc., it will have an external type polarizing film. If they are configured in this way, it significantly enhances the effect of suppressing external light reflection and decreasing the number of production steps.

When the display device according to the present invention includes no linear polarizing plate, quarter wave plate, or circular polarizing plate above the color filter layer etc. disposed on the same substrate, it will serve to produce a display device devoid of a polarizing film. Similarly, when the display device according to the present invention includes no linear polarizing plate, quarter wave plate, or circular polarizing plate disposed on another substrate and adhered on top of the color filter layer etc., it will serve to produce a display device devoid of a polarizing film. If they are configured in this way, it significantly enhances the effect of realizing lower voltage driving of the light emission characteristics, improved light emission luminance, improved flexibility, and improved bending property. Furthermore, the absence of a polarizing film significantly enhances the effect of reducing the cost required for manufacturing the display device.

It is also preferable that the sealing layer, color filter layer, black matrix layer, overcoat layer, TFT planarization layer, TFT protection layer, and interlayer insulation layer are cured films formed by curing the same photosensitive composition as used for the pixel separation layer etc. described above. Furthermore, it is also preferable that these layers contain the same colorant, resin, or compound as used in the pixel separation layer etc. described above.

Examples and preferable features of the colorant (D-DL) present in the sealing layer, color filter layer, black matrix layer, overcoat layer, TFT planarization layer, TFT protection layer, or interlayer insulation layer are the same as the examples and preferable features described in relation to the colorant (D-DL) in the aforementioned pixel separation layer etc. Examples and preferable features of the resins present in these layers are the same as the examples and preferable features described in relation to the resin (A1-DL), resin (A2-DL), and resin (A3-DL) in the aforementioned pixel separation layer etc.

Examples and preferable features of the compounds present in these layers are the same as the examples and preferable features described above in relation to the compound (C1-DL), compound (C2-DL), compound (C1x-DL), compound (C2x-DL), compounds having phosphoric acid based structures, compounds having the sulfur element, and compounds having the chlorine element or the bromine element present in the aforementioned pixel separation layer etc.

### <Configuration of Display Device>

It is preferable that the display device according to the present invention includes a first electrode, a second electrode, a pixel separation layer, an organic layer containing a light emitting layer, a sealing layer, a color filter layer, and a black matrix layer that are disposed on one substrate. In the display device according to the present invention, it is preferable that the first electrode, the organic layer containing a light emitting layer, the second electrode, the sealing layer, and the color filter layer are disposed one on top of another in this order.

If, for example, a pixel separation layer and a color filter layer are formed on separate substrates, followed by adhering together the substrate having the pixel separation layer and the substrate having the color filter layer using an adhesive etc., emission defects etc. due to poor alignment accuracy of adhesion position can occur. In addition, a pixel separation layer and a color filter layer are formed on separate substrates in this case, and exposure alignment errors can occur during the formation of laminate structures on each substrate, possibly leading to emission defects etc. due to design errors in the laminate structures when the separate substrates are adhered together. Compared to this, in the case where these layers are formed on the same substrate in the display device according to the present invention, it serves to suppress the occurrence of emission defects etc. due to, for example, poor alignment accuracy or exposure alignment errors between the pixel parts and the color filter layer part, thereby significantly enhancing the effect of preventing a decrease in panel yield and improving the reliability of the light emitting element.

### <Configuration of Display Device in Plan View>

The display device according to the present invention has a plurality of pixel parts in a plan view. If in a plan view, a pixel part is defined as an area that is located in an opening part in a pixel separation layer part and that is located on a first electrode part and includes an organic layer part containing a light emitting layer, then it is preferable for the display device according to the present invention to include a plurality of pixel parts and a pixel separation layer part having a plurality of opening parts, and it is preferable to include a plurality of pixel parts, a pixel separation layer part having a plurality of opening parts, a plurality of color filter layer parts, and a black matrix layer part having a plurality of opening parts.

If in the plan view, a pixel part is defined as an area that is located in an opening part in a pixel size control layer part and that is located on a first electrode part and includes an organic layer part containing a light emitting layer, then it is preferable for the display device according to the present invention to include a plurality of pixel parts and a pixel size control layer part having a plurality of opening parts, and it is preferable to include a plurality of pixel parts, a pixel size control layer part having a plurality of opening parts, a plurality of color filter layer parts, and a black matrix layer part having a plurality of opening parts.

In the display device according to the present invention, it is more preferable that each pixel part overlaps with a color filter layer part and an opening part in the black matrix layer part in the plan view.

In the display device according to the present invention, it is preferable that the black matrix layer part does not overlap with a color filter layer part in the plan view. If it is configured in this way, it significantly enhances the effect of improving the light emission luminance. In addition, this significantly enhances the effect of improving the light emission luminance in a wide angular field of view.

In the case where the black matrix layer part does not overlap with a color filter layer part in the plan view of the display device according to the present invention, it is preferable for the display device according to the present invention to further include an overcoat layer that isolates the black matrix layer part and the color filter layer part. Furthermore, it is preferable that the plan view includes an overcoat layer part that isolates the black matrix layer part and the color filter layer parts. For the display device according to the present invention, it is preferable that each pixel part overlaps with the overcoat layer part in the plan view. On the other hand, for the display device according to the present invention, it is preferable that each pixel part does not overlap with the overcoat layer part. If they are configured in this way, it significantly enhances the effect of realizing suppressed external light reflection and improved light emission luminance. In addition, this significantly enhances the effect of improving the light emission luminance in a wide angular field of view.

<Detection Intensity of Sulfur Ion (S⁻), Chlorine Ion (Cl⁻), Bromine Ion (Br⁻), and Indium Oxide Ion (InO²⁻) on First Electrode>

The display device according to the present invention satisfies the relationship represented by the general formula (SA-1) and/or the relationship represented by the general formula (XA-1):

$$2 \leq ( {S}_{Dep / Anode} ) \leq 200 \qquad ( SA - 1 )$$

$$2 \leq ( {X}_{Dep / Anode} ) \leq 200 , \qquad ( XA - 1 )$$

wherein:
(S_{Dep/Anode}) counts represents the detection intensity of the sulfur ion (S⁻),
(X_{Dep/Anode}) counts represents the total of (Cl_{Dep/Anode}) and (Br_{Dep/Anode}),
(Cl_{Dep/Anode}) counts represents the detection intensity of the chlorine ion (Cl⁻),
(Br_{Dep/Anode}) counts represents the detection intensity of the bromine ion (Br⁻),
all measured by time-of-flight secondary ion mass spectrometry at a position 3 nm deep in a pixel part from the surface of the first electrode, the surface being in contact with the organic layer containing a light emitting layer.

The general formula (SA-1) is an equation indicating that the detection intensity of the sulfur ion (S⁻) is within a specific range. The general formula (XA-1) is an equation indicating that the total of the detection intensity of the chlorine ion (Cl⁻) and the detection intensity of the bromine ion (Br⁻) is within a specific range. Larger detection intensities of the sulfur ion, chlorine ion, or bromine ion on the surface of the first electrode in contact with the organic layer containing a light emitting layer in a pixel part means that larger proportions of the surface of the first electrode are modified by these elements. If the detection intensities of the sulfur ion, chlorine ion, and bromine ion are adjusted as described above, it serves to realize excellent light emission characteristics that allows lower voltage driving to be achieved by controlling the difference in the work function. As a result, this allows a higher light emission luminance to be achieved at the same driving voltage. This in turn enhances the effect of improving the reliability of the light emitting element. In addition, it is considered that this also allows a higher light emission luminance to be achieved at the same driving voltage. It is also expected that for example, the polarization structure and electric charge balance on the first electrode in an organic EL display can be controlled by intentional adjustment of the detection intensities of these ions on the first electrode. It is inferred from this that suppression of ion migration and electromigration attributed to metal impurities and ion impurities that can adversely affect the light emission characteristics can significantly enhance the effect of improving the reliability of the light emitting element. In addition, it is inferred that suppression of migration and aggregation of metal in the first electrode can significantly enhance the effect of improving the reliability of the light emitting element.

From the perspective of realizing lower voltage driving of the light emission characteristics, improved light emission luminance, and improved reliability of the light emitted light, the display device according to the present invention preferably satisfies the relationships represented by the general formula (SA-1) and the general formula (XA-1) specified above.

From the perspective of realizing lower voltage driving of the light emission characteristics, improved light emission luminance, and improved reliability of the light emitted light, the display device according to the present invention preferably further satisfies the relationships represented by the general formula (SA-1a) and/or the general formula (XA-1a):

$$2 \leq ( {S}_{Dep / Anode} ) \leq 100 \qquad ( SA - 1 a )$$

$$2 \leq ( {X}_{Dep / Anode} ) \leq 100. \qquad ( XA - 1 a )$$

From the perspective of realizing lower voltage driving of the light emission characteristics, improved light emission luminance, and improved reliability of the light emitting element, (S_{Dep/Anode}) is preferably 2 or more, more preferably 4 or more, still more preferably 6 or more, still more preferably 8 or more, and particularly preferably 10 or more. On the other hand, from the perspective of realizing lower voltage driving of the light emission characteristics, improved light emission luminance, and improved reliability of the light emitting element, (S_{Dep/Anode}) is preferably 200 or less, more preferably 170 or less, still more preferably 150 or less, still more preferably 120 or less, and particularly preferably 100 or less. In addition, (S_{Dep/Anode}) is preferably 80 or less, more preferably 60 or less, still more preferably 40 or less, still more preferably 30 or less, and particularly preferably 25 or less.

From the perspective of realizing lower voltage driving of the light emission characteristics, improved light emission luminance, and improved reliability of the light emitting element, (X_{Dep/Anode}) is preferably 2 or more, more preferably 4 or more, still more preferably 6 or more, still more preferably 8 or more, and particularly preferably 10 or more. On the other hand, from the perspective of realizing lower voltage driving of the light emission characteristics, improved light emission luminance, and improved reliability of the light emitting element, (X_{Dep/Anode}) is preferably 200 or less, more preferably 170 or less, still more preferably 150 or less, still more preferably 120 or less, and particularly preferably 100 or less. In addition, (X_{Dep/Anode}) is preferably 80 or less, more preferably 60 or less, still more preferably 40 or less, still more preferably 30 or less, and particularly preferably 25 or less.

Here, the detection intensity of the sulfur ion (S⁻), the detection intensity of the chlorine ion (Cl⁻), and the detection intensity of the bromine ion (Br⁻) are calculated as the average of three measurements taken by time-of-flight secondary ion mass spectrometry. It is also preferable that the average values of the detection intensities of each ion measured at positions 3 nm and 4 nm from the surface of the first electrode satisfy the above relationships, and it is more preferable that the average values of the detection intensities of each ion measured at positions 3 nm, 4 nm, and 5 nm from the surface of the first electrode satisfy the above relationships.

Here, for the display device according to the present invention, the surface of the first electrode that is in contact with the organic layer containing a light emitting layer can be identified by depth measurement performed by time-of-flight secondary ion mass spectrometry. First, an etching ion species accelerated by applying a bias is allowed to collide against a pixel part through the light emitting layer, and etching is performed in the depth direction toward the first electrode while allowing the primary ion species accelerated by applying a bias to collide through the light emitting layer. Then, secondary ions released at this time are observed to measure the depth profile in the depth direction from the light emitting layer toward the first electrode. In the depth profile, the point where the detection intensity reaches 100 or more for ions of at least one of the elements contained in the outermost layer of the first electrode that faces the light emitting layer is assumed to represent the surface of the first electrode. In addition, to determine the position 3 nm deep from the surface of the first electrode, the depth profile in the depth direction from the light emitting layer toward the first electrode is measured down to the bottom of the first electrode while also measuring the thickness of the first electrode, and calculating the sputter rate of the first electrode from these measurements, thereby determining the position 3 nm deep from the surface of the first electrode.

Similarly, for the display device according to the present invention, the surface of the transparent conductive oxide film layer that contains indium as the main constituent element and is in contact with the organic layer containing a light emitting layer can be identified based on depth measurement performed by time-of-flight secondary ion mass spectrometry. For the pixel part, secondary ions are observed in the same way from the light emitting layer to determine the depth profile in the depth direction. In the depth profile, the point where the detection intensity of the indium oxide ion (InO²⁻) reaches 100 or more is assumed to represent the surface of the transparent conductive oxide film layer containing indium as the main constituent element. In addition, to determine the position 3 nm deep from the surface of the transparent conductive oxide film layer containing indium as the main constituent element, the depth profile in the depth direction from the light emitting layer toward the first electrode is measured down to the bottom of the transparent conductive oxide film layer while also measuring the thickness of the transparent conductive oxide film layer, and the sputter rate of the transparent conductive oxide film layer is calculated from these measurements, thereby determining the position 3 nm deep from the surface of the transparent conductive oxide film layer containing indium as the main constituent element.

To determine the bottom of the first electrode or the bottom of the transparent conductive oxide film layer, in the depth profile, the point where the detection intensity reaches 100 or more for ions of at least one of the elements contained in the layer directly under the first electrode or in the layer directly under the transparent conductive oxide film layer is assumed to represent the bottom of the first electrode or the bottom of the transparent conductive oxide film layer. The thickness of the first electrode and the thickness of the transparent conductive oxide film layer can be measured by means of TEM or SEM. In another method, the first electrode or the transparent conductive oxide film layer is examined by elemental analysis, and a metal film or oxide film having the same elemental composition is formed to a desired thickness. Then, the resulting metal film or oxide film is subjected to depth measurement by time-of-flight secondary ion mass spectrometry to measure the depth profile in the depth direction to the bottom of the metal film or oxide film, followed by calculating the sputter rate of the metal film or oxide film from the measured thickness of the metal film or oxide film. Good elemental composition analysis techniques include, for example, Rutherford backscattering spectrometry and other analysis techniques.

In the case where in the display device according to the present invention, the first electrode has a transparent conductive oxide film layer and a non-transparent conductive metal layer and has, as the outermost layer of the first electrode that faces the light emitting layer, a transparent conductive oxide film layer containing indium as the main constituent element, the display device according to the present invention preferably satisfies the relationship represented by the general formula (SA-1) specified above, further satisfies the relationships represented by the general formula (SA-2) and the general formula (InSA-1), and/or satisfies the relationship represented by the general formula (XA-1) specified above, and further satisfies the relationships represented by the general formula (XA-2) and the general formula (InXA-1):

$$0.0001 \leq ( {S}_{Dep / Anode} / ( {In O}_{Dep / Anode} ) \leq 0.1 \qquad ( SA - 2 )$$

$$1 , 000 \leq ( {In O}_{Dep / Anode} ) \leq 40 , 000 \qquad ( InSA - 1 )$$

$$0.0001 \leq ( {X}_{Dep / Anode} ) / ( {In O}_{Dep / Anode} ) \leq 0.1 \qquad ( XA - 2 )$$

$$1 , 000 \leq ( {In O}_{Dep / Anode} ) \leq 40 , 000 \qquad ( InXA - 1 )$$

wherein (InO_{Dep/Anode}) counts is the detection intensity of the indium oxide ion (InO₂⁻), measured by time-of-flight secondary ion mass spectrometry at a position 3 nm deep in the pixel part from the surface of the transparent conductive oxide film layer, the surface being in contact with the organic layer containing a light emitting layer.

If they are configured in this way, each pixel part of the display device according to the present invention has, as the outermost layer of the first electrode that faces the light emitting layer, a transparent conductive oxide film layer having a thickness of 3 nm or more and containing indium as the main constituent element. The general formula (SA-2) is an equation showing that the detection intensity of the sulfur ion (S⁻) and the detection intensity of the indium oxide ion (InO₂⁻) have a specific intensity ratio. The general formula (XA-2) is an equation showing that the total of the detection intensity of the chlorine ion (Cl⁻) and the detection intensity of the bromine ion (Br⁻) and the detection intensity of the indium oxide ion (InO₂⁻) have a specific intensity ratio. The general formula (InSA-1) and the general formula (InXA-1) are equations showing that the detection intensity of the indium oxide ion (InO₂⁻) is within a specific range. A larger detection intensity of the indium oxide ion on the surface of the first electrode that is in contact with the organic layer containing a light emitting layer in a pixel part means that a larger proportion of the exposed surface of the transparent conductive oxide film layer contains indium as the main constituent element. If they are configured in this way, it significantly enhances the effect of realizing lower voltage driving of the light emission characteristics, improved light emission luminance, and improved reliability of the light emitting element.

From the perspective of realizing lower voltage driving of the light emission characteristics, improved light emission luminance, and improved reliability of the light emitting element, the display device according to the present invention preferably satisfies the relationship represented by the general formula (SA-1) specified above, further satisfies the relationships represented by the general formula (SA-2) and the general formula (InSA-1), and also satisfies the relationship represented by the general formula (XA-1) specified above and further satisfies the relationships represented by the general formula (XA-2) and the general formula (InXA-1).

From the perspective of realizing lower voltage driving of the light emission characteristics, improved light emission luminance, and improved reliability of the light emitting element, (S_{Dep/Anode})/(InO_{Dep/Anode}) is preferably 0.0003 or more, more preferably 0.0005 or more, and still more preferably 0.0010 or more. Furthermore, from the perspective of realizing lower voltage driving of the light emission characteristics and improved light emission luminance, it is preferably 0.0020 or more, more preferably 0.0040 or more, still more preferably 0.0060 or more, still more preferably 0.0080 or more, and particularly preferably 0.0100 or more. On the other hand, (S_{Dep/Anode})/(InO_{Dep/Anode}) is preferably 0.0800 or less, more preferably 0.0600 or less, still more preferably 0.0400 or less, still more preferably 0.0300 or less, and particularly preferably 0.0250 or less.

(InO_{Dep/Anode}) is more preferably 1,500 or more and still more preferably 2,000 or more. On the other hand, (InO_{Dep/Anode}) is preferably 30,000 or less, more preferably 20,000 or less, still more preferably 15,000 or less, and particularly preferably 10,000 or less. Furthermore, from the perspective of realizing lower voltage driving of the light emission characteristics and improved light emission luminance, it is preferably 7,500 or less, more preferably 6,000 or less, still more preferably 5,000 or less, still more preferably 4,000 or less, and particularly preferably 3,500 or less.

From the perspective of realizing lower voltage driving of the light emission characteristics, improved light emission luminance, and improved reliability of the light emitting element, (X_{Dep/Anode})/(InO_{Dep/Anode}) is preferably 0.0003 or more, more preferably 0.0005 or more, and still more preferably 0.0010 or more. Furthermore, from the perspective of realizing lower voltage driving of the light emission characteristics and improved light emission luminance, it is preferably 0.0020 or more, more preferably 0.0040 or more, still more preferably 0.0060 or more, still more preferably 0.0080 or more, and particularly preferably 0.0100 or more. On the other hand, (X_{Dep/Anode})/(InO_{Dep/Anode}) is preferably 0.0800 or less, more preferably 0.0600 or less, still more preferably 0.0400 or less, still more preferably 0.0300 or less, and particularly preferably 0.0250 or less.

(InO_{Dep/Anode}) is more preferably 1,500 or more and still more preferably 2,000 or more. On the other hand, (InO_{Dep/Anode}) is preferably 30,000 or less, more preferably 20,000 or less, still more preferably 15,000 or less, and particularly preferably 10,000 or less. Furthermore, from the perspective of realizing lower voltage driving of the light emission characteristics and improved light emission luminance, it is preferably 7,500 or less, more preferably 6,000 or less, still more preferably 5,000 or less, still more preferably 4,000 or less, and particularly preferably 3,500 or less.

Here, the detection intensity of the indium oxide ion (InO₂⁻) is calculated as the average of three measurements taken by time-of-flight secondary ion mass spectrometry. It is also preferable that the average values of the detection intensities of each ion measured at positions 3 nm and 4 nm from the surface of the first electrode satisfy the above relationships, and it is more preferable that the average values of the detection intensities of each ion measured at positions 3 nm, 4 nm, and 5 nm from the surface of the first electrode satisfy the above relationships.

<Detection Intensity of Carbon Ion (C⁻) and Indium Oxide Ion (InO₂⁻) on First Electrode>

From the perspective of realizing lower voltage driving of the light emission characteristics, improved light emission luminance, and improved reliability of the light emitting element, the display device according to the present invention preferably satisfies the relationship represented by the general formula (CA-1) wherein (C_{Dep/Anode}) counts is the detection intensity of the carbon ion (C⁻) measured by time-of-flight secondary ion mass spectrometry at a position 3 nm deep in a pixel part from the surface of the first electrode that is in contact with the organic layer containing a light emitting layer:

$$20 \leq ( {C}_{Dep / Anode} ) \leq 4 , 0. \qquad ( CA - 1 )$$

The general formula (CA-1) is an equation indicating that the detection intensity of the carbon ion (C⁻) is within a specific range. A larger detection intensity of the carbon ion on the surface of the first electrode that is in contact with the organic layer containing a light emitting layer in a pixel part means that carbon atoms account for a larger proportion on the surface of the first electrode. (C_{Dep/Anode}) is preferably 50 or more, more preferably 75 or more, and still more preferably 100 or more. On the other hand, (C_{Dep/Anode}) is preferably 3,000 or less, more preferably 2,000 or less, and still more preferably 1,000 or less.

In the case where in the display device according to the present invention, the first electrode has a transparent conductive oxide film layer and a non-transparent conductive metal layer and has, as the outermost layer of the first electrode that faces the light emitting layer, a transparent conductive oxide film layer containing indium as the main constituent element, the display device according to the present invention preferably satisfies the relationship represented by the general formula (CA-1) and further satisfies the relationships represented by the general formula (CA-2) and the general formula (InCA-1) wherein (InO_{Dep/Anode}) counts is the detection intensity of the indium oxide ion (InO₂⁻) measured by time-of-flight secondary ion mass spectrometry at a position 3 nm deep in the pixel part from the surface of the transparent conductive oxide film layer, the surface being in contact with the organic layer containing a light emitting layer:

$$0.001 \leq ( {C}_{Dep / Anode} ) / ( {In O}_{Dep / Anode} ) \leq 4. \qquad ( CA - 2 )$$

$$1 , 000 \leq ( {In O}_{Dep / Anode} ) \leq 40 , 0. \qquad ( InCA - 1 )$$

The general formula (CA-2) is an equation indicating that the detection intensity of the carbon ion (C⁻) and the detection intensity of the indium oxide ion (InO₂⁻) have a specific intensity ratio. The general formula (InCA-1) is an equation indicating that the detection intensity of the indium oxide ion (InO₂⁻) is within a specific range. If they are configured in this way, it significantly enhances the effect of realizing lower voltage driving of the light emission characteristics, improved light emission luminance, and improved reliability of the light emitting element.

(C_{Dep/Anode})/(InO_{Dep/Anode}) is preferably 0.003 or more, more preferably 0.005 or more, still more preferably 0.010 or more, and particularly preferably 0.020 or more. Furthermore, from the perspective of realizing lower voltage driving of the light emission characteristics and improved light emission luminance, it is preferably 0.050 or more, more preferably 0.075 or more, and still more preferably 0.100 or more. On the other hand, (C_{Dep/Anode})/(InO_{Dep/Anode}) is preferably 3.0 or less, more preferably 2.0 or less, and still more preferably 1.0 or less. (InO_{Dep/Anode}) is preferably 1,200 or more, more preferably 1,500 or more, and still more preferably 2,000 or more. On the other hand, (InO_{Dep/Anode}) is preferably 30,000 or less, more preferably 20,000 or less, still more preferably 15,000 or less, and particularly preferably 10,000 or less. Furthermore, from the perspective of realizing lower voltage driving of the light emission characteristics and improved light emission luminance, it is preferably 7,500 or less, more preferably 6,000 or less, still more preferably 5,000 or less, still more preferably 4,000 or less, and particularly preferably 3,500 or less.

Here, the detection intensity of the carbon ion (C⁻) is calculated as the average of three measurements taken by time-of-flight secondary ion mass spectrometry. It is also preferable that the average values of the detection intensities of each ion measured at positions 3 nm and 4 nm from the surface of the first electrode satisfy the above relationships, and it is more preferable that the average values of the detection intensities of each ion measured at positions 3 nm, 4 nm, and 5 nm from the surface of the first electrode satisfy the above relationships.

<Detection Intensity of Cyanide Ion (CN⁻) and Indium Oxide Ion (InO₂⁻) on First Electrode>

From the perspective of realizing lower voltage driving of the light emission characteristics, improved light emission luminance, and improved reliability of the light emitting element, the display device according to the present invention preferably satisfies the relationship represented by the general formula (CNA-1) wherein (CN_{Dep/Anode}) counts is the detection intensity of the cyanide ion (CN⁻) measured by time-of-flight secondary ion mass spectrometry at a position 3 nm deep in a pixel part from the surface of the first electrode that is in contact with the organic layer containing a light emitting layer:

$$20 \leq ( {CN}_{Dep / Anode} ) \leq 4 , 0. \qquad ( CNA - 1 )$$

The general formula (CNA-1) is an equation indicating that the detection intensity of the cyanide ion (CN⁻) is within a specific range. A larger detection intensity of the cyanide ion on the surface of the first electrode that is in contact with the organic layer containing a light emitting layer in a pixel part means that carbon atoms bonded to nitrogen atoms account for a larger proportion on the surface of the first electrode. (CN_{Dep/Anode}) is preferably 50 or more, more preferably 75 or more, and still more preferably 100 or more. On the other hand, (CN_{Dep/Anode}) is preferably 3,000 or less, more preferably 2,000 or less, and still more preferably 1,000 or less.

In the case where in the display device according to the present invention, the first electrode has a transparent conductive oxide film layer and a non-transparent conductive metal layer and has, as the outermost layer of the first electrode that faces the light emitting layer, a transparent conductive oxide film layer containing indium as the main constituent element, the display device according to the present invention preferably satisfies the relationship represented by the general formula (CNA-1) and further satisfies the relationships represented by the general formula (CNA-2) and the general formula (InCNA-1) wherein (InO_{Dep/Anode}) counts is the detection intensity of the indium oxide ion (InO₂⁻) measured by time-of-flight secondary ion mass spectrometry at a position 3 nm deep in the pixel part from the surface of the transparent conductive oxide film layer, the surface being in contact with the organic layer containing a light emitting layer:

$$0.001 \leq ( {CN}_{Dep / Anode} ) / ( {In O}_{Dep / Anode} ) \leq 4. \qquad ( CNA - 2 )$$

$$1 , 000 \leq ( {In O}_{Dep / Anode} ) \leq 40 , 0. \qquad ( InCNA - 1 )$$

The general formula (CNA-2) is an equation indicating that the detection intensity of the cyanide ion (C⁻) and the detection intensity of the indium oxide ion (InO₂⁻) have a specific intensity ratio. The general formula (InCNA-1) is an equation indicating that the detection intensity of the indium oxide ion (InO₂⁻) is within a specific range. If they are configured in this way, it significantly enhances the effect of realizing lower voltage driving of the light emission characteristics, improved light emission luminance, and improved reliability of the light emitting element.

(CN_{Dep/Anode})/(InO_{Dep/Anode}) is preferably 0.003 or more, more preferably 0.005 or more, still more preferably 0.010 or more, and particularly preferably 0.020 or more. Furthermore, from the perspective of realizing lower voltage driving of the light emission characteristics and improved light emission luminance, it is preferably 0.050 or more, more preferably 0.075 or more, and still more preferably 0.100 or more. On the other hand, (CN_{Dep/Anode})/(InO_{Dep/Anode}) is preferably 3.0 or less, more preferably 2.0 or less, and still more preferably 1.0 or less. (InO_{Dep/Anode}) is preferably 1,200 or more, more preferably 1,500 or more, and still more preferably 2,000 or more. On the other hand, (InO_{Dep/Anode}) is preferably 30,000 or less, more preferably 20,000 or less, still more preferably 15,000 or less, and particularly preferably 10,000 or less. Furthermore, from the perspective of realizing lower voltage driving of the light emission characteristics and improved light emission luminance, it is preferably 7,500 or less, more preferably 6,000 or less, still more preferably 5,000 or less, still more preferably 4,000 or less, and particularly preferably 3,500 or less.

Here, the detection intensity of the cyanide ion (CN⁻) is calculated as the average of three measurements taken by time-of-flight secondary ion mass spectrometry. It is also preferable that the average values of the detection intensities of each ion measured at positions 3 nm and 4 nm from the surface of the first electrode satisfy the above relationships, and it is more preferable that the average values of the detection intensities of each ion measured at positions 3 nm, 4 nm, and 5 nm from the surface of the first electrode satisfy the above relationships.

<Detection Intensity Ratio of Sulfur Ion (S⁻), Chlorine Ion (Cl⁻), and Bromine Ion (Br⁻) on Pixel Separation Layer Part and First Electrode Part>

From the perspective of realizing lower voltage driving of the light emission characteristics, improved light emission luminance, and improved reliability of the light emitting element, the display device according to the present invention preferably satisfies the relationship represented by the general formula (SD-1) and/or the relationship represented by the general formula (XD-1):

$$0.1 \leq ( {S}_{Anode} ) / ( {S}_{PDL} ) \leq 20 \qquad ( SD - 1 )$$

$$0.1 \leq ( {X}_{Anode} ) / ( {X}_{PDL} ) \leq 20 , \qquad ( XD - 1 )$$

wherein:
(SP_{DL}) is the ratio of the ion detection intensity of the sulfur ion (S⁻),
(X_{PDL}) is the total of (Cl_{PDL}) and (Br_{PDL}),
(Cl_{PDL}) is the ratio of the ion detection intensity of the chlorine ion (Cl⁻),
(Br_{PDL}) is the ratio of the ion detection intensity of the bromine ion (Br⁻),
the ratios being relative to the total anion detection intensities measured by time-of-flight secondary ion mass spectrometry on the surface of the pixel separation layer part that is in contact with the second electrode part or is exposed in the opening part in the second electrode part, in the region not overlapping with the region including the organic layer containing a light emitting layer on the pixel separation layer part;
(S_{Anode}) is the ratio of the ion detection intensity of the sulfur ion (S⁻),
(X_{Anode}) is the total of (Cl_{Anode}) and (Br_{Anode}),
(Cl_{Anode}) is the ratio of the ion detection intensity of the chlorine ion (Cl⁻), and
(Br_{Anode}) is the ratio of the ion detection intensity of the bromine ion (Br⁻),
the ratios being relative to the total anion detection intensities measured by time-of-flight secondary ion mass spectrometry on the surface of the first electrode part in contact with the organic layer part containing a light emitting layer in the pixel part.

The term “surface of the pixel separation layer” mentioned above refers either to the surface region of the pixel separation layer part where the organic layer part containing a light emitting layer is absent and where the second electrode part has been removed to expose the pixel separation layer part or to the surface region of the pixel separation layer part that includes neither the organic layer part containing a light emitting layer on the pixel separation layer part or the second electrode part thereon. In addition, the term “surface of the first electrode part” mentioned above refers to the surface region of the first electrode part where the organic layer part containing a light emitting layer has been removed to expose the first electrode part. The general formula (SD-1) is an equation indicating that the ratio of the detection intensity of the sulfur ion (S⁻) on the pixel separation layer part and the ratio of the detection intensity of the sulfur ion (S⁻) on the first electrode part have a specific intensity ratio. The general formula (XD-1) is an equation indicating that the total of the ratio of the detection intensity of the chlorine ion (Cl⁻) and the ratio of the detection intensity of the bromine ion (Br⁻) on the pixel separation layer part and the total of the ratio of the detection intensity of the chlorine ion (CI) and the ratio of the detection intensity of the bromine ion (Br⁻) on the first electrode part have a specific intensity ratio. As the ratios of (S_{Anode})/(SP_{DL}) and (X_{Anode})/(X_{PDL}) increase, it suggests that the proportion of the surface area of the first electrode part modified by these elements increases. More specifically, it means that these elements exist in larger quantities on the surface of the first electrode part. If they are configured in this way, it significantly enhances the effect of realizing lower voltage driving of the light emission characteristics, improved light emission luminance, and improved reliability of the light emitting element.

(S_{Anode})/(SP_{DL}) is preferably 0.3 or more, more preferably 0.5 or more, and still more preferably 1.0 or more. On the other hand, (S_{Anode})/(SP_{DL}) is preferably 15 or less, more preferably 12 or less, and still more preferably 10 or less.

(X_{Anode})/(X_{PDL}) is preferably 0.3 or more, more preferably 0.5 or more, and still more preferably 1.0 or more. On the other hand, (X_{Anode})/(X_{PDL}) is preferably 15 or less, more preferably 12 or less, and still more preferably 10 or less.

From the perspective of realizing lower voltage driving of the light emission characteristics, improved light emission luminance, and improved reliability of the light emitting element, the display device according to the present invention preferably satisfies the relationship represented by the general formula (SD-1) described above, further satisfies the relationships represented by the general formula (SD-2) and the general formula (SD-3), and/or satisfies the relationship represented by the general formula (XD-1) described above, and further satisfies the relationships represented by the general formula (XD-2) and the general formula (XD-3).

$$0.00001 \leq ( {S}_{Anode} ) \leq 0 \text{.00200} \qquad ( SD - 2 )$$

$$0.0001 \leq ( {S}_{P D L} ) \leq 0.0 \; 100 \qquad ( SD - 3 )$$

$$0.00001 \leq ( {X}_{Anode} ) \leq 0.0 \; 0200 \qquad ( XD - 2 )$$

$$0.0001 \leq ( {X}_{PDL )} \leq 0.0100 \qquad ( XD - 3 )$$

The general formula (SD-2) is an equation indicating that the detection intensity of the sulfur ion (S⁻) on the first electrode part is within a specific range. The general formula (SD-3) is an equation indicating that the detection intensity of the sulfur ion (S⁻) on the pixel separation layer part is within a specific range. The general formula (XD-2) is an equation indicating that the total of the ratio of the detection intensity of the chlorine ion (Cl⁻) and the ratio of the detection intensity of the bromine ion (Br⁻) on the first electrode part is within a specific range. The general formula (XD-2) is an equation indicating that the total of the ratio of the detection intensity of the chlorine ion (Cl⁻) and the ratio of the detection intensity of the bromine ion (Br⁻) on the pixel separation layer part is within a specific range. If they are configured in this way, it significantly enhances the effect of realizing lower voltage driving of the light emission characteristics, improved light emission luminance, and improved reliability of the light emitting element.

From the perspective of realizing lower voltage driving of the light emission characteristics, improved light emission luminance, and improved reliability of the light emitting element, the display device according to the present invention preferably satisfies the relationship represented by the general formula (SD-1) described above, further satisfies the relationships represented by the general formula (SD-2) and the general formula (SD-3), and satisfies the relationship represented by the general formula (XD-1) described above, and further satisfies the relationships represented by the general formula (XD-2) and the general formula (XD-3).

(S_{Anode}) is preferably 0.00003 or more, more preferably 0.00005 or more, and still more preferably 0.00010 or more. On the other hand, (S_{Anode}) is preferably 0.00150 or less, more preferably 0.00120 or less, and still more preferably 0.00100 or less. (SP_{DL}) is preferably 0.0002 or more, more preferably 0.0003 or more, and still more preferably 0.0005 or more. On the other hand, (SP_{DL}) is preferably 0.0070 or less, more preferably 0.0050 or less, and still more preferably 0.0030 or less.

(X_{Anode}) is preferably 0.00003 or more, more preferably 0.00005 or more, and still more preferably 0.00010 or more. On the other hand, (X_{Anode}) is preferably 0.00150 or less, more preferably 0.00120 or less, and still more preferably 0.00100 or less. (X_{PDL}) is preferably 0.0002 or more, more preferably 0.0003 or more, and still more preferably 0.0005 or more. On the other hand, (X_{PDL}) is preferably 0.0070 or less, more preferably 0.0050 or less, and still more preferably 0.0030 or less.

In the display device according to the present invention, the pixel part preferably overlaps with, while being isolated from, the color filter layer part and the opening part in the black matrix layer part in a plan view. If the display device according to the present invention is configured in this way, the color filter layer part is isolated from the pixel part. For the display device according to the present invention, it is preferable that the distance between the color filter layer part and the pixel part is 5.0 to 20.0 μm. If they are configured in this way, it allows the pixel part, the color filter layer part, and the black matrix layer part to be arranged with appropriate distances provided between them, thereby significantly enhances the effect of realizing suppressed external light reflection, lower voltage driving of the light emission characteristics, improved light emission luminance, improved luminescent color purity, and improved reliability of the light emitting element. From the perspective of suppressing external light reflection and improving the reliability of the light emitting element, the distance between the color filter layer part and the pixel part is preferably 5.0 μm or more, more preferably 7.0 μm or more, still more preferably 9.0 μm or more, and particularly preferably 10.0 μm or more. On the other hand, from the perspective of realizing lower voltage driving of the light emission characteristics, improved light emission luminance, improved flexibility, and improved bending property, the distance between the color filter layer part and the pixel part is preferably 20.0 μm or less, more preferably 18.0 μm or less, still more preferably 16.0 μm or less, and particularly preferably 15.0 μm or less.

### <Configuration of Display Device Having a Plurality of Pixel Parts of Different Colors>

The display device according to the present invention seen in a plan view preferably has pixel parts which include pixel parts of a first color, pixel parts of a second color, and pixel parts of a third color, wherein the first, second, and third colors are different from each other, and when seen in a plan view, it preferably has color filter layer parts which include color filter layer parts of a first color corresponding to the pixel parts of the first color, color filter layer parts of a second color corresponding to the pixel parts of the second color, and color filter layer parts of a third color corresponding to the pixel parts of the third color. The expression of “color filter layer parts of a first color corresponding to the pixel parts of the first color” suggests that the pixel parts of the first color and the color filter layer parts of the first color have a color of the same type. The same applies to the color filter layer parts of a second color corresponding to the pixel parts of the second color and the color filter layer parts of a third color corresponding to the pixel parts of the third color. The difference between the maximum emission wavelength in the emission spectrum of light emission from a pixel part of the first color and the maximum transmission wavelength in the transmission spectrum of a color filter layer part of the first color is preferably 30 nm or less, more preferable 20 nm or less, and still more preferable to be 10 nm or less. The same applies to the color filter layer parts of the third color corresponding to the pixel parts of the second color and the color filter layer parts of the third color corresponding to the pixel parts of the third color.

For the display device according to the present invention seen in a plan view, it is preferable that each pixel part of the first color overlaps with a color filter layer part of the first color, that each pixel part of the second color overlaps with a color filter layer part of the second color, and that each pixel part of the third color overlaps with a color filter layer part of the third color. In the case where the first color, the second color, and the third color are green, red, and blue, respectively, the display device according to the present invention can provide a display device that can perform full color emission. Accordingly, if they are configured in this way, the display device according to the present invention can perform full color light emission and realize suppressed external light reflection, excellent light emission characteristics to enable low voltage driving, improved light emission luminance, and improved reliability of the light emitting element. FIG. 7 gives a plan view illustrating an example of a display device that is designed to include pixel parts of a first color, pixel parts of a second color, and pixel parts of a third color.

If the display device according to the present invention is configured in this way, it is preferable that the average value of the pattern dimension in the long axis direction of the pixel parts of the first color is smaller than the average value of the pattern dimension in the long axis direction of the pixel parts of the second color and also smaller than the average value of the pattern dimension in the long axis direction of the pixel parts of the third color. For the display device according to the present invention, the average value of the pattern dimension in the long axis direction of the pixel parts of the first color is preferably 5.0 to 25.0 μm. If they are configured in this way, it significantly enhances the effect of realizing suppressed external light reflection, lower voltage driving of the light emission characteristics, improved light emission luminance, improved luminescent color purity, and improved reliability of the light emitting element.

From the perspective of realizing suppressed external light reflection, lower voltage driving of the light emission characteristics, improved light emission luminance, and improved reliability of the light emitting element, the average value of the pattern dimension in the long axis direction of the pixel parts of the first color is preferably 5.0 μm or more, more preferably 6.0 μm or more, still more preferably 7.0 μm or more, still more preferably 8.0 μm or more, and particularly preferably 10.0 μm or more. On the other hand, from the perspective of realizing suppressed external light reflection and improved light emission luminance, the average value of the pattern dimension in the long axis direction of the pixel parts of the first color is preferably 50.0 μm or less, more preferably 40.0 μm or less, and still more preferably 35.0 μm or less. Furthermore, from the perspective of realizing suppressed external light reflection, lower voltage driving of the light emission characteristics, improved light emission luminance, and improved reliability of the light emitting element, the pattern dimension in the long axis direction of the pixel parts of the first color is preferably 30.0 μm or less, more preferably 25.0 μm or less, still more preferably 20.0 μm or less, still more preferably 17.0 μm or less, and particularly preferably 15.0 μm or less.

Examples and preferable features related to the average value of the pattern dimension in the long axis direction of the pixel parts of the second color and the average value of the pattern dimension in the long axis direction of the pixel parts of the third color are the same as the examples and preferable features related to the average value of the pattern dimension in the long axis direction of the pixel parts of the first color described above.

The display device according to the present invention satisfies the relationships represented by the general formula (CD-1a) and the general formula (CD-1b) wherein:
(CD_{L1}) μm is the average value of the pattern dimension in the long axis direction of the pixel parts of the first color;
(CD_{L2}) μm is the average value of the pattern dimension in the long axis direction of the pixel parts of the second color; and
(CD_{L3}) μm is the average value of the pattern dimension in the long axis direction of the pixel parts of the third color. The display device according to the present invention preferably further satisfies the relationship represented by the general formula (CD-2a) or the general formula (CD-3a), and more preferably satisfies the relationship represented by the general formula (CD-2b) or the general formula (CD-3b).

(CD_{L1})<(CD_{L2}) (CD-1a)

(CD_{L1})<(CD_{L3}) (CD-1b)

(CD_{L2})≤(CD_{L3}) (CD-2a)

(CD_{L2})<(CD_{L3}) (CD-2b)

(CD_{L2})≥(CD_{L3}) (CD-3a)

(CD_{L2})>(CD_{L3}) (CD-3b)

The display device according to the present invention preferably further satisfies the relationships represented by the general formula (CD-1/2a) and/or the general formula (Cd-1/3a), and more preferably satisfies the relationships represented by the general formula (CD-1/2a) and the general formula (CD-1/3a). The display device according to the present invention preferably further satisfies the relationship represented by the general formula (CD-2/3a) or the general formula (CD-2/3b).

$$1. 01 \times ( C {D}_{L 1} ) \leq ( C {D}_{L 2} ) \leq 1.4 \times ( C {D}_{L 2} ) \qquad ( CD - 1 / 2 a )$$

$$1.2 \times ( C {D}_{L 1} ) \leq ( C {D}_{L 3} ) \leq 1.6 \times ( C {D}_{L 1} ) \qquad ( CD - 1 / 3 a )$$

$$1.01 \times ( C {D}_{L 2} ) \leq ( C {D}_{L 3} ) \leq 1.4 \times ( C {D}_{L 2} ) \qquad ( CD - 2 / 3 a )$$

$$1.01 \times ( C {D}_{L 3} ) \leq ( C {D}_{L 2} ) \leq 1.4 \times ( C {D}_{L 3} ) \qquad ( CD - 2 / 3 b )$$

In regard to the pixel parts of the first color, the pixel parts of the second color, and the pixel parts of the third color of the display device according to the present invention, the first color is preferably green or red and more preferably green from the perspective of realizing suppressed external light reflection, lower voltage driving of the light emission characteristics, improved light emission luminance, and improved reliability of the light emitting element. The second color is preferably green, red, or blue, of which red is more preferable. The third color is preferably red or blue, of which blue is more preferable.

When the first color is green, the second color is preferably red or blue, of which red is more preferable.

When the first color is green while the second color is red, the third color is preferably blue. When the first color is green while the second color is blue, the third color is preferably red. When the first color is red, the second color is preferably green or blue, of which green is more preferable.

When the first color is red while the second color is green, the third color is preferably blue. It is particularly preferable that the first color is green; the second color is red; and the third color is blue.

It is also preferable that the first color is green; the second color is blue; and the third color is red.

For the display device according to the present invention, it is also preferable that the pixel parts, seen in the plan view, include other pixel parts having an additional color wherein the first color, the second color, the third color, and the additional color are different from each other, and it is also preferable that the color filter layer parts, seen in the plan view, include other color filter layer parts having an additional color wherein the pixel parts of the additional color, seen in the plan view, overlap with the color filter layer parts of the additional color. It is preferable that only one additional color is used and it is also preferable that two or more additional colors are used. It is preferable to use one or more additional colors selected from the group consisting of white, orange, yellow, and purple.

For the display device according to the present invention, the maximum emission wavelength in the emission spectrum of emission from a red pixel part is preferably 560 to 700 nm. The maximum emission wavelength in the emission spectrum of emission from a green pixel part is preferably 500 to 560 nm. The maximum emission wavelength in the emission spectrum of emission from a blue pixel part is preferably 420 to 500 nm.

For the display device according to the present invention, the maximum transmission wavelength in the transmission spectrum of a red color filter layer part is preferably 560 to 700 nm. The maximum transmission wavelength in the transmission spectrum of a green color filter layer part is preferably 500 to 560 nm. The maximum transmission wavelength in the transmission spectrum of a blue color filter layer part is preferably 420 to 500 nm.

<Formation Method for First Electrode with Specific Detection Intensities of Sulfur Ion (S⁻), Chlorine Ion (Cl⁻), and Bromine Ion (Br⁻)>

For the display device according to the present invention, described below are methods for forming a first electrode that is configured so that the detection intensities of the sulfur ion, chlorine ion, and bromine ion in a pixel part are in specific intensity ranges on the surface of the first electrode that is in contact with the organic layer including a light emitting layer. The first electrode of the display device according to the present invention can be produced, for example, by one of the methods (I) to (V) described below.
(I) A method in which a photosensitive composition including an alkali soluble resin (A), a photosensitizer (C), and a compound (I) which will be described later is prepared and a pattern of a photosensitive composition is formed on the first electrode, followed by exposing the outermost layer of the first electrode (hereinafter “the method (I) of forming a pattern of a photosensitive composition including a specific compound”)
(II) A method in which a non-photosensitive composition including an alkali soluble resin (A) and a compound (I) which will be described later is prepared and a coating layer of the non-photosensitive composition is formed on the first electrode, followed by patterning the coating layer of the non-photosensitive composition and exposing the outermost layer of the first electrode (hereinafter “the method (II) of patterning a coating layer of a non-photosensitive composition including a specific compound”)
(III) A method in which a solution containing a compound (I) which will be described later is brought into contact with the first electrode (hereinafter “the method (III) of contacting with a solution of a specific compound”)
(IV) A method in which a compound (I) which will be described later is gasified and brought into contact with the first electrode (hereinafter “the method (IV) of contacting with gas of a specific compound”)
(V) A method in which a compound (I) which will be described later is ionized and brought into contact with the first electrode (hereinafter “the method (V) of contacting with ion of a specific compound”)

### <Method (I) of Forming a Pattern of a Photosensitive Composition Including a Specific Compound>

The first electrode of the display device according to the present invention can be formed by a method in which a pattern is formed on the first electrode using a photosensitive composition including the compound (I) which contains the sulfur element, chlorine element, or bromine element as described later. The method (I) of forming a pattern of a photosensitive composition including a specific compound is designed for modifying the surface of the first electrode with the sulfur element, chlorine element, or bromine element and exposing the surface-modified outermost layer of the first electrode during the patterning step. For the patterning step, a preferable technique is direct patterning by photolithography. A cured film having a pattern formed by this method corresponds to the pixel separation layer, which enables the production of the display device according to the present invention. The photosensitive composition including a specific compound contains an alkali soluble resin (A) and a photosensitizer (C). Resins useful as the alkali soluble solution (A) will be described later. Compounds useful as the photosensitizer (C) will be described later. It is preferable that the photosensitive composition including a specific compound further includes a solvent. Useful solvents include those compounds described later.

Examples of the method of forming a pattern on the first electrode using a photosensitive composition that includes a compound containing the sulfur element, chlorine element, or bromine element include:

(1) the method of applying active actinic ray through a photomask and then performing development with a developer liquid to produce a pattern. This method is intended for direct patterning by photolithography.

The active actinic ray to use for irradiation through a photomask is preferably j-line (wavelength 313 nm), i-line (wavelength 365 nm), h-line (wavelength 405 nm), or g-line (wavelength 436 nm) of a mercury lamp, and the use of a mixed line of i-line, h-line, and g-line is more preferable. The developer liquid to use for the development with a developer liquid is preferably an alkaline solution and more preferably an organic alkaline solution or an aqueous solution of an alkaline compound. An organic solvent may be used as the developer liquid.

It is preferable to further perform cleaning with a rinse liquid after finishing the development for forming a pattern with a developer liquid. The rinse liquid is preferably water, an aqueous solution of an alcohol, an aqueous solution of an ester, an aqueous solution of a compound exhibiting acidity, or an organic solvent, of which water is more preferable.

### <Method (II) of Patterning a Coating Layer of a Non-Photosensitive Composition Including a Specific Compound>

The first electrode of the display device according to the present invention can be produced by a method in which a non-photosensitive composition including the compound (I), which is a compound containing the sulfur element, chlorine element, or bromine element as described later, is spread over the first electrode to produce a film, followed by forming a pattern. The method (II) of patterning a coating layer of a non-photosensitive composition including a specific compound is designed for modifying the surface of the first electrode with the sulfur element, chlorine element, or bromine element and exposing the surface-modified outermost surface of the first electrode during the patterning step. For the patterning step, a preferable technique is etching to carry out patterning. A cured film having a pattern formed by this method corresponds to the pixel separation layer, which enables the production of the display device according to the present invention. The non-photosensitive composition including a specific compound contains an alkali soluble resin (A). Resins useful as the alkali soluble solution (A) will be described later. It is preferable that the non-photosensitive composition including a specific compound further include a solvent. Useful solvents include those compounds described later.

Examples of methods for forming a film on the first electrode using a non-photosensitive composition that includes a compound containing the sulfur element, chlorine element, or bromine element, followed by patterning it, include the following:
(1) the method of forming a pattern by wet etching using a photoresist,
(2) the method of forming a pattern by dry etching using a photoresist, and
(3) the method of forming a pattern after forming all openings simultaneously using a photoresist during the photoresist development step.

Etching solutions useful for wet etching include, for example, acidic solutions, alkaline solutions, and organic solvents. Etching gases useful for dry etching include, for example, halogenated hydrocarbons, halogenated sulfur, halogenated boron, halogenated rare gases, halogens, oxygen, ozone, and rare gases. As the developer liquid to use for photoresist development, it is preferable to use an alkaline solution and it is more preferable to use an organic alkaline solution or an aqueous solution of an alkaline compound. An organic solvent may also be used as the developer liquid.

It is preferable to further perform cleaning with a rinse liquid after patterning by wet etching. It is also preferable to further perform cleaning with a rinse liquid after simultaneous formation of all openings and patterning during the photoresist development step. The rinse liquid is preferably water, an aqueous solution of an alcohol, an aqueous solution of an ester, an aqueous solution of a compound exhibiting acidity, or an organic solvent, of which water is more preferable.

<Method (III) of Contacting with a Solution of a Specific Compound>

The first electrode of the display device according to the present invention can be formed by a method in which a solution containing the compound (I) that contains the sulfur element, chlorine element, or bromine element as described later is brought into contact with the surface of the first electrode. The method (III) of contacting with a solution of a specific compound is intended to carry out surface modification of the surface of the first electrode with the sulfur element, chlorine element, or bromine element. The display device according to the present invention can be produced by forming a pixel separation layer using a photosensitive composition or a non-photosensitive composition on the first electrode produced by the aforementioned method. It is preferable that the solution of a compound that contains the sulfur element, chlorine element, or bromine element further contains a solvent. Useful solvents include those compounds described later.

Examples of methods for bringing a solution of a compound containing the sulfur element, chlorine element, or bromine element into contact with the surface of the first electrode include the following:
(1) the method of coating the surface of the first electrode with a solution of a compound containing the sulfur element, chlorine element, or bromine element,
(2) the method of spraying the surface of the first electrode with a solution of a compound containing the sulfur element, chlorine element, or bromine element, and
(3) the method of immersing the first electrode in a solution of a compound containing the sulfur element, chlorine element, or bromine element.

It is preferable to further perform cleaning with a rinse liquid after bringing a solution of a compound containing the sulfur element, chlorine element, or bromine element into contact with the surface of the first electrode. The rinse liquid is preferably water, an aqueous solution of an alcohol, an aqueous solution of an ester, an aqueous solution of a compound exhibiting acidity, or an organic solvent, of which water is more preferable.

<Method (IV) of Contacting with Gas of a Specific Compound>

The first electrode of the display device according to the present invention can be formed by a method in which the undermentioned compound (I), which is a compound containing the sulfur element, chlorine element, or bromine element, is gasified and brought into contact with the surface of the first electrode. The method (IV) of contacting with a gas of a specific compound is intended to carry out surface modification of the surface of the first electrode with the sulfur element, chlorine element, or bromine element. The display device according to the present invention can be produced by forming a pixel separation layer using a photosensitive composition or a non-photosensitive composition on the first electrode produced by the aforementioned method.

Examples of methods for gasifying a compound containing the sulfur element, chlorine element, or bromine element and bringing it into contact with the surface of the first electrode include the following:
(1) the method of gasifying a compound containing the sulfur element, chlorine element, or bromine element, filling a container with it, and bringing it into contact with the surface of the first electrode,
(2) the method of gasifying a compound containing the sulfur element, chlorine element, or bromine element and spraying the surface of the first electrode with it to achieve contact between them, and
(3) the method of gasifying a compound containing the sulfur element, chlorine element, or bromine element and filling a container with it, followed by forming a film on the first electrode by chemical vapor deposition.
   <Method (V) of Contacting with Ion of a Specific Compound>

The first electrode of the display device according to the present invention can be formed by a method in which the undermentioned compound (I), which is a compound containing the sulfur element, chlorine element, or bromine element, is ionized and brought into contact with the surface of the first electrode. The method (IV) of contacting with an ion of a specific compound is intended to carry out surface modification of the surface of the first electrode with the sulfur element, chlorine element, or bromine element. The display device according to the present invention can be produced by forming a pixel separation layer using a photosensitive composition or a non-photosensitive composition on the first electrode produced by the aforementioned methods.

Examples of methods for ionizing a compound containing the sulfur element, chlorine element, or bromine element and bringing it into contact with the surface of the first electrode include the following:
(1) the method of gasifying a compound containing the sulfur element, chlorine element, or bromine element, filling a container with it, ionizing it by electromagnetic wave, and bringing it into contact with the surface of the first electrode, and
(2) the method of gasifying a compound containing the sulfur element, chlorine element, or bromine element, further ionizing it by electromagnetic wave, accelerating it by applying a bias, and allowing it to collide against the surface of the first electrode.

### <Cured Film of Non-Photosensitive Composition and Photosensitive Composition>

For the display device according to the present invention, it is preferable that the pixel separation layer, pixel size control layer, spacer layer, sealing layer, color filter layer, black matrix layer, overcoat layer, TFT planarization layer, TFT protection layer, and interlayer insulation layer are cured films of non-photosensitive compositions, and it is more preferable that they are cured films of photosensitive compositions. It is preferable that the non-photosensitive compositions and the photosensitive compositions contain components as specified below.

The term “curing” refers to the process in which a crosslinked structure is formed through a reaction while causing a loss of fluidity of the film, or the state of such a film. There are no particular limitations on the reaction, and good reactions include those caused by heating, irradiation with energy rays, etc., of which those caused by heating are preferable. The state of a film that has lost fluidity after the formation of crosslinked structures by heating is referred to as heat-cured. Good heating conditions include, for example, heating at 150° C. to 500° C. for 5 to 300 minutes. Good heating methods include, for example, heating by means of an oven, hot plate, infrared ray, flash annealing device, and laser annealing device. Good processing atmospheres include, for example, atmospheres of air, oxygen, nitrogen, helium, neon, argon, krypton, and xenon, gas atmospheres containing 1 to 10,000 mass ppm (0.0001 to 1 mass %) of oxygen, gas atmospheres containing 10,000 mass ppm (1 mass %) or more of oxygen, and vacuum atmosphere.

### <Non-Photosensitive Composition and Photosensitive Composition>

The display device according to the third aspect of the present invention is described below. Non-photosensitive compositions and photosensitive compositions according to another aspect of the present invention are also described. Hereinafter, for the display device according to the present invention, the terms “non-photosensitive composition” and “photosensitive composition” refer to the photosensitive composition according to the third aspect of the present invention or the non-photosensitive composition or the photosensitive composition used to form the cured film present in the display device according to the first aspect or the second aspect of the present invention. In addition, the term “the composition according to the present invention” used herein refers to any of these compositions. As compared with this, when referring to a composition according to a specific aspect, for example, the term “the photosensitive composition according to the third aspect of the present invention” is used.

The photosensitive composition according to the third aspect of the present invention is a photosensitive composition that includes an alkali soluble resin (A), a photosensitizer (C), and a colorant (D) and satisfies the requirement (I) and/or the requirement (II) given below:
(I) further including one or more selected from the group consisting of components containing the sulfur element, components containing the chlorine element, and components containing the bromine element and satisfying the requirement (1a) and/or the requirement (2a) given below:
(1a) the content of the sulfur element in the photosensitive composition is 0.01 to 100 mass ppm,
(2a) the total content of the chlorine element and the bromine element in the photosensitive composition is 0.01 to 100 mass ppm,
(II) further including one or more selected from the group consisting of components containing sulfur based anions as given below and components containing halogen anions as given below and satisfying the requirement (1b) and/or the requirement (2b) given below:
sulfur based anion: one or more ions selected from the group consisting of sulfide ions, hydrogen sulfide ions, sulfate ions, and hydrogen sulfate ions, halogen anion: a chloride ion and/or a bromide ion,
(1b) the total content of sulfide ions, hydrogen sulfide ions, sulfate ions, and hydrogen sulfate ions in the photosensitive composition is 0.01 to 500 mass ppm, and
(2b) the total content of chloride ions and bromide ions in the photosensitive composition is 0.01 to 500 mass ppm.

If they are configured in this way, the photosensitive composition according to the present invention can serve to provide a cured film that realizes excellent light emission characteristics to enable low voltage driving and high reliability of the light emitting element. It is inferred that if the photosensitive composition contains trace amounts of a component containing the sulfur element, a component containing a sulfur based anion as described above, a component containing the chlorine element, a component containing the bromine element, or a component containing a halogen anion as described above, the surface of the first electrode that faces the light emitting layer and corresponds to the opening part in the pixel separation layer part or the opening part in the pixel size control layer part is modified by these elements or ions during the step of forming a pattern of the photosensitive composition on the first electrode. It is considered that after forming a pattern of the photosensitive composition, there occurs the transition of these elements or ions contained in the pixel separation layer, and then this causes the modification of the surface of the first electrode with these elements or ions. It is inferred that as a result, the adjustment of the difference in the work function works for realizing excellent light emission characteristics that enable low voltage driving. In addition, it is considered that this also allows a higher light emission luminance to be achieved at the same driving voltage. It is also considered that for example, the polarization structure and charge balance in the pixel separation layer in an organic EL display can be controlled by intentionally adding trace amounts of these components. It is inferred from this that suppression of ion migration and electromigration attributed to metal impurities and ion impurities that can adversely affect the light emission characteristics can significantly enhance the effect of improving the reliability of the light emitting element. In addition, it is inferred that suppression of migration and aggregation of metal in the first electrode can significantly enhance the effect of improving the reliability of the light emitting element.

### <Alkali Soluble Resin (A)>

The composition according to the present invention contains an alkali soluble resin (A). The alkali soluble resin (A) is defined as a resin having an acidic group and solubility in an alkaline developer. The alkali soluble resin (A) present in the photosensitive composition is preferably a resin that allows the photosensitive composition to be made positive or negative by the photosensitizer (C) which will described later and that has solubility to enable the formation of a positive or negative pattern when developed with an alkaline developer. It is preferable for the alkali soluble resin (A) to have an acidic group in its structural unit.

The composition according to the present invention has the effect of realizing excellent light emission characteristics to enable low voltage driving and high reliability of the light emitting element as a result of including the alkali soluble resin (A) and further including a component containing the sulfur element, a component containing a sulfur based anion, a component containing the chlorine element, a component containing the bromine element, or a component containing a halogen anion which will be described later while maintaining the contents of the sulfur element, sulfur based anions, chlorine element, bromine element, and halogen anions in specific ranges. If they are configured in this way, even when the alkali soluble resin (A) contains unintended impurities, neither an increase in voltage driving of the light emission characteristics nor a decrease in reliability of the light emitting element will be caused by these impurities.

Since the alkali soluble resin (A) is included, the cured film of the photosensitive composition will have improved heat resistance due to the introduction of the resin structure of the alkali soluble resin (A) and outgassing from the pixel separation layer etc. will be suppressed. As a result, the degradation of the light emitting element is suppressed, accordingly significantly enhancing the effect of realizing improved reliability of the light emitting element.

From the perspective of realizing lower voltage driving of the light emission characteristics and improved light emission luminance, the alkali soluble resin (A) preferably has a phenolic hydroxyl group and more preferably has a phenolic hydroxyl group in the structural unit of the resin. It is inferred that since the alkali soluble resin (A) included has a phenolic hydroxyl group, it acts to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage.

From the perspective of realizing improved reliability of the light emitting element, the alkali soluble resin (A) preferably has a radical polymerizable group and more preferably has a radical polymerizable group in the structural unit of the resin. When the alkali soluble resin (A) included has a radical polymerizable group, it serves to introduce a crosslinked structure formed through radical polymerization of a radical polymerizable group such as (meth)acryloyl group and as a result, it allows the photosensitive composition to form a cured film having a higher heat resistance due to increased crosslink density. It is inferred that as a result, outgassing from the pixel separation layer etc. is suppressed, accordingly significantly enhancing the effect of improving the reliability of the light emitting element.

From the perspective of realizing lower voltage driving of the light emission characteristics, improved light emission luminance, and improved reliability of the light emitting element, the alkali soluble resin (A) preferably includes a resin having a radical polymerizable group and a resin not having a radical polymerizable group. It is inferred that in the case of a positive type photosensitive composition, the inclusion of an alkali soluble resin (A) not having a radical polymerizable group enables the control of the number of double bond groups in the photosensitive composition, and the alkali solubility is increased due to the interaction between the double bond groups in the photosensitive composition and the aromatic rings in the photosensitizer (C) which will be described later. On the other hand, it is inferred that in the case of a negative type photosensitive composition, the inclusion of an alkali soluble resin (A) not having a radical polymerizable group serves to control excessive photocuring, thereby suppressing residue formation. It is considered that accordingly, during the step of surface modification by the sulfur element, aforementioned sulfur based anions, chlorine element, bromine element, or aforementioned halogen anions, it serves to suppress the inhibition of surface modification due to residue formation on the surface of the first electrode.

The radical polymerizable group is preferably an ethylenically unsaturated double bond group. The radical polymerizable group is more preferably one or more selected from the group consisting of photoreactive groups, alkenyl groups having 2 to 5 carbon atoms, and alkynyl groups having 2 to 5 carbon atoms. Preferable examples of photoreactive groups include styryl group, cinnamoyl group, maleimide group, nadimide group, or (meth)acryloyl group, of which (meth)acryloyl group is more preferable. On the other hand, preferable examples of alkenyl groups having 2 to 5 carbon atoms or alkynyl groups having 2 to 5 carbon atoms include vinyl group, allyl group, 2-methyl-2-propenyl group, crotonyl group, 2-methyl-2-butenyl group, 3-methyl-2-butenyl group, 2,3-dimethyl-2-butenyl group, ethynyl group, or 2-propargyl group, of which vinyl group and allyl group are more preferable.

### <Alkali Soluble Resin (A); Resin (A1), Resin (A2), and Resin (A3)>

For the composition according to the present invention, it is preferable that the alkali soluble resin (A) contains a resin (A1) and/or a resin (A3) as specified below.
Resin (A1): a resin having a structural unit containing one or more selected from the group consisting of imide structure, amide structure, oxazole structure, and siloxane structure
Resin (A3): a resin having a phenolic hydroxyl group

It is preferable for the resin (A1) to have one or more selected from the group consisting of imide structure, amide structure, oxazole structure and siloxane structure, in the structural unit of the resin. The resin (A3) preferably has a phenolic hydroxyl group in at least one of the main chain of the resin, side chain of the resin, and chain end of the resin and more preferably contains a phenolic hydroxyl group in the structural unit of the resin.

If they are configured in this way, it significantly enhances the effect of realizing lower voltage driving of the light emission characteristics, improved light emission luminance, and improved reliability of the light emitting element. Furthermore, it is inferred that the resin (A1) and the resin (A3) work to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. In addition, it is inferred that the high heat resistance of the imide structure, amide structure, oxazole structure, or siloxane structure in the resin (A1) or that of the aromatic skeleton in the resin (A3) serves to suppress the outgassing from the pixel separation layer etc., accordingly significantly enhancing the effect of improving the reliability of the light emitting element.

Here, in the case of resins that have structures or groups characteristic of two or more of the resin (A1), the resin (A3), and the resin (A2) that is specified below, they are classified into any of them according to the following rules.

Resin (A2): a resin having a radical polymerization group

If there is a resin that seems to be classifiable into two or more of the resin (A1), resin (A2), and resin (A3), it is classified into any one category as described below. Specifically, a resin is classified as resin (A1) if it has a structural unit that contains one or more selected from the group consisting of imide structure, amide structure, oxazole structure, and siloxane structure (hereinafter simply referred to as “imide structure etc. based structural unit”), has no radical polymerizable group, and has a phenolic hydroxyl group. Compared to this, a resin is classified as the resin (A2) if the resin has an imide structure etc. based structural unit, has a radical polymerizable group, and has no phenolic hydroxyl group. Furthermore, a resin is classified as the resin (A3) if the resin has no imide structure etc. based structural unit, has a radical polymerizable group, and has a phenolic hydroxyl group. Compared to this, a resin is classified as the resin (A2) if the resin has an imide structure etc. based structural unit, has a radical polymerizable group, and has a phenolic hydroxyl group.

It is preferable that the resin formed by curing a resin (A1) is preferably a resin (A1-DL) present in the aforementioned pixel separation layer, etc. It is preferable that the resin formed by curing a resin (A2) is preferably a resin (A2-DL) present in the aforementioned pixel separation layer, etc. It is preferable that the resin formed by curing a resin (A3) is preferably a resin (A3-DL) present in the aforementioned pixel separation layer, etc.

From the perspective of realizing lower voltage driving of the light emission characteristics, improved light emission luminance, and improved reliability of the light emitting element, the resin (A1) preferably contains one or more selected from the group consisting of the resin (A1-1), resin (A1-2), resin (A1-3), resin (A1-4), resin (A1-5), resin (A1-6), and resin (A1-7) specified below. The resin (A1) more preferably contains one or more selected from the group consisting of the resin (A1-1), resin (A1-2), resin (A1-3), resin (A1-4), resin (A1-5), and resin (A1-6) specified below, and still more preferably contains the resin (A1-1) and/or the resin (A1-5). The resin (A1) may be either a single one thereof or a copolymer thereof.
Resin (A1-1): polyimide
Resin (A1-2): polyimide precursor
Resin (A1-3): polybenzoxazole
Resin (A1-4): polybenzoxazole precursor
Resin (A1-5): polyamide-imide
Resin (A1-6): polyamide-imide precursor
Resin (A1-7): polysiloxane

From the perspective of realizing lower voltage driving of the light emission characteristics, improved light emission luminance, and improved reliability of the light emitting element, the resin (A3) preferably contains one or more selected from the group consisting of the resin (A3-1), resin (A3-2), resin (A3-3), and resin (A3-4) specified below. The resin (A3) more preferably contains resin (A3-1) and/or the resin (A3-3), and still more preferably contains resin (A3-1). The resin (A3) may be either a single one thereof or a copolymer thereof.
Resin (A3-1): phenolic resin
Resin (A3-2): polyhydroxystyrene
Resin (A3-3): phenolic group-containing epoxy resin
Resin (A3-4): phenolic group-containing acrylic resin

The alkali soluble resin (A) preferably contains a resin (A2) as specified below. The alkali soluble resin (A) more preferably contains a resin (A1) and/or a resin (A3) and further contains a resin (A2) as specified below. The alkali soluble resin (A) more preferably contains a resin (A1) and a resin (A2) and particularly preferably contains a resin (A1), resin (A3), and resin (A2).

Resin (A2): a resin having a radical polymerizable group

If they are configured in this way, it significantly enhances the effect of improving the reliability of the light emitting element. The resin (A2) is a resin having a radical polymerizable group such as (meth)acryloyl group. When the resin (A2) is included, it allows a crosslinked structure formed by the radical polymerization of a radical polymerizable group such as (meth)acryloyl group to be introduced in the cured film of the photosensitive composition, resulting in a significant effect of improving the crosslink density. It is inferred that the high heat resistance of such a crosslinked structure serves to suppress the outgassing from the pixel separation layer etc., accordingly significantly enhancing the effect of improving the reliability of the light emitting element.

From the perspective of realizing lower voltage driving of the light emission characteristics, improved light emission luminance, and improved reliability of the light emitting element, the resin (A2) preferably contains one or more selected from the group consisting of the resin (A2-a), resin (A2-b), resin (A2-c), resin (A2-d), resin (A2-e), resin (A2-f), resin (A2-g), resin (A2-1), resin (A2-2), and resin (A2-3) specified below. The resin (A2) more preferably contains one or more selected from the group consisting of the (A2-a), resin (A2-b), resin (A2-c), resin (A2-d), resin (A2-e), resin (A2-f), and resin (A2-g), and still more preferably contains one or more selected from the group consisting of the resin (A2-a), resin (A2-b), resin (A2-c), resin (A2-d), resin (A2-e), and resin (A2-f).

From the perspective of realizing lower voltage driving of the light emission characteristics, improved light emission luminance, and improved reliability of the light emitting element, it is also more preferable that the resin (A2) contains one or more selected from the group consisting of the (A2-a), resin (A2-b), resin (A2-c), resin (A2-d), resin (A2-e), resin (A2-f), and resin (A2-g) and further contains one or more selected from the group consisting of the resin (A2-1), resin (A2-2), and resin (A2-3). The resin (A2) may be either a single one thereof or a copolymer thereof.
Resin (A2-a): unsaturated group-containing polyimide
Resin (A2-b): unsaturated group-containing polyimide precursor
Resin (A2-c): unsaturated group-containing polybenzoxazole
Resin (A2-d): unsaturated group-containing polybenzoxazole precursor
Resin (A2-e): unsaturated group-containing polyamide-imide
Resin (A2-f): unsaturated group-containing polyamide-imide precursor
Resin (A2-g): unsaturated group-containing polysiloxane
Resin (A2-1): polycyclic side chain-containing resin
Resin (A2-2): acid modified epoxy resin
Resin (A2-3): acrylic resin

### <Alkali Soluble Resin (A); Resin (A3a) and Resin (A3b)>

From the perspective of improving the reliability of the light emitting element, it is also preferable that the alkali soluble resin (A) to use for the composition according to the present invention contains a resin (A3b) as described below. The resin (A3b) preferably has a phenolic hydroxyl group in at least one of the main chain of the resin, side chain of the resin, and chain end of the resin and further has a radical polymerizable group in at least either the side chain of the resin or chain end of the resin.

Resin (A3b): a resin (A3) having a phenolic hydroxyl group and a radical polymerizable group

From the perspective of preventing narrow mask bias after development and improving the halftone characteristics, the resin (A3b) preferably has a double bond equivalent weight of 500 g/mol or more, more preferably 700 g/mol or more, and still more preferably 1,000 g/mol or more. On the other hand, from the perspective of improving the sensitivity during light exposure and improving the reliability of the light emitting element, its double bond equivalent weight is preferably 3,000 g/mol or less, more preferably 2,000 g/mol or less, and still more preferably 1,500 g/mol or less.

From the perspective of realizing lower voltage driving of the light emission characteristics and improved light emission luminance, it is also preferable that the alkali soluble resin (A) to use for the composition according to the present invention contains a resin (A3a) as described below. The resin (A3a) preferably has a phenolic hydroxyl group in at least one of the main chain of the resin, side chain of the resin, and chain end of the resin.

Resin (A3a): a resin (A3) that has a phenolic hydroxyl group and does not have a radical polymerizable group

For the composition according to the present invention, from the perspective of realizing lower voltage driving of the light emission characteristics, improved light emission luminance, and improved reliability of the light emitting element, it is preferable that the alkali soluble resin (A) contains the resin (A3b) and that the alkali soluble resin (A) further contains the resin (A3a).

### <Acidic Groups>

The resin (A1) and resin (A2) each have an acidic group in at least one of the main chain of the resin, side chain of the resin, and chain end of the resin. Furthermore, from the perspective of suppressing narrow mask bias after development and improving the halftone characteristics, it is preferable that, of the resin (A1) and the resin (A2), the resin (A2) having the aforementioned imide structure etc. based structural unit has, as acidic group, a weakly acidic group (WA) as specified blow, more preferably has a phenolic hydroxyl group or a silanol group, and still more preferably has a phenolic hydroxyl group. On the other hand, from the perspective of reducing the residue remaining after development, the resin (A1) and resin (A2) each preferably have, as acidic group, a carboxyl group, carboxylic anhydride group, or sulfonic acid group, and still more preferably have a carboxyl group or a carboxylic anhydride group. It is also preferable that the resin (A1) and resin (A2) each have, as acidic group, a weakly acidic group (WA) and further have a carboxyl group, carboxylic anhydride group, or sulfonic acid group.

Weakly acidic group (WA): one or more selected from the group consisting of phenolic hydroxyl group, hydroxyimide group, hydroxyamide group, silanol group, 1,1-bis(trifluoromethyl)methylol group, and mercapto group

From the perspective of improving the sensitivity during light exposure and improving the reliability of the light emitting element, the resin (A1) preferably has an acid equivalent weight of 200 g/mol or more, more preferably 250 g/mol or more, and still more preferably 300 g/mol or more. On the other hand, from the perspective of reducing the residue remaining after development, preventing narrow mask bias after development, and improving the halftone characteristics, the acid equivalent weight is preferably 600 g/mol or less, more preferably 500 g/mol or less, and still more preferably 450 g/mol or less.

From the perspective of improving the sensitivity during light exposure and improving the reliability of the light emitting element, the resin (A2) preferably has an acid equivalent weight of 300 g/mol or more, more preferably 350 g/mol or more, and still more preferably 400 g/mol or more. On the other hand, from the perspective of reducing the residue remaining after development, preventing narrow mask bias after development, and improving the halftone characteristics, the acid equivalent weight is preferably 700 g/mol or less, more preferably 600 g/mol or less, and still more preferably 550 g/mol or less.

The resin (A3) has a phenolic hydroxyl group. The resin (A3) preferably has at least one of structural units having phenolic hydroxyl groups and chain end structures having phenolic hydroxyl groups. From the perspective of preventing narrow mask bias after development and improving the halftone characteristics, it is also preferable that the resin (A3) contains a hydroxyimide group, hydroxyamide group, silanol group, 1,1-bis(trifluoromethyl)methylol group, or mercapto group. On the other hand, from the perspective of reducing the residue remaining after development, the resin (A3) preferably further has a carboxyl group, carboxylic anhydride group, or sulfonic acid group, and more preferably has a carboxyl group or a carboxylic anhydride group.

From the perspective of improving the sensitivity during light exposure and improving the reliability of the light emitting element, the resin (A3) preferably has an acid equivalent weight of 70 g/mol or more, more preferably 80 g/mol or more, and still more preferably 90 g/mol or more. On the other hand, from the perspective of reducing the residue remaining after development, preventing narrow mask bias after development, and improving the halftone characteristics, the acid equivalent weight is preferably 450 g/mol or less, more preferably 350 g/mol or less, and still more preferably 300 g/mol or less.

### <Alkali Soluble Resin (A); Polyimide and Polyimide Precursor>

The resin (A1-1) and the resin (A2-a), which are polyimides, are described collectively below. Features of the resin (A1-2) and the resin (A2-b), which are polyimide precursors, are also described collectively below. Examples of the polyimide precursors include resins obtainable by reacting a tetracarboxylic acid or a corresponding tetracarboxylic dianhydride etc. with a diamine or a diisocyanate compound etc. Furthermore, other examples of polyimide precursors include polyamide acids, polyamide acid esters, polyamide acid amides, and polyisoimides. Examples of polyimides include resins obtainable by subjecting a polyimide precursor to dewatering cyclization by heating or through a reaction using a catalyst. Polyimides and polyimide precursors may be resins in the form of copolymers with polyamides that can be produced by adding a dicarboxylic acid or a corresponding dicarboxylic acid active diester to the resin synthesis reaction.

From the perspective of realizing lower voltage driving of the light emission characteristics, improved light emission luminance, and improved reliability of the light emitted light, the polyimide to use preferably has a structural unit as represented by the general formula (1). Structural units as represented by the general formula (1) preferably account for 50 to 100 mol %, more preferably 60 to 100 mol %, and still more preferably 70 to 100 mol %, of all structural units in the polyimide component.

From the perspective of realizing lower voltage driving of the light emission characteristics, improved light emission luminance, and improved reliability of the light emitted light, the polyimide precursor to use preferably has a structural unit as represented by the general formula (3). Structural units as represented by the general formula (3) preferably account for 50 to 100 mol %, more preferably 60 to 100 mol %, and still more preferably 70 to 100 mol %, of all structural units in the polyimide precursor component.

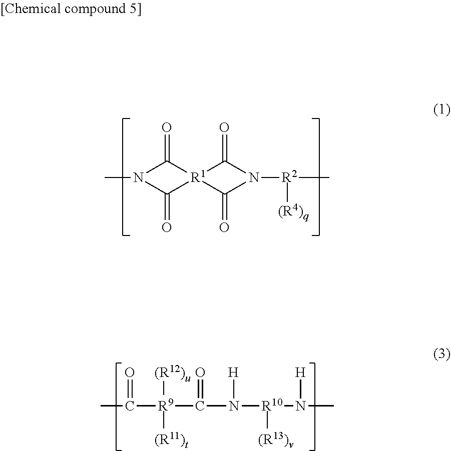

In the general formula (1) and the general formula (3), R¹ and R⁹ are each independently a tetravalent to decavalent organic group. R² and R¹⁰ are each independently a divalent to decavalent organic group. R³, R⁴, and R¹³ are each independently a phenolic hydroxyl group, a sulfonic acid group, a mercapto group, or a substituent group as represented by the general formula (7) or the general formula (8). R¹¹ is a substituent group as represented by the general formula (7) or the general formula (8). R¹² is a phenolic hydroxyl group, a sulfonic acid group, or a mercapto group. Here, p is an integer of 0 to 6; q is an integer of 0 to 8; t is an integer of 2 to 8 and u is an integer of 0 to 6 wherein 2≤t+u≤8; and v is an integer of 0 to 8.

It is preferable that in the general formula (1) and the general formula (3), R¹, R⁹, R², and R¹⁰ are each independently an aliphatic structure containing 2 to 20 carbon atoms, an alicyclic structure containing 4 to 20 carbon atoms, and an aromatic structure containing 6 to 30 carbon atoms. However, in the case where R³ or R⁴ is a phenolic hydroxyl group, R¹ or R² bonded to the phenolic hydroxyl group contains an aromatic structure in its structure. Furthermore, in the case where R¹² or R¹³ is a phenolic hydroxyl group, R⁹ or R¹⁰ bonded to the phenolic hydroxyl group contains an aromatic structure in its structure. Here, q is preferably an integer of 1 to 8; and vis preferably an integer 1 to 8. R¹ and R⁹ are occasionally referred to as carboxylic acid residues. R² and R¹⁰ are occasionally referred to as amine residues. The aforementioned aliphatic structures, alicyclic structures, and aromatic structures may each contain a heteroatom and may each be either a non-substitution product or a substitution product.

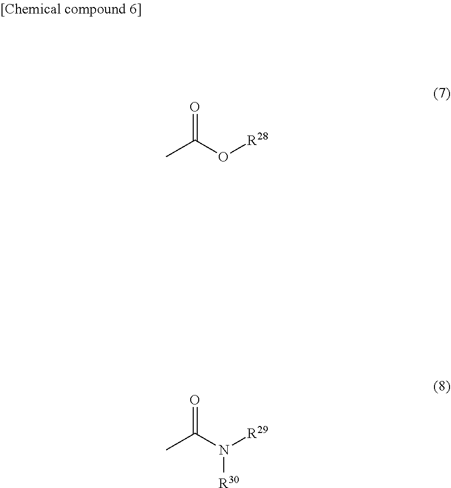

In the general formula (7) and the general formula (8), R²⁸ to R³⁰ are each independently a hydrogen atom, an alkyl group containing 1 to 10 carbon atoms, an acyl group containing 2 to 6 carbon atoms, or an aryl group containing 6 to 15 carbon atoms. In the general formula (7) and the general formula (8), it is preferable that R²⁸ to R³⁰ are each independently a hydrogen atom, an alkyl group containing 1 to 6 carbon atoms, an acyl group containing 2 to 4 carbon atoms, or an aryl group containing 6 to 10 carbon atoms. The alkyl groups, acyl groups, and aryl groups described above may each have a heteroatom and may each be a non-substitution product or a substitution product.

In regard to polyimide precursors, in the case where R¹¹ in a structural unit as represented by the general formula (3) is a substituent group as represented by the general formula (7) in which R²⁸ is a hydrogen atom, that structural unit is referred to as an amic acid structural unit. In the case where R¹¹ in a structural unit as represented by the general formula (3) is a substituent group as represented by the general formula (7) in which R²⁸ is an alkyl group having 1 to 10 carbon atoms, an acyl group having 2 to 6 carbon atoms, or an aryl group having 6 to 15 carbon atoms, that structural unit is referred to as an amic acid ester structural unit. In the case where R¹¹ in a structural unit as represented by the general formula (3) is a substituent group as represented by the general formula (8), that structural unit is referred to as an amic acid amide structural unit. From the perspective of suppressing narrow mask bias after development and improving the halftone characteristics, it is preferable for a polyimide precursor to have an amic acid ester structural unit and/or an amic acid amide structural unit. Examples of a polyimide precursor having an amic acid ester structural unit and/or an amic acid amide structural unit include resins obtainable by esterification and/or amidation of some of the carboxyl groups bonded to the carboxyl residue. Furthermore, a polyimide precursor may also have cyclized imide structural units obtainable by imide cyclization of some of the amic acid structural units, amic acid ester structural units, and amic acid amide structural units. From the perspective of suppressing narrow mask bias after development and improving the halftone characteristics, the total content of amic acid ester structural units and amic acid amide structural units is preferably 10 mol % or more, more preferably 30 mol % or more, and still more preferably 50 mol % or more relative to the total content of amic acid structural units, amic acid ester structural units, amic acid amide structural units, or cyclized imide structural units. On the other hand, from the perspective of reducing the residue remaining after development, the total content of amic acid ester structural units and amic acid amide structural units is preferably 100 mol % or more, more preferably 90 mol % or more, and still more preferably 80 mol % or more.

### <Alkali Soluble Resin (A); Polybenzoxazole Precursor and Polybenzoxazole>

The resin (A1-3) and the resin (A2-c), which are polybenzoxazole, are described collectively below. The resin (A1-4) and the resin (A2-d), which are polybenzoxazole precursors, are also described collectively below. Examples of the polybenzoxazole precursors include resins that are obtainable by reacting a dicarboxylic acid or a corresponding dicarboxylic acid active diester with a diamine such as bisaminophenol compounda. In addition, other examples of polybenzoxazole precursors include polyhydroxyamide. Examples of polybenzoxazole include resins obtainable by subjecting a polybenzoxazole precursor to dewatering cyclization by heating or through a reaction using a catalyst. The polybenzoxazole and polybenzoxazole precursors may be resins in the form of copolymers with polyamides that are obtainable by adding a diamine or diisocyanate compound etc. to the resin synthesis reaction.

From the perspective of realizing lower voltage driving of the light emission characteristics, improved light emission luminance, and improved reliability of the light emitted light, the polybenzoxazole to use preferably has a structural unit as represented by the general formula (2). It is preferable that structural units as represented by the general formula (2) account for 50 to 100 mol %, more preferably 60 to 100 mol %, and still more preferably 70 to 100 mol %, of all structural units present in the polybenzoxazole component.

From the perspective of realizing lower voltage driving of the light emission characteristics, improved light emission luminance, and improved reliability of the light emitted light, the polybenzoxazole precursor to use preferably has a structural unit as represented by the general formula (4). It is preferable that structural units as represented by the general formula (4) account for 50 to 100 mol %, more preferably 60 to 100 mol %, and still more preferably 70 to 100 mol %, of all structural units present in the polybenzoxazole precursor component.

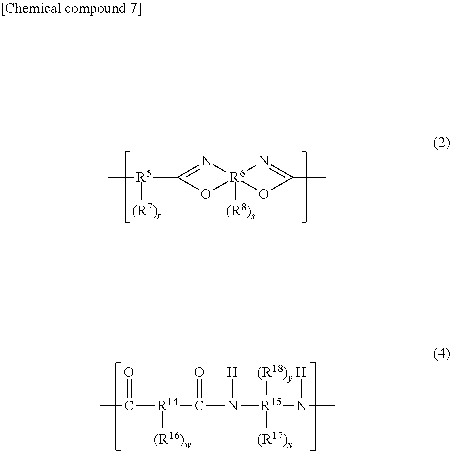

In the general formula (2) and the general formula (4), R⁵ and R¹⁴ are each independently a divalent to decavalent organic group. R⁶ and R¹⁵ are each independently a tetravalent to decavalent organic group having an aromatic structure. R⁷, R⁸, and R¹⁶ are each independently a phenolic hydroxyl group, a sulfonic acid group, a mercapto group, or a substituent group as represented by the general formula (7) or the general formula (8) given above. R¹⁷ is a phenolic hydroxyl group. R¹⁸ is a sulfonic acid group, a mercapto group, or a substituent group as represented by the general formula (7) or the general formula (8) given above. Here, r is an integer of 0 to 8; s is an integer of 0 to 6; w is an integer of 0 to 8; and x is an integer of 2 to 8 and y is an integer of 0 to 6 wherein 2≤x+y≤8.

It is preferable that in the general formula (2) and the general formula (4), R⁵, R¹⁴, R⁶, and R¹⁵ are each independently an aliphatic structure containing 2 to 20 carbon atoms, an alicyclic structure containing 4 to 20 carbon atoms, and an aromatic structure containing 6 to 30 carbon atoms. However, in the case where R⁷ or R⁸ is a phenolic hydroxyl group, R⁵ or R⁶ bonded to the phenolic hydroxyl group contains an aromatic structure in its structure. Furthermore, in the case where R¹⁶ is a phenolic hydroxyl group, R¹⁴ bonded to the phenolic hydroxyl group contains an aromatic structure in its structure. Furthermore, R¹⁵ bonded to R¹⁷ contains an aromatic structure in its structure. Here, s is preferably an integer of 1 to 6. R⁵ and R¹⁴ are occasionally referred to as carboxylic acid residues. R⁶ and R¹⁵ are occasionally referred to as amine residues. The aforementioned aliphatic structures, alicyclic structures, and aromatic structures may each contain a heteroatom and may each be either a non-substitution product or a substitution product.

### <Alkali Soluble Resin (A); Polyamide-Imide and Polyamide-Imide Precursor>

The resin (A1-5), resin (A1-6), resin (A2-e), and resin (A2-f), which are polyamide-imide or polyamide-imide precursors, are described collectively below. Examples of polyamide-imide precursors include resins obtainable by reacting a tricarboxylic acid or a corresponding tricarboxylic anhydride etc. with a diamine or a diisocyanate compound etc. Examples of polyamide-imide include resins obtainable by subjecting a polyamide-imide precursor to dewatering cyclization by heating or through a reaction using a catalyst. The polyamide-imide and polyamide-imide precursors may be resins in the form of copolymers with polyamide that are obtainable by adding dicarboxylic acid or a corresponding dicarboxylic acid active diester to the resin synthesis reaction.

From the perspective of realizing lower voltage driving of the light emission characteristics, improved light emission luminance, and improved reliability of the light emitted light, the polyamide-imide to use preferably has a structural unit as represented by the general formula (5). It is preferable that structural units as represented by the general formula (5) account for 50 to 100 mol %, more preferably 60 to 100 mol %, and still more preferably 70 to 100 mol %, of all structural units present in the polyamide-imide component.

From the perspective of realizing lower voltage driving of the light emission characteristics, improved light emission luminance, and improved reliability of the light emitted light, the polyamide-imide precursor to use preferably has a structural unit as represented by the general formula (6). It is preferable that structural units as represented by the general formula (6) account for 50 to 100 mol %, more preferably 60 to 100 mol %, and still more preferably 70 to 100 mol %, of all structural units present in the polyamide-imide precursor component.

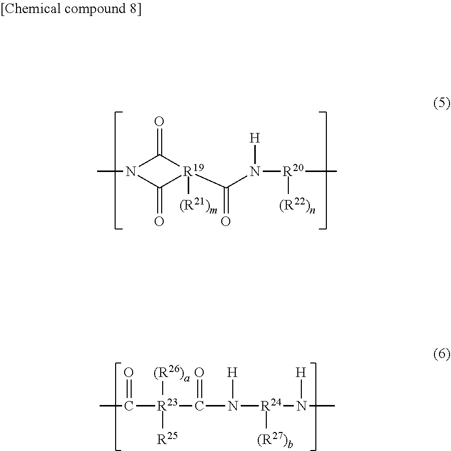

In the general formula (5) and the general formula (6), R¹⁹ and R²³ are each independently a trivalent to decavalent organic group. R²⁰ and R²⁴ are each independently a divalent to decavalent organic group. R²¹, R²², and R²⁷ are each independently a phenolic hydroxyl group, a sulfonic acid group, a mercapto group, or a substituent group as represented by the general formula (7) or the general formula (8) given above. R²⁵ is a substituent group as represented by the general formula (7) or the general formula (8). R²⁶ is a phenolic hydroxyl group, a sulfonic acid group, or a mercapto group. Here, m is an integer of 0 to 7; n is an integer of 0 to 8; a is an integer of 0 to 7; and b is an integer of 0 to 8.

It is preferable that in the general formula (5) and the general formula (6), R¹⁹, R²³, R²⁰, and R²⁴ are each independently an aliphatic structure containing 2 to 20 carbon atoms, an alicyclic structure containing 4 to 20 carbon atoms, and an aromatic structure containing 6 to 30 carbon atoms. However, in the case where R²¹ or R²² is a phenolic hydroxyl group, R¹⁹ or R²⁰ bonded to the phenolic hydroxyl group contains an aromatic structure in its structure. Furthermore, in the case where R²⁶ or R²⁷ is a phenolic hydroxyl group, R²³ or R²⁴ bonded to the phenolic hydroxyl group contains an aromatic structure in its structure. Here, n is preferably an integer of 1 to 8, and b is preferably an integer of 1 to 8. R¹⁹ and R²³ are occasionally referred to as carboxylic acid residues. R²⁰ and R²⁴ are occasionally referred to as amine residues. The aforementioned aliphatic structures, alicyclic structures, and aromatic structures may each contain a heteroatom and may each be either a non-substitution product or a substitution product.

### <Structural Units Containing Fluorine Atoms>

From the perspective of realizing lower voltage driving of the light emission characteristics, improved light emission luminance, and improved reliability of the light emitted light, it is preferable that the polyimides, polyimide precursors, polybenzoxazoles, polybenzoxazole precursors, polyamide-imides, and polyamide-imide precursors (hereinafter referred to as “polyimide based resins”) contain structural units having fluorine atoms. The term “light exposure” used herein means the application of active actinic ray (radiation) such as, for example, visible light, ultraviolet ray, electron beam, and X-ray. Hereinafter, the term “light exposure” means the application of active actinic ray (radiation).

In the case where the structural units present in each resin component of a polyimide based resin include structural units derived from carboxylic acid or structural units derived from carboxylic acid derivatives that contain fluorine atoms and further include structural units derived from amine or structural units derived from amine derivatives that contain fluorine atoms, it is preferable that the structural units containing fluorine atoms preferably account for 10 to 100 mol %, more preferably 30 to 100 mol %, and still more preferably 50 to 100 mol %, of all structural units present in each resin component. Here, the aforementioned structural units derived from carboxylic acids or structural units derived from carboxylic acid derivatives include structural units derived from tetracarboxylic acids or corresponding tetracarboxylic dianhydride, structural units derived from dicarboxylic acids or corresponding dicarboxylic acid active diesters, or structural units derived from tricarboxylic acids or corresponding tricarboxylic anhydrides. In addition, the aforementioned structural units derived from amines or structural units derived from amine derivatives include structural units derived from diamine, structural units derived from diisocyanate compounds, and structural units derived from bisaminophenol compounds.

Furthermore, in the case where, of all structural units present in each resin component, only the structural units derived from carboxylic acids or structural units derived from carboxylic acid derivatives contain fluorine atoms, the structural units containing fluorine atoms preferably account for 10 to 100 mol %, more preferably 30 to 100 mol %, and still more preferably 50 to 100 mol %, of the total of all structural units derived from carboxylic acids and all structural units derived from carboxylic acid derivatives.

On the other hand, in the case where, of all structural units present in each resin component, only the structural units derived from amines or structural units derived from amine derivatives contain fluorine atoms, the structural units containing fluorine atoms preferably account for 10 to 100 mol %, more preferably 30 to 100 mol %, and still more preferably 50 to 100 mol %, of the total of all structural units derived from amines and all structural units derived from amine derivatives.

### <Acidic Group>

A polyimide based resin has an acidic group in at least one of the main chain of the resin, side chain of the resin, and chain end of the resin. Such resins preferably have structural units having acidic groups such as structural units derived from carboxylic acids having acidic groups and structural units derived from diamines having acidic groups, or preferably have chain end structures having acidic groups. In addition, those resins obtainable by reacting part of the hydroxyl groups etc. present in each of the above resins with a polyfunctional carboxylic dianhydride are also preferable, and those resins obtainable by introducing an acidic group into at least one of the main chain of each resin, side chain of each resin, and chain end of each resin through a reaction using a catalyst are also preferable.

### <Radical Polymerizable Group>

The resin (A2-a), resin (A2-b), resin (A2-c), resin (A2-d), resin (A2-e), and resin (A2-f), which belong to the category of resin (A2), (hereinafter referred to as “polyimide based resins (A2)”) have radical polymerizable groups. These resins (A2) are preferably resins that are obtainable by reacting part of the acidic groups etc. present in the resin (A1-1), resin (A1-2), resin (A1-3), resin (A1-4), resin (A1-5), or resin (A1-6) (hereinafter referred to as “polyimide based resins (A1)”) with a compound having a radical polymerizable group. In addition, resins obtainable by introducing radical polymerizable groups, through reactions using catalysts, into at least either the side chain of each resin or chain end of each resin are also preferable. The compounds having radical polymerizable groups are preferably electrophilic compounds that have radical polymerizable groups. From the perspective of reactivity and compound availability, preferable electrophilic compounds include isocyanate compounds, epoxy compounds, alcohol compounds, aldehyde compounds, ketone compounds, and carboxylic anhydrides, of which isocyanate compounds, epoxy compounds, and alcohol compounds are more preferable.

From the perspective of preventing narrow mask bias after development and improving the halftone characteristics, it is preferable that the aforementioned polyimide based resins (A2) have double bond equivalent weights of 500 g/mol or more, more preferably 700 g/mol or more, and still more preferably 1,000 g/mol or more. On the other hand, from the perspective of improving the sensitivity during light exposure and improving the reliability of the light emitting element, its double bond equivalent weight is preferably 3,000 g/mol or less, more preferably 2,000 g/mol or less, and still more preferably 1,500 g/mol or less.

### <Other Structural Units, End-Capping Agents, and Molecular Weight>

From the perspective of enhancing the reliability of the light emitting element, it is preferable for the structural units present in polyimide based resins to include structural units having aromatic groups such as structural units derived from aromatic carboxylic acid and structural units derived from aromatic diamine. In addition, from the perspective of achieving lower taper in the pattern shape, also preferable are structural units having silyl groups or siloxane bonds such as structural units derived from silicone diamine and structural units having oxyalkylene skeletons such as structural units derived from oxyalkylene diamine. Furthermore, it is also preferable that the chain ends of the resins are capped with end-capping agents such as monoamine and dicarboxylic anhydride. From the perspective of improving sensitivity during exposure, the polyimide based resins preferably have, at the chain ends of the resins, crosslinkable groups or radical polymerizable groups that can react with resins etc., and more preferably have maleimide groups or nadimide groups.

From the perspective of improving the reliability of the light emitting element, the polystyrene based weight average molecular weight (hereinafter Mw) of the polyimide based resins determined by gel permeation chromatography (hereinafter GPC) is preferably 1,000 or more, more preferably 3,000 or more, and still more preferably 5,000 or more. On the other hand, from the perspective of reducing the residue remaining after development and achieving lower taper in the pattern shape, their Mw is preferably 100,000 or less, more preferably 50,000 or less, still more preferably 30,000 or less, and particularly preferably 20,000 or less. Polyimide based resins can be synthesized by generally known method. Good tetracarboxylic acids, tricarboxylic acids, dicarboxylic acids, and their derivatives, as well as diamines, bisaminophenol compounds, monoamines, and their derivatives that are useful for the synthesis of each resin include those compounds described in International Publication No. 2017/057281 and International Publication No. 2017/159876.

### <Alkali Soluble Resin (A); Polysiloxane>

The resin (A1-7) and the resin (A2-g), which are polysiloxane, are described collectively below. Examples of polysiloxane include those resins that are obtainable by hydrolyzing one or more selected from the group consisting of trifunctional organosilanes, tetrafunctional organosilanes, difunctional organosilanes, and monofunctional organosilanes, followed by dehydration and condensation.

From the perspective of realizing lower voltage driving of the light emission characteristics, improved light emission luminance, and improved reliability of the light emitted light, it is preferable that the polysiloxane has a trifunctional organosilane unit represented by the general formula (9) and/or a tetrafunctional organosilane unit represented by the general formula (10).

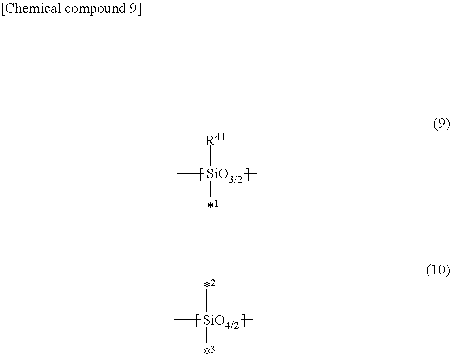

In general formula (9), R⁴¹ is a hydrogen atom or a monovalent organic group. In the general formula (9) and the general formula (10), *1 to *3 are each independently a bonding point in the resin. In the general formula (9), it is preferable that R⁴¹ is a hydrogen atom, an alkyl group containing 1 to 10 carbon atoms, a cycloalkyl group containing 4 to 10 carbon atoms, an aryl group containing 6 to 15 carbon atoms, a halogenated alkyl group containing 1 to 10 carbon atoms, a halogenated cycloalkyl group containing 4 to 10 carbon atoms, or a halogenated aryl group containing 6 to 15 carbon atoms. The alkyl groups, cycloalkyl groups, aryl groups, halogenated alkyl groups, halogenated cycloalkyl groups, and halogenated aryl groups described above may each have a heteroatom and may each be either a non-substitution product or a substitution product.

In the polysiloxane component, trifunctional organosilane units as represented by the general formula (9) preferably account for 50 to 100 mol %, more preferably 60 to 100 mol %, and still more preferably 70 to 100 mol %, in terms of molar proportion of Si atoms. From the perspective of reducing the residue remaining after development, the trifunctional organosilane units are preferably organosilane units having epoxy groups.

From the perspective of reducing the residue remaining after development, it is preferable that in the polysiloxane component, tetrafunctional organosilane units as represented by the general formula (10) account for 1 mol % or more, more preferably 5 mol % or more, and still more preferably 10 mol % or more, in terms of molar proportion of Si atoms from the perspective of reducing the residue remaining after development. On the other hand, from the perspective of achieving lower taper in the pattern shape, tetrafunctional organosilane units as represented by the general formula (10) preferably account for 40 mol % or less, more preferably 30 mol % or less, and still more preferably 20 mol % or less, in terms of molar proportion of Si atoms.

### <Acidic Group>

The polysiloxane has a silanol group, as acidic group, in at least one of the main chain of the resin, side chain of the resin, and chain end of the resin. The polysiloxane to use preferably further has an acidic group other than the silanol group. The polysiloxane to use is preferably a resin containing an organosilane unit having an acidic group. In addition, it is also preferably a resin that is obtainable by reacting part of the hydroxyl groups in the resin with a polyfunctional carboxylic dianhydride, and also preferably a resin that is obtainable by introducing an acidic group into at least one of the main chain of the resin, side chain of the resin, and chain end of the resin through a reaction using a catalyst.

### <Radical Polymerizable Group>

The resin (A2-g) is a resin (A2) and has a radical polymerizable group. The resin (A2-g) preferably has an organosilane unit having a radical polymerizable group. In addition, it is also preferably a resin that is obtainable by reacting part of the acidic groups in the resin with a compound having a radical polymerizable group, and also preferably a resin that is obtainable by introducing a radical polymerizable group into at least either the side chain of the resin or chain end of the resin through a reaction using a catalyst. From the perspective of preventing narrow mask bias after development and improving the halftone characteristics, the resin (A2-g) preferably has a double bond equivalent weight of 500 g/mol or more, more preferably 700 g/mol or more, and still more preferably 1,000 g/mol or more. On the other hand, from the perspective of improving the sensitivity during light exposure and improving the reliability of the light emitting element, its double bond equivalent weight is preferably 3,000 g/mol or less, more preferably 2,000 g/mol or less, and still more preferably 1,500 g/mol or less.

### <Other Structural Units and Molecular Weight>

From the perspective of achieving lower taper in the pattern shape, the structural units present in the polysiloxane are also preferably bifunctional organosilane units or monofunctional organosilane units. In addition, from the perspective of realizing improved reliability of the light emitted light, they are also preferably organosilane units having aromatic groups. The individual organosilane units may be arranged in either a regular or irregular sequence. Regular sequences are formed, for example, by alternating copolymerization, periodic copolymerization, block copolymerization, or graft copolymerization. Irregular sequences are formed, for example, by random copolymerization. Furthermore, the individual organosilane units may be arranged in either a two-dimensional array or a three-dimensional array. A two-dimensional array is formed, for example, by linear chains. A three-dimensional array is formed, for example, by ladder-like, cage-like, or network-like chains.

From the perspective of improving the reliability of the light emitting element, the polystyrene based Mw of the polysiloxane determined by GPC is preferably 500 or more and more preferably 1,000 or more. On the other hand, from the perspective of reducing the residue remaining after development and achieving lower taper in the pattern shape, its Mw is preferably 50,000 or less and more preferably 10,000 or less. Polysiloxane compounds can be synthesized by generally known methods. Examples of organosilane compounds include those described in International Publications WO 2017/057281 and WO 2017/159876.

### <Alkali Soluble Resin (A); Polycyclic Side Chain-Containing Resin>

The resin (A2-1), which is a polycyclic side chain-containing resin, is described below. Polycyclic side chain-containing resins include, for example, those obtainable through the reactions described below under (1-a2-1) to (6-a2-1). If necessary, a polyfunctional alcohol compound may also be reacted at any reaction stage.
(1-a2-1) A resin obtainable by reacting a polyfunctional phenol compound with a polyfunctional carboxylic dianhydride, and then reacting the resulting compound with an epoxy compound
(2-a2-1) A resin obtainable by reacting a polyfunctional phenol compound with an epoxy compound and then reacting the resulting compound with a polyfunctional carboxylic dianhydride
(3-a2-1) A resin obtainable by reacting a cyclic skeleton-containing polyfunctional alcohol compound with a polyfunctional carboxylic dianhydride, and then reacting the resulting compound with an epoxy compound
(4-a2-1) A resin obtainable by reacting a cyclic skeleton-containing polyfunctional alcohol compound with an epoxy compound, and then reacting the resulting compound with a polyfunctional carboxylic dianhydride.
(5-a2-1) A resin obtainable by reacting a polyfunctional epoxy compound with a polyfunctional carboxylic acid compound, and then reacting the resulting compound with an epoxy compound
(6-a2-1) A resin obtainable by reacting a polyfunctional epoxy compound with a carboxylic acid compound, and then reacting the resulting compound with a polyfunctional carboxylic dianhydride

From the perspective of realizing lower voltage driving of the light emission characteristics, improved light emission luminance, and improved reliability of the light emitted light, the polycyclic side chain-containing resin preferably has a structural unit having a condensed polycyclic structure or a structural unit having a condensed polycyclic heterocyclic structure. The condensed polycyclic structure or the condensed polycyclic heterocyclic structure is preferably a fluorene structure, xanthene structure, and isoindolinone structure.

### <Acidic Group>

The polycyclic side chain-containing resin has an acidic group in at least one of the main chain of the resin, side chain of the resin, and chain end of the resin. The polycyclic side chain-containing resin preferably has at least one of structural units derived from polyfunctional carboxylic acid compounds, structural units derived from polyfunctional carboxylic dianhydrides, and chain end structures having acidic groups. In addition, it is also preferably a resin that is obtainable by reacting part of the hydroxyl groups in the resin with a polyfunctional carboxylic dianhydride, and also preferably a resin that is obtainable by introducing an acidic group into at least one of the main chain of the resin, side chain of the resin, and chain end of the resin through a reaction using a catalyst.

### <Radical Polymerizable Group>

The resin (A2-1) is a resin (A2) and has a radical polymerizable group. It is preferable that the resin (A2-1) has at least one of structural units derived from epoxy compounds having radical polymerizable groups, structural units derived from carboxylic acid compounds having radical polymerizable groups, and chain end structures having radical polymerizable groups. In addition, also preferable is a resin that is obtainable by reacting part of the acidic groups in the resin with a compound having a radical polymerizable group, and also preferable is a resin that is obtainable by introducing a radical polymerizable group into at least one of the main chain of the resin, side chain of the resin, and chain end of the resin through a reaction using a catalyst. From the perspective of preventing narrow mask bias after development and improving the halftone characteristics, the resin (A2-1) preferably has a double bond equivalent weight of 300 g/mol or more, more preferably 400 g/mol or more, and still more preferably 500 g/mol or more. On the other hand, from the perspective of improving the sensitivity during light exposure and improving the reliability of the light emitting element, its double bond equivalent weight is preferably 1,500 g/mol or less, more preferably 1,000 g/mol or less, and still more preferably 700 g/mol or less.

### <Other Structural Units, End-Capping Agents, and Molecular Weight>

From the perspective of improving the reliability of the light emitting element, it is preferable that the structural units present in the polycyclic side chain-containing resins include structural units having aromatic groups such as structural units derived from aromatic polyfunctional carboxylic acid compounds and structural units derived from aromatic polyfunctional carboxylic dianhydrides. Furthermore, it is also preferable that the chain ends of the resins are capped with end-capping agents such as monocarboxylic acids, dicarboxylic anhydrides, and tricarboxylic anhydrides.

From the perspective of enhancing the reliability of the light emitting element, the polystyrene based Mw of the polycyclic side chain-containing resins as determined by GPC is preferably 500 or more and more preferably 1,000 or more. On the other hand, from the perspective of reducing the residue remaining after development and achieving lower taper in the pattern shape, their Mw is preferably 50,000 or less and more preferably 10,000 or less. Polycyclic side chain-containing resins can be synthesized by generally known methods. Examples of the phenol compounds, alcohol compounds, epoxy compounds, carboxylic anhydrides, and carboxylic acid compounds include those described in International Publications WO 2017/057281 and WO 2017/159876.

Examples of polycyclic side chain-containing resins include ADEKA ARKLS (registered trademark) WR-101 and WR-301 (both manufactured by ADEKA Corporation) and OGSOL (registered trademark) CR-1030 (manufactured by Osaka Gas Chemicals Co., Ltd.).

### <Alkali Soluble Resin (A): Acid Modified Epoxy Resin>

The (A2-2), which is an acid modified epoxy resin, is described below. Examples of acid modified epoxy resins include those obtainable through the reactions described below under (1-a2-2) and (2-a2-2). If necessary, a polyfunctional alcohol compound may also be reacted at any reaction stage.
(1-a2-2) A resin obtainable by reacting a polyfunctional epoxy compound with a polyfunctional carboxylic acid compound, and then reacting the resulting compound with an epoxy compound
(2-a2-2) A resin obtainable by reacting a polyfunctional epoxy compound with a carboxylic acid compound, and then reacting the resulting compound with a polyfunctional carboxylic dianhydride

From the perspective of realizing lower voltage driving of the light emission characteristics, improved light emission luminance, and improved reliability of the light emitted light, it is preferable that the acid modified epoxy resin contains a structural unit having a condensed polycyclic structure, a structural unit having a condensed polycyclic heterocyclic structure, a structural unit having a structure containing a directly connected aromatic skeleton and alicyclic skeleton, or a structural unit having a structure containing at least two directly connected aromatic skeletons. The condensed polycyclic structure unit or the condensed polycyclic heterocyclic structure is preferably a naphthalene structure, fluorene structure, or xanthene structure. The alicyclic skeleton is preferably a tricyclo[5.2.1.0^{2,6}]decane structure. The structure having at least two directly connected aromatic skeletons is preferably the biphenyl structure.

### <Acidic Group>

The acid modified epoxy resin has an acidic group in at least one of the main chain of the resin, side chain of the resin, and chain end of the resin. The acid modified epoxy resin preferably has at least one of structural units derived from polyfunctional carboxylic acid compounds, structural units derived from polyfunctional carboxylic dianhydrides, and chain end structures having acidic groups. Good methods for producing an acid modified epoxy resin include, for example, a method in which a polyfunctional epoxy compound and a polyfunctional carboxylic acid compound are reacted to produce a resin having a carboxyl group in the resin, and a method in which a polyfunctional epoxy compound and a carboxylic acid compound are reacted, followed by reacting part of the hydroxyl groups in the resin with a polyfunctional carboxylic dianhydride. In addition, another good method for producing an acid modified epoxy resin is, for example, to introduce an acidic group into a resin that does not have an acidic group. More specifically, good methods include, for example, a method in which part of the hydroxyl groups etc. in a resin are reacted with a polyfunctional carboxylic dianhydride and a method in which an acidic group is introduced into at least one of the main chain of a resin having no carboxyl group, side chain of such a resin, and chain end of such a resin, through a reaction using a catalyst.

### <Radical Polymerizable Group>

The resin (A2-2) is a resin (A2) and has a radical polymerizable group. It is preferable that the resin (A2-2) has at least one of structural units derived from epoxy compounds having radical polymerizable groups, structural units derived from carboxylic acid compounds having radical polymerizable groups, and chain end structures having radical polymerizable groups. In addition, also preferable is a resin that is obtainable by reacting part of the acidic groups in the resin with a compound having a radical polymerizable group, and also preferable is a resin that is obtainable by introducing a radical polymerizable group into at least one of the main chain of the resin, side chain of the resin, and chain end of the resin through a reaction using a catalyst. From the perspective of preventing narrow mask bias after development and improving the halftone characteristics, the resin (A2-2) preferably has a double bond equivalent weight of 300 g/mol or more, more preferably 400 g/mol or more, and still more preferably 500 g/mol or more. On the other hand, from the perspective of improving the sensitivity during light exposure and improving the reliability of the light emitting element, its double bond equivalent weight is preferably 1,500 g/mol or less, more preferably 1,000 g/mol or less, and still more preferably 700 g/mol or less.

### <Other Structural Units, End-Capping Agents, and Molecular Weight>

From the perspective of improving the reliability of the light emitting element, it is preferable that the structural units present in the acid modified epoxy resins include structural units having aromatic groups such as structural units derived from aromatic polyfunctional carboxylic acid compounds and structural units derived from aromatic polyfunctional carboxylic dianhydrides. Furthermore, it is also preferable that the chain ends of the resins are capped with end-capping agents such as monocarboxylic acids, dicarboxylic anhydrides, and tricarboxylic anhydrides.

From the perspective of enhancing the reliability of the light emitting element, the polystyrene based Mw of the acid modified epoxy resins as determined by GPC is preferably 500 or more and more preferably 1,000 or more. On the other hand, from the perspective of reducing the residue remaining after development and achieving lower taper in the pattern shape, their Mw is preferably 50,000 or less and more preferably 20,000 or less. Acid modified epoxy resins can be synthesized by generally known methods. Examples of the epoxy compounds, carboxylic anhydrides, and carboxylic acid compounds include those described in International Publications WO 2017/057281 and WO 2017/159876.

Examples of acid modified epoxy resins include KAYARAD (registered trademark) PCR-1222H, CCR-1171H, TCR-1348H, ZAR-1494H, ZFR-1401H, ZCR-1798H, ZXR-1807H, ZCR-6002H, and ZCR-8001H (all manufactured by Nippon Kayaku Co., Ltd.).

### <Alkali Soluble Resin (A); Acrylic Resin>

The resin (A2-3), which is an acrylic resin, is described below. Examples of acrylic resins include those resins that are obtainable through radical copolymerization of one or more selected from the group consisting of (meth)acrylic acid derivatives, (meth)acrylic ester derivatives, styrene derivatives, and other copolymerization components.

### <Acidic Group>

The acrylic resin has an acidic group in at least one of the main chain of the resin, side chain of the resin, and chain end of the resin. It is preferable that the acrylic resin has a structural unit derived from a (meth)acrylic acid derivative or a chain end structure having an acidic group. In addition, also preferable is a resin that is obtainable by reacting part of the hydroxyl groups in the resin with a polyfunctional carboxylic dianhydride, and also preferable is a resin that is obtainable by introducing an acidic group into at least one of the main chain of the resin, side chain of the resin, and chain end of the resin through a reaction using a catalyst.

### <Radical Polymerizable Group>

The resin (A2-3), which is a resin (A2), has a radical polymerizable group. The resin (A2-3) is preferably a resin that is obtainable by reacting part of the acidic groups present in a resin with an epoxy compound having a radical polymerizable group. In addition, also preferable is a resin that is obtainable by reacting part of the epoxy groups in the resin with carboxylic acid compounds having radical polymerizable groups. In addition, also preferable is a resin that is obtainable by introducing a radical polymerizable group into at least either the side chain of the resin or chain end of the resin through a reaction using a catalyst. From the perspective of preventing narrow mask bias after development and improving the halftone characteristics, the resin (A2-3) preferably has a double bond equivalent weight of 500 g/mol or more, more preferably 700 g/mol or more, and still more preferably 1,000 g/mol or more. On the other hand, from the perspective of improving the sensitivity during light exposure and improving the reliability of the light emitting element, its double bond equivalent weight is preferably 4,000 g/mol or less, more preferably 3,000 g/mol or less, still more preferably 2,000 g/mol or less, and particularly preferably 1,500 g/mol or less.

### <Other Structural Units and Molecular Weight>

From the perspective of enhancing the reliability of the light emitting element, it is preferable that the structural units present in acrylic resins are structural units having aromatic groups such as structural units derived from aromatic (meth)acrylate derivatives and structural units derived from styrene derivatives, and also preferable are structural units having alicyclic groups such as structural units derived from alicyclic (meth)acrylate derivatives.

From the perspective of enhancing the reliability of the light emitting element, the polystyrene based Mw of the acrylic resins as determined by GPC is preferably 1,000 or more and more preferably 3,000 or more. On the other hand, from the perspective of reducing the residue remaining after development and achieving lower taper in the pattern shape, their Mw is preferably 50,000 or less and more preferably 20,000 or less. Acrylic resins can be synthesized by generally known methods. Examples of (meth)acrylic acid derivatives, (meth)acrylate derivatives, styrene derivatives, and other copolymerization components include those described in International Publications WO 2017/057281 and WO 2017/159876.

### <Alkali Soluble Resin (A); Phenol Resin>

The resin (A3-1), which is a phenol resin, is described below. Examples of phenol resins include resins that are obtainable by reacting a phenolic compound etc. with one or more selected from the group consisting of aldehyde compounds, ketone compounds, alkoxymethyl compounds, and methylol compounds. It is preferable that the phenol resin contains a novolac resin and/or a resole resin. The novolac resin is a resin that is obtainable through a reaction using an acid catalyst. The resole resin is a resin that is obtainable through a reaction using a base catalyst. The inclusion of a resin (A3-1) serves to significantly enhance the effect of realizing lower voltage driving of the light emission characteristics and improved light emission luminance.

From the perspective of realizing lower voltage driving of the light emission characteristics, improved light emission luminance, and improved reliability of the light emitting element, the phenol resin preferably has one or more of the structural units represented by the general formula (31), (32), (33), (34), (35), (38), (39), or (40).

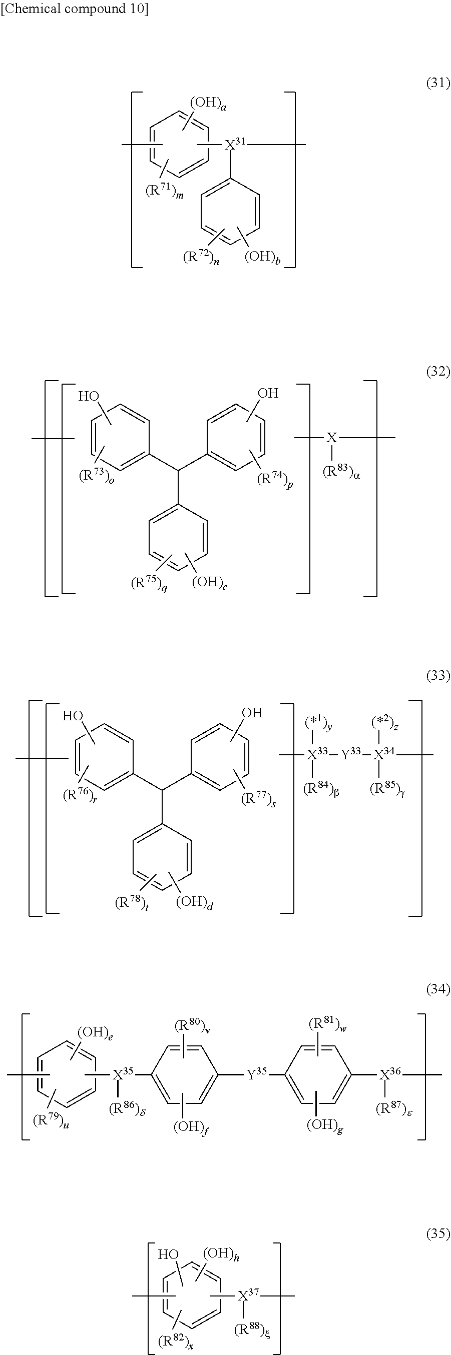

In the general formulas (31) to (35), X³¹ to X³⁷ are each independently an aliphatic structure containing 1 or 2 carbon atoms. Y³³ is an alkylene group having 1 to 10 carbon atoms. Y³⁵ is a direct bond, an alkylene group having 1 to 6 carbon atoms, an alkylidene group having 1 to 6 carbon atoms, a halogenated alkylene group having 1 to 6 carbon atoms, a halogenated alkylidene group having 1 to 6 carbon atoms, an aromatic group, a condensed polycyclic structure, a condensed polycyclic heterocyclic structure, a structure having a directly bonded aromatic ring skeleton and alicyclic skeleton, or a structure having at least two directly bonded aromatic ring skeletons. R⁷¹ to R⁸² are each independently a halogen atom, an alkyl group having 1 to 10 carbon atoms, an aryl group having 6 to 15 carbon atoms, an alkenyl group having 2 to 10 carbon atoms, an alkoxy group having 1 to 10 carbon atoms, an alkenyloxy group having 2 to 10 carbon atoms, an acyl group having 1 to 10 carbon atoms, a carboxyl group, an amino group, or a ring-forming group. A ring connected by a ring-forming group represents a monocyclic or condensed polycyclic hydrocarbon ring. R⁸³ to R⁸⁸ are each independently an alkyl group having 1 to 10 carbon atoms, a cycloalkyl group having 4 to 10 carbon atoms, an aryl group having 6 to 15 carbon atoms, or a hydroxyl group. Here, a is an integer of 1 to 4; b is an integer of 1 to 5; m is an integer of 0 to 3; n is an integer of 0 to 4; c is an integer of 1 to 4; o and p are each independently an integer of 0 to 3; q is an integer of 0 to 4; d is an integer of 1 to 4; r and s are each independently an integer of 0 to 3; t is an integer of 0 to 4; e is an integer of 1 to 4; f, g, v, and w are each independently an integer of 0 to 4; u is an integer of 0 to 3; h is an integer of 1 to 3; x is an integer of 0 to 2; y and z are each independently an integer of 0 or 1; α, β, γ, δ, ε, and ζ are each independently an integer of 0 to 4; and *¹ and *² each independently represent a bonding point in the resin.

In the general formulas (31) to (35), Y³⁵ is preferably an aromatic group, a condensed polycyclic structure, a condensed polycyclic heterocyclic structure, a structure having a directly bonded aromatic ring skeleton and alicyclic skeleton, or a structure having at least two directly bonded aromatic ring skeletons, of which a condensed polycyclic structure or a condensed polycyclic heterocyclic structure are more preferable. The aforementioned aliphatic structure, alkyl group, cycloalkyl group, aryl group, alkenyl group, alkoxy group, alkenyloxy group, acyl group, ring-forming group, alkylene group, alkylidene group, aromatic group, condensed polycyclic structure, condensed polycyclic heterocyclic structure, aromatic ring skeleton, and alicyclic skeleton may have a heteroatom and may be either a non-substitution product or a substitution product. Preferable examples of the condensed polycyclic hydrocarbon ring formed by a ring-forming group include naphthalene ring, anthracene ring, pyrene ring, indane ring, indene ring, tetrahydronaphthalene ring, fluorene ring, xanthene ring, and isoindolinone ring.

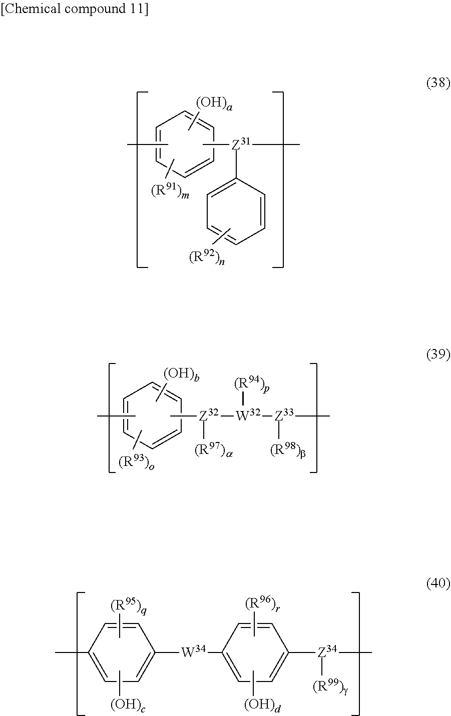

In the general formulas (38) to (40), Z³¹ to Z³⁴ are each independently an aliphatic structure containing 1 or 2 carbon atoms. W³² is an aromatic group, a condensed polycyclic structure, a condensed polycyclic heterocyclic structure, a structure having a directly bonded aromatic ring skeleton and alicyclic skeleton, or a structure having at least two directly bonded aromatic ring skeletons. W³⁴ is a direct bond, an alkylene group having 1 to 6 carbon atoms, an alkylidene group having 1 to 6 carbon atoms, a halogenated alkylene group having 1 to 6 carbon atoms, a halogenated alkylidene group having 1 to 6 carbon atoms, an aromatic group, a condensed polycyclic structure, a condensed polycyclic heterocyclic structure, a structure having a directly bonded aromatic ring skeleton and alicyclic skeleton, or a structure having at least two directly bonded aromatic ring skeletons. R⁹¹ to R⁹⁶ are each independently a halogen atom, an alkyl group having 1 to 10 carbon atoms, an aryl group having 6 to 15 carbon atoms, an alkenyl group having 2 to 10 carbon atoms, an alkoxy group having 1 to 10 carbon atoms, an alkenyloxy group having 2 to 10 carbon atoms, an acyl group having 1 to 10 carbon atoms, a carboxyl group, an amino group, or a ring-forming group. A ring connected by a ring-forming group represents a monocyclic or condensed polycyclic hydrocarbon ring. R⁹⁷ to R⁹⁹ are each independently an alkyl group having 1 to 10 carbon atoms, a cycloalkyl group having 4 to 10 carbon atoms, an aryl group having 6 to 15 carbon atoms, or a hydroxyl group. Here, a is an integer of 1 to 4; m is an integer of 0 to 3; n is an integer of 0 to 5; b is an integer of 1 to 4; o is an integer of 0 to 3; p is an integer of 0 to 10; 0≤p≤(X−2) where X is the valence of W³²; c and d are each independently an integer of 1 to 4; q and r are each independently an integer of 0 to 3; and a, B, and y are each independently an integer of 0 to 4.

In the general formulas (38) to (40), W³² is preferably a condensed polycyclic structure or a condensed polycyclic heterocyclic structure. W³⁴ is preferably an aromatic group, a condensed polycyclic structure, a condensed polycyclic heterocyclic structure, a structure having a directly bonded aromatic ring skeleton and alicyclic skeleton, or a structure having at least two directly bonded aromatic ring skeletons, of which a condensed polycyclic structure or a condensed polycyclic heterocyclic structure are more preferable. The aforementioned aliphatic structure, alkyl group, cycloalkyl group, aryl group, alkenyl group, alkoxy group, alkenyloxy group, acyl group, ring-forming group, alkylene group, alkylidene group, aromatic group, condensed polycyclic structure, condensed polycyclic heterocyclic structure, aromatic ring skeleton, and alicyclic skeleton may have a heteroatom and may be either a non-substitution product or a substitution product. Preferable examples of the condensed polycyclic hydrocarbon ring formed by a ring-forming group include naphthalene ring, anthracene ring, pyrene ring, indane ring, indene ring, tetrahydronaphthalene ring, fluorene ring, xanthene ring, and isoindolinone ring.

The contents of the structural units represented by the general formula (31) given above, the structural units represented by the general formula (32), the structural units represented by the general formula (34), the structural units represented by the general formula (35), and the structural units represented by the general formula (38) in the total structural units of phenolic resins are preferably 50 mol % or more, more preferably 60 mol % or more, and still more preferably 70 mol % or more. On the other hand, the contents of the structural units represented by the general formula (31) given above, the structural units represented by the general formula (32), the structural units represented by the general formula (34), the structural units represented by the general formula (35), and the structural units represented by the general formula (38) are preferably 100 mol % or less and more preferably 90 mol % or less.

The contents of the structural units represented by the general formula (33) given above, the structural units represented by the general formula (39), and the structural units represented by the general formula (40) in the total structural units of phenolic resins are preferably 5 mol % or more, more preferably 10 mol % or more, more preferably 15 mol % or more, and still more preferably 20 mol % or more. On the other hand, the contents of the structural units represented by the general formula (33) given above, the structural units represented by the general formula (39), and the structural units represented by the general formula (40) are preferably 70 mol % or less, more preferably 60 mol % or less, and still more preferably 50 mol % or less.

From the perspective of realizing lower voltage driving of the light emission characteristics and improved light emission luminance, it is also preferable that the phenol resin to use has a structural unit as represented by the general formula (36). It is preferable that the content of the structural units represented by the general formula (36) accounts for 50 to 100 mol %, more preferably 60 to 100 mol %, and still more preferably 70 to 100 mol %, of all structural units in the phenol resin.

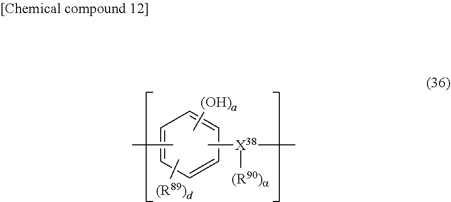

In the general formula (36), X³⁸ is an aliphatic structure having 1 to 6 carbon atoms. R⁸⁹ is a halogen atom, an alkyl group having 1 to 10 carbon atoms, an aryl group having 6 to 15 carbon atoms, an alkenyl group having 2 to 10 carbon atoms, an alkoxy group having 1 to 10 carbon atoms, an alkenyloxy group having 2 to 10 carbon atoms, an acyl group having 1 to 10 carbon atoms, a carboxyl group, an amino group, or a ring-forming group. A ring connected by a ring-forming group represents a monocyclic or condensed polycyclic hydrocarbon ring. R⁹⁰ is an alkyl group having 1 to 10 carbon atoms, a cycloalkyl group having 4 to 10 carbon atoms, or an aryl group having 6 to 15 carbon atoms. Here, a is an integer of 1 to 4; b is an integer of 0 to 3; and a is an integer of 0 to 4. The aforementioned aliphatic structure, alkyl group, aryl group, alkenyl group, alkoxy group, acyl group, ring-forming group, and alkylene group may each have a heteroatom and may each be a non-substitution product or a substitution product. Preferable examples of the condensed polycyclic hydrocarbon ring formed by a ring-forming group include naphthalene ring, anthracene ring, pyrene ring, indane ring, indene ring, tetrahydronaphthalene ring, fluorene ring, xanthene ring, and isoindolinone ring.

### <Acidic Group>

The phenol resin has, as acidic group, a phenolic hydroxyl group in at least one of the main chain of the resin, side chain of the resin, and chain end of the resin. The phenol resin is preferably a resin that is obtainable by reacting a phenolic compound with one or more selected from the group consisting of aldehyde compounds, alkoxymethyl compounds, and methylol compounds. In addition, also preferable is a resin that is obtainable by introducing a phenolic hydroxyl group into at least one of the main chain of the resin, side chain of the resin, or the chain end of the resin through a reaction using a catalyst. Here, it may also have carboxyl groups and/or carboxylic anhydride groups. Examples include resins obtained by reacting the phenolic hydroxyl groups in the resins with carboxylic anhydrides, and resins obtained by reacting, as the phenolic compound, a phenolic compound having a carboxyl group and/or a carboxylic anhydride group.

### <Radical Polymerizable Group>

The phenol resin preferably includes a resin (A3b-1) as specified below. The resin (A3b-1) is a resin (A3b) having at least one radical polymerizable group.

Resin (A3b-1): unsaturated group-containing phenolic resin

The resin (A3b-1) is preferably a resin that is obtainable by reacting part of the acidic groups present in the resin with an epoxy compound having a radical polymerizable group. In addition, also preferable is a resin that is obtainable by introducing a radical polymerizable group into at least either the side chain of the resin or chain end of the resin through a reaction using a catalyst. Here, in the case where the alkali soluble resin (A) includes a resin (A3b-1), it is preferable that the alkali soluble resin (A) further includes a resin (A3a-1) specified below. The unsaturated group is preferably an ethylenically unsaturated double bond group. The resin (A3a-1) is a resin (A3a) that does not have a radical polymerizable group. Resin (A3a-1): phenolic resin having no unsaturated group

### <Other Structural Units and Molecular Weight>

From the perspective of improving the reliability of the light emitting element, the structural units present in the phenolic resin are also preferably structural units having aromatic groups such as structural units derived from aromatic aldehyde compounds and structural units derived from aromatic ketone compounds, and are also preferably structural units having alicyclic groups such as structural units derived from alicyclic aldehyde compounds, structural units derived from alicyclic ketone compounds, structural units derived from alicyclic alkoxymethyl compounds, and structural units derived from alicyclic methylol compounds.

From the perspective of enhancing the reliability of the light emitting element, the polystyrene based Mw of the phenol resins as determined by GPC is preferably 500 or more and more preferably 1,000 or more. On the other hand, from the perspective of reducing the residue remaining after development and achieving lower taper in the pattern shape, their Mw is preferably 50,000 or less, more preferably 30,000 or less, still more preferably 10,000 or less, still more preferably 5,000 or less, and particularly preferably 3,000 or less. Phenol resins can be synthesized by generally known methods. Examples of the phenol compounds, aldehyde compounds, ketone compounds, alkoxymethyl compounds, and methylol compounds include those described in International Publication WO 2017/159876.

### <Alkali Soluble Resin (A); Polyhydroxystyrene>

The resin (A3-2), which is polyhydroxystyrene, is described below. Examples of the polyhydroxystyrene include resins that are obtainable by radical copolymerization of a hydroxystyrene derivative etc. with a styrene derivative and/or other copolymerization components. Such other copolymerization components include (meth)acrylic acid derivatives and (meth)acrylate derivatives. The inclusion of the resin (A3-2) serves to significantly enhance the effect of realizing lower voltage driving of the light emission characteristics and improved light emission luminance.

### <Acidic Group>

Polyhydroxystyrene has, as acid group, a phenolic hydroxyl group in at least one of the main chain of the resin, side chain of the resin, and chain end of the resin. The polyhydroxystyrene resin to use is preferably a resin that is obtainable by radical copolymerization of a copolymerization component that at least contains a hydroxystyrene derivative. In addition, also preferable is a resin that is obtainable by preparing a resin through further radical copolymerization with a copolymer component containing a (meth)acrylate having a reactive group such as epoxy group and reacting the epoxy group etc. present in the resin with a phenol compound etc. having a carboxyl group, and also preferable is a resin that is obtainable by introducing a phenolic hydroxyl group into at least one of the main chain of the resin, side chain of the resin, or the chain end of the resin through a reaction using a catalyst. Here, they may also have carboxyl groups and/or carboxylic anhydride groups. Examples include resins that are obtainable by reacting phenolic hydroxyl groups in the resin with a carboxylic anhydride, and resins that are obtainable by reacting, as other copolymerization components, those copolymerization components having carboxyl groups and/or carboxylic anhydride groups.

### <Radical Polymerizable Group>

The polyhydroxystyrene resin preferably includes a resin (A3b-2) as specified below. The resin (A3b-2) is a resin (A3b) that has at least one radical polymerizable group.

Resin (A3b-2): unsaturated group-containing polyhydroxystyrene

The resin (A3b-2) is preferably a resin that is obtainable by reacting part of the acidic groups present in the resin with an epoxy compound having a radical polymerizable group. In addition, also preferable is a resin that is obtainable by reacting the epoxy group etc. in the resin with a carboxylic acid compound having radical polymerizable groups. Here, in the case where the alkali soluble resin (A) includes a resin (A3b-2), it is preferable that the alkali soluble resin (A) further includes a resin (A3a-2) as specified below. The unsaturated group is preferably an ethylenically unsaturated double bond group. The resin (A3a-2) is a resin (A3a) that does not have a radical polymerizable group.

Resin (A3b-2): unsaturated group-free polyhydroxystyrene

### <Other Structural Units and Molecular Weight>

From the perspective of improving the reliability of the light emitting element, it is preferable that the structural units present in the polyhydroxystyrene are structural units having aromatic groups such as structural units derived from aromatic (meth)acrylate derivatives and also preferable are structural units having alicyclic groups such as structural units derived from alicyclic (meth)acrylate derivatives.

From the perspective of improving the reliability of the light emitting element, the polystyrene based Mw of the polyhydroxystyrene as determined by GPC is preferably 500 or more and more preferably 1,000 or more. On the other hand, from the perspective of reducing the residue remaining after development and achieving lower taper in the pattern shape, its Mw is preferably 50,000 or less and more preferably 20,000 or less. Polyhydroxystyrene can be synthesized by a generally known method. Examples of hydroxystyrene derivatives, styrene derivatives, and other copolymerization components include those described in International Publication WO 2017/159876.

### <Alkali Soluble Resin (A); Phenol Group-Containing Epoxy Resin>

The resin (A3-3), which is a phenol group-containing epoxy resin, is described below. Examples of phenol group-containing epoxy resins include those obtainable through reactions as described below under (1-a3-3) and (2-a3-3). If necessary, a polyfunctional alcohol compound may be further reacted at any reaction stage. The phenol group-containing epoxy resin has a cyclic skeleton in the structural units of the resin. The inclusion of the resin (A3-3) serves to significantly enhance the effect of realizing lower voltage driving of the light emission characteristics and improved light emission luminance. Here, the phenol group-containing epoxy resin is occasionally referred to as phenol group modified epoxy resin.
(1-a3-3) A resin obtainable by reacting a polyfunctional epoxy compound with a phenol compound having an epoxy reactive group
(2-a3-3) A resin obtainable by further reacting the aforementioned resin (1-a3-3) with a polyfunctional carboxylic dianhydride or a polyfunctional carboxylic acid compound

From the perspective of realizing lower voltage driving of the light emission characteristics, improved light emission luminance, and improved reliability of the light emitted light, it is preferable that the phenol group-containing epoxy resin contains a structural unit having a condensed polycyclic structure, a structural unit having a condensed polycyclic heterocyclic structure, a structural unit having a directly connected aromatic skeleton and alicyclic skeleton, or a structural unit having a structure having at least two directly connected aromatic skeletons. The condensed polycyclic structure unit or the condensed polycyclic heterocyclic structure is preferably a naphthalene structure, fluorene structure, or xanthene structure. The alicyclic skeleton is preferably a tricyclo[5.2.1.0^{2,6}]decane structure. The structure having at least two directly connected aromatic skeletons is preferably the biphenyl structure.

### <Acidic Group>

The phenol group-containing resin has, as acidic group, a phenolic hydroxyl group in at least one of the main chain of the resin, side chain of the resin, and chain end of the resin. It is preferable that the phenol group-containing epoxy resin is a resin that is obtainable by reacting a polyfunctional epoxy compound etc. with a phenol compound having an carboxyl group. In addition, also preferable is a resin that is obtainable by introducing a phenolic hydroxyl group into at least one of the main chain of the resin, side chain of the resin, or the chain end of the resin through a reaction using a catalyst. Here, they may also have carboxyl groups and/or carboxylic anhydride groups. Examples include resins that are obtainable by reacting the hydroxy groups in the resins with carboxylic anhydrides.

### <Radical Polymerizable Group>

The phenol group-containing epoxy resin preferably contains a resin (A3b-3) as specified below. The resin (A3b-3) is a resin (A3b) having at least one radical polymerizable group. Resin (A3b-3): unsaturated group-containing phenol group-containing epoxy resin

The resin (A3b-3) is preferably a resin that is obtainable by reacting part of the acidic groups etc. present in the resin with an epoxy compound etc. having a radical polymerizable group. In addition, also preferable is a resin that is obtainable by reacting the epoxy groups etc. present in the resin with a carboxylic acid compound etc. having a radical polymerizable group. Here, in the case where the alkali soluble resin (A) includes a resin (A3b-3), it is preferable that the alkali soluble resin (A) further includes a resin (A3a-3) as specified below. The unsaturated group is preferably an ethylenically unsaturated double bond group. The resin (A3a-3) is a resin (A3a) that does not have a radical polymerizable group. Resin (A3a-3): unsaturated group-free phenol group-containing epoxy resin

### <Other Structural Units and Molecular Weight>

From the perspective of improving the reliability of the light emitting element, it is preferable that the structural units present in the phenol group-containing epoxy resins include structural units having aromatic groups such as structural units derived from aromatic polyfunctional carboxylic acid compounds and structural units derived from aromatic polyfunctional carboxylic dianhydrides.

From the perspective of improving the reliability of the light emitting element, the polystyrene based Mw of the phenol group-containing epoxy resins as determined by GPC is preferably 500 or more and more preferably 1,000 or more. On the other hand, from the perspective of reducing the residue remaining after development and achieving lower taper in the pattern shape, their Mw is preferably 50,000 or less and more preferably 20,000 or less. Phenol group-containing epoxy resins can be synthesized by generally known methods.

### <Alkali Soluble Resin (A); Phenol Group-Containing Acrylic Resin>

The resin (A3-4), which is a phenol group-containing acrylic resin, is described below. Examples of phenol group-containing acrylic resins include those obtainable through the reactions described below under (1-a3-4) to (5-a3-4). The inclusion of the resin (A3-4) serves to significantly enhance the effect of realizing lower voltage driving of the light emission characteristics and improved light emission luminance. Here, phenol group-containing acrylic resins are occasionally referred to as phenol group modified acrylic resins.
(1-a3-4) A resin obtainable through radical copolymerization of one or more selected from the group consisting of (meth)acrylic acid derivatives, (meth)acrylate derivatives, styrene derivatives, and other copolymerization components, followed by further reacting the resulting resin with a phenol compound having an addition-reactive group
(2-a3-4) A resin obtainable by further reacting the above resin (1-a3-4) with a polyfunctional carboxylic dianhydride or a polyfunctional carboxylic acid compound
(3-a3-4) A resin obtainable through radical copolymerization of copolymerization components having phenolic hydroxyl groups and one or more selected from the group consisting of (meth)acrylic acid derivatives, (meth)acrylate derivatives, styrene derivatives, and other copolymerization components. Here, the copolymerization components having phenolic hydroxyl groups are different from the hydroxystyrene derivatives.
(4-a3-4) A resin obtainable by further reacting the above resin (3-a3-4) with a phenol compound having an addition-reactive group
(5-a3-4) A resin obtainable by further reacting the above resin (4-a3-4) with a polyfunctional carboxylic dianhydride or a polyfunctional carboxylic acid compound

### <Acidic Group>

The phenol group-containing acrylic resin has, as acidic group, a phenolic hydroxyl group in at least one of the main chain of the resin, side chain of the resin, and chain end of the resin. The phenol group-containing acrylic resin is preferably a resin obtainable by preparing a resin through radical copolymerization of a copolymerization component containing a (meth)acrylate having a reactive group such as epoxy group and further reacting the epoxy group etc. present in the resulting resin with a phenol compound having a carboxyl group. In addition, also preferable is a resin that is obtainable by introducing a phenolic hydroxyl group into at least one of the main chain of the resin, side chain of the resin, or the chain end of the resin through a reaction using a catalyst. Here, they may also have carboxyl groups and/or carboxylic anhydride groups. Examples include resins that are obtainable by reacting the hydroxy groups present in the resins with carboxylic anhydrides.

### <Radical Polymerizable Group>

The phenol group-containing acrylic resin preferably contains a resin (A3b-4) as specified below. The resin (A3b-4) is a resin (A3b) having at least one radical polymerizable group. Resin (A3b-4): unsaturated group-containing phenolic group-containing acrylic resin

The resin (A3b-4) is preferably a resin that is obtainable by reacting part of the acidic groups etc. present in the resin with an epoxy compound etc. having a radical polymerizable group. In addition, also preferable is a resin that is obtainable by reacting the epoxy groups etc. present in the resin with a carboxylic acid compound etc. having a radical polymerizable group. Here, in the case where the alkali soluble resin (A) includes a resin (A3b-4), it is preferable that the alkali soluble resin (A) further includes a resin (A3a-4) as specified below. The unsaturated group is preferably an ethylenically unsaturated double bond group. The resin (A3a-4) is a resin (A3a) that does not have a radical polymerizable group. Resin (A3a-4): unsaturated group-free phenolic group-containing acrylic resin

### <Other Structural Units and Molecular Weight>

From the perspective of improving the reliability of the light emitting element, the structural units present in the phenol group-containing acrylic resins are also preferably structural units having aromatic groups such as structural units derived from aromatic (meth)acrylate derivatives and structural units derived from styrene derivatives, and also preferable are structural units having alicyclic groups such as structural units derived from alicyclic (meth)acrylate derivatives.

From the perspective of improving the reliability of the light emitting element, the polystyrene based Mw of the phenol group-containing acrylic resins as determined by GPC is preferably 1,000 or more and more preferably 3,000 or more. On the other hand, from the perspective of reducing the residue remaining after development and achieving lower taper in the pattern shape, their Mw is preferably 50,000 or less and more preferably 20,000 or less. Phenol group-containing acrylic resins can be synthesized by generally known methods.

### <Content of Alkali Soluble Resin (A)>

For the present invention, from the perspective of realizing lower voltage driving of the light emission characteristics, improved light emission luminance, and improved reliability of the light emitting element, the total content of the resin (A1) is preferably 5 mass % or more, more preferably 10 mass % or more, still more preferably 20 mass % or more, still more preferably 30 mass % or more, and particularly preferably 35 mass % or more, of the total mass, which accounts for 100 mass %, of the alkali soluble resin (A). On the other hand, from the perspective of realizing lower voltage driving of the light emission characteristics and improved light emission luminance, the total content of the resin (A1) is preferably 100 mass % or less, more preferably 90 mass % or less, still more preferably 80 mass % or less, still more preferably 75 mass % or less, and particularly preferably 70 mass % or less.

For the present invention, from the perspective of improving the reliability of the light emitting element, the total content of the resin (A2) is preferably 5 mass % or more, more preferably 10 mass % or more, still more preferably 15 mass % or more, still more preferably 20 mass % or more, and particularly preferably 25 mass % or more, of the total mass, which accounts for 100 mass %, of the alkali soluble resin (A). On the other hand, from the perspective of realizing lower voltage driving of the light emission characteristics, improved light emission luminance, and improved reliability of the light emitted light, the total content of the resin (A2) is preferably 95 mass % or less, more preferably 85 mass % or less, still more preferably 75 mass % or less, still more preferably 70 mass % or less, and particularly preferably 65 mass % or less.

For the present invention, from the perspective of realizing lower voltage driving of the light emission characteristics, improved light emission luminance, and improved reliability of the light emitting element, the total content of the resin (A3) is preferably 5 mass % or more, more preferably 7 mass % or more, still more preferably 10 mass % or more, still more preferably 15 mass % or more, and particularly preferably 20 mass % or more, of the total mass, which accounts for 100 mass %, of the alkali soluble resin (A). On the other hand, from the perspective of improving the reliability of the light emitted light, the total content of the resin (A3) is preferably 90 mass % or less, more preferably 80 mass % or less, still more preferably 70 mass % or less, still more preferably 65 mass % or less, and particularly preferably 60 mass % or less.

From the perspective of realizing lower voltage driving of the light emission characteristics, improved light emission luminance, and improved reliability of the light emitting element, the content of the alkali soluble resin (A) is preferably 10 mass % or more, more preferably 20 mass % or more, and still more preferably 25 mass % or more, relative to the total solid content, excluding the solvent, of the composition according to the present invention. On the other hand, from the perspective of improving the reliability of the light emitted light, the content of the alkali soluble resin (A) is preferably 75 mass % or less, more preferably 65 mass % or less, and still more preferably 55 mass % or less. Furthermore, in the case where the composition according to the present invention includes an alkali soluble resin (A) and a radical polymerizable compound (B), the content of the alkali soluble resin (A) in the composition according to the present invention is preferably 25 parts by mass or more, more preferably 35 parts by mass or more, and still more preferably 45 parts by mass or more, relative to the total quantity of the alkali soluble resin (A) and the radical polymerizable compound (B) which accounts for 100 parts by mass. On the other hand, the content of the alkali soluble resin (A) is preferably 85 parts by mass or less, more preferably 80 parts by mass or less, and still more preferably 75 parts by mass or less. Here, the total solid content of the composition means the content of all components except the solvent present in the composition. Furthermore, the solid content can be determined by heating 1 g of the composition at 150° C. for 30 minutes to ensure liquid evaporation and exsiccation, measuring the mass of the remainder left after the heating, and calculating the concentration of solids from the difference in mass between before and after the heating.

### <Radical Polymerizable Compound (B)>

It is preferable that the composition according to the present invention further contains a radical polymerizable compound (B) (hereinafter referred to as “compound (B)”). The compound (B) is a compound that has a radical polymerizable group and it is preferably a compound that has at least two radical polymerizable groups. Examples and preferable features related to such radical polymerizable groups are as described above in relation to the alkali soluble resin (A). If the compound (B) is included, it significantly enhances the effect of improving the reliability of the light emitting element. When a cured film is formed from the photosensitive composition, crosslinked structures are introduced through radical polymerization of radical polymerizable groups such as (meth)acryloyl group present in the compound (B), and the resulting increase in crosslink density leads to a highly increased heat resistance. It is inferred that as a result, the outgassing from the pixel separation layer etc. is suppressed, accordingly significantly enhancing the effect of improving the reliability of the light emitting element.

The radical polymerizable group is preferably an ethylenically unsaturated double bond group. In the case where the photosensitive composition has negative photosensitivity, radicals are generated from the photopolymerization initiator (C1), which will be described later, in the light exposure step to cause radical polymerization of the compound (B). Accordingly, the light-exposed portion of the film of the photosensitive composition becomes insoluble in the alkaline developer, thereby significantly enhancing the effect of forming a negative type pattern. Furthermore, photocuring is accelerated when exposed to light, leading to an increase in sensitivity in the light exposure step. On the other hand, in the case where the photosensitive resin composition has positive photosensitivity, radical polymerization of the compound (B) occurs during post-development light exposure or heat curing in the portion that is left unexposed in the light exposure patterning step. This leads to an increase in the degree of crosslinking in the film of the photosensitive composition, thereby significantly enhancing the effect of controlling the pattern formation after heat curing. The radical polymerizable group in the compound (B) is more preferably a (meth)acryloyl group because it can realize faster radical polymerization.

It is preferable that compound (B) includes one or more selected from the group consisting of a hydrophobic skeleton-containing radical polymerizable compound (B1) (hereinafter referred to as “compound (B1)”), a flexible skeleton-containing radical polymerizable compound (B2) (hereinafter referred to as “compound (B2)”), and a cyclic skeleton-containing radical polymerizable compound (B3) (hereinafter referred to as “compound (B3)”). From the perspective of realizing lower voltage driving of the light emission characteristics, improved light emission luminance, and improved reliability of the light emitting element, the compound (B) preferably includes the compound (B1) and/or compound (B3), and more preferably further includes the compound (B2).

From the perspective of preventing narrow mask bias after development and improving the halftone characteristics, the compound (B) preferably has a double bond equivalent weight of 80 g/mol or more, more preferably 90 g/mol or more. On the other hand, from the perspective of improving the sensitivity during light exposure, its double bond equivalent weight is preferably 800 g/mol or less, more preferably 600 g/mol or less.

In the case where the composition according to the present invention includes the alkali soluble resin (A) and the compound (B), it is preferable, from the perspective of improving the sensitivity in the light exposure step and reducing the residue remaining after development, that the content of the compound (B) present in the composition according to the present invention is preferably 15 parts by mass or more, more preferably 20 parts by mass or more, and still more preferably 25 parts by mass or more, relative to the total mass, which accounts for 100 parts by mass, of the alkali soluble resin (A) and the compound (B). On the other hand, from the perspective of preventing narrow mask bias after development and improving the halftone characteristics and also from the perspective of improving the reliability of the light emitting element, the content of the compound (B) is preferably 75 parts by mass or less, more preferably 65 parts by mass or less, and still more preferably 55 parts by mass or less.

### <Radical Polymerizable Compound (B); Compound (B1)>

It is preferable that the composition according to the present invention includes the compound (B), that the compound (B) includes the compound (B1), that the compound (B1) has the structure (I-b1) and the structure (II-b1) given below, preferably having at least two structures (II-b1).
Structure (I-b1): a structure including one or more selected from the group consisting of fluorene structure, indane structure, condensed polycyclic alicyclic structure, indolinone structure, and isoindolinone structure
Structure (II-b1): a structure containing an organic group having a radical polymerizable group

The radical polymerizable group preferably has a (meth)acryloyl group. The inclusion of the compound (B1) significantly enhances the effect of realizing lower voltage driving of the light emission characteristics, improved light emission luminance, and improved reliability of the light emitting element.

From the perspective of improving the sensitivity during light exposure, suppressing narrow mask bias after development, and improving the halftone characteristics, it is more preferable that the compound (B1) has the structure (I-b1), the structure (II-b1), and either of the structure (III-b1) and the structure (IV-b1) given below.
Structure (III-b1): a structure containing an alkylene carbonyl group, oxyalkylene carbonyl group, or aminoalkylene carbonyl group
Structure (IV-b1): a structure containing a hydroxy group-containing alkylene group or a hydroxy group-containing oxyalkylene group

The total number of structures (III-b1) and structures (IV-b1) present in the compound (B1) is preferably 2 or more, more preferably 3 or more, and still more preferably 4 or more. On the other hand, the total number of structures (III-b1) and structures (IV-b1) is preferably 10 or less, more preferably 8 or less, and still more preferably 6 or less. It is preferable that the compound (B1) has the structure (III-b1). The structure (III-b1) is preferably a structure derived from a lactone compound or a structure derived from a lactam compound.

From the perspective of preventing narrow mask bias after development and improving the halftone characteristics, the compound (B1) preferably has a double bond equivalent weight of 150 g/mol or more, more preferably 190 g/mol or more. On the other hand, from the perspective of reducing the residue remaining after development, its double bond equivalent weight is preferably 600 g/mol or less, more preferably 400 g/mol or less.

In the case where the composition according to the present invention includes the alkali soluble resin (A) and the compound (B), it is preferable, from the perspective of preventing narrow mask bias after development and improving the halftone characteristics, that the content of the compound (B1) present in the composition according to the present invention is preferably 5 parts by mass or more, more preferably 10 parts by mass or more, relative to the total mass, which accounts for 100 parts by mass, of the alkali soluble resin (A) and the compound (B). On the other hand, it is preferable, from the perspective of reducing the residue remaining after development, that the compound (B1) preferably accounts for 25 parts by mass or less, more preferably 20 parts by mass or less.

### <Radical Polymerizable Compound (B); Compound (B2)>

It is preferable that the composition according to the present invention includes the compound (B), that the compound (B) includes the compound (B2), and that the compound (B2) has the structure (I-b2), structure (II-b2), and structure (III-b2) given below, preferably having at least two structures (II-b2).
Structure (I-b2): a structure derived from a compound having at least two hydroxy groups Structure (II-b2): a structure containing an organic group having a radical polymerizable group
Structure (III-b2): a structure containing an alkylene group, oxyalkylene group, hydroxy group-containing alkylene group, hydroxy group-containing oxyalkylene group, alkylene carbonyl group, oxyalkylene carbonyl group, or aminoalkylene carbonyl group

The radical polymerizable group preferably has a (meth)acryloyl group. If the compound (B2) is included, it significantly enhances the effect of improving the reliability of the light emitting element.

From the perspective of improving the sensitivity during light exposure, reducing the residue remaining after development, and improving the halftone characteristics, it is more preferable that the (I-b2) structure in the compound (B2) is the structure (I-b2x) given below.

Structure (I-b2x): a structure containing one or more selected from the group consisting of structures derived from aliphatic polyfunctional alcohols, alicyclic structures, and heterocyclic alicyclic structures

From the perspective of improving the sensitivity during light exposure, reducing the residue remaining after development, suppressing narrow mask bias after development, and improving the halftone characteristics, it is more preferable that the compound (B2) has the structure (III-b2x) given below.

Structure (III-b2x): a structure containing an alkylene carbonyl group, oxyalkylene carbonyl group, or aminoalkylene carbonyl group

The total number of structures (III-b2) and structures (III-b2x) present in the compound (B2) is preferably 2 or more, more preferably 3 or more, and still more preferably 4 or more. On the other hand, the total number of structures (III-b2) and structures (III-b2x) is preferably 12 or less, more preferably 10 or less, and still more preferably 8 or less. The alkylene group, oxyalkylene group, hydroxy group-containing alkylene group, and hydroxy group-containing oxyalkylene group are preferably structures derived from epoxy compounds or structures derived from alkylene glycols. It is preferable that the compound (B2) has the structure (III-b2x). The structure (III-b2x) is preferably a structure derived from a lactone compound or a structure derived from a lactam compound.

From the perspective of improving the sensitivity during light exposure, reducing the residue remaining after development, and improving the halftone characteristics, the number of radical polymerizable groups present in the compound (B2) is preferably 2 or more, more preferably 3 or more, and still more preferably 4 or more. On the other hand, from the perspective of improving the halftone characteristics and achieving lower taper in the pattern shape, the number of radical polymerizable groups is preferably 12 or less, more preferably 10 or less, and still more preferably 8 or less. Furthermore, from the perspective of improving the halftone characteristics and achieving lower taper in the pattern shape, the compound (B2) preferably has a double bond equivalent weight of 100 g/mol or more, more preferably 120 g/mol or more. On the other hand, from the perspective of improving the sensitivity during light exposure, reducing the residue remaining after development, and improving the halftone characteristics, its double bond equivalent weight is preferably 600 g/mol or less, more preferably 400 g/mol or less. From the perspective of improving the sensitivity during light exposure, reducing the residue remaining after development, preventing narrow mask bias after development, and improving the halftone characteristics, the compound (B2) more preferably contains a compound having at least three structures (II-b2) and a compound having at least two structures (II-b2).

In the case where the composition according to the present invention includes the alkali soluble resin (A) and the compound (B), it is preferable, from the perspective of improving the sensitivity during light exposure, reducing the residue remaining after development, and improving the halftone characteristics, that the content of the compound (B2) present in the composition according to the present invention is preferably 10 parts by mass or more, more preferably 20 parts by mass or more, relative to the total mass, which accounts for 100 parts by mass, of the alkali soluble resin (A) and the compound (B). On the other hand, it is preferable, from the perspective of improving the halftone characteristics and achieving lower taper in the pattern shape, that the compound (B2) accounts for 40 parts by mass or less, more preferably 35 parts by mass or less.

### <Radical Polymerizable Compound (B); Compound (B3)>

It is preferable that the composition according to the present invention includes the compound (B), that the compound (B) includes the compound (B3), that the compound (B3) has the structure (I-b3) and structure (II-b3) given below, preferably having at least two structures (II-b3).
Structure (I-b3): a structure containing an alicyclic structure and/or a heterocyclic alicyclic structure
Structure (II-b3): a structure containing an organic group having a radical polymerizable group

The compound (B3) is a different compound from the compound (B1) and the compound (B2). Here, a compound that corresponds to both the compound (B1) and the compound (B2) should be regarded as belonging to the category of compound (B1). The radical polymerizable group preferably has a (meth)acryloyl group. The inclusion of the compound (B3) significantly enhances the effect of realizing lower voltage driving of the light emission characteristics, improved light emission luminance, and improved reliability of the light emitting element.

From the perspective of reducing the residue remaining after development, suppressing narrow mask bias after development, and improving the halftone characteristics, it is preferable that the aforementioned structure (I-b3) in the compound (B3) is a structure containing a cyclic structure having at least two nitrogen atoms. The cyclic structure having at least two nitrogen atoms is preferably an isocyanuric acid structure and/or a triazine structure.

From the perspective of preventing narrow mask bias after development and improving the halftone characteristics, the compound (B3) preferably has a double bond equivalent weight of 150 g/mol or more, more preferably 190 g/mol or more. On the other hand, from the perspective of reducing the residue remaining after development, its double bond equivalent weight is preferably 600 g/mol or less, more preferably 400 g/mol or less.

In the case where the composition according to the present invention includes the alkali soluble resin (A) and the compound (B), it is preferable, from the perspective of preventing narrow mask bias after development and improving the halftone characteristics, that the content of the compound (B3) present in the composition according to the present invention is preferably 5 parts by mass or more, more preferably 10 parts by mass or more, relative to the total mass, which accounts for 100 parts by mass, of the alkali soluble resin (A) and the compound (B). On the other hand, it is preferable, from the perspective of reducing the residue remaining after development, that the compound (B3) preferably accounts for 25 parts by mass or less, more preferably 20 parts by mass or less.

### <Photosensitizer (C)>

The photosensitive composition according to the present invention includes a photosensitizer (C). The photosensitizer (C) refers to a compound that is converted into another compound when it undergoes bond cleavage, reaction, or structural change under light exposure, thereby imparting positive or negative photosensitivity to the photosensitive composition.

The composition according to the present invention has the effect of realizing excellent light emission characteristics to enable low voltage driving and high reliability of the light emitting element as a result of including the photosensitizer (C) and further including a component containing the sulfur element, a component containing a sulfur based anion, a component containing the chlorine element, a component containing the bromine element, or a component containing a halogen anion, which will be described later, while maintaining the contents of the sulfur element, sulfur based anions, chlorine element, bromine element, and halogen anions, which will be described later, in specific ranges. If they are configured in this way, even when the photosensitizer (C) contains unintended impurities, neither an increase in voltage driving of the light emission characteristics nor a decrease in reliability of the light emitting element will be caused by these impurities.

If the photosensitizer (C) is included, it significantly enhances the effect of improving the reliability of the light emitting element. As crosslinked structures are introduced due to heat curing of the photosensitizer (C), the resulting increase in crosslink density allows the photosensitive composition to form a cured film having a highly increased heat resistance. It is inferred that as a result, the outgassing from the pixel separation layer etc. is suppressed, accordingly significantly enhancing the effect of improving the reliability of the light emitting element.

The photosensitizer (C) preferably contains one or more selected from the group consisting of a photopolymerization initiator (C1) (hereinafter referred to as “compound (C1)”), naphthoquinone diazide compound (C2) (hereinafter referred to as “compound (C2)”), and photoacid generator (C3). To prepare a photosensitive composition having negative type photosensitivity, it preferably includes the compound (C1) and more preferably includes the compound (C2) and/or the photoacid generator (C3). To prepare a photosensitive composition having positive type photosensitivity, it preferably includes the compound (C2) and more preferably further includes the compound (C1) and/or the photoacid generator (C3).

From the perspective of improving the sensitivity during light exposure, it is preferable that the photosensitizer (C) accounts for 0.3 mass % or more, more preferably 1.0 mass % or more, and still more preferably 2.0 mass % or more, of the total solid content, excluding the solvent, of the photosensitive composition according to the present invention. On the other hand, from the perspective of reducing the residue remaining after development, the content of the photosensitizer (C) is preferably 25 mass % or less, more preferably 20 mass % or less, and still more preferably 15 mass % or less.

### <Photosensitizer (C); Compound (C1)>

The compound (C1) is a compound that generates radicals as it undergoes bond cleavage and/or a reaction when it is exposed to light. The inclusion of the compound (C1) is desirable for forming a negative pattern. Even if radicals are generated only in small quantities from the compound (C1) under light exposure, reactions including the aforementioned radical polymerization of the compound (B) etc. proceed in a series, which is suitable for forming a negative type pattern with a small exposure of light, resulting in a significant increase in sensitivity during light exposure. If the compound (C1) is included, it significantly enhances the effect of improving the reliability of the light emitting element. When a cured film is formed from the photosensitive composition, the compound (C1) acts to accelerate the radical polymerization of radical polymerizable groups such as (meth)acryloyl group to introduce crosslinked structures, and the resulting increase in crosslink density leads to a highly increased heat resistance. It is inferred that as a result, the outgassing from the pixel separation layer etc. is suppressed, accordingly significantly enhancing the effect of improving the reliability of the light emitting element.

Preferable examples of the compound (C1) include benzyl ketal based compounds, a-hydroxyketone based compounds, a-aminoketone based compounds, acylphosphine oxide based compounds, biimidazole based compounds, oxime ester based compounds, acridine based compounds, titanocene based compounds, benzophenone based compounds, acetophenone based compounds, aromatic ketoester based compounds, and benzoate based compounds, of which a-hydroxyketone based compounds, a-aminoketone based compounds, acylphosphine oxide based compounds, biimidazole based compounds, and oxime ester based compounds are more preferable from the perspective of improving the sensitivity during light exposure, oxime ester based compounds being still more preferable from the perspective of improving the sensitivity during light exposure, improving the halftone characteristics, and reducing the residue remaining after development.

From the perspective of improving the sensitivity during light exposure, it is preferable that the compound (C1) accounts for 0.3 mass % or more, more preferably 1.0 mass % or more, and still more preferably 2.0 mass % or more, of the total solid content, excluding the solvent, of the photosensitive composition according to the present invention. On the other hand, from the perspective of reducing the residue remaining after development, the content of the compound (C1) is preferably 25 mass % or less, more preferably 20 mass % or less, and still more preferably 15 mass % or less. Furthermore, in the case where the photosensitive composition according to the present invention includes the alkali soluble resin (A) and the compound (B), it is preferable that the content of the compound (C1) present in the photosensitive composition according to the present invention is preferably 1 part by mass or more, more preferably 3 parts by mass or more, and still more preferably 5 parts by mass or more, relative to the total mass, which accounts for 100 parts by mass, of the alkali soluble resin (A) and the compound (B). On the other hand, the content of the compound (C1) is preferably 30 parts by mass or less, more preferably 25 parts by mass or less, and still more preferably 20 parts by mass or less.

### <Photosensitizer (C); Compound (C1-1)>

For the photosensitive composition according to the present invention, the compound (C1) preferably contains an oxime ester based compound (C1-1) (hereinafter referred to as “compound (C1-1)”). The compound (C1-1) is a compound that has an oxime ester structure that works as skeleton to generate radicals as it undergoes bond cleavage and/or a reaction when it is exposed to light. If the compound (C1-1) is included, it significantly enhances the effect of improving the sensitivity during light exposure, improving the halftone characteristics, and reducing the residue remaining after development. From the perspective of improving the sensitivity during light exposure, improving the halftone characteristics, and reducing the residue remaining after development, it is preferable, for the photosensitive composition according to the present invention, that the compound (C1) includes the compound (C1-1) and further includes the compound (B) described above. The compound (C1-1) has high absorbance of the light used for light exposure, and therefore, it is suitable for highly efficient radical generation, resulting in a significant increase in the reaction rate of radical polymerization of the compound (B).

It is preferable that the compound (C1-1) has a condensed polycyclic structure, condensed polycyclic heterocyclic structure, or diphenyl sulfide structure. The compound (C1-1) preferably has a structure containing at least one oxime ester structure bonded to a condensed polycyclic structure, condensed polycyclic heterocyclic structure, or diphenyl sulfide structure (a-oxime structure) or a structure containing at least one oxime ester carbonyl structure bonded thereto (a structure in which an oxime ester structure is bonded via a carbonyl structure; B-oxime structure), and more preferably has a structure containing at least one oxime ester structure bonded thereto. Preferable examples of the condensed polycyclic structure include fluorene structure, benzofluorene structure, dibenzofluorene structure, indene structure, indane structure, benzoindene structure, and benzoindane structure, of which fluorene structure, benzofluorene structure, and dibenzofluorene structure are more preferable. Preferable examples of the condensed polycyclic heterocyclic structure include carbazole structure, dibenzofuran structure, dibenzothiophene structure, benzocarbazole structure, indole structure, indoline structure, benzoindole structure, benzoindoline structure, phenothiazine structure, and phenothiazine oxide structure, of which carbazole structure, benzocarbazole structure, indole structure, and benzoindole structure are more preferable. From the perspective of improving the sensitivity during light exposure, suppressing narrow mask bias after development, and improving the halftone characteristics, it is preferable that the compound (C1-1) has a fluorene structure, benzofluorene structure, dibenzofluorene structure, benzocarbazole structure, indole structure, benzoindole structure, phenothiazine structure, or phenothiazine oxide structure.

From the perspective of improving the sensitivity during light exposure, suppressing narrow mask bias after development, and improving the halftone characteristics, it is preferable that the compound (C1-1) has one or more selected from the group consisting of the nitro group, naphthyl carbonyl structure, trimethylbenzoyl structure, thiophenyl carbonyl structure, furylcarbonyl structure, at least two oxime ester structures, and at least two oxime ester carbonyl structures (hereinafter referred to as “specific substituents present in the compound (C1-1)”). In particular, it preferably has a structure in which a specific substituent present in the compound (C1-1) is bonded to a condensed polycyclic structure, condensed polycyclic heterocyclic structure, or diphenyl sulfide structure, or more preferably has a structure in which a specific substituent present in the compound (C1-1) is bonded to a fluorene structure, benzofluorene structure, or dibenzofluorene structure.

If the compound (C1-1) has a fluorene structure, benzofluorene structure, or dibenzofluorene structure, it allows the compound (C1-1) to exhibit photobleaching capability, which significantly enhances the effect of improving the sensitivity during light exposure, suppressing narrow mask bias after development, and improving the halftone characteristics. Photobleaching capability means the tendency to cause a decrease in absorbance in the ultraviolet wavelength range (for example, 400 nm or less) and/or in the visible light wavelength range (380-780 nm) as a result of undergoing bond cleavage and/or a reaction under light exposure. Similarly, from the perspective of exhibiting photobleaching capability, it is also preferable for the compound (C1-1) to have a diphenyl sulfide structure, indole structure, benzoindole structure, phenothiazine structure, or phenothiazine oxide structure, and also preferable to have a structure in which at least one oxime ester carbonyl structure is bonded to a condensed polycyclic structure or condensed polycyclic heterocyclic structure.

From the perspective of improving the sensitivity during light exposure, suppressing narrow mask bias after development, and improving the halftone characteristics, the compound (C1-1) preferably has a halogen-substituted group, and more preferably has a fluorine-substituted group. In the case where the aforementioned alkali soluble resin (A) has a structural unit containing a halogen atom, it is inferred that the compatibility between the resin and photopolymerization initiator is increased to promote the photocuring to proceed from the surface toward deeper layers of the film. Here, the polyimide based resin described above preferably has a structural unit containing a fluorine atom. Preferable examples of the halogen-substituted groups include the trifluoromethyl group, trifluoropropyl group, trichloropropyl group, tetrafluoropropyl group, fluorocyclopentyl group, fluorophenyl group, pentafluorophenyl group, trifluoropropoxy group, tetrafluoropropoxy group, and pentafluorophenoxy group.

From the perspective of improving the sensitivity during light exposure, suppressing narrow mask bias after development, and improving the halftone characteristics, it is preferable that the compound (C1-1) has a radical polymerizable group. The radical polymerizable group is preferably an ethylenically unsaturated double bond group. The radical polymerizable group is more preferably one or more selected from the group consisting of photoreactive groups, alkenyl groups having 2 to 5 carbon atoms, and alkynyl groups having 2 to 5 carbon atoms. Preferable examples of the photoreactive groups include the styryl group, cinnamoyl group, maleimide group, nadimide group, and (meth)acryloyl group, of which (meth)acryloyl group is more preferable. On the other hand, preferable examples of the alkenyl groups having 2 to 5 carbon atoms and alkynyl groups having 2 to 5 carbon atoms include the vinyl group, allyl group, 2-methyl-2-propenyl group, crotonyl group, 2-methyl-2-butenyl group, 3-methyl-2-butenyl group, 2,3-dimethyl-2-butenyl group, ethynyl group, and 2-propargyl group, of which vinyl group and allyl group are more preferable. In particular, it is preferable to have a structure in which a radical polymerizable group is bonded to a condensed polycyclic structure, condensed polycyclic heterocyclic structure, or diphenyl sulfide structure.

The preferable content of the compound (C1-1) relative to the total solid content, excluding the solvent, of the photosensitive composition according to the present invention is as described above in relation to the preferable content of the compound (C1). In addition, in the case where the photosensitive composition according to the present invention includes the alkali soluble resin (A) and the compound (B), the preferable content of the compound (C1-1) in the photosensitive composition according to the present invention is as described above in relation to the preferable content of the compound (C1). The compound having a structure derived from the compound (C1) is preferably the aforementioned compound (C1-DL) and/or compound (C1x-DL) present in the pixel separation layer etc. The compound having a structure derived from the compound (C1-1) is preferably the aforementioned compound (C1-DL) and/or compound (C1x-DL) present in the pixel separation layer etc.

### <Photosensitizer (C); Compound (C2)>

The compound (C2) is a compound that generates an indenecarboxylic acid and/or a sulfoindenecarboxylic acid as it undergoes structural change under light exposure. When it is exposed to light, the compound (C2) undergoes structural change into an acid compound, and accordingly, the light-exposed portion of the film of the photosensitive composition becomes soluble in the alkaline developer, thereby significantly enhancing the effect of forming a positive type pattern. Furthermore, the solubility of the light-exposed portion in the alkaline developer is increased selectively, thereby significantly enhancing the effect of ensuring a higher resolution after development. On the other hand, in the case where the photosensitive composition according to the present invention has negative type photosensitivity, the inclusion of the aforementioned compound (C1) and compound (C2) in the photosensitizer (C) acts to significantly enhance the effect of suppressing narrow mask bias after development, improving the halftone characteristics, suppressing narrow mask bias after development, and achieving lower taper in the pattern shape.

The compound (C2) is preferably a 1,2-naphthoquinonediazide-5-sulfonate or 1,2-naphthoquinonediazide-4-sulfonate of a compound having a phenolic hydroxyl group. Methods for producing the compound (C2) include, for example, a method in which a compound having a phenolic hydroxyl group is esterified with naphthoquinonediazide sulfonic acid and a method in which a compound having a phenolic hydroxyl group is esterified with naphthoquinonediazide sulfonic acid chloride. The naphthoquinonediazide sulfonic acid chloride is preferably 1,2-naphthoquinonediazide-5-sulfonic acid chloride or 1,2-naphthoquinonediazide-4-sulfonic acid chloride.

From the perspective of improving the sensitivity during light exposure, it is preferable for the compound (C2) to account for 0.3 mass % or more, more preferably 1.0 mass % or more, and still more preferably 2.0 mass % or more, of the total solid content, excluding the solvent, of the photosensitive composition according to the present invention. On the other hand, from the perspective of reducing the residue remaining after development, the content of the compound (C1) is preferably 25 mass % or less, more preferably 20 mass % or less, and still more preferably 15 mass % or less. Furthermore, in the case where the photosensitive composition according to the present invention includes the alkali soluble resin (A) and the compound (B), it is preferable that the content of the compound (C2) present in the photosensitive composition according to the present invention is preferably 1 part by mass or more, more preferably 3 parts by mass or more, and still more preferably 5 parts by mass or more, relative to the total mass, which accounts for 100 parts by mass, of the alkali soluble resin (A) and the compound (B). On the other hand, the content of the compound (C2) is preferably 30 parts by mass or less, more preferably 25 parts by mass or less, and still more preferably 20 parts by mass or less. The compound having a structure derived from the compound (C2) is preferably the aforementioned compound (C2-DL) and/or compound (C2x-DL) present in the pixel separation layer etc.

### <Photosensitizer (C); Photoacid Generator (C3)>

The photoacid generator (C3) is a compound that generates an acid as a result of bond cleavage and/or a reaction that occur when exposed to light. Even if an acid is generated only in small quantities from the photoacid generator (C3) under light exposure, the cationic polymerization of the cationic polymerizable compound and/or the crosslinking of the undermentioned crosslinking agent (G) etc. with the resin proceed in series, which is suitable for negative type pattern formation with a small exposure of light. It is also preferable that the photosensitizer (C) to contain the aforementioned compound (C1) and photoacid generator (C3). On the other hand, in the case where the photosensitizer (C) contains the aforementioned compound (C2) and photoacid generator (C3), an acid can be generated from the photoacid generator (C3) during post-development light exposure. The acid generated acts to promote the crosslinking of the undermentioned crosslinking agent (C) etc. with the resin during the subsequent heat curing step, thereby significantly enhancing the effect of improving the heat resistance of the cured film and improving the chemical resistance of the cured film.

Examples of the photoacid generator (C3) include ionic compounds and nonionic compounds. Preferable examples of the ionic compounds include triorganosulfonium salt based compounds. Preferable examples of the nonionic compounds include halogen-containing compounds, diazomethane compounds, sulfone compounds, sulfonic acid ester compounds, carboxylate compounds, sulfone imide compounds, phosphate compounds, and sulfone benzotriazole compounds. The preferable content of the compound (C3) relative to the total solid content, excluding the solvent, of the photosensitive composition according to the present invention is as described above in relation to the preferable content of the photosensitizer (C).

### <Colorant (D); Black Colorant (Da)>

The composition according to the present invention contains a colorant (D). The colorant (D) is a compound that colors a material by absorbing light in a visible light wavelength range (380-780 nm). If the colorant (D) is included, it serves to give a desired color to the light penetrating the film of the composition or the light reflected by the film of the composition. In addition, it can give light-shielding capability to the film of the composition.

The composition according to the present invention has the effect of realizing excellent light emission characteristics to enable low voltage driving and high reliability of the light emitting element when it contains the colorant (D) and further contains a component containing the sulfur element, a component containing a sulfur based anion, a component containing the chlorine element, a component containing the bromine element, and a component containing a halogen anion which will be described later while maintaining the contents of the sulfur element, sulfur based anions, chlorine element, bromine element, and halogen anions, which will be described later, adjusted in specific ranges. If they are configured in this way, even when the colorant (D) contains unintended impurities, neither an increase in voltage driving of the light emission characteristics nor a decrease in reliability of the light emitting element will be caused by these impurities.

If the colorant (D) is included, it significantly enhances the effect of improving the reliability of the light emitting element. The colorant (D) serves to block incident external light, thereby allowing the cured film of the photosensitive composition to work effectively for suppressing external light reflection. In addition, due to increased light blocking efficiency in the visible light wavelength region and the ultraviolet region, the outgassing from the pixel separation layer etc. is suppressed. As a result, the degradation of the light emitting element is suppressed, accordingly significantly enhancing the effect of improving the reliability of the light emitting element.

The colorant (D) is preferably a pigment or a dye. The pigment is a compound that works to color a material as it is physically adsorbed on or interacts with the surface of the relevant material, and it is insoluble in most solvents etc. The dye is a compound that works to color a material as it is chemically adsorbed on the surface structure of the relevant material, and it is soluble in most solvents etc. In particular, when blocking of visible light is necessary, it is preferable for the colorant (D) to contain a black colorant (Da) and/or a mixture of two or more colorants.

The black colorant (Da) is a compound that acts to color a material black as it absorbs light in the visible light wavelength range. If the black colorant (Da) is included, it significantly enhances the effect of allowing the composition to form a film with improved light blocking efficiency and improving the reliability of the light emitting element. A composition containing the black colorant (Da) gives a film that is suitable for applications that require an increase in contrast realized by suppressing external light reflection, prevention of light leakage from adjacent pixels, or prevention of malfunction of TFTs, and is particularly suitable for pixel separation layers, spacer layers, black matrix layers, TFT planarization layers, TFT protection layers, and interlayer insulation layers. In the case of a mixture of two or more colorants, it is preferable to include two or more colorants selected from the group consisting of red, orange, yellow, green, blue, and purple. The mixture of two or more colorants is more preferably a mixture that gives a pseudo black color as the two or more colorants absorb light in the visible wavelength range. The composition according to the present invention may include the black colorant (Da) and further include a colorant other than black (Db). The inclusion of a colorant other than black (Db) serves to allow the composition to form a film having a desired color on the color coordinate. The colorant (D) is preferably the colorant (D-DL) present in the pixel separation layer etc. which is described above.

The colorant (D) is regarded as black when it has a Colour Index Generic Name (hereinafter referred to as C.I. number) that contains “BLACK”. In the case of a colorant that does not have a C.I. number, it is regarded as black if the resulting cured film has a black color. To the examine the color of the resulting cured film, the transmission spectrum of the cured film of a composition containing the colorant (D) is observed and converted over a film thickness range of 0.1 to 1.5 μm so that the transmittance at a wavelength of 550 nm is 10% based on the Lambert-Beer's equation for a transmittance per 1.0 μm of film thickness at a wavelength of 550 nm. The color under examination is regarded as black if the transmittance in the wavelength rage of 450 to 650 nm is 25% or less in the converted transmission spectrum. The transmission spectrum of a cured film can be obtained by the method described in paragraph of International Publication WO 2019/087985.

For the pigment, it is preferable that the primary particle diameters and the average primary particle diameter are 20 to 150 nm. From the perspective of improving the reliability of the light emitting element, the primary particle diameters and the average primary particle diameter of a pigment are preferably 20 nm or more, more preferably 30 nm or more, still more preferably 40 nm or more, still more preferably 50 nm or more, and particularly preferably 60 nm or more. On the other hand, from the perspective of suppressing the external light reflection and improving the reliability of the light emitting element, the primary particle diameters and the average primary particle diameter of a pigment are preferably 150 nm or less, more preferably 120 nm or less, still more preferably 100 nm or less, still more preferably 90 nm or less, and particularly preferably 80 nm or less. For a pigment, the primary particle diameter is defined as the long axis diameter of a primary particle of the pigment. The preferable range of the average primary particle diameter of a pigment in a pigment dispersion is as described above in relation to the preferable range of the primary particle diameters and the average primary particle diameter of a pigment.

The primary particle diameter of a pigment can be measured by slicing the cured film to prepare a specimen for measurement, polishing it by ion milling treatment to create a cross section with enhanced smoothness, observing and photographing positions in the depth range of 0.2 to 0.8 μm from the surface of the cured film using a transmission electron microscope (hereinafter referred to as TEM) at a magnification of 50,000 times, and analyzing the image with image analysis software for particle size distribution (Mac-View, manufactured by MOUNTECH Co., Ltd.). Then, the average primary particle diameter of the pigment can be determined by photographing and analyzing the cross section of the specimen for measurement, and calculating the average of measured diameters of 30 primary particles. Furthermore, observation by transmission electron microscopy-energy dispersive X-ray spectroscopy (hereinafter referred to as TEM-EDX) is performed to identify the elements constituting the particles. Here, the average primary particle diameter of the pigment in the pigment dispersion can be determined based on particle diameter distribution measured by the dynamic light scattering method.

From the perspective of improving the light blocking efficiency and improving the reliability of the light emitting element, the colorant (D) preferably accounts for 5 mass % or more, more preferably 10 mass % or more, still more preferably 20 mass % or more, and particularly preferably 30 mass % or more, of the total solid content, excluding the solvent, of the composition according to the present invention. On the other hand, from the perspective of improving the sensitivity during light exposure and improving the reliability of the light emitting element, the content of the colorant (D) is preferably 70 mass % or less, and more preferably 50 mass %. For the composition according to the present invention, the preferable content of the black colorant (Da) is as described above in relation to the preferable content of the colorant (D).

### <Colorant (D); Black Pigment, Mixture of Two or More Color Pigments of Different Colors, Black Dye, and Mixture of Two or More Color Dyes of Different Colors>

For the composition according to the present invention, it is preferable that the colorant (D) includes a black pigment and/or a mixture of two or more color pigments of different colors, and that the black pigment contains an organic black pigment, the organic black pigment containing one or more selected from the group consisting benzofuranone based black pigments, perylene based black pigments, and azo based black pigments, whereas the two or more color pigments of different colors include two or more pigments of different colors selected from the group consisting of red, orange, yellow, green, blue, and purple.

If they are configured in this way, it significantly enhances the effect of realizing lower voltage driving of the light emission characteristics, improved light emission luminance, and improved reliability of the light emitting element. It is inferred that these pigments act to increase the conductivity on the surface of the first electrode that faces the light emitting layer and corresponds to the opening part in the pixel separation layer part or the opening part in the pixel size control layer part. Accordingly, this is considered to promote lower voltage driving of the light emission characteristics. It is inferred that as a result, this ensures that a highly enhanced light emission luminance is achieved at the same driving voltage. In addition, due to increased light blocking efficiency of the pixel separation layer etc. in the visible light wavelength region and the ultraviolet region, the outgassing from the pixel separation layer etc. is suppressed and the degradation of the light emitting element is prevented, thereby significantly enhancing the effect of improving the reliability of the light emitting element.

The black colorant (Da) preferably contains a black pigment. The black pigment preferably contains an organic black pigment and/or an inorganic black pigment, and more preferably contains an organic black pigment. The mixture of two or more colorant of different colors preferably contains a mixture of two or more color pigment of different colors. The mixture of two or more color pigments of different colors preferably contains two or more pigments of different colors selected from the group consisting of red, orange, yellow, green, blue, and purple. The mixture of two or more color pigments of different colors is more preferably a color pigment mixture containing a blue pigment, a red pigment, and a yellow pigment; a color pigment mixture containing a blue pigment, a red pigment, and an orange pigment; a color pigment mixture containing a blue pigment, a purple pigment, and an orange pigment; or a color pigment mixture containing a purple pigment and a yellow pigment. The mixture of two or more color pigments of different colors preferably contains one or more pigments selected from the group consisting of anthraquinone based pigments, diketopyrrolopyrrole based pigments, perylene based pigments, isoindoline based pigments, isoindolinone based pigments, imidazolone based pigments, quinacridone based pigments, pyranthrone based pigments, phthalocyanine based pigments, indanthrone based pigments, and dioxazine based pigments, and more preferably contains one or more pigments selected from the group consisting of perylene based pigments, imidazolone based pigments, and indanthrone based pigments. For the composition according to the present invention, the preferable contents of the black colorant and the mixture of two or more color pigments of different colors are as described above in relation to the preferable content of the colorant (D).

For the composition according to the present invention, it is preferable that the colorant (D) contains a black dye and/or a mixture of two or more coloring dyes of different colors and that the black dye contains an azo based black dye whereas the mixture of two or more coloring dyes of different colors contains two or more dyes of different colors selected from the group consisting of red, orange, yellow, green, blue, and purple dyes, wherein the mixture of two or more coloring dyes of different colors contains one or more dyes selected from the group consisting of squarylium based dyes, xanthene based dyes, triarylmethane based dyes, and phthalocyanine based dyes.

If they are configured in this way, it significantly enhances the effect of realizing lower voltage driving of the light emission characteristics, improved light emission luminance, and improved reliability of the light emitting element. It is inferred that these dyes act to increase the conductivity on the surface of the first electrode that faces the light emitting layer and corresponds to the opening part in the pixel separation layer part or the opening part in the pixel size control layer part. Accordingly, this is considered to promote lower voltage driving of the light emission characteristics. It is inferred that as a result, this ensures that a highly enhanced light emission luminance is achieved at the same driving voltage. In addition, due to increased light blocking efficiency of the pixel separation layer etc. in the visible light wavelength region and the ultraviolet region, the outgassing from the pixel separation layer etc. is suppressed and the degradation of the light emitting element is prevented, thereby significantly enhancing the effect of improving the reliability of the light emitting element.

The black colorant (Da) preferably contains a black dye. The black dye preferably includes a black dye containing a metal element and/or a black dye containing no metal element, and more preferably includes a black dye containing no metal element. The black dye is preferably an azo based black dye. Preferable examples of the black dye include Solvent Blacks 27-47, of which Solvent Blacks 27, 29, and 34 are more preferable (all numbers showing C. I. numbers). Examples of black dye products include VALIFAST (registered trademark) Black 3804 (Solvent Black 34), 3810 (Solvent Black 29), 3820 (Solvent Black 27), 3830 (Solvent Black 27), and NUBIAN (registered trademark) Black TN-870 (Solvent Black 7) (all manufactured by Orient Chemical Industries, Co., Ltd.). The mixture of two or more colorants of different colors preferably contains a mixture of two or more coloring dyes of different colors. The two or more coloring dyes of different colors preferably contains two or more dyes of different colors selected from the group consisting of red, orange, yellow, green, blue, and purple. The mixture of two or more coloring dyes of different colors is preferably a coloring dye mixture containing a blue dye, a red dye, and a yellow dye; a coloring dye mixture containing a blue dye, a red dye, and an orange dye; a coloring dye mixture containing a blue dye, a purple dye, and an orange dye; or a coloring dye mixture containing a purple dye and a yellow dye. The mixture of two or more coloring dyes of different colors preferably contains one or more dyes selected from the group consisting of a squarylium based dye, xanthene based dye, triarylmethane based dye, and phthalocyanine based dye, more preferably contains a xanthene based dye and/or a triarylmethane based dye, and still more preferably contains a xanthene based dye. For the composition according to the present invention, the preferable contents of the black dye and the mixture of two or more coloring dyes of different colors are as described above in relation to the preferable content of the colorant (D).

It is also preferable that the black colorant (Da) contains a black pigment and further contains a pigment other than black and/or a dye other than black. It is also preferable that the black colorant (Da) contains a black dye and further contains a pigment other than black and/or a dye other than black. The pigment other than black preferably contains one or more pigments of different colors selected from the group consisting of red, orange, yellow, green, blue, and purple and more preferably contains two or more pigments of different colors. The dye other than black preferably contains one or more dyes of different colors selected from the group consisting of red, orange, yellow, green, blue, and purple and more preferably contains two or more dyes of different colors.

<Colorant (D); Organic Black Pigment and/or Inorganic Black Pigment>

Examples of organic black pigments include benzofuranone based black pigments, perylene based black pigments, azo based black pigments, anthraquinone based black pigments, aniline based black pigments, and carbon black. The organic black pigments preferably include one or more selected from the group consisting of carbon black, benzofuranone based black pigments, perylene based black pigments, and azo based black pigments. For the composition according to the present invention, the preferable content of the organic black pigment is as described above in relation to the preferable content of the colorant (D).

The inorganic black pigments preferably include fine particles, oxides, complex oxides, sulfides, sulfates, nitrates, carbonates, nitrides, carbides, or oxynitrides of metal elements and more preferably include nitrides, carbides, or oxynitrides of metal elements. The metal elements are preferably Ti, Zr, V, Cr, Mn, Co, Ni, Y, Nb, Hf, Ta, W, Re, Fe, Cu, Zn, and Ag, and more preferably Ti, Zr, V, Cr, Y, Nb, Hf, Ta, W, and Re, of which titanium, zirconium, vanadium, and niobium are still more preferable. The inorganic black pigments preferably include nitrides, carbides, and oxynitrides of titanium, zirconium, vanadium, or niobium. The inorganic black pigments preferably further include elements other than the aforementioned metal elements, more preferably include B, Al, Si, Mn, Co, Ni, Fe, Cu, Zn, or Ag, and particularly preferably include B, Al, or Si. For the composition according to the present invention, the preferable content of the inorganic black pigment is as described above in relation to the preferable content of the colorant (D).

### <Colorant (D); Benzofuranone Based Black Pigment, Perylene Based Black Pigment, and Azo Based Black Pigment>

The organic black pigment preferably contains one or more selected from the group consisting of benzofuranone based black pigments, perylene based black pigments, and azo based black pigments, more preferably contains a benzofuranone based black pigment and/or a perylene based black pigment, and still more preferably contains a benzofuranone based black pigment.

If they are configured in this way, it significantly enhances the effect of realizing lower voltage driving of the light emission characteristics, improved light emission luminance, and improved reliability of the light emitting element. It is inferred that the benzofuranone based black pigment in particular acts to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. Furthermore, as compared with common organic pigments, benzofuranone based black pigments are high in light blocking efficiency per unit mass of the pigment, thereby significantly enhancing the effect of suppressing the external light reflection and improving the reliability of the light emitting element. In addition, as compared with common organic pigments and inorganic pigments, benzofuranone based black pigments have higher insulating efficiency and lower dielectricity, thereby significantly enhancing the effect of improving the reliability of the light emitting element.

The benzofuranone based black pigment preferably contains at least two benzofuran-2(3H)-one structures that may share a benzene ring or at least two benzofuran-3 (2H)-one structures that may share a benzene ring, and more preferably contains a compound having a structure as represented by the aforementioned general formula (161) or the aforementioned general formula (162), a geometric isomer thereof, a salt thereof, or a salt of a geometric isomer thereof.

The perylene based black pigment preferably has a perylene structure, and more preferably it is a compound having a structure as represented by any of the aforementioned general formulas (164) to (166) or a salt thereof, and still more preferably contains a compound having a 3,4,9,10-perylenetetracarboxylic acid bisbenzimidazole structure, a geometric isomer thereof, a salt thereof, or a salt of a geometric isomer thereof.

The azo based black pigment preferably has an azo group, and more preferably contains a compound having an azomethine structure and a carbazole structure or a salt thereof, and still more preferably it is a compound having a structure as represented by the aforementioned general formula (168) or a salt thereof.

Examples of the benzofuranone based black pigment include IRGAPHOR (registered trademark) BLACK S0100CF (manufactured by BASF), black pigments as described in International Publication WO 2010/081624, and black pigments as described in International Publication WO 2010/081756. Examples of the perylene based black pigment include C. I. Pigment Black 31 and C. I. Pigment Black 32 (each number showing a C. I. number). In addition to the aforementioned ones, other examples include PALIOGEN (registered trademark) BLACK S0084, K0084, L0086, K0086, K0087, K0088, EH0788, FK4280, and FK4281 (all manufactured by BASF). Furthermore, examples of the azo based black pigment (D1a-1c) include CHROMOFINE (registered trademark) BLACK A1103 (manufactured by Dainichiseika Colour & Chemicals Mfg. Co., Ltd.), black pigments as described in Japanese Unexamined Patent Publication (Kokai) No. HEI-01-170601, and black pigments as described in Japanese Unexamined Patent Publication (Kokai) No. HEI-02-034664. For the composition according to the present invention, the preferable contents of the benzofuranone based black pigment, perylene based black pigment, and azo based black pigment are as described above in relation to the preferable content of the colorant (D). It is preferable that the benzofuranone based black pigment is the benzofuranone based black pigment present in the pixel separation layer etc. which is described above. It is preferable that the perylene based black pigment is the perylene based black pigment present in the pixel separation layer etc. which is described above. It is preferable that the azo based black pigment is the azo based black pigment present in the aforementioned pixel separation layer etc. which is described above.

### <Thermal Color Developer and Oxidative Color Developer>

From the perspective of improving the reliability of the light emitting element, the composition according to the present invention preferably contains the colorant (D) and further contains a thermal color developer and/or an oxidative color developer. A thermal color developer is a compound that colors a material by absorbing light in a visible light wavelength range (380-780 nm) when heated in an inert atmosphere. The thermal color developer is preferably a compound having a structure that undergoes structural change or decomposition when heated in an inert atmosphere, and more preferably a compound containing at least two phenolic hydroxyl groups and having an aromatic structure. The compound containing at least two phenolic hydroxyl groups and having an aromatic structure is preferably one that undergoes structural change or decomposition into a compound having a quinone structure and/or a quinoid structure and more preferably undergoes structural change or decomposition into a compound (Q1) and/or a compound (Q2) as described above, when heated in an inert atmosphere.

The oxidative color developer is a compound that colors a material by absorbing light in a visible light wavelength range (380-780 nm) when heated in a gas atmosphere containing oxygen. The oxidative color developer is preferably a compound having a structure that undergoes structural change or decomposition when heated in a gas atmosphere containing oxygen, and more preferably a compound containing at least two phenolic hydroxyl groups and having an aromatic structure. The compound containing at least two phenolic hydroxyl groups and having an aromatic structure is preferably one that undergoes structural change or decomposition into a compound having a quinone structure and/or a quinoid structure and more preferably undergoes structural change or decomposition into a compound (Q1) and/or a compound (Q2) as described above, when heated in a gas atmosphere containing oxygen.

The thermal color developer and the oxidative color developer are each preferably a compound having a bis(4-hydroxyphenyl) methane structure and/or a tris(4-hydroxyphenyl) methane structure and more preferably a compound having a tris(4-hydroxyphenyl) methane structure.

From the perspective of improving the light blocking efficiency and improving the reliability of the light emitting element, the thermal color developer and oxidative color developer each preferably accounts for 5 mass % or more, more preferably 10 mass % or more, still more preferably 15 mass % or more, and particularly preferably 20 mass % or more, of the total solid content, excluding the solvent, of the composition according to the present invention. On the other hand, from the perspective of improving the sensitivity during light exposure and improving the reliability of the light emitting element, the contents of the thermal color developer and oxidative color developer are preferably 50 mass % or less, and more preferably 40 mass % or less.

### <Cover Layer (DC)>

From the perspective of improving the reliability of the light emitting element, it is preferable that the organic black pigment present in the composition according to the present invention preferably further has a cover layer (DC). The cover layer (DC) is, for example, a layer covering the pigment surface that is formed by surface treatment with a silane coupling agent, surface treatment with a silicate, surface treatment with a metal alkoxide, or surface treatment with a resin. If a cover layer (DC) is present, it serves to improve the acid resistance, alkali resistance, solvent resistance, dispersion stability, or heat resistance of the organic black pigment. In particular, if the benzofuranone based black pigment further has a cover layer (DC), it serves to significantly enhance the effect of reducing the residue remaining after development that is attributed to the pigment, realizing lower voltage driving of the light emission characteristics, improved light emission luminance, and improved reliability of the light emitting element. The average covering rate of the cover layer (DC) on an organic black pigment is preferably 50 to 100%, more preferably 70 to 100%, and still more preferably 90 to 100%. The average covering rate of the cover layer (DC) on an organic black pigment can be determined by the method described in paragraph of International Publication No. 2019/087985.

### <Cover Layer (DC); Silica Cover Layer, Metal Oxide Cover Layer, and Metal Hydroxide Cover Layer>

From the perspective of realizing lower voltage driving of the light emission characteristics, improved light emission luminance, and improved reliability of the light emitting element, the cover layer (DC) preferably contains one or more selected from the group consisting of a silica cover layer, metal oxide cover layer, and metal hydroxide cover layer, and more preferably contains a silica cover layer. The silica component in the silica cover layer may be, for example, a silicon dioxide (SiO₂) or a hydrate thereof. The metal oxide in the metal oxide cover layer may be, for example, a hydrate of a metal oxide rather than the pure metal oxide. Examples of metal oxide include alumina (Al₂O₃) and alumina hydrate (Al₂O₃·nH₂O). Examples of metal hydroxide present in metal hydroxide cover layers include aluminum hydroxide (Al(OH)₃).

From the perspective of reducing the residue remaining after development and improving the reliability of the light emitting element, it is preferable that the silica cover layer accounts for 1 part by mass or more, more preferably 5 parts by mass or more, relative to the organic black pigment, which accounts for 100 parts by mass. On the other hand, from the perspective of reducing the residue remaining after development, it is preferable that the silica cover layer accounts for 20 parts by mass or less, more preferably 10 parts by mass or less. In addition, from the perspective of reducing the residue remaining after development and improving the reliability of the light emitting element, the total content of the metal oxide cover layer and the metal hydroxide cover layer is preferably 0.1 part by more or more, more preferably 0.5 part by mass or more, relative to the organic black pigment, which accounts for 100 parts by mass. On the other hand, from the perspective of reducing the residue remaining after development, the total content of the metal oxide cover layer and the metal hydroxide cover layer is preferably 20 parts by mass or less, more preferably 10 parts by mass or less.

### <Dispersant (E)>

It is preferable that the composition according to the present invention further includes a dispersant (E). The dispersant (E) is a compound that has a surface affinity structure that interacts with the surface of the aforementioned pigment etc. and a dispersion stabilization structure that works to improve the dispersion stability. Examples of the dispersion stabilization structure include ionic substituents and polar substituents that stabilize dispersion by electrostatic repulsion, and polymer chains that stabilize dispersion by steric hindrance. The inclusion of the dispersant (E) serves to significantly enhance the effect of realizing lower voltage driving of the light emission characteristics and improved light emission luminance.

The surface affinity structure present in the dispersant (E) preferably contains at least one selected from the group consisting of basic groups, acidic groups, salt structures of basic groups, and salt structures of acidic groups, and more preferably contains a basic group and/or a salt structure of a basic group. The dispersant (E) preferably contains a dispersant having a basic group, a dispersant having a basic group and an acidic group, or a dispersant having a salt structure of a basic group, and more preferably contains a dispersant having a basic group or a dispersant having a basic group and an acidic group. Here, it may contain a dispersant having an acidic group, a dispersant having a salt structure of an acidic group, or a dispersant containing neither a basic group nor an acidic group.

Examples of preferable basic groups present in the dispersant (E) include tertiary amino groups and nitrogen-containing ring structures such as pyrrolidine structure, pyrrole structure, imidazole structure, and piperidine structure. Examples of preferable acidic groups present in the dispersant (E) include the carboxyl group, sulfonic acid group, phosphoric acid group, and phenolic hydroxyl group. Examples of preferable salt structure of a basic group present in the dispersant (E) include a quaternary ammonium salt structure and a salt structure of a nitrogen-containing ring structure as described above. Examples of preferable counteranions for the salt structure of a basic group include carboxylate anions, sulfonate anions, phenoxy anions, sulfate anions, nitrate anions, phosphate anions, and halogen anions, of which carboxylate anions are more preferable. Preferable examples of a dispersant (E) having a polymer chain include fluororesin based dispersants, silicone based dispersants, acrylic resin based dispersants, polyoxyalkylene ether based dispersants, polyester based dispersants, polyurethane based dispersants, polyol based dispersants, polyalkylene amine based dispersants, polyethylene-imine based dispersants, and polyallylamine based dispersants.

From the perspective of reducing the residue remaining after development, the dispersant (E) preferably has an amine value of 5 mg KOH/g or more, more preferably 10 mg KOH/g or more. On the other hand, from the perspective of reducing the residue remaining after development, its amine value is preferably 100 mg KOH/g or less, more preferably 70 mg KOH/g or less. The amine value referred to herein is defined as the mass of potassium hydroxide equivalent to the mass of an acid that reacts with 1 g of the dispersant (E) or 1 g the compound (E1) and it is expressed in mg KOH/g.

From the perspective of reducing the residue remaining after development, the acid value of the dispersant (E) is preferably 10 mg KOH/g or more, more preferably 20 mg KOH/g or more. On the other hand, from the perspective of reducing the residue remaining after development, its acid value is preferably 100 mg KOH/g or less, more preferably 70 mg KOH/g or less. The acid value referred to herein is defined as the mass of potassium hydroxide that reacts with 1 g of the dispersant (E) or 1 g of the compound (E1) and it is expressed in mg KOH/g.

In the case where the composition according to the present invention includes a pigment, it is preferable, from the perspective of reducing the residue remaining after development, that the content of the dispersant (E) is 5 parts by weight or more, more preferably 15 parts by weight or more, relative to 100 parts by weight of the pigment. On the other hand, it is preferable, from the perspective of reducing the residue remaining after development, that the dispersant (E) accounts for 50 parts by mass or less, more preferably 40 parts by mass or less.

### <Dispersant (E); Dispersant Having Basic Group (E1)>

From the perspective of realizing lower voltage driving of the light emission characteristics, improved light emission luminance, and improved reliability of the light emitting element, it is preferable, for the composition according to the present invention, that the colorant (D) contains a black pigment and/or a mixture of two or more color pigments of different colors and further contains a dispersant (E), wherein the dispersant (E) contains a dispersant (E1) having a basic group and wherein the dispersant (E1) having the basic group has a structure as represented by the general formula (26) and/or a structure as represented by the general formula (29), as well as a polyoxyalkylene structure.

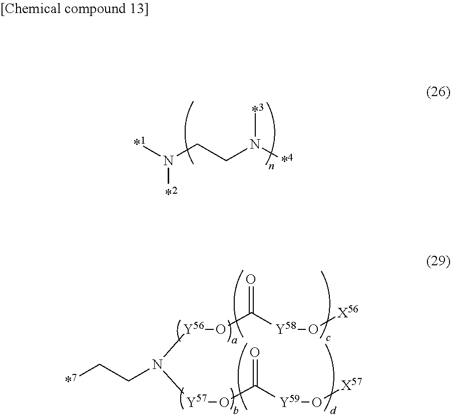

In the formula (26), n is an integer of 1 to 9, and *¹ to *⁴ are each independently a bonding point to a polyoxyalkylene structure. In the general formula (29), X⁵⁶ and X⁵⁷ are each independently a hydrogen atom or an alkyl group having 1 to 6 carbon atoms. Y⁵⁶ to Y⁵⁹ are each independently an alkylene group having 1 to 6 carbon atoms. Here, a and b are each independently an integer of 1 to 100; c and d are each independently an integer of 0 to 100; and *⁷ is a bonding point to a carbon atom or a nitrogen atom.

It is inferred that if a pigment and a dispersant of a specific structure are included in the photosensitive composition, it will act to prevent excessive interactions from occurring between the pigment and the surface of the first electrode that faces the light emitting layer, thereby serving for suppression of residue formation attributed to the pigment. It is also inferred that the dispersant of a specific structure acts to enhance the surface modification action on the surface of the first electrode that faces the light emitting layer and corresponds to the opening part in the pixel separation layer part or the opening part in the pixel size control layer part. Accordingly, this is considered to promote lower voltage driving of the light emission characteristics. It is inferred that as a result, this ensures that a highly enhanced light emission luminance is achieved at the same driving voltage. In addition, as the dispersity of the pigment is increased, the pigment becomes finer and increases in light blocking efficiency, and it serves to suppress the outgassing from the pixel separation layer etc. and reduce the degradation of the light emitting element, thereby significantly enhancing the effect of improving the reliability of the light emitting element. For the composition according to the present invention, the preferable content of the dispersant (E1) having a basic group is as described above in relation to the preferable content of the dispersant (E).

<Compound (F); compound (F0) and compound (FB)>

It is preferable that the composition according to the present invention further includes a compound (F0) and/or a compound (FB) as specified below.
Compound (F0): a compound having an acidic group containing a phosphorus atom and/or a compound having a salt of an acidic group containing a phosphorus atom
Compound (FB): a compound having a betaine structure containing a phosphorus atom

If a compound (F0) and/or a compound (FB) are included, it serves to significantly enhance the effect of realizing lower voltage driving of the light emission characteristics and improved light emission luminance. Hereinafter, the compound (F0) and the compound (FB) will be occasionally referred to collectively as compound (F).

The compound (F0) preferably has a structure (I-f0) as specified below.

Structure (I-f0): a structure containing one or more selected from the group consisting of a monovalent or divalent aliphatic group having 4 to 30 carbon atoms, alkylaryl group having 10 to 30 carbon atoms, and oxyalkylene group bonded to an aryl group having 6 to 15 carbon atoms

The compound (FB) preferably has a structure (I-fb) as specified below.

Structure (I-fb): a structure containing a monovalent or divalent aliphatic group having 1 to 6 carbon atoms and having an ammonium ion structure

It is preferable that the composition according to the present invention includes the compound (F0) and/or the compound (FB), wherein the compound (F0) contains a compound (F1) as specified below while the compound (FB) contains a compound (FB1) as specified below. Compound (F1): one or more compounds selected from the group consisting of phosphoric acid compounds, phosphonic acid compounds, phosphinic acid compounds, and salts thereof.

Compound (FB1): one or more compounds selected from the group consisting of bataine phosphate compounds, betaine phosphonate compounds, and betaine phosphinate compounds

The composition according to the present invention preferably includes the compound (F1) and/or the compound (FB1). It is also preferable that two or more compounds (F1) or two or more compounds (FB1) are included. If the compound (F1) and/or the compound (FB1) are included, it serves to significantly enhance the effect of realizing lower voltage driving of the light emission characteristics, improved light emission luminance, and improved reliability of the light emitting element. It is inferred that if a compound having a phosphoric acid based structure is present in the pixel separation layer, it serves to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. It is also considered that while the surface of the first electrode undergoes surface modification with the phosphorus element, a dense film is formed due to self-assembly of substituent groups on phosphorus atoms. Accordingly, it is inferred that the heat resistance and oxidation resistance of the first electrode are increased, thereby significantly enhancing the effect of improving the reliability of the light emitting element.

It is preferable that the compound (F1) has a structure (I-f1) and/or a structure (II-f1) as specified below.

Structure (I-f1): a structure containing one or more groups selected from the group consisting of monovalent aliphatic groups having 4 to 30 carbon atoms, divalent aliphatic groups having 6 to 30 carbon atoms, and alkylaryl groups having 10 to 30 carbon atoms

Structure (II-f1): a structure containing one or more groups selected from the group consisting of oxyalkylene group bonded to a monovalent aliphatic group having 4 to 30 carbon atoms, oxyalkylene group bonded to an alkylaryl group having 10 to 30 carbon atoms, and oxyalkylene group bonded to an aryl group having 6 to 15 carbon atoms

The compound (F1) preferably has a substituent bonded to a phosphorus atom and/or a substituent bonded to an oxygen atom in a P—O bond, wherein the substituents have the structure (I-f1) and/or the structure (II-f1). The structure (I-f1) is preferably a structure (I-f1x) as described below.

Structure (I-f1x): a structure containing one or more groups selected from the group consisting of monovalent aliphatic groups having 6 to 12 carbon atoms, divalent aliphatic groups having 6 to 12 carbon atoms, and alkylaryl groups having 14 to 26 carbon atoms

The monovalent aliphatic groups are preferably alkyl groups, alkenyl groups, or alkynyl groups, of which alkyl groups are more preferable. The divalent aliphatic groups are preferably alkylene groups, alkenylene groups, or alkynylene groups, of which alkylene groups are more preferable. Furthermore, the structure (I-f1) is preferably a straight-chain structure or a branched structure, of which a straight-chain structure is more preferable. The structure (II-f1) is preferably a structure (II-f1x) as described below.

Structure (II-f1x): a structure containing one or more groups selected from the group consisting of oxyalkylene group bonded to a monovalent aliphatic group having 6 to 12 carbon atoms, oxyalkylene group bonded to an alkylaryl group having 14 to 26 carbon atoms, and oxyalkylene group bonded to an aryl group having 6 to 10 carbon atoms

The monovalent aliphatic groups are preferably alkyl groups, alkenyl groups, or alkynyl groups, of which alkyl groups are more preferable. Furthermore, the structure (II-f1) is preferably a straight-chain structure or a branched structure, of which a straight-chain structure is more preferable.

It is preferable that the compound (FB1) has a structure (I-fb1) as specified below.

Structure (I-fb1): a structure containing a monovalent or divalent aliphatic group having 1 to 6 carbon atoms and having an ammonium ion structure

It is preferable that the compound (FB1) has a substituent bonded to a phosphorus atom and/or a substituent bonded to an oxygen atom in a P—O bond, wherein the substituents have the structure (I-fb1).

In the structure (I-fb1), the monovalent or divalent aliphatic group having 1 to 6 carbon atoms is preferably a divalent aliphatic group having 1 to 4 carbon atoms. The monovalent aliphatic group is preferably an alkyl group, alkenyl group, or alkynyl group, of which an alkyl group is more preferable. The divalent aliphatic group is preferably an alkylene group, alkenylene group, or alkynylene group, of which an alkylene group is more preferable. Furthermore, the monovalent or divalent aliphatic group having 1 to 6 carbon atoms preferably has a straight-chain structure or a branched structure, of which a straight-chain structure is more preferable. The monovalent or divalent aliphatic groups having 1 to 6 carbon atoms may have, as substituents, alkyl groups having 1 to 6 carbon atoms, alkoxy groups having 1 to 6 carbon atoms, carboxyl groups, hydroxyl groups, or amino groups.

In the structure (I-fb1), the ammonium ion structure is preferably an ammonium ion structure, primary ammonium ion structure, secondary ammonium ion structure, tertiary ammonium ion structure, or quaternary ammonium ion structure, of which a quaternary ammonium ion structures is more preferable. The quaternary ammonium ion structure preferably has 4 alkyl groups having 1 to 6 carbon atoms and more preferably has 4 alkyl groups having 1 to 4 carbon atoms. The 4 alkyl groups are each independently an alkyl group having 1 to 6 carbon atoms, wherein their numbers of carbon atoms may be identical to or different from each other.

It is also preferable that the compound (FB1) has a structure (II-fb1) as specified below. Structure (II-fb1): a fatty acid ester structure derived from a fatty acid compound having 6 to 30 carbon atoms and/or an aliphatic ether structure derived from an aliphatic alcohol having 6 to 30 carbon atoms

The compound (FB1) preferably has two or more substituents bonded to phosphorus atoms and/or two or more substituents bonded to oxygen atoms in P—O bonds, wherein the substituents have the structure (I-fb1) and the structure (II-fb1).

The structure (II-fb1) preferably has a monovalent or divalent aliphatic group having 6 to 30 carbon atoms and more preferably has a monovalent or divalent aliphatic group having 10 to 20 carbon atoms. The monovalent aliphatic group is preferably an alkyl group, alkenyl group, or alkynyl group, of which an alkyl group is more preferable. The divalent aliphatic group is preferably an alkylene group, alkenylene group, or alkynylene group, of which an alkylene group is more preferable. Furthermore, the monovalent or divalent aliphatic group having 6 to 30 carbon atoms preferably has a straight-chain structure or a branched structure, of which a straight-chain structure is more preferable.

For the compound (F0), the compound having a salt of an acidic group containing a phosphorus atom means a salt of an acidic group containing a phosphorus atom or a compound having, as a partial structure, a salt structure of an acidic group containing a phosphorus atom. For the compound (F0), the salt of an acidic group containing a phosphorus atom is, for example, a salt formed from an acidic group containing a phosphorus atom and a compound having a cationic structure. Examples include ammonium salts or tetraalkylammonium salts of acidic groups containing phosphorus atoms having the structure (I-f0) described above. For the compound (F0), examples of the compound having, as a partial structure, a salt structure of an acidic group containing a phosphorus atom include a compound having, as a partial structure, a salt structure formed from an acidic group containing a phosphorus atom and a compound having a cationic structure. Examples include compounds having, as partial structures, ammonium salt structures or tetraalkylammonium salt structures of acidic groups containing phosphorus atoms having the structure (I-f0) described above. Other examples include resins having, in the main chain, side chain, or chain end, ammonium salt structures or tetraalkylammonium salt structures of acidic groups containing phosphorus atoms having the structure (I-f0) described above. Similarly, examples of the salts of phosphoric acid compounds, salts of phosphonic acid compounds, or salts of phosphinic acid compounds in the compound (F1) include salts of phosphoric acid compounds, phosphonic acid compounds, or phosphinic acid compounds with compounds having cationic structures.

From the perspective of reducing the residue remaining after development and improving the reliability of the light emitting element, the total content of the compound (F1) and the compound (FB1) is preferably 0.02 mass % or more, more preferably 0.05 mass % or more, still more preferably 0.15 mass % or more, and particularly preferably 0.25 mass % or more, of the total solid content, excluding the solvent, of the composition according to the present invention. On the other hand, from the perspective of reducing the residue remaining after development and improving the reliability of the light emitting element, the total content of the compound (F1) and the compound (FB1) is preferably 1.8 mass % or less, still more preferably 1.5 mass % or less, still more preferably 1.3 mass % or less, and particularly preferably 1.0 mass % or less. Furthermore, in the case where the composition according to the present invention includes the alkali soluble resin (A) and the compound (B), it is preferable that the total content of the compound (F1) and compound (FB1) present in the composition according to the present invention preferably accounts for 0.05 part by mass or more, more preferably 0.10 parts by mass or more, still more preferably 0.30 part by mass or more, and particularly preferably 0.50 parts by mass or more, relative to the total mass, which accounts for 100 parts by mass, of the alkali soluble resin (A) and the compound (B). On the other hand, the total content of the compound (F1) and compound (FB1) is preferably 3.0 parts by mass or less, more preferably 2.5 parts by mass or less, still more preferably 2.0 parts by mass or less, and particularly preferably 1.5 parts by mass or less.

### <Crosslinking Agent (G)>

The composition according to the present invention preferably further includes a crosslinking agent (G). The crosslinking agent (G) is a compound that has a crosslinkable group that can be bonded to resins etc. or a compound that has a cationic polymerizable group. The inclusion of the crosslinking agent (G) allows the photosensitive composition to form a cured film having improved heat resistance due to the introduction of crosslinked structures by the crosslinking agent (G) and serves to suppress the outgassing from the pixel separation layer etc. As a result, the degradation of the light emitting element is suppressed, accordingly significantly enhancing the effect of improving the reliability of the light emitting element.

The crosslinking agent (G) is preferably a compound having one or more groups selected from the group consisting of alkoxyalkyl groups, hydroxyalkyl groups, epoxy groups, oxetanyl groups, and blocked isocyanate groups (hereinafter referred to as “specific crosslinkable groups”), and more preferably a compound having at least two groups selected from the group consisting of the specific crosslinkable groups. The alkoxyalkyl groups are preferably alkoxymethyl groups, and more preferably methoxymethyl groups. The hydroxyalkyl groups are preferably methylol groups.

From the perspective of realizing lower voltage driving of the light emission characteristics, improved light emission luminance, and improved reliability of the light emitting element, it is preferable that the crosslinking agent (G) contains one or more selected from the group consisting of the compound (G1), the compound (G2), and the compound (G3), which will be described later. The compound (G) preferably contains the compound (G1) and more preferably further contains the compound (G2) and/or the compound (G3). It is inferred that the compound (G1), the compound (G2), and the compound (G3) can act to reduce the residue remaining after development and/or reducing the residue remaining after thermal curing in the pixel separation layer part or the opening part in the pixel size control layer part. Accordingly, this is considered to promote lower voltage driving of the light emission characteristics. It is inferred that as a result, this ensures that a highly enhanced light emission luminance is achieved at the same driving voltage.

### <Crosslinking Agent (G); Compound (G1), Compound (G2), and Compound (G3)>

It is preferable that the crosslinking agent (G) contains a compound (G1) as described below. The compound (G1) is a compound having a structure (I-g1) and a structure (II-g1) as specified below, preferably having at least two structures (II-g1).

Compound (G1): a hydrophobic skeleton-containing epoxy crosslinking agent

Structure (I-g1): a structure containing one or more selected from the group consisting of a condensed polycyclic structure, a condensed polycyclic heterocyclic structure, a structure having a directly bonded aromatic ring skeleton and alicyclic skeleton, or a structure having at least two directly bonded aromatic ring skeletons

Structure (II-g1): a structure containing an organic group having an epoxy group

It is preferable that the compound (G1) has a structure containing one or more types of structures selected from the group consisting of fluorene structure, indane structure, indolinone structure, isoindolinone structure, xanthene structure, tricyclo[5.2.1.0^{2,6}]decane structure, and binaphthyl structure.

From the perspective of reducing the residue remaining after development, the compound (G1) preferably has an epoxy group equivalent weight of 150 g/mol or more, more preferably 170 g/mol or more, and still more preferably 190 g/mol or more. On the other hand, from the perspective of preventing narrow mask bias after development and improving the halftone characteristics, its epoxy group equivalent weight is preferably 800 g/mol or less, more preferably 600 g/mol or less, and still more preferably 500 g/mol or less.

It is also preferable that the crosslinking agent (G) contains the compound (G2) as described below.

Compound (G2): a compound having at least two phenolic hydroxyl groups and at least two crosslinkable groups

It is preferable that the compound (G2) has at least two structures (I-g2) as described below. Furthermore, the compound (G2) more preferably has at least two structures (I-g2x) as described below.

Structure (I-g2): a structure in which a phenolic hydroxyl group and a crosslinkable group are bonded to an aromatic structure

Structure (I-g2x): a structure in which a phenolic hydroxyl group and at least two crosslinkable groups are bonded to an aromatic structure

It is preferable that the crosslinking agent (G) contains a compound (G3) as described below.

Compound (G3): a compound that has a structure containing a cyclic structure having at least two nitrogen atoms and has at least two crosslinkable groups

The compound (G3) preferably has one or more types of structures selected from the group consisting of isocyanurate structure, triazine structure, glycoluril structure, imidazolidinone structure, pyrazole structure, imidazole structure, triazole structure, tetrazole structure, and purine structure, and more preferably has an isocyanurate structure and/or a triazine structure.

From the perspective of preventing narrow mask bias after development and improving the halftone characteristics, the compound (G1) preferably accounts for 0.3 mass % or more, more preferably 1.0 mass % or more, and still more preferably 2.0 mass % or more, of the total solid content, excluding the solvent, of the composition according to the present invention. On the other hand, from the perspective of reducing the residue remaining after development, the compound (G1) preferably accounts for 25 mass % or less, more preferably 20 mass % or less, and still more preferably 15 mass % or less. Furthermore, in the case where the composition according to the present invention includes the alkali soluble resin (A) and the compound (B), it is preferable that the compound (G1) present in the composition according to the present invention preferably accounts for 1 part by mass or more, more preferably 3 parts by mass or more, and still more preferably 5 parts by mass or more, relative to the total mass, which accounts for 100 parts by mass, of the alkali soluble resin (A) and the compound (B). On the other hand, the content of the compound (G1) is preferably 30 parts by mass or less, more preferably 25 parts by mass or less, and still more preferably 20 parts by mass or less.

From the perspective of reducing the residue remaining after development, preventing narrow mask bias after development, and improving the halftone characteristics, the total content of the compound (G2) and compound (G3) is preferably 0.3 mass % or more, more preferably 1.0 mass % or more, and still more preferably 2.0 mass % or more, of the total solid content, excluding the solvent, of the composition according to the present invention. On the other hand, from the perspective of reducing the residue remaining after development and improving the sensitivity during light exposure, the total content of the compound (G2) and the compound (G3) is preferably 25 mass % or less, more preferably 20 mass % or less, and still more preferably 15 mass % or less. Furthermore, in the case where the composition according to the present invention includes the alkali soluble resin (A) and the compound (B), it is preferable that the total content of the compound (G2) and the compound (G3) present in the composition according to the present invention accounts for 1 part by mass or more, more preferably 3 parts by mass or more, and still more preferably 5 parts by mass or more, relative to the total mass, which accounts for 100 parts by mass, of the alkali soluble resin

(A) and the compound (B). On the other hand, the total content of the compound (G2) and the compound (G3) is preferably 30 parts by mass or less, more preferably 25 parts by mass or less, and still more preferably 20 parts by mass or less.

### <Inorganic Particles (H)>

It is preferable that the composition according to the present invention further includes inorganic particles (H). The inorganic particles (H) are particles containing, as the main component, an element selected from the group consisting of metal elements, metalloid elements, and semiconductor elements. The main component of the inorganic particles (H) refers to the component that accounts for the largest proportion in mass among the constituent elements of the inorganic particles (H). For example, the inorganic particles (H) are those in which the mass of compounds selected from the group consisting of metal compounds, metalloid compounds, and semiconductor compounds accounts for 90 mass % or more of the total mass excluding water. Examples of the metal compounds, metalloid compounds, and semiconductor compounds include halides, oxides, nitrides, hydroxides, carbonates, sulfates, nitrates, and metasilicates of the elements specified above.

The inclusion of the inorganic particles (H) allows the photosensitive composition to form a cured film to have significantly improved heat resistance due to the introduction of robust structures of the inorganic particles (H) and accordingly serves to suppress the outgassing from the pixel separation layer etc. As a result, the degradation of the light emitting element is suppressed, accordingly significantly enhancing the effect of improving the reliability of the light emitting element.

The inorganic particles (H) are preferably the inorganic particles present in the pixel separation layer etc. which is described above.

For the composition according to the present invention, it is preferable that the inorganic particles (H) contain, as the main constituent element, Si, Al, Ti, V, Zn, Zr, Nb, Sn, Li, Cr, Mn, Fe, Co, Ni, Cu, Sr, Ag, Ba, La, Ce, Ta, W, or Re, more preferably contain, as the main constituent element, silicon, aluminum, titanium, vanadium, chromium, iron, cobalt, copper, zinc, zirconium, niobium, tin, or cerium, and still more preferably contain silicon as the main constituent element. Here, to determine whether the inorganic particles (H) contain Si, Al, Ti, V, Zn, Zr, Nb, Sn, Li, Cr, Mn, Fe, Co, Ni, Cu, Sr, Ag, Ba, La, Ce, Ta, W, or Re as the main constituent element, the determination should be based on the mass of any one of these elements. If any of these elements is included as the main constituent element, the outgassing from the pixel separation layer etc. is suppressed, accordingly significantly enhancing the effect of improving the reliability of the light emitting element. The inorganic particles (H) are preferably silica particles, alumina particles, titania particles, vanadium oxide particles, chromium oxide particles, iron oxide particles, cobalt oxide particles, zinc oxide particles, zirconium oxide particles, niobium oxide particles, tin oxide particles, or cerium oxide particles, of which silica particles are more preferable.

The inorganic particles (H) preferably contain one or more elements selected from the group consisting of Si, Al, Ti, V, Zn, Zr, Nb, Sn, Li, Na, Mg, K, Ca, Cr, Mn, Fe, Co, Ni, Cu, Sr, Y, Ag, Ba, La, Ce, Hf, Ta, W, and Re, more preferably contain one or more elements selected from the group consisting of silicon, aluminum, titanium, vanadium, chromium, iron, cobalt, copper, zinc, zirconium, niobium, tin, cerium, sodium, magnesium, potassium, calcium, and hafnium, and still more preferably contain the silicon element. Such elements may be the same as the main constituent element of the inorganic particles (H). It is also preferable that the inorganic particles (H) contain these elements as elements other than the main constituent element.

In the case where the composition according to the present invention includes the inorganic particles (H) wherein the inorganic particles (H) contain, as the main constituent element, Si, Al, Ti, V, Zn, Zr, Nb, Sn, Li, Cr, Mn, Fe, Co, Ni, Cu, Sr, Ag, Ba, La, Ce, Ta, W, or Re, it is preferable, for the composition according to the present invention, that the inorganic particles (H) have a radical polymerizable group and/or a thermal reactive group on the surface thereof.

If they are configured in this way, it significantly enhances the effect of realizing suppressed external light reflection, lower voltage driving of the light emission characteristics, improved light emission luminance, and improved reliability of the light emitting element. If the inorganic particles (H) included have a radical polymerizable group and/or a thermal reactive group on the surface thereof, it serves for the introduction of a crosslinked structure formed through radical polymerization of a radical polymerizable group such as (meth)acryloyl group and as a result, it allows the photosensitive composition to form a cured film having a higher heat resistance due to an increased crosslink density. It is inferred that as a result, the outgassing from the pixel separation layer etc. is suppressed, accordingly significantly enhancing the effect of improving the reliability of the light emitting element.

The radical polymerizable group is preferably an ethylenically unsaturated double bond group. The radical polymerizable group is more preferably one or more selected from the group consisting of photoreactive groups, alkenyl groups having 2 to 5 carbon atoms, and alkynyl groups having 2 to 5 carbon atoms. Preferable examples of such photoreactive groups include the styryl group, cinnamoyl group, maleimide group, nadimide group, and (meth)acryloyl group, of which (meth)acryloyl group is more preferable. On the other hand, preferable examples of the alkenyl groups having 2 to 5 carbon atoms and alkynyl groups having 2 to 5 carbon atoms include the vinyl group, allyl group, 2-methyl-2-propenyl group, crotonyl group, 2-methyl-2-butenyl group, 3-methyl-2-butenyl group, 2,3-dimethyl-2-butenyl group, ethynyl group, and 2-propargyl group, of which vinyl group and allyl group are more preferable. Preferable examples of the thermal reactive groups include alkoxymethyl group, methylol group, epoxy group, oxetanyl group, and blocked isocyanate group.

It is also preferable that the inorganic particles (H) have, on the surface thereof, one or more types of groups selected from the group consisting of silanol groups, alkoxysilyl groups, alkylsilyl groups, dialkylsilyl groups, trialkylsilyl groups, phenylsilyl groups, and diphenylsilyl groups. It is also preferable that the inorganic particles (H) have a radical polymerizable group and/or a thermal reactive group on the surface thereof, and further have a functional group derived therefrom.

The inorganic particles (H) having a functional group on the surface thereof can be produced by introducing a surface-modifying group derived from an organosilane compound containing a functional group through a dehydration condensation reaction with hydroxyl groups and/or silanol groups present on the surface of the inorganic particles (H).

Furthermore, the inorganic particles (H) having a functional group on the surface thereof can also be produced by introducing a surface-modifying group derived from an isocyanate compound containing a functional group through a urethanation reaction with hydroxyl groups and/or silanol groups present on the surface of the inorganic particles (H). If the surface of the inorganic particles (H) is modified with a surface-modifying group derived from an organosilane compound containing a functional group and with a surface-modifying group derived from an isocyanate compound containing a functional group in this order, it allows the inorganic particles (H) to be modified with surface-modifying groups containing the two functional groups.

From the perspective of improving the reliability of the light emitting element, the inorganic particles (H) preferably account for 5 mass % or more, more preferably 10 mass % or more, still more preferably 15 mass % or more, and particularly preferably 20 mass % or more, of the total solid content, excluding the solvent, of the composition according to the present invention. On the other hand, from the perspective of improving the sensitivity during light exposure and improving the reliability of the light emitting element, the content of the inorganic particles (H) is preferably 50 mass % or less, and more preferably 40 mass % or less.

<Inorganic particles (H); silica particles (H1)>

In the case where the composition according to the present invention includes the inorganic particles (H) wherein the inorganic particles (H) contain, as the main constituent element, Si, Al, Ti, V, Zn, Zr, Nb, Sn, Li, Cr, Mn, Fe, Co, Ni, Cu, Sr, Ag, Ba, La, Ce, Ta, W, or Re, it is preferable, for the composition according to the present invention, that the inorganic particles (H) include silica particles (H1). Here, the silica particles (H1) are a kind of the inorganic particles (H) and are inorganic particles containing silicon as the main constituent element.

If they are configured in this way, it significantly enhances the effect of realizing lower voltage driving of the light emission characteristics, improved light emission luminance, and improved reliability of the light emitting element. The inclusion of the silica particles (H1) allows the photosensitive composition to form a cured film having significantly improved heat resistance due to the introduction of robust structures of the silica particles (H1) and accordingly serves to suppress the outgassing from the pixel separation layer etc. As a result, the degradation of the light emitting element is suppressed, accordingly significantly enhancing the effect of improving the reliability of the light emitting element. It is inferred that this also acts to enhance the surface modification action on the surface of the first electrode that faces the light emitting layer and corresponds to the opening part in the pixel separation layer part or the opening part in the pixel size control layer part. Accordingly, this is considered to serve for promoting lower voltage driving of the light emission characteristics through the adjustment of the difference in the work function. It is inferred that as a result, this ensures that a highly enhanced light emission luminance is achieved at the same driving voltage. Furthermore, they work to reduce the reflection and scattering of the incident light on the surface of the cured film and accordingly significantly enhance the effect of suppressing external light reflection.

The silica particles (H1) are defined as inorganic particles containing the silicon element as the main constituent element. Examples of the silica particles (H1) include particles having a pure silicon dioxide content of 90 mass % or more relative to the total mass excluding water, particles of silicon dioxide (anhydrous silica), particles of silicon dioxide hydrates (hydrated silica or white carbon), particles of quartz glass, and particles containing orthosilicic acid, metasilicic acid, and metadisilicic acid. The silica particles (H1) are preferably in the form of a silica particle dispersion in an organic solvent and/or water as dispersion media. The silica particles (H1) are preferably the silica particles present in the pixel separation layer etc. which are described above.

The silica particles (H1) preferably have primary particle diameters and an average primary particle diameter of 5 to 50 nm. From the perspective of improving the reliability of the light emitting element, the primary particle diameters and the average primary particle diameter of the silica particles (H1) are preferably 5 nm or more, more preferably 7 nm or more, and still more preferably 10 nm or more. On the other hand, from the perspective of suppressing the external light reflection and improving the reliability of the light emitting element, the primary particle diameters and the average primary particle diameter of the silica particles (H1) are preferably 50 nm or less, more preferably 40 nm or less, still more preferably 30 nm or less, still more preferably 25 nm or less, particularly preferably 20 nm or less, and most preferably 15 nm or less. The primary particle diameter of a silica particle is defined as the long axis diameter of a primary particle of silica. The preferable range of the average primary particle diameter of the silica particles (H1) in the silica particle dispersion is as described above in relation to the preferable ranges of the primary particle diameters and average primary particle diameter of the silica particles (H1) which are described above. It should be noted that silicon dioxide contained in surface treatment agents or cover layers present in an organic pigment or inorganic pigment is not regarded as silica particles regardless of their primary particle diameter and aspect ratio.

The primary particle diameters and the aspect ratios of the silica particles (H1) can be measured by slicing a cured film to prepare a thin specimen for measurement, polishing it by ion milling treatment to create a cross section with enhanced smoothness, observing and photographing positions in the depth range of 0.2 to 0.8 μm from the surface of the cured film using a TEM at a magnification of 50,000 times, and analyzing the image with image analysis software for particle size distribution (Mac-View, manufactured by MOUNTECH Co., Ltd.). Then, the average primary particle diameter of the silica particles (H1) can be determined by photographing and analyzing the cross section of a specimen for measurement, and calculating the average of measured diameters of 30 primary particles of the silica particles (H1). In addition, the elements constituting the particles can be analyzed based on observations made by TEM-EDX, making it possible to identify the silica particles in the cured film. Here, the average primary particle diameter of the silica particles (H1) in a silica particle dispersion can be determined based on particle diameter distribution measurement performed by the dynamic light scattering method.

The composition according to the present invention may not only contain silica particles (H1) having primary particle diameters or an average primary particle diameter of 5 to 50 nm, but also contain silica particles (H1) having primary particle diameters or an average primary particle diameter of less than 5 nm and/or silica particles (H1) having primary particle diameters or an average primary particle diameter of more than 50 nm.

From the perspective of improving the reliability of the light emitting element, the silica particles (H1) preferably contain the sodium element. The sodium element may exist in the form of, for example, ion (Na+) or salt with a silanol group (Si—ONa). The content of the sodium element in the silica particles (H1) is preferably 1 mass ppm or more, more preferably 5 mass ppm or more, still more preferably 10 mass ppm or more, and particularly preferably 50 mass ppm or more. Furthermore, from the perspective of improving the reliability of the light emitting element, it is preferably 100 mass ppm or more, more preferably 300 mass ppm or more, and still more preferably 500 mass ppm or more. On the other hand, the content of the sodium element in the silica particles (H1) is preferably 10,000 mass ppm or less, more preferably 7,000 mass ppm or less, still more preferably 5,000 mass ppm or less, still more preferably 3,000 mass ppm or less, and particularly preferably 1,000 mass ppm or less. Silica particles containing the sodium element can be produced by reacting sodium silicate, which is a strong alkali, as source of silicon with a mineral acid, which is a strong acid, under alkaline conditions. The preferable content of the silica particles (H1) in the composition according to the present invention is as described above in relation to the preferable content of the inorganic particles (H).

### <Compound (I); Compound (I1a), Compound (I1b), Compound (I2a), and Compound (I2b)>

From the perspective of realizing lower voltage driving of the light emission characteristics, improved light emission luminance and improved reliability of the light emitting element, it is preferable that the composition according to the present invention further includes one or more selected from the group consisting of the compound (I1a), compound (I1b), compound (I2a), and compound (I2b), which are described below.
Compound (I1a): one or more compounds selected from the group consisting of thiol compounds, sulfide compounds, disulfide compounds, sulfoxide compounds, sulfone compounds, sultone compounds, thiophene compounds, and sulfonic acid compounds
Compound (I1b): a compound containing, as anion species, one or more selected from the group consisting of sulfide ions, hydrogen sulfide ions, sulfate ions, and hydrogen sulfate ions, and also containing, as cation species, an ammonium ion, primary ammonium ion, secondary ammonium ion, tertiary ammonium ion, or quaternary ammonium ion
Compound (I2a): one or more compounds selected from the group consisting of alkyl chloride compounds, cycloalkyl chloride compounds, aryl chloride compounds, alkyl bromide compounds, cycloalkyl bromide compounds, and aryl bromide compounds
Compound (I2b): a compound containing, as anion species, a chloride ion and/or a bromide ion and also containing, as cation species, an ammonium ion, primary ammonium ion, secondary ammonium ion, tertiary ammonium ion, or quaternary ammonium ion

Hereinafter, the compound (I1a), compound (I1b), compound (I2a), and compound (I2b) are occasionally referred to collectively as the compound (I).

It is inferred that if these compounds are included in the photosensitive composition, they act to cause surface modification of the surface of the first electrode that faces the light emitting layer, and accordingly, adjustment of the difference in the work function occurs to enhance significantly the effect of realizing lower voltage driving of the light mission characteristics and improved light emission luminance. In addition, it is considered that as the polarization structure and charge balance in the cured film are controlled, ion migration and electromigration are suppressed to significantly enhance the effect of improving the reliability of the light emitting element. Furthermore, it is inferred that the suppression of migration and aggregation of metal in the first electrode works to enhance the effect of improving the reliability of the light emitting element.

If they are configured in this way in the composition according to the present invention, it is preferable, from the perspective of realizing lower voltage driving of the light emission characteristics, improved light emission luminance, and improved reliability of the light emitting element,
that, in the case where the composition according to the present invention includes the compound (I1a), the compound (I1a) contains one or more compounds selected from the group consisting of thiol compounds, sulfide compounds, disulfide compounds, and sulfonic acid compounds,
that, in the case where the composition according to the present invention includes the compound (I1b), the compound (I1b) contains, as anion species, one or more selected from the group consisting of sulfide ions, hydrogen sulfide ions, sulfate ions, and hydrogen sulfate ion, and also contains, as cation species, a quaternary ammonium ion,
that, in the case where the composition according to the present invention includes the compound (I2a), the compound (I2a) contains one or more compounds selected from the group consisting of alkyl chloride compounds, cycloalkyl chloride compounds, alkyl bromide compounds, and cycloalkyl bromide compounds, and
that, in the case where the composition according to the present invention includes the compound (I2b), the compound (I2b) contains, as anion species, a chloride ion and/or a bromide ion, and also contains, as cation species, a quaternary ammonium ion.

It is inferred that if these compounds are included in the photosensitive composition, they act to cause surface modification of the surface of the first electrode that faces the light emitting layer as described above, thereby enhancing significantly the effect of realizing lower voltage driving of the light mission characteristics and improved light emission luminance. As described above, it is considered that the polarization structure and charge balance in the cured film are controlled, thereby significantly enhancing the effect of improving the reliability of the light emitting element. Furthermore, as described above, it is inferred that the suppression of migration and aggregation of metals in the first electrode works to enhance the effect of improving the reliability of the light emitting element.

From the perspective of realizing lower voltage driving of the light emission characteristics, improved light emission luminance, and improved reliability of the light emitting element, it is more preferable that the composition according to the present invention includes the compound (I1a) and/or the compound (I1b). It is still more preferable that the composition according to the present invention includes the compound (I1a) and/or the compound (I1b) and further includes the compound (I2a) and/or the compound (I2b). It is also more preferable that the composition according to the present invention includes the compound (I1a) and the compound (I1b). It is also more preferable that the composition according to the present invention includes the compound (I2a) and the compound (I2b). It is also preferable that it includes two or more types of each of the compound (I1a), compound (I1b), compound (I2a), and compound (I2b).

The compound (I1a) and the compound (I2a) preferably have the structure (I-Ia) specified below.

Structure (I-Ia): a structure containing one or more groups selected from the group consisting of monovalent or divalent aliphatic groups having 4 to 30 carbon atoms, alkylaryl groups having 10 to 30 carbon atoms, arylalkyl groups having 10 to 30 carbon atoms, and aryl groups having 6 to 15 carbon atoms

The compound (I1a) and the compound (I2a) preferably have the structure (II-Ia) and/or the structure (III-Ia) specified below.

Structure (II-Ia): a structure containing one or more groups selected from the group consisting of monovalent aliphatic groups having 4 to 30 carbon atoms, divalent aliphatic groups having 6 to 30 carbon atoms, alkylaryl groups having 10 to 30 carbon atoms, and alkylaryl groups having 10 to 30 carbon atoms

Structure (III-Ia): a structure containing one or more groups selected from the group consisting of oxyalkylene group bonded to a monovalent aliphatic group having 4 to 30 carbon atoms, oxyalkylene group bonded to an alkylaryl group having 10 to 30 carbon atoms, oxyalkylene group bonded to an alkylaryl group having 10 to 30 carbon atoms, and oxyalkylene group bonded to an aryl group having 6 to 15 carbon atoms

The compound (I1a) preferably has a substituent group bonded to a sulfur atom, wherein the substituent group is preferably the structure (I-Ia) and wherein the substituent group is more preferably the structure (II-Ia) and/or the structure (III-Ia).

The compound (I2a) preferably has a substituent group bonded to a chlorine atom or a bromine atom, wherein the substituent group is preferably the structure (I-Ia) and wherein the substituent group is more preferably the structure (II-Ia) and/or the structure (III-Ia).

The structure (II-Ia) is preferably the structure (II-Iax) specified below.

Structure (II-Iax): a structure containing one or more groups selected from the group consisting of monovalent aliphatic groups having 6 to 12 carbon atoms, divalent aliphatic groups having 6 to 12 carbon atoms, alkylaryl groups having 14 to 26 carbon atoms, and alkylaryl groups having 14 to 26 carbon atoms

The structure (III-Ia) is preferably the structure (III-Iax) specified below.

Structure (III-Iax): a structure containing one or more groups selected from the group consisting of oxyalkylene group bonded to a monovalent aliphatic group having 6 to 12 carbon atoms, oxyalkylene group bonded to an alkylaryl group having 14 to 26 carbon atoms, oxyalkylene group bonded to an alkylaryl group having 14 to 26 carbon atoms, and oxyalkylene group bonded to an aryl group having 6 to 10 carbon atoms

In the structure (I-Ia), structure (II-Ia), and structure (III-Ia), the monovalent aliphatic group is preferably an alkyl group, alkenyl group, or alkynyl group, of which an alkyl group is more preferable. The divalent aliphatic group is preferably an alkylene group, alkenylene group, or alkynylene group, of which an alkylene group is more preferable. Furthermore, the monovalent or divalent aliphatic group is preferably a straight-chain structure or a branched structure, of which a straight-chain structure is more preferable.

The compound (I1b) and the compound (I2b) preferably have the structure (I-Ib) specified below.

Structure (I-Ib): a structure containing one or more groups selected from the group consisting of monovalent or divalent aliphatic groups having 1 to 6 carbon atoms, alkylaryl groups having 7 to 30 carbon atoms, arylalkyl groups having 7 to 30 carbon atoms, and aryl group having 6 to 15 carbon atoms

It is preferable that the compound (I1b) and the compound (I2b) have a substituent bonded to a nitrogen atom in an ammonium ion etc. as listed above as cation species, wherein the substituent preferably has the structure (I-Ib).

The structure (I-Ib) is preferably the (I-Ibx) structure specified below.

Structure (I-Ibx): a structure containing one or more groups selected from the group consisting of monovalent aliphatic groups having 1 to 4 carbon atoms, alkylaryl groups having 7 to 26 carbon atoms, arylalkyl groups having 7 to 26 carbon atoms, and aryl group having 6 to 10 carbon atoms

In the structure (I-Ib), the monovalent aliphatic group is preferably an alkyl group, alkenyl group, or alkynyl group, of which an alkyl group is more preferable. The divalent aliphatic group is preferably an alkylene group, alkenylene group, or alkynylene group, of which an alkylene group is more preferable. Furthermore, the monovalent or divalent aliphatic group is preferably a straight-chain structure or a branched structure, of which a straight-chain structure is more preferable. The monovalent or divalent aliphatic groups may have, as substituents, alkyl groups having 1 to 6 carbon atoms, alkoxy groups having 1 to 6 carbon atoms, carboxyl groups, hydroxyl groups, or amino groups.

In the structure (I-Ib), the aforementioned ammonium ion etc. are preferably an ammonium ion, primary ammonium ion, secondary ammonium ion, tertiary ammonium ion, or quaternary ammonium ion, of which a quaternary ammonium ion is more preferable. The quaternary ammonium ion preferably has 4 alkyl groups having 1 to 6 carbon atoms and more preferably has 4 alkyl groups having 1 to 4 carbon atoms. The 4 alkyl groups are each independently an alkyl group having 1 to 6 carbon atoms, wherein their numbers of carbon atoms may be identical to or different from each other.

For the compound (I1a), examples of the thiol compounds include butanethiol, hexanethiol, octanethiol, dodecanethiol, octadecanethiol, ethanedithiol, octanedithiol, cyclopropanethiol, cyclohexanethiol, thiophenol, toluenethiol, benzylthiol, mercaptopropyl trimethoxysilane, mercaptooctyl trimethoxysilane, and mercaptododecyl trimethoxysilane.

Examples of the sulfide compounds include dimethyl sulfide, dibutyl sulfide, dihexyl sulfide, dioctyl sulfide, didodecyl sulfide, dicyclopropyl sulfide, dicyclohexyl sulfide, diphenyl sulfide, ditolyl sulfide, and dibenzyl sulfide.

Examples of the disulfide compounds include dimethyl sulfide, dibutyl sulfide, dihexyl disulfide, dioctyl sulfide, didodecyl sulfide, dicyclopropyl sulfide, dicyclohexyl sulfide, diphenyl sulfide, ditolyl disulfide, and dibenzyl sulfide.

Examples of the sulfonic acid compounds include methanesulfonic acid, propanesulfonic acid, butanesulfonic acid, hexanesulfonic acid, octanesulfonic acid, dodecanesulfonic acid, cyclopropanesulfonic acid, cyclohexanesulfonic acid, benzenesulfonic acid, toluenesulfonic acid, and phenylmethanesulfonic acid.

For the compound (I1b), examples of the compound containing, as anion species, one or more selected from the group consisting of sulfide ions, hydrogen sulfide ions, sulfate ions, and hydrogen sulfate ions, and further containing, as cation species, a quaternary ammonium ion include bis(tetraethylammonium) sulfide, bis(tetrabutylammonium) sulfide, bis(butyltriethylammonium) sulfide, bis(octyltriethylammonium) sulfide, bis(dodecyltriethylammonium) sulfide, bis(cyclohexyltriethylammonium) sulfide, bis(phenyltriethylammonium) sulfide, bis(tolyltriethylammonium) sulfide, bis(benzyltriethylammonium) sulfide, bis(tetraethylammonium) sulfate, bis(tetrabutylammonium) sulfate, bis(butyltriethylammonium) sulfate, bis(octyltriethylammonium) sulfate, bis(dodecyltriethylammonium) sulfate, bis(cyclohexyltriethylammonium) sulfate, bis(phenyltriethylammonium) sulfate, bis(tolyltriethylammonium) sulfate, and bis(benzyltriethylammonium) sulfate.

For the compound (I2a), examples of the alkyl chloride compounds, cycloalkyl chloride compounds, and aryl chloride compounds include dichloromethane, dichloroethane, tetrachloroethane, chloroform, carbon tetrachloride, chlorocyclopropane, epichlorohydrin, butyl chloride, hexyl chloride, octyl chloride, dodecyl chloride, cyclohexyl chloride, phenyl chloride, tolyl chloride, and benzyl chloride.

Examples of the alkyl bromide compounds, cycloalkyl bromide compounds, and aryl bromide compounds include dibromomethane, dibromoethane, tetrabromoethane, bromoform, carbon tetrabromide, bromocyclopropane, epibromohydrin, butyl bromide, hexyl bromide, octyl bromide, dodecyl bromide, cyclohexyl bromide, phenyl bromide, tolyl bromide, and benzyl bromide.

For the compound (I2b), examples of the compound containing, as anion species, a chloride ion and/or a bromide ion and further containing, as cation species, a quaternary ammonium ion include tetramethylammonium chloride, tetraethylammonium chloride, tetrabutylammonium chloride, butyltriethylammonium chloride, octyltriethylammonium chloride, dodecyltriethylammonium chloride, cyclopropyltriethylammonium chloride, cyclohexyltriethylammonium chloride, phenyltriethylammonium chloride, tolyltriethylammonium chloride, benzyltriethylammonium chloride, tetramethylammonium bromide, tetraethylammonium bromide, tetrabutylammonium bromide, butyltriethylammonium bromide, octyltriethylammonium bromide, dodecyltriethylammonium bromide, cyclopropyltriethylammonium bromide, cyclohexyltriethylammonium bromide, phenyltriethylammonium bromide, tolyltriethylammonium bromide, and benzyltriethylammonium bromide.

The compound (I1a) is preferably the compound (I1a-DL) present in the pixel separation layer etc. described above. The compound (I2a) is preferably the compound (I2a-DL) present in the pixel separation layer etc. described above. The compound (I1b) is preferably the compound (I1b-DL) present in the pixel separation layer etc. described above. The compound (12b) is preferably the compound (I2b-DL) present in the pixel separation layers, etc. described above.

On the other hand, if the storage stability of the photosensitive composition is poor, for example, the generation of foreign substances after storage at room temperature may become a problem. If foreign substances are generated during the storage of the photosensitive composition, the foreign substances may remain in the pixel separation layer, the pixel size control layer, or the opening parts during the formation of the pixel separation layer or the pixel size control layer, and such foreign substances may cause a reduction in the reliability of the light emitting element. The photosensitive composition used in the display device according to the present invention can significantly enhance the effect of improving storage stability when the content of the compound (I) is controlled in an appropriate range.

<Contents of sulfur element, sulfur based anions, chlorine element, bromine element, and halogen anions>

The composition according the present invention not only includes the alkali soluble resin (A), photosensitizer (C), and colorant (D), but also satisfies the requirement (I) and/or the requirement (II) specified below.

(I) It further includes one or more selected from the group consisting of components containing the sulfur element, components containing the chlorine element, and components containing the bromine element and further satisfies the requirement (1a) and/or the requirement (2a) specified below.

(1a) The content of the sulfur element in the photosensitive composition is 0.01 to 100 mass ppm.

(2a) The total content of the chlorine element and the bromine element in the photosensitive composition is 0.01 to 100 mass ppm.

(II) It further includes one or more selected from the group consisting of components containing a sulfur based anion as specified below and components containing a halogen anion as specified below and further satisfies the requirement (1b) and/or the requirement (2b) specified below.

Sulfur based anion: one or more ions selected from the group consisting of sulfide ions, hydrogen sulfide ions, sulfate ions, and hydrogen sulfate ions halogen anion: a chloride ion and/or a bromide ion,
(1b) The total content of sulfide ions, hydrogen sulfide ions, sulfate ions, and hydrogen sulfate ions in the photosensitive composition is 0.01 to 500 mass ppm.

(2b) The total content of chloride ions and bromide ions in the photosensitive composition is 0.01 to 500 mass ppm.

If they are configured in this way, the composition according to the present invention can enhance the effect of realizing excellent light emission characteristics to enable low voltage driving and high reliability of the light emitting element. If they are configured in this way, even when the components present in the composition according to the present invention contain unintended impurities, neither an increase in voltage driving of the light emission characteristics nor a decrease in reliability of the light emitting element will be caused by these impurities. As described above, if the photosensitive composition includes trace amounts of a component containing the sulfur element, a component containing a sulfur based anion as described above, a component containing the chlorine element, a component containing the bromine element, or a component containing a halogen anion as described above, the surface of the first electrode that faces the light emitting layer is expected to be modified by these elements or ions. It is inferred that as a result, the adjustment of the difference in the work function works for realizing excellent light emission characteristics that enable low voltage driving and improved light emission characteristics. It is also considered that the polarization structure and charge balance in the cured film can be controlled by intentionally adding trace amounts of these components. It is inferred from this that the suppression of ion migration and electromigration can enhance the effect of improving the reliability of the light emitting element. In addition, it is inferred that suppression of migration and aggregation of metal in the first electrode can enhance the effect of improving the reliability of the light emitting element. Here, if at least one of the sulfur element, sulfur based anions described above, chlorine element, bromine element, and halogen anions described above has a content within the specific range in the photosensitive composition, the surface of the first electrode that faces the light emitting layer is expected be modified selectively by such an element or ion.

For example, the requirement (1a) specified above is satisfied if the photosensitive composition includes a component containing the sulfur element and additionally the content of the sulfur element in the photosensitive composition is 50 mass ppm.

As another example, the requirement (1b) specified above is satisfied if the photosensitive composition includes a component containing a sulfide ion and additionally the content of the sulfur element in the photosensitive composition is 500 mass ppm while the content of the sulfide ion in the photosensitive composition is 500 mass ppm.

As still another example, the requirement (1a) specified above and the requirement (1b) specified above are satisfied if the photosensitive composition includes a component containing a sulfide ion and additionally the content of the sulfur element in the photosensitive composition is 50 mass ppm while the content of the sulfide ion in the photosensitive composition is 50 mass ppm.

As still another example, the requirement (1a) specified above and the requirement (1b) specified above are satisfied if the photosensitive composition includes a component containing the sulfur element and a component containing a sulfide ion and additionally the content of the sulfur element in the photosensitive composition is 60 mass ppm while the content of the sulfide ion in the photosensitive composition is 30 mass ppm.

It is more preferable that the composition according to the present invention includes a component containing the sulfur element while further satisfying the requirement (1a) specified above and/or that it includes a component containing a sulfur based anion while further satisfying the requirement (1b) specified above, and it is still more preferable that it includes a component containing the sulfur element while further satisfying the requirement (1a) specified above and also that it includes a component containing a sulfur based anion while further satisfying the requirement (1b) specified above.

If they are configured in this way, it significantly enhances the effect of realizing lower voltage driving of the light emission characteristics, improved light emission luminance, and improved reliability of the light emitting element. This is considered to be because the component containing trace amounts of the sulfur element or the component containing a sulfur based anion as specified above present in the photosensitive composition are likely to interact easily with the surface of the first electrode that faces the light emitting layer due to the polarizability of the sulfur element or sulfur atoms in the sulfur based anions. Accordingly, it is inferred that the surface of the first electrode that faces the light emitting layer is modified by the sulfur element or sulfur based anions.

It is more preferable that the composition according to the present invention includes a component containing the sulfur element while further satisfying the requirement (1a) specified above and/or that it includes a component containing a sulfur based anion while further satisfying the requirement (1b) specified above, and at the same time includes one or more selected from the group consisting of components containing the chlorine element and components containing the bromine element while further satisfying the requirement (2a) specified above, and/or that it includes a component containing a halogen anion while further satisfying the requirement (2b) specified above.

If they are configured in this way, it significantly enhances the effect of realizing lower voltage driving of the light emission characteristics, improved light emission luminance, and improved reliability of the light emitting element. This is considered to be because the inclusion of trace amounts of these components in the photosensitive composition serves for additional surface modification by the chlorine element, bromine element, or halogen anions as specified above, after the surface of the first electrode that faces the light emitting layer is first modified by the sulfur element or sulfur based anions. It is inferred that as a result, a dense film is formed on the surface of the first electrode to realize high density surface modification.

From the perspective of realizing lower voltage driving of the light emission characteristics, improved light emission luminance, and improved reliability of the light emitting element, it is more preferable that the composition according to the present invention includes a component containing the sulfur element and/or a component containing a sulfur based anion as specified above and still more preferably includes a component containing the sulfur element and a component containing a sulfur based anion as specified above. Furthermore, it is still more preferable that the composition according to the present invention includes a component containing the chlorine element and/or a component containing the bromine element, as well as a component containing a halogen anion as specified above. It is still more preferable that the composition according to the present invention includes a component containing the sulfur element and/or a component containing a sulfur based anion as specified above and further includes one or more selected from the group consisting of components containing the sulfur element, components containing the bromine element, and components containing halogen anions as specified above. The sulfur based anion specified above more preferably contains a sulfide ion and/or a hydrogen sulfide ion. As the halogen anion specified above, it is more preferable to contain a chloride ion.

In the case where the composition according to the present invention includes a component containing the sulfur element, it is preferable that the requirement (1a) specified above is satisfied. In the case where the composition according to the present invention includes a component containing a sulfur based anion as specified above, it is preferable that the requirement (1b) specified above is satisfied. It is preferable that the composition according to the present invention includes a component containing the sulfur element and/or a sulfur based anion as specified above and further satisfies the requirement (1a) and/or the requirement (1b) specified above, and it is more preferable that it includes a component containing the sulfur element and a sulfur based anion and further satisfies the requirement (1a) and the requirement (1b) specified above.

In the case where the composition according to the present invention includes a component containing the chlorine element, it is preferable that the requirement (2a) specified above is satisfied. In the case where the composition according to the present invention includes a component containing the bromine element, it is preferable that the requirement (2a) specified above is satisfied. In the case where the composition according to the present invention includes a component containing a halogen anion as specified above, it is preferable that the requirement (2b) is satisfied.

It is preferable that the composition according to the present invention includes one or more selected from the group consisting of components containing the chlorine element, components containing the bromine element, and components containing halogen anions as specified above and further satisfies the requirement (2a) and/or the requirement (2b) specified above, and it is more preferable that it includes a component containing the chlorine element and/or a component containing the bromine element, as well as a component containing a halogen anion as specified above and further satisfies the requirement (2a) and the requirement (2b) specified above.

It is preferable that the composition according to the present invention not only includes a component containing the sulfur element and/or a component containing a sulfur based anion as specified above and further satisfies the requirement (1a) and/or the requirement (1b) specified above, but also includes one or more selected from the group consisting of components containing the sulfur element, components containing the bromine element, and components containing halogen anions as specified above while further satisfying the requirement (2a) and/or the requirement (2b) specified above, and it is still more preferable that it not only includes a component containing the sulfur element and a component containing a sulfur based anion as specified above while further satisfying the requirement (1a) and the requirement (1b) specified above, but also includes a component containing the chlorine element and/or a component containing the bromine element as well as a component containing a halogen anion as specified above while further satisfying the requirement (2a) and the requirement (2b) specified above.

For the composition according to the present invention, it is preferable that one or more selected from the group consisting components containing the sulfur element, components containing sulfur based anions, components containing the chlorine element, components containing the bromine element, and components containing halogen anions contain the compound (I) specified above. Examples and preferable features related to the compound (I) are as described above.

On the other hand, in the case where the storage stability of the photosensitive composition is poor, for example, the generation of foreign substances after storage at room temperature may become a problem. If foreign substances are generated during the storage of the photosensitive composition, the foreign substances may remain in the pixel separation layer, the pixel size control layer, or the opening parts during the formation of the pixel separation layer, and accordingly, these foreign substances may cause a reduction in the reliability of the light emitting element. The composition according to the present invention can be significantly improved in storage stability if the contents of the component containing the sulfur element, components containing sulfur based anions as specified above, components containing the chlorine element, components containing the bromine element, or components containing halogen anions as specified above are adjusted in appropriate ranges.

The content of the sulfur element present in the photosensitive composition is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the content of the sulfur element is preferably 700 mass ppm or less, more preferably 500 mass ppm or less, and still more preferably 300 mass ppm or less. Furthermore, from the perspective of improving the reliability of the light emitting element and improving the storage stability, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The total content of the chlorine element and the bromine element present in the photosensitive composition is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of the chlorine element and the bromine element is preferably 700 mass ppm or less, more preferably 500 mass ppm or less, and still more preferably 300 mass ppm or less. Furthermore, from the perspective of improving the reliability of the light emitting element and improving the storage stability, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The content of the sulfur element in the photosensitive composition refers to the total quantity of the sulfur element present in the form of isolated atoms, ions, compounds, or compound ions. Similarly, the content of the chlorine element in the photosensitive composition refers to the total quantity of the chlorine element present in the form of isolated atoms, ions, compounds, or compound ions. Similarly, the content of the bromine element in the photosensitive composition refers to the total quantity of the bromine element present in the form of isolated atoms, ions, compounds, or compound ions.

The total content of sulfide ions, hydrogen sulfide ions, sulfate ions, and hydrogen sulfate ions in the photosensitive composition is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of sulfide ions, hydrogen sulfide ions, sulfate ions, and hydrogen sulfate ions is preferably 1,000 mass ppm or less, more preferably 700 mass ppm or less. Furthermore, from the perspective of improving the storage stability, it is preferably 500 mass ppm or less, more preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The total content of chloride ions and bromide ions present in the photosensitive composition is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of chloride ions and bromide ions is preferably 1,000 mass ppm or less, more preferably 700 mass ppm or less. Furthermore, from the perspective of improving the storage stability, it is preferably 500 mass ppm or less, more preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

### <Water Content>

From the perspective of realizing lower voltage driving of the light emission characteristics, improved light emission luminance, and improved reliability of the light emitting element, it is preferable that the composition according to the present invention further satisfies the requirement (3) specified below.

(3) The content of water present in the photosensitive composition is 0.01 to 2.0 mass %.

It is inferred that the inclusion of trace amounts of water in the photosensitive composition allows the water molecules to interact with the sulfur element, sulfur based anions as specified above, chlorine element, bromine element, or halogen anions as specified above, thereby, for example, forming hydrogen bonds. It is considered that accordingly, the sulfur element, sulfur based anions as specified above, chlorine element, bromine element, and halogen anions as specified above become stable in the photosensitive composition. As a result, when a pattern of a photosensitive composition is formed on the first electrode, this is presumed to act to enhance the surface modification action on the surface of the first electrode that faces the light emitting layer and corresponds to the opening part in the pixel separation layer part or the opening part in the pixel size control layer part.

The content of water present in the photosensitive composition is preferably 0.01 mass % or more, more preferably 0.03 mass % or more, still more preferably 0.05 mass % or more, still more preferably 0.07 mass % or more, and particularly preferably 0.1 mass % or more. On the other hand, the content of water is preferably 3.5 parts mass % or less, more preferably 3.0 mass % or less, and still more preferably 2.5 mass % or less. Furthermore, from the perspective of improving the reliability of the light emitting element, it is preferably 2.0 mass % or less, more preferably 1.7 mass % or less, still more preferably 1.5 mass % or less, and particularly preferably 1.2 mass % or less. Furthermore, from the perspective of realizing lower voltage driving of the light emission characteristics, improved light emission luminance, and improved reliability of the light emitting element, it is preferably 1.0 mass % or less, more preferably 0.7 mass % or less, and still more preferably 0.5 mass % or less.

<Contents of sodium element, potassium element, magnesium element, and calcium element>

From the perspective of realizing lower voltage driving of the light emission characteristics, improved light emission luminance, and improved reliability of the light emitting element, it is preferable that the composition according to the present invention further includes one or more selected from the group consisting of components containing the sodium element, components containing the potassium element, components containing the magnesium element, and components containing the calcium element, and further satisfies the requirement (4) specified below.

(4) The total content of the sodium element, potassium element, magnesium element, and calcium element present in the photosensitive composition is 0.01 to 100 mass ppm.

It is inferred that if the photosensitive composition includes trace amounts of a component containing the sodium element, component containing the potassium element, component containing the magnesium element, or component containing the calcium element, these metal elements may form bonds such as ionic bonds and covalent bonds with the sulfur element, sulfur based anions as specified above, chlorine element, bromine element, or halogen anions as specified above to form salts or compounds. It is considered that accordingly, the sulfur element, sulfur based anions as specified above, chlorine element, bromine element, and halogen anions as specified above become stable in the photosensitive composition. As a result, when a pattern of a photosensitive composition is formed on the first electrode, this is presumed to act to enhance the surface modification action on the surface of the first electrode that faces the light emitting layer and corresponds to the opening part in the pixel separation layer part or the opening part in the pixel size control layer part. It is also considered that for example, the polarization structure and charge balance in the pixel separation layer in an organic EL display can be controlled by intentionally adding trace amounts of components containing these metal elements. It is inferred from this that the suppression of ion migration and electromigration attributed to metal impurities and ion impurities that can adversely affect the light emission characteristics can enhance the effect of improving the reliability of the light emitting element.

From the perspective of realizing lower voltage driving of the light emission characteristics, improved light emission luminance, and improved reliability of the light emitting element, the composition according to the present invention more preferably includes a component containing the sodium element and/or a component containing the potassium element, and still more preferably includes a component containing the sodium element. It is also still more preferable that the composition according to the present invention include a component containing the sodium element and a component containing the potassium element.

Furthermore, it is more preferable that the composition according to the present invention includes a component containing the magnesium element and a component containing the calcium element. It is also still more preferable that the composition according to the present invention includes a component containing the sodium element and/or a component containing the potassium element and further includes a component containing the magnesium element and/or a component containing the calcium element.

For the composition according to the present invention, it is preferable that one or more selected from the group consisting of components containing the sodium element, components containing the potassium element, components containing the magnesium element, and components containing the calcium element contain the inorganic particles (H) specified above. More specifically, it is preferable that the inorganic particles (H) contain one or more elements selected from the group consisting of sodium, potassium, magnesium, and calcium. The sodium element, potassium element, magnesium element, and calcium element may be the same as the main constituent element of the inorganic particles (H). It is also preferable that the inorganic particles (H) contain one or more elements selected from the group consisting of sodium, potassium, magnesium, and calcium as elements other than the main constituent element. Examples and preferable features related to the inorganic particles (H) are as described above.

From the perspective of realizing lower voltage driving of the light emission characteristics, improved light emission luminance, and improved reliability of the light emitting element, the inorganic particles (H) that contain the sodium element and/or the potassium element are preferably silica particles (H1) that contain the sodium element and/or the potassium element, and more preferably silica particles (H1) that contain the sodium element.

The total content of the sodium element, potassium element, magnesium element, and calcium element present in the photosensitive composition is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of the sodium element, potassium element, magnesium element, and calcium element is preferably 700 mass ppm or less, more preferably 500 mass ppm or less, and still more preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The content of the sodium element in the photosensitive composition refers to the total quantity of the sulfur element present in the form of isolated atoms, ions, compounds, or compound ions. Similarly, the content of the potassium element in the photosensitive composition refers to the total quantity of the potassium element present in the form of isolated atoms, ions, compounds, or compound ions. Similarly, the content of the magnesium element in the photosensitive composition refers to the total quantity of the magnesium element present in the form of isolated atoms, ions, compounds, or compound ions. Similarly, the content of the calcium element in the photosensitive composition refers to the total quantity of the calcium element present in the form of isolated atoms, ions, compounds, or compound ions.

### <Contents of Benzene, Toluene, Xylene, and Naphthalene>

From the perspective of realizing lower voltage driving of the light emission characteristics, improved light emission luminance, and improved reliability of the light emitting element, it is preferable that the composition according to the present invention further includes one or more selected from the group consisting of benzene, toluene, xylene, and naphthalene and further satisfies the requirement (5) specified below.

(5) The total content of benzene, toluene, xylene, and naphthalene present in the photosensitive composition is 0.01 to 100 mass ppm.

It is inferred that the inclusion of trace amounts of benzene, toluene, xylene, or naphthalene allows these compounds having IT electrons to undergo interactions, such as coordination bonding involving TT electrons, with the sulfur element, sulfur based anions as specified above, chlorine element, bromine element, or halogen anions as specified above, thereby forming complexes. It is considered that accordingly, the sulfur element, sulfur based anions as specified above, chlorine element, bromine element, and halogen anions as specified above become stable in the photosensitive composition. Furthermore, it is inferred that due to the TT-electron interaction between compounds containing TT electrons, these elements or ions are in a locally oriented and aggregated state. As a result, when a pattern of a photosensitive composition is formed on the first electrode, this is presumed to act to enhance the surface modification action on the surface of the first electrode that faces the light emitting layer and corresponds to the opening part in the pixel separation layer part or the opening part in the pixel size control layer part.

From the perspective of realizing lower voltage driving of the light emission characteristics, improved light emission luminance, and improved reliability of the light emitting element, the composition according to the present invention more preferably includes toluene and/or xylene, and still more preferably includes toluene. It is also still more preferable that the composition according to the present invention includes two or more selected from the group consisting of benzene, toluene, xylene, and naphthalene, and also still more preferable that it includes three or more thereof.

The total content of benzene, toluene, xylene, and naphthalene present in the photosensitive composition is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of benzene, toluene, xylene, and naphthalene is preferably 700 mass ppm or less, more preferably 500 mass ppm or less, and still more preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

### <Contents of Glycol Ether Compounds Having Specific Structures>

From the perspective of realizing lower voltage driving of the light emission characteristics, improved light emission luminance, and improved reliability of the light emitting element, it is preferable that the composition according to the present invention further includes a compound as represented by the general formula (21) and/or a compound as represented by the general formula (22), and further satisfies the requirement (6) specified below. It is more preferable that the composition according to the present invention includes a compound as represented by the general formula (21) and a compound as represented by the general formula (22).

(6) The total content of the compound represented by the general formula (21) and the compound represented by the general formula (22) present in the photosensitive composition is 0.001 to 1.0 mass %.

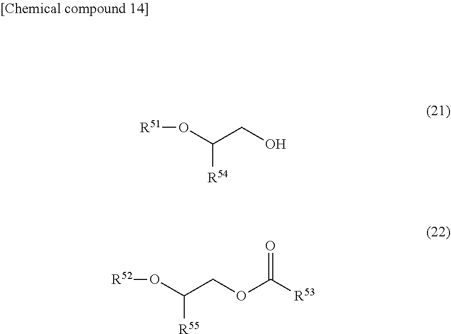

(In the general formula (21) and the general formula (22), R⁵¹ to R⁵³ each independently represent an alkyl group having 1 to 6 carbon atoms. R⁵⁴ and R⁵⁵ are each independently a hydrogen atom or an alkyl group having 1 to 6 carbon atoms.)

It is inferred that if the photosensitive composition includes trace amounts of a compound as represented by the general formula (21) or trace amounts of a compound as represented by the general formula (22), these specific compounds having glycol ether groups undergo interactions, such as coordination bonding, with the sulfur element, sulfur based anions as specified above, chlorine element, bromine element, or halogen anions as specified above, thereby forming complexes. Specifically, it is inferred that these specific compounds function as chelate-type ligands through unshared electron pairs on two adjacent oxygen atoms. It is considered that accordingly, the sulfur element, sulfur based anions as specified above, chlorine element, bromine element, or halogen anions as specified above become stable in the photosensitive composition. As a result, when a pattern of a photosensitive composition is formed on the first electrode, this is presumed to act to enhance the surface modification action on the surface of the first electrode that faces the light emitting layer and corresponds to the opening part in the pixel separation layer part or the opening part in the pixel size control layer part. After making a variety of studies, it was found that the function as chelate-type ligands and advantageous effects of the present invention are attributed to specific features of the specific compounds having glycol ether groups. Therefore, the inclusion of trace amounts of a compound as represented by the general formula (21) or trace amounts of a compound as represented by the general formula (22) in the photosensitive composition serves to significantly enhance the effect of realizing lower voltage driving of the light emission characteristics, improved light emission luminance, and improved reliability of the light emitting element.

The total content of the compound represented by the general formula (21) and the compound represented by the general formula (22) is preferably 0.001 mass % or more, more preferably 0.003 mass % or more, still more preferably 0.005 mass % or more, and still more preferably 0.007 mass % or more. Furthermore, from the perspective of realizing lower voltage driving of the light emission characteristics, improved light emission luminance, and improved reliability of the light emitted light, it is preferably 0.01 mass % or more, more preferably 0.03 mass % or more, still more preferably 0.05 mass % or more, still more preferably 0.07 mass % or more, and particularly preferably 0.1 mass % or more. On the other hand, the total content of the compound represented by the general formula (21) and the compound represented by the general formula (22) is preferably 2.5 mass % or less, more preferably 2.0 mass % or less, and still more preferably 1.5 mass % or less. Furthermore, from the perspective of improving the reliability of the light emitting element, it is preferably 1.0 mass % or less, more preferably 0.85 mass % or less, still more preferably 0.75 mass % or less, and particularly preferably 0.60 mass % or less. Furthermore, from the perspective of realizing lower voltage driving of the light emission characteristics, improved light emission luminance, and improved reliability of the light emitting element, it is preferably 0.50 mass % or less, more preferably 0.35 mass % or less, and still more preferably 0.25 mass % or less.

### <Content of Surface Active Agent>

From the perspective of realizing lower voltage driving of the light emission characteristics, improved light emission luminance, and improved reliability of the light emitting element, it is preferable that the composition according to the present invention further includes a surface active agent, wherein the surface active agent contains one or more structure types selected from the group consisting of structure (a) containing fluorine, structure (b) containing a silyl group, and structure (c) containing a siloxane bond, and further satisfies the requirement (7) specified below.

For the composition according to the present invention, it is more preferable that the surface active agent has a structure (b) containing a silyl group and/or a structure (c) containing a siloxane bond.
Structure (a) containing fluorine: a structure that contains an alkyl group having two or more fluorine atoms and/or an alkylene group having two or more fluorine atoms
Structure (b) containing silyl group: a structure that contains one or more selected from the group consisting of an alkyl group having two or more trimethylsilyl groups, an alkylene group having two or more trimethylsilyl groups, and two or more end structures having trimethylsilyl groups
Structure (c) containing siloxane bond: a structure that contains one or more selected from the group consisting of an alkyl group having two or more dimethylsiloxane bonds, an alkylene group having two or more dimethylsiloxane bonds, and a polydimethylsiloxane structure having two or more dimethylsiloxane bonds

(7) The content of the surface active agent in the photosensitive composition is 10 to 2,000 mass ppm.

If the photosensitive composition includes trace amounts of a surface active agent having a specific structure, it is inferred that these compounds are likely to interact with the surface of the first electrode that faces the light emitting layer to prevent excessive interaction from occurring between high hydrophobicity components in the photosensitive composition and the surface of the first electrode, thereby suppressing the residue formation attributed to the high hydrophobicity components. It is considered that accordingly, during the step of surface modification by the sulfur element, sulfur based anions as specified above, chlorine element, bromine element, or halogen anions as specified above, it serves to suppress the inhibition of surface modification due to residue formation on the surface of the first electrode. As a result, when a pattern of the photosensitive composition is formed on the first electrode, this is presumed to act to enhance the surface modification action on the surface of the first electrode that faces the light emitting layer and corresponds to the opening part in the pixel separation layer part or the opening part in the pixel size control layer part.

It is preferable that the surface active agent has a polymer chain and has one or more selected from the group consisting of the structure (a) containing fluorine, the structure (b) containing a silyl group, and the structure (c) containing a siloxane bond in at least one of the main chain of the polymer chain, side chain of the polymer chain, or chain end of the polymer chain. Examples of surface active agents having polymer chains include fluororesin based surface active agents, silicone based surface active agents, acrylic resin based surface active agents, polyoxyalkylene ether based surface active agents, polyester based surface active agents, polyurethane based surface active agents, polyol based surface active agents, polyalkylene amine based surface active agents, polyethylene-imine based surface active agents, and polyallylamine based surface active agents, of which fluororesin based surface active agents, silicone based surface active agents, and acrylic resin based surface active agents are preferable.

The content of the surface active agents in the photosensitive composition is preferably 10 mass ppm or more, more preferably 30 mass ppm or more, still more preferably 50 mass ppm or more, still more preferably 70 mass ppm or more, and particularly preferably 100 mass ppm or more. On the other hand, the content of the surface active agents is preferably 15,000 mass ppm or less, more preferably 10,000 mass ppm or less, and still more preferably 5,000 mass ppm or less. Furthermore, from the perspective of realizing lower voltage driving of the light emission characteristics, improved light emission luminance, and improved reliability of the light emitting element, it is preferably 2,000 mass ppm or less, more preferably 1,500 mass ppm or less, still more preferably 1,000 mass ppm or less, still more preferably 500 mass ppm or less, and particularly preferably 200 mass ppm or less.

### <Contents of Hafnium Element and Yttrium Element>

From the perspective of realizing lower voltage driving of the light emission characteristics, improved light emission luminance, and improved reliability of the light emitting element, it is preferable that the composition according to the present invention includes the colorant (D) containing a black pigment and/or a mixture of two or more pigments of different colors, and further includes a component containing the hafnium element and/or a component containing the yttrium element while satisfying the requirement (8) specified below. The composition according to the present invention more preferably includes a component containing the hafnium element and a component containing the yttrium element.

(8) The total content of the hafnium element and the yttrium element in the photosensitive composition is 0.01 to 100 mass ppm.

It is inferred that if a pigment and trace amounts of a component containing the hafnium element or a component containing the yttrium element are included in the photosensitive composition, it will act to prevent excessive interactions from occurring between the pigment and the surface of the first electrode that faces the light emitting layer, thereby serving for suppression of residue formation attributed to the pigment. It is inferred that these metal elements are likely to undergo interactions, such as ion bonding and coordination bonding, with the sulfur element, sulfur based anions as specified above, chlorine element, bromine element, or halogen anions as specified above, thereby forming salts or complexes. It is considered that accordingly, the sulfur element, sulfur based anions as specified above, chlorine element, bromine element, or halogen anions as specified above become stable in the photosensitive composition. As a result, when a pattern of the photosensitive composition is formed on the first electrode, this is presumed to act to enhance the surface modification action on the surface of the first electrode that faces the light emitting layer and corresponds to the opening part in the pixel separation layer part or the opening part in the pixel size control layer part. It is also considered that, for example, the polarization structure and charge balance in the pixel separation layer in an organic EL display can be controlled by intentionally adding trace amounts of components containing these metal elements. It is inferred from this that the suppression of ion migration and electromigration attributed to metal impurities and ion impurities that can adversely affect the light emission characteristics can enhance the effect of improving the reliability of the light emitting element.

From the perspective of realizing lower voltage driving of the light emission characteristics, improved light emission luminance, and improved reliability of the light emitting element, it is more preferable that the composition according to the present invention includes a component containing the hafnium element. It is still more preferable that composition according to the present invention includes a component containing the hafnium element and a component containing the yttrium element.

For the composition according to the present invention, the component containing the hafnium element and/or the component containing the yttrium element preferably contain the inorganic particles (H) specified above. More specifically, it is preferable that the inorganic particles (H) contain the hafnium element and/or the yttrium element. The hafnium element or the yttrium element may be the same as the main constituent element of the inorganic particles (H). It is also preferable that the inorganic particles (H) contain the hafnium element and/or the yttrium element as components other than the main constituent element. Examples and preferable features related to the inorganic particles (H) are as described above.

Examples of the inorganic particles (H) containing the hafnium element and/or the yttrium element include those of hafnium oxide (HfO₂), composite oxides of the hafnium element and a metal element other than the hafnium element, solid solutions of hafnium oxide and an oxide of a metal element other than the hafnium element, hafnium oxynitride, composite oxynitride of the hafnium element and a metal element other than the hafnium element, and solid solutions of hafnium oxynitride and an oxynitride of a metal element other than the hafnium element. From the perspective of realizing lower voltage driving of the light emission characteristics, improved light emission luminance, and improved reliability of the light emitting element, it is preferable to adopt hafnium oxide (HfO₂) or a composite oxide of the hafnium element and a metal element other than the hafnium element, and it is more preferable to adopt the composite oxide of the zirconium element and the hafnium element (ZrO₂—HfO₂). Examples of the inorganic particles (H) containing the hafnium element and/or the yttrium element include, for example, those of Hafnium oxide P, R, or S (all manufactured by ATI METALS) and Hafnium Oxide Fine Particles (manufactured by Kojundo Chemical Lab. Co., Ltd.).

It is also preferable that the inorganic particles (H) containing the hafnium element and/or the yttrium element is a component of a pigment dispersion that contains a pigment as the colorant (D). For example, in the case where the photosensitive composition includes a pigment as the colorant (D) and also where the production process of the photosensitive composition has a step for mixing a pigment dispersion and other components, the inorganic particles (H) containing the hafnium element and/or the yttrium element may be added to the photosensitive composition as a component of the pigment dispersion. When preparing a pigment dispersion containing a pigment as the colorant (D), it is preferable that a grinding media that includes the inorganic particles (H) containing the hafnium element and/or the yttrium element is used to perform wet polishing of the surface of the grinding media by mechanical energy to allow the resulting fine particles to be codispersed with the pigment. This technique allows the inorganic particles (H) containing the hafnium element and/or the yttrium element to be included in the pigment dispersion. By preparing a photosensitive composition using the resulting pigment dispersion, it can be included in the photosensitive composition.

The total content of the hafnium element and yttrium element present in the photosensitive composition is preferably 0.01 mass ppm or more, more preferably 0.03 mass ppm or more, still more preferably 0.05 mass ppm or more, still more preferably 0.07 mass ppm or more, and particularly preferably 0.1 mass ppm or more. On the other hand, the total content of the hafnium element and the yttrium element is preferably 700 mass ppm or less, more preferably 500 mass ppm or less, and still more preferably 300 mass ppm or less. Furthermore, from the perspective of improving the reliability of the light emitting element, it is preferably 100 mass ppm or less, more preferably 70 mass ppm or less, still more preferably 50 mass ppm or less, still more preferably 30 mass ppm or less, and particularly preferably 10 mass ppm or less. Furthermore, from the perspective of realizing lower voltage driving of the light emission characteristics, improved light emission luminance, and improved reliability of the light emitting element, it is preferably 7 mass ppm or less, more preferably 5 mass ppm or less, still more preferably 3 mass ppm or less, and particularly preferably 1 mass ppm or less.

The content of the hafnium element in the photosensitive composition refers to the total quantity of the hafnium element present in the form of isolated atoms, ions, compounds, or compound ions. Similarly, the content of the yttrium element in the photosensitive composition refers to the total quantity of the yttrium element present in the form of isolated atoms, ions, compounds, or compound ions.

### <Content of Polyoxyalkylene Ether Compound>

From the perspective of realizing lower voltage driving of the light emission characteristics, improved light emission luminance, and improved reliability of the light emitting element, it is preferable that the composition according to the present invention further includes a polyoxyalkylene ether compound wherein the polyoxyalkylene ether compound contains the hydrophobic structure (a) and the hydrophilic structure (b) specified below and further satisfies the requirement (9) specified below.

Hydrophobic structure (a): a structure containing a group selected from the group consisting of monovalent or divalent aliphatic groups having 1 to 30 carbon atoms, aryl groups having 6 to 15 carbon atoms, arylalkyl groups having 7 to 25 carbon atoms, alkylaryl groups having 7 to 25 carbon atoms, and aryl groups having 6 to 15 carbon atoms bonded to at least two arylalkyl groups having 7 to 25 carbon atoms

Hydrophilic structure (b): 2 to 20 oxyalkylene groups having 1 to 6 carbon atoms (9) The content of the polyoxyalkylene ether compound present in the photosensitive composition is 10 to 5,000 mass ppm.

It is inferred that if the photosensitive composition includes trace amounts of a polyoxyalkylene ether compound having a specific structure, the compound will act to modify the surface of the first electrode that faces the light emitting layer after being adsorbed thereon, and therefore, even in the case where a high hydrophobicity component of the photosensitive composition is attached to the surface of the first electrode, the compound serves to promote its dissolution in the alkaline developer, thereby suppressing the residue formation attributed to the high hydrophobicity component. It is considered that accordingly, during the step of surface modification by the sulfur element, sulfur based anions as specified above, chlorine element, bromine element, or halogen anions as specified above, it serves to suppress the inhibition of surface modification due to residue formation on the surface of the first electrode. As a result, when a pattern of the photosensitive composition is formed on the first electrode, this is presumed to act to enhance the surface modification action on the surface of the first electrode that faces the light emitting layer and corresponds to the opening part in the pixel separation layer part or the opening part in the pixel size control layer part.

In the hydrophobic structure (a), the monovalent or divalent aliphatic groups having 1 to 30 carbon atoms are preferably monovalent or divalent aliphatic groups having 4 to 12 carbon atoms. The aryl groups having 6 to 15 carbon atoms are preferably aryl groups having 6 to 10 carbon atoms. The arylalkyl groups having 7 to 25 carbon atoms are preferably arylalkyl groups having 7 to 15 carbon atoms. The alkylaryl groups having 7 to 25 carbon atoms are preferably alkylaryl groups having 7 to 15 carbon atoms. The aryl groups having 6 to 15 carbon atoms bonded to at least two arylalkyl groups having 7 to 25 carbon atoms are preferably aryl groups having 6 to 15 carbon atoms bonded to at least two alkenyl groups having 2 to 5 carbon atoms having aryl groups having 6 to 15 carbon atoms. It is more preferable that the hydrophobic structure (a) has an aryl group having 6 to 15 carbon atoms bonded to at least two arylalkyl groups having 7 to 25 carbon atoms.

In the hydrophilic structure (b), the oxyalkylene groups having 1 to 6 carbon atoms are preferably oxyethylene groups or oxypropylene groups, of which oxyethylene groups are more preferable. In the hydrophilic structure (b), the number of oxyalkylene groups having 1 to 6 carbon atoms is preferably 2 or more, more preferably 3 or more, and still more preferably 4 or more. On the other hand, the number of oxyalkylene groups having 1 to 6 carbon atoms is preferably 20 or less, more preferably 15 or less, and still more preferably 10 or less.

The polyoxyalkylene ether compound preferably further has the hydrophilic group (c) specified below.

Hydrophilic group (c): a hydroxyl group bonded to a phenolic hydroxyl group and/or an oxyalkylene group having 1 to 6 carbon atoms

In the hydrophilic group (c), the number of phenolic hydroxyl groups is preferably 1 or more, more preferably 2 or more, and still more preferably 3 or more. On the other hand, the number of phenolic hydroxyl groups is preferably 10 or less, more preferably 8 or less, and still more preferably 6 or less. The number of hydroxyl groups bonded to oxyalkylene groups having 1 to 6 carbon atoms is preferably 1 or more, more preferably 2 or more, and still more preferably 3 or more. On the other hand, the number of hydroxyl groups bonded to oxyalkylene groups having 1 to 6 carbon atoms is preferably 10 or less, more preferably 8 or less, and still more preferably 6 or less.

The content of the polyoxyalkylene ether compound present in the photosensitive composition is preferably 10 mass ppm or more, more preferably 30 mass ppm or more, still more preferably 50 mass ppm or more, still more preferably 70 mass ppm or more, and particularly preferably 100 mass ppm or more. On the other hand, the content of the polyoxyalkylene ether compound is preferably 15,000 mass ppm or less, more preferably 10,000 mass ppm or less, and still more preferably 7,000 mass ppm or less. Furthermore, from the perspective of improving the reliability of the light emitting element, it is preferably 5,000 mass ppm or less, more preferably 2,000 mass ppm or less, still more preferably 1,500 mass ppm or less, still more preferably 1,000 mass ppm or less, and particularly preferably 500 mass ppm or less.

### <Dissolution Accelerator>

From the perspective of realizing lower voltage driving of the light emission characteristics, improved light emission luminance, and improved reliability of the light emitting element, it is preferable that the composition according to the present invention further includes a dissolution accelerator. The dissolution accelerator is a compound having an acidic group and/or a hydrophilic group that is soluble in the alkaline developer. If a dissolution accelerator is included, the effect of suppressing residue generation caused by hydrophobic components in the photosensitive composition becomes significant. It is considered that accordingly, during the step of surface modification by the sulfur element, sulfur based anions as specified above, chlorine element, bromine element, or halogen anions as specified above, it serves to suppress the inhibition of surface modification due to residue formation on the surface of the first electrode.

It is preferable that the dissolution accelerator contains one or more compounds selected from the group consisting of polyfunctional carboxylic acid compounds, polyfunctional phenolic compounds, and hydroxyimide compounds, of which polyfunctional phenolic compounds are more preferable. The dissolution accelerator preferably contains a phenolic hydroxyl group. The number of phenolic hydroxyl groups contained in the dissolution accelerator is preferably 2 or more, more preferably 3 or more, and still more preferably 4 or less. On the other hand, the number of phenolic hydroxyl groups is preferably 10 or less, more preferably 8 or less, and still more preferably 6 or less.

### <Ink Repellent Agent>

From the perspective of realizing lower voltage driving of the light emission characteristics, improved light emission luminance, and improved reliability of the light emitting element, it is preferable that the composition according to the present invention further includes an ink repellent agent. The ink repellent agent is a compound that has a water repellent structure and/or an oil repellent structure and further has a reactive group. The inclusion of the ink repellent agent serves to improve the liquid repellency of the film and significantly enhance the effect of increasing the contact angle of pure water on the film and/or the contact angle of organic solvents on the film. In addition, the effect of suppressing residue generation caused by hydrophobic components in the photosensitive composition becomes significant. It is considered that accordingly, during the step of surface modification by the sulfur element, sulfur based anions as specified above, chlorine element, bromine element, or halogen anions as specified above, it serves to suppress the inhibition of surface modification due to residue formation on the surface of the first electrode.

It is preferable that the water repellent structure and/or the oil repellent structure of the ink repellent agent have one or more selected from the group consisting of a structure (a) containing fluorine, a structure (b) containing silyl groups, and a structure (c) containing siloxane bonds.
Structure (a) containing fluorine: a structure that contains an alkyl group having two or more fluorine atoms and/or an alkylene group having two or more fluorine atoms
Structure (b) containing silyl structure: a structure that contains an alkyl group containing two or more trimethylsilyl groups and/or an alkylene group containing two or more trimethylsilyl groups
Structure (c) containing siloxane bond: a structure that contains one or more selected from the group consisting of an alkyl group having two or more dimethylsiloxane bonds, an alkylene group having two or more dimethylsiloxane bonds, and a polydimethylsiloxane structure having two or more dimethylsiloxane bonds

It is preferable that the reactive group present in the ink repellent agent has at least two radical polymerizable groups and/or at least two thermally reactive groups. The radical polymerizable group is preferably an ethylenically unsaturated double bond group. The radical polymerizable group is more preferably one or more selected from the group consisting of photoreactive groups, alkenyl groups having 2 to 5 carbon atoms, and alkynyl groups having 2 to 5 carbon atoms. Preferable examples of such photoreactive groups include the styryl group, cinnamoyl group, maleimide group, nadimide group, and (meth)acryloyl group, of which (meth)acryloyl group is more preferable. On the other hand, preferable examples of the alkenyl groups having 2 to 5 carbon atoms and alkynyl groups having 2 to 5 carbon atoms include the vinyl group, allyl group, 2-methyl-2-propenyl group, crotonyl group, 2-methyl-2-butenyl group, 3-methyl-2-butenyl group, 2,3-dimethyl-2-butenyl group, ethynyl group, and 2-propargyl group, of which vinyl group and allyl group are more preferable. Preferable examples of the thermal reactive groups include the alkoxymethyl group, methylol group, epoxy group, oxetanyl group, and blocked isocyanate group.

The ink repellent agent preferably has a polymer chain and preferably has a water repellent structure and/or an oil repellent structure as specified above in at least one of the main chain of the polymer chain, side chain of the polymer chain, or chain end of the polymer chain. It also preferably has a reactive group as specified above in at least one of the main chain of the polymer chain, side chain of the polymer chain, or chain end of the polymer chain. Examples of ink repellent agents having polymer chains include fluororesin based ink repellent agents, silicone based ink repellent agents, acrylic resin based ink repellent agents, polyoxyalkylene ether based ink repellent agents, polyester based ink repellent agents, polyurethane based ink repellent agents, polyol based ink repellent agents, polyalkylene amine based ink repellent agents, polyethylene-imine based ink repellent agents, and polyallylamine based ink repellent agents, of which fluororesin based ink repellent agents, silicone based ink repellent agents, and acrylic resin based ink repellent agents are preferable.

### <Other Additives>

It is preferable that the composition according to the present invention further contains one or more selected from the group consisting of sensitizers, chain transfer agents, polymerization inhibitors, and silane coupling agents. The sensitizers are preferably compounds having a fluorene structure, benzofluorene structure, fluorenone structure, or thioxanthone structure. The chain transfer agents are preferably compounds having at least two mercapto groups. The polymerization inhibitors are preferably hindered phenolic compounds, hindered amine compounds, or benzoimidazole compounds. The silane coupling agents are preferably trifunctional organosilanes, tetrafunctional organosilanes, or silicate compounds.

### <Solvent>

The composition according to the present invention preferably includes a solvent. If a solvent is included, it serves to form a film of a photosensitive composition and/or a non-photosensitive composition having a desired thickness on the substrate, and enhances the effect of forming a film having highly uniform thickness. From the perspective of the solubilities of the various resins and various additives, the solvent is preferably a compound having an alcoholic hydroxyl group, a compound having a carbonyl group, a compound having an ester bond, or a compound having at least three ether bonds. The content of the solvent in the photosensitive composition may be adjusted appropriately to suite the coating method to use etc. For example, when the spin coating technique is used to form a coating film, the content of the solvent in the photosensitive composition is commonly adjusted to 50 to 95 mass %.

If the composition according to the present invention includes the colorant (D) wherein the colorant (D) contains a pigment, it preferably contains a solvent having a carbonyl group and/or a solvent having an ester bond. Preferable examples of the carbonyl groups include alkyl carbonyl groups, dialkyl carbonyl groups, formyl groups, carboxyl groups, amide groups, imide groups, urea bonds, and urethane bonds. Preferable examples of the ester bonds include carboxylate bonds, carbonate ester bonds, and formate bonds, of which carboxylate bonds are more preferable. Of the carboxylate bonds, acetate bonds, propionate bonds, and butyrate bonds are more preferable, of which acetate bonds are still more preferable. From the perspective of reducing the residue remaining after development and improving resolution after development, the sum of the contents of the solvents having carbonyl groups and the contents of the solvents having ester bonds is preferably 30 to 100 mass %, more preferably 50 to 100 mass %, and still more preferably 70 to 100 mass %, of all solvents.

### <Production Method for the Composition According to the Present Invention>

Described below is a typical production method for the composition according to the present invention. In the case where the composition according to the present invention includes the colorant (D) wherein the colorant (D) contains a pigment, the dispersant (E) is added as necessary to a solution of the alkali soluble resin (A) and the pigment is dispersed in the mixture solution using a disperser to prepare a pigment dispersion. Then, the alkali soluble resin (A), radical polymerizable compound (B), photosensitizer (C), other additives as necessary, and appropriate solvents are added to this pigment dispersion, followed by stirring for 20 minutes to 3 hours to prepare a uniform solution. After the stirring, the resulting solution is filtered to provide the composition according to the present invention. From the perspective of reducing the residue remaining after development, it is preferable to use a bead mill as disperser. Examples of the grinding medium to use for the bead mill include titania beads, zirconia beads, and zircon beads. As the grinding medium, the use of zirconia beads is preferable, and it is more preferable to adopt ceramic beads in which the pure content of zirconia (ZrO₂) and hafnium oxide (HfO₂) is 90 mass % or more or ceramic beads in which the pure content of the complex oxide of the zirconium element and the hafnium element (ZrO₂—HfO₂) is 90 mass % or more. The diameter of the grinding medium is preferably 0.01 mm or more, more preferably 0.015 mm or more, and still more preferably 0.03 mm or more. On the other hand, the diameter of the grinding medium is preferably 6 mm or less, more preferably 5 mm or less, and still more preferably 3 mm or less.

### <Cured Product and Optical Density, Taper Angle, Step Shape, and Contact Angle of Cured Product>

The cured product according to the present invention is a cured product of the composition according to the present invention. The term “curing” refers to the process in which a crosslinked structure is formed through a reaction while causing a loss of fluidity of the film, or the state of such a film. There are no particular limitations on the reaction, and good reactions include those caused by heating, irradiation with energy rays, etc., of which those caused by heating are preferable. The state of a film that has lost fluidity after the formation of crosslinked structures by heating is referred to as heat-cured. Good heating conditions include heating at 150° C. to 500° C. for 5 to 300 minutes. Good heating methods include, for example, heating by means of an oven, hot plate, infrared ray, flash annealing device, and laser annealing device. Good processing atmospheres include, for example, atmospheres of air, oxygen, nitrogen, helium, neon, argon, krypton, and xenon, as well as gas atmospheres containing 1 to 10,000 mass ppm (0.0001 to 1 mass %) of oxygen, gas atmospheres containing 10,000 mass ppm (1 mass %) or more of oxygen, and vacuum atmosphere.

For the cured film prepared by curing the composition according to the present invention, the optical density per μm of film thickness in the visible light wavelength range (380 to 780 nm) is preferably 0.5 to 3.0 from the perspective of suppressing the external light reflection and preventing light leakage from adjacent pixels. The optical density per μm of film thickness can be controlled by varying the components and their contents in the colorant (D) described above. Here, the optical density of the cured film prepared by curing the composition according to the present invention is as described above in relation to the optical density of the pixel separation layer. The taper angle of the inclined sides of a cross section of the cured pattern contained in the cured film prepared by curing the composition according to the present invention is preferably 10 to 55° from the perspective of preventing electrode disconnection and improving the reliability of the light emitting element in an organic EL display.

FIG. 8 gives a schematic cross section illustrating an example of a cross section of a cured pattern having a step shape contained in the cured film prepared by curing the composition according to the present invention. Examples and preferable features related to FIG. 8 are as described previously. Examples and preferable features related to the cured pattern having a step shape contained in the cured film prepared by curing the composition according to the present invention are as described above in relation to the cured pattern having a step shape present in the pixel separation layer. If the film thickness difference (ΔT_{FT-HT}) μm between (T_{FT}) μm and (T_{HT}) μm is 1.5 μm or more, the formation of the light emitting layer can be performed with a small contact area with the deposition mask, and it enhances significantly the effect of suppressing the yield reduction of the panel and improving the reliability of the light emitting element in the organic EL display. Furthermore, one step-shaped cured pattern layer alone can develop a sufficiently large difference in film thickness to significantly enhance the effect of decreasing the process time and improving the productivity. On the other hand, if the film thickness difference is 10.0 μm or less, the light exposure energy required for forming a step-shaped cured pattern can be reduced, leading to a shorter process time and an improved productivity.

The cured film prepared by curing the composition according to the present invention preferably has a specific range of contact angles with pure water and/or organic solvents. In such a case, the cured film prepared by curing the composition according to the present invention is preferably the pixel separation layer in an organic EL display.

### <Display Devices and Semiconductor Devices Including the Cured Product According to the Present Invention>

Described below are display devices that include the cured product according to the present invention. Display devices according to the present invention include, for example, organic EL displays, quantum dot displays, micro-LED displays, LED displays, liquid crystal displays, plasma displays, and field emission displays. Of these display devices according to the present invention, organic EL displays, quantum dot displays, and micro-LED displays are preferable, and organic EL displays are more preferable.

In order to achieve a desired current density, the composition according to the present invention can not only develop good light emission characteristics to enable low voltage driving, but also have high reliability of the light emitting elements. Therefore, the cured film prepared by curing the composition according to the present invention under the curing conditions specified above is preferably used as the pixel separation layer, TFT planarization layer, TFT protection layer, and interlayer insulation layer in organic EL displays. Furthermore, it is suitable as black matrix and black column spacer, and particularly preferable for use in organic EL displays. As a result, the high reliability of the light emitting element can lead to increased durability of organic EL displays. For the reasons described above, the composition according to the present invention is particularly suitable for use in forming pixel separation layers for organic EL displays. Furthermore, it is particularly suitable for use in batch production of step shapes in pixel separation layers for organic EL displays. Thus, the composition according to the present invention is suitable for use in batch production of step shapes in pixel separation layers for organic EL displays.

In addition, the composition according to the present invention includes trace amounts of a component containing the sulfur element, a component containing sulfur based anions as specified above, a component containing the chlorine element, a component containing the bromine element, or components containing halogen anions as specified above in the photosensitive composition. Accordingly, cured films prepared by curing the composition according to the present invention under the curing conditions specified above can also be used suitably in electronic components such as semiconductor devices and multi-layered circuit boards. More specifically, they can also be used suitably in semiconductor's passivation film, semiconductor device's protective film, interlayer insulation film in multi-layered wiring for high-density packaging, interlayer insulation film disposed between redistribution layers, etc.

In this way, the semiconductor device according to the present invention is a semiconductor device having metal wiring and an insulation film, and it is a semiconductor device in which the cured film prepared by curing the composition according to the present invention is used as insulation film. In general, a semiconductor device means a device containing, as components, a semiconductor element or an integrated circuit that integrates such elements. The semiconductor device according to present invention include not only a semiconductor element but also other components, such as circuit board, used for producing the semiconductor devices. In addition, the semiconductor device according to the present invention may also be in the form of a semiconductor package containing a semiconductor element etc. protected by encapsulation resin and provided with a function for electric connection to external components.

### <Display Device>

The display device according to the present invention includes a cured product according to the present invention. The display device according to the present invention is preferably a display device that includes a substrate, a first electrode, a second electrode, a pixel separation layer, and an organic layer containing a light emitting layer. For the display device according to the present invention, it is preferable that the pixel separation layer is the cured product according to the present invention. Furthermore, the display device that includes the cured product according to the present invention is preferably an organic EL display.

If the colorant (D) present in the composition according to the present invention contains the black colorant (Da), it can serve to produce a cured film having improved light blocking efficiency. Accordingly, the display device including a cured film prepared by curing the composition according to the present invention can enhance significantly the effect of preventing the electrode wiring from becoming visible and suppressing external light reflection even when it has no polarizing films such as linear polarizing plates, quarter wave plates, and circular polarizing plates on the light extraction side of the organic layer containing a light emitting layer. Thus, the absence of a polarizing film that is poor in flexibility or bendability serves to significantly enhance the effect of improving flexibility and bendability. Therefore, it is suitable particularly for flexible displays that have a structure in which the cured film is disposed on a flexible substrate and have no polarizing films on the light extraction side of the organic layer containing a light emitting layer.

### <Production Methods for Cured Product>

The production method for the cured product according to the present invention includes the steps (1) to (4) described below:
(1) a step for forming a coating film of the composition according to the present invention on a substrate,
(2) a step for applying active actinic ray to the coating film of the photosensitive composition through a photomask,
(3) a step for development using a developer to form a pattern of the photosensitive composition, and
(4) a step for heating the pattern to produce a cured pattern of the photosensitive composition.

Here, in these steps, the techniques described in paragraph [0453] to paragraph [0481] of International Publication WO 2019/087985 may be applied. In the step for forming a coating film, it is preferable to perform prebaking after spreading the coating film. In the step for producing a cured pattern, it is preferable to heat the pattern to heat-cure it.

### <Schematic Cross-Sectional View of Production Process for Display Device>

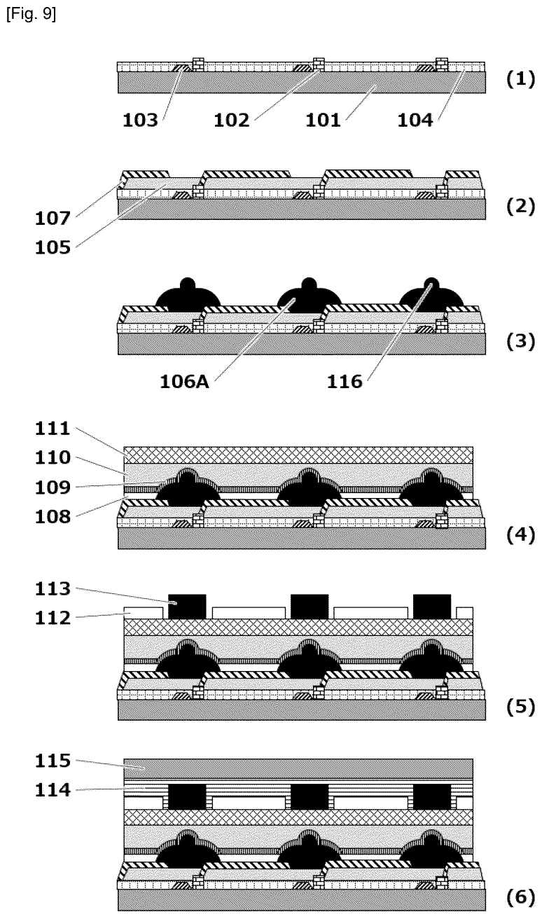

For the display device according to the present invention, an example of a process for producing a display device that includes a pixel separation layer having a step shape is described below with reference to the schematic cross-sectional view illustrated in FIG. 9. First (step 1), after forming a TFT element layer 103 on a substrate 101, the formation of a conductive layer/metal wiring 102 by patterning based on the sputtering method and the etching method using a photoresist and the formation of an interlayer insulation layer 104 by patterning based on the photolithography method using a photosensitive composition are repeated multiple times to form a laminated structure of conductive layers/metal wiring 102 and interlayer insulation layers 104. Next (step 2), after forming a TFT planarization layer/TFT protection layer 105 by patterning based on the photolithography method using a photosensitive composition, a silver-palladium-copper alloy (hereinafter APC) layer is formed by patterning based on the sputtering method and the etching method using a photoresist and in addition, in a similar way, a first electrode 107, which is a non-transparent electrode (reflective electrode), is formed by creating an indium tin oxide (hereinafter ITO) layer on top of the APC layer by the sputtering method and the etching method. Thereafter (step 3), a pixel separation layer 106A having a step shape in which the pixel separation layer has a thick part 116 is formed by patterning based on the photolithography method using a photosensitive composition and a halftone photomask. Next (step 4), after forming an organic layer 108 containing a light emitting layer from an EL emission material by the vapor deposition method using a vapor deposition mask, a second electrode 109, which is a transparent electrode, is formed by depositing a magnesium-silver alloy (hereinafter referred to as MgAg) layer by the vapor deposition method. In addition, after forming a sealing layer 110 by depositing a trisilicon tetranitride layer by the chemical vapor deposition method, a touch panel wiring/touch panel electrode 111 is formed by the vapor deposition method and the etching method. Next (step 5), after forming a color filter layer 112 by patterning based on the photolithography method using a photosensitive composition, a black matrix layer 113 is formed in a similar way by the photolithography method. Subsequently (step 6), after forming an overcoat layer 114 by patterning based on the photolithography method using a photosensitive composition, an opposite substrate 115 is attached to produce a display device that includes a pixel separation layer having a step shape.

### <Display Device Production Method>

The production method to use for the display device according to the present invention preferably include steps as described below:
(1) a step for forming a first electrode,
(2) a step for forming a pixel separation layer on the first electrode,
(3) a step for forming an organic layer containing a light emitting layer on the first electrode,
(4) a step for forming a second electrode on the organic layer containing a light emitting layer,
(5) a step for forming a sealing layer, and
(6) a step for forming a color filter layer and a black matrix layer.

For the production method for a display device according to the present invention, it is also preferable that a step for forming a pixel size control layer on the first electrode and the pixel separation layer is included after the step (2) for forming a pixel separation layer on the first electrode.

For the production method for a display device according to the present invention, it is also preferable that a step for forming a spacer layer on the pixel separation layer is included after the step (2) for forming a pixel separation layer on the first electrode.

By carrying out these steps, it is possible to produce a display device that has a first electrode and a second electrode intersecting each other and further has a pixel part that corresponds to the opening part in the pixel separation layer or the opening part in the pixel size control layer. Each pixel part in the display device according to the present invention is a location where the oppositely arranged first electrode and second electrode intersect and overlap each other, also is a location that is defined by the pixel separation layer on the first electrode, and also is a location that is on the first electrode and includes the organic layer containing a light emitting layer. In the case of an active matrix type display device, the structure containing a switching means may overlap part of the pixel part. In the case of such a configuration, the shape of the pixel part may be partially missing.

For the production method for a display device according to the present invention, it is also preferable that a step for forming a laminated structure of an inorganic layer and/or an organic layer is further included after the step (6) described above. Furthermore, it is more preferable that a step for further forming a laminated structure of an inorganic layer and/or an organic layer on top of the color filter layer, black matrix layer, or overcoat layer (hereinafter referred to as “color filter layer etc.”) (the step hereinafter referred to as “a step for lamination on top of the color filter layer etc.”). The step for lamination on top of the color filter layer etc. is preferably a step for forming a laminated structure of an inorganic layer and/or an organic layer on top of the color filter layer, etc. disposed on the same substrate. Alternatively, it is also preferable, for the step for lamination on top of the color filter layer etc., that a step for forming a laminated structure of an inorganic layer and/or an organic layer on a different substrate is followed by a step for adhering a laminated structure of an inorganic layer and/or an organic layer on top of the color filter layer etc. Furthermore, it is more preferable to include a step in which a laminated structure of an inorganic layer and/or an organic layer is adhered on top of the color filter layer etc. by adding an adhesive layer. Examples of the inorganic layer and the organic layer include adhesive layers, metal wiring, wiring electrodes, touch panel wiring, touch panel electrodes, interlayer insulation layers, wiring protection layers, step planarization layers, linear polarizing plates, quarter wave plates, circular polarizing plates, and substrates.

The production method for a display device according to the present invention is suitable for producing organic EL displays, quantum dot displays, and micro-LED displays, and particularly suitable for producing organic EL displays.

### EXAMPLES

The present invention will now be illustrated more specifically with reference to Examples, Reference examples, and Comparative examples, although the invention is not limited to the scopes thereof. Some of the compounds used in the descriptions and tables of the examples given below are referred to using abbreviations. The abbreviations used for the compounds are listed in Table 1-1.

TABLE 1-1

| Abbreviation | Name of substance |
|---|---|
| 6FDA | 4,4′-hexafluoropropane-2,2-diyl-bis(1,2-phthalic anhydride) |
| APC | argentum-palladium-copper (silver-palladium-copper alloy) |
| BAD | benzaldehyde |
| BAHF | 2,2-bis(3-amino-4-hydroxyphenyl) hexafluoropropane |
| BAPF | 9,9-bis(3-amino-4-hydroxyphenyl) fluorene |
| BGPF | 9,9-bis(4-glycidoxyphenyl) fluorene |
| BnMA | methacrylic acid benzyl |
| BPFL | 9,9′-bis(4-hydroxyphenyl) fluorene |
| cyEpoTMS | 2-(3,4-epoxy cyclohexyl) ethyl trimethoxysilane |
| DFA | N,N-dimethyl formamide dimethyl acetal |
| DHBA | 3,5-dihydroxybenzoic acid |
| EDM | diethylene glycol ethyl methyl ether |
| GMA | glycidyl methacrylate |
| HAD | formaldehyde |
| HPMA | (4-hydroxy)phenyl methacrylate |
| HST | 4-hydroxystyrene |
| ITO | indium oxide tin |
| KBM-503 | 3-methacryloyloxypropyl trimethoxysilane (manufactured by Shin-Etsu Chemical |
| | Co., Ltd.) |
| MAA | methacrylic acid |
| MAP | m-aminophenol |
| MBA | 3-methoxy-n-butyl acetate |
| MCS | m-cresol |
| MEK | methyl ethyl ketone |
| MEK-ST-40 | silica particle dispersion in methyl ethyl ketone used as dispersion medium |
| | (manufactured by Nissan Chemical Industries, Ltd.) |
| MEK-ST-L | silica particle dispersion in methyl ethyl ketone used as dispersion medium |
| | (manufactured by Nissan Chemical Industries, Ltd.) |
| MeTMS | methyl trimethoxysilane |
| MgAg | magnesium-argentum (magnesium-silver alloy) |
| MHBA | 4-hydroxybenzoic acid; monohydroxybenzoic acid |
| MOI | 2-methacryloxyethyl isocyanate |
| MOP | 4-methoxyphenol |
| NA | 5-norbornene-2,3-dicarboxylic anhydride |
| NC-3000-H | epoxy resin having structural unit containing biphenyl backbone, benzene |
| | backbone, and 1 epoxy group (manufactured by Nippon Kayaku Co., Ltd.) |
| NC-3500 | epoxy resin having structural unit containing biphenyl backbone, benzene |
| | backbone, and 2 epoxy groups (manufactured by Nippon Kayaku Co., Ltd.) |
| NPDL | 1,4-naphthalene diol |
| ODB-HBT | mixture of dicarboxylic acid derivatives formed by reacting bis(4-carboxyphenyl) |
| | ether and 1-hydroxy-1,2,3-benzotriazole |
| ODPA | oxydiphthalic dianhydride |
| PGMEA | propylene glycol monomethyl ether acetate |
| PHA | phthalic anhydride |
| PhTMS | phenyl trimethoxysilane |
| SAD | salicyl aldehyde |
| SiDA | 1,3-bis(3-aminopropyl)tetramethyl disiloxane |
| STR | styrene |
| TCDM | tricyclo[5.2.1.0^{2, 6}]decane-8-yl methacrylate; |
| | methylol-tricyclodecane methacrylate |
| THPHA | 1,2,3,6-tetrahydrophthalic anhydride |
| TMAC | trimellitic anhydride chloride |
| TMAH | tetramethyl ammonium hydroxide |
| TMOS | tetramethoxysilane |
| XLN | 2,6-xylenol |

### Synthesis Examples for Resins

Table 1-2 to Table 1-5 summarize the components of the resins prepared as the alkali soluble solution (A) in Synthesis examples 1 to 22. The different resins were synthesized by generally known methods based on the methods described in the documents listed below using different appropriate monomeric compounds at appropriate copolymerization ratios. The copolymerization ratios of the monomers used are listed in Table 1-2 to Table 1-5.

Synthesis examples 1 and 2 used the method described in Synthesis example 1 given in paragraph of International Publication WO 2017/057281.

Synthesis example 4 used the method described in Synthesis example 15 given in paragraph of International Publication WO 2017/057281.

Synthesis example 5 used the method described in Synthesis example 12 given in paragraph of International Publication WO 2017/057281.

Synthesis example 9 used the method described in Synthesis example 30 given in paragraph of International Publication WO 2017/057281.

Synthesis example 10 used the method described in Synthesis example 45 given in paragraph of International Publication WO 2017/057281.

Synthesis examples 21 and 22 used the method described in Synthesis example 46 given in paragraph of International Publication WO 2017/057281.

Synthesis example 3 used the method described in Synthesis example 6 given in paragraph of International Publication WO 2017/159876.

Synthesis examples 11 and 12 used the method described in Synthesis example 25 given in paragraph of International Publication WO 2017/159876.

Synthesis example 13 used the method described in Synthesis example 20 given in paragraph of International Publication WO 2017/159876.

Synthesis examples 15 to 18 used the method described in Synthesis example 21 given in paragraph of International Publication WO 2017/159876.

Synthesis example 19 used the method described in Synthesis example 23 given in paragraph of International Publication WO 2017/159876.

Synthesis example 6 used the method described in Synthesis example 9 given in paragraph of International Publication WO 2017/057143.

Synthesis examples 7 and 8 used the method described in Synthesis example 9 given in paragraph of International Publication WO 2018/159384.

Synthesis example 14 used the method described in Synthesis example 5 given in paragraph of International Publication WO 2012/141165.

Synthesis example 20 used the method described in Production example 1 given in paragraph of Japanese Unexamined Patent Publication (Kokai) No. 2020-042150.

Here, in Synthesis examples 3 and 8, radical polymerizable groups were introduced based on the method described in Synthesis example 6 given in paragraph of International Publication WO 2017/159876.

In Synthesis examples 13, 17 and 22, radical polymerizable groups were introduced based on the method described in Synthesis example 20 given in paragraph of International Publication WO 2017/159876.

In Synthesis example 11, an unsaturated carboxylic acid was reacted with NC-3000-H, which contains epoxy groups. It was completely ring-opened and added to epoxy groups derived from NC-3000-H.

In Synthesis example 12, an unsaturated carboxylic acid was reacted with NC-3500, which contains epoxy groups. It was completely ring-opened and added to epoxy groups derived from NC-3500.

In Synthesis example 13 and 17 and 22, GMA, which contains epoxy groups, was reacted. All epoxy groups in GMA were ring-opened and added.

In Synthesis example 20, a carboxyl group-containing phenol compound was reacted with structural units derived from NC-3000-H, which contains epoxy groups. It was completely ring-opened and added to epoxy groups derived from NC-3000-H.

In Synthesis example 21, a carboxyl group-containing phenol compound was reacted with structural units derived from GMA, which contains epoxy groups. It was completely ring-opened and added to epoxy groups derived from GMA.

The compound (HA) used in Synthesis example 4, which is a hydroxy group-containing diamine having the structure given below, was synthesized by a generally known method based on the synthesis method described in Synthesis example 1 given in paragraph to paragraph of International Publication WO 2016/056451. Here, the resin prepared in Synthesis example 4 using the compound (HA), which is a hydroxy group-containing diamine having the structure given below, is a polyimide precursor having an amic acid ester structural unit, an amic acid structural unit, and a cyclized imide structure.

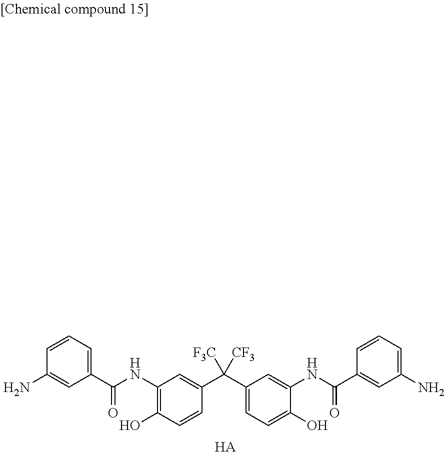

In Synthesis example 14, synthesis was performed based on the synthesis method described in Synthesis example 3 and Synthesis example 5 given in paragraph [0109] to paragraph [0122] of International Publication WO 2012/141165. Specifically, a phenol compound having the structure given below was synthesized as a condensation product of XLN and SAD, instead of the condensation product of XLN and 4-hydroxybenzaldehyde, and the resulting phenol compound was used for the condensation reaction with an aldehyde compound.

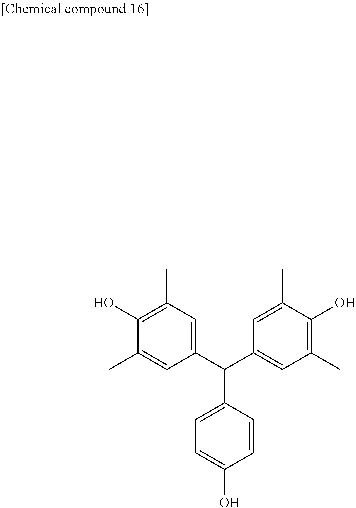

In Synthesis example 4, DFA, which is an esterification agent, was reacted with the amic acid structural unit in the resin. It was subjected to structural conversion into an amic acid ester structural unit having methyl groups.

In Synthesis example 13, epoxy group-containing GMA was reacted with carboxyl groups derived from MAA in the resin. All epoxy groups in GMA were ring-opened and added. In Synthesis example 22, epoxy group-containing GMA was reacted with phenolic hydroxy groups derived from HPMA in the resin. All epoxy groups in GMA were ring-opened and added.

TABLE 1-2

| | | monomer [mole ratio] | | | | | structural | | | |
|---|---|---|---|---|---|---|---|---|---|---|
| | | | | | | electro- | units having | | | |
| | | | | | | philic | fluorine | weight | acid equivalent weight | double |
| | | | | | | unsaturated | atom in all | average | phenol equivalent weight | bond |
| | | carboxylic | | | end | compound | structural | molec- | carboxylic acid | equivalent |
| | | acid | | | capping | esterifying | units | ular | equivalent weight | weight |
| | polymer | derivative | amine derivative | | agent | agent | [mol %] | weight | [g/mol] | [g/mol] |
| Synthesis | polyimide | ODPA | BAHF | SIDA | MAP | — | 40.5 | 27,000 | acid equivalent weight: 330 | — |
| example 1 | (PI-1) | (100) | (85) | (5) | (20) | | | | phenol equivalent weight: | |
| | | | | | | | | | 330 | |
| Synthesis | polyimide | ODPA | BAPF | SIDA | MAP | — | 0.0 | 25,000 | acid equivalent weight: 340 | — |
| example 2 | (PI-2) | (100) | (85) | (5) | (20) | | | | phenol equivalent weight: | |
| | | | | | | | | | 340 | |
| Synthesis | polyimide | ODPA | BAHF | SIDA | MAP | MOI | 40.5 | 30,000 | acid equivalent weight: 500 | 1,400 |
| example 3 | (PI-3) | (100) | (85) | (5) | (20) | (50) | | | phenol equivalent weight: | |
| | | | | | | | | | 500 | |
| Synthesis | polyimide | 6FDA | HA (55) | SIDA | MAP | DFA | 71.7 | 20,000 | acid equivalent weight: 380 | — |
| example 4 | precursor | (100) | BAHF (10) | (5) | (60) | (200) | | | phenol equivalent weight: | |
| | (PIP-1) | | | | | | | | 470 | |
| | | | | | | | | | carboxylic acid equivalent | |
| | | | | | | | | | weight: 1,800 | |
| Synthesis | poly- | ODB-HBT | BAHF | SIDA | NA | — | 43.2 | 27,000 | acid equivalent weight: 460 | — |
| example 5 | benzoxazole | (80) | (95) | (5) | (40) | | | | phenol equivalent weight: | |
| | (PB-1) | | | | | | | | 670 | |
| | | | | | | | | | carboxylic acid equivalent | |
| | | | | | | | | | weight: 1,420 | |
| Synthesis | poly- | ODB-HBT | BAHF | — | NA | — | 45.5 | 22,000 | acid equivalent weight: 260 | — |
| example 6 | benzoxazole | (80) | (100) | | (40) | | | | phenol equivalent weight: | |
| | precursor | | | | | | | | 310 | |
| | (PBP-1) | | | | | | | | carboxylic acid equivalent | |
| | | | | | | | | | weight: 1,530 | |
| Synthesis | polyamide- | TMAC | BAHF | — | NA | — | 45.5 | 25,000 | acid equivalent weight: 280 | — |
| example 7 | imide | (80) | (100) | | (40) | | | | phenol equivalent weight: | |
| | (PAI-1) | | | | | | | | 280 | |
| Synthesis | polyamide- | TMAC | BAHF | — | NA | MOI | 45.5 | 28,000 | acid equivalent weight: 420 | 1,320 |
| example 8 | imide | (80) | (100) | | (40) | (50) | | | phenol equivalent weight: | |
| | (PAI-2) | | | | | | | | 420 | |

TABLE 1-3

| | | | | | | | | acid | | |
|---|---|---|---|---|---|---|---|---|---|---|
| | | | | | | structural | | equivalent | | |
| | | | | | | units having | | weight | carboxylic | double |
| | | | | | | aromatic | weight | (=silanol | acid | bond |
| | | monomer [mol %] | | | | group in | average | equivalent | equivalent | equivalent |
| | | | | | tetrafunctional | polysiloxane | molecular | weight) | weight | weight |
| | polymer | trifunctional organosilane | | | organosilane | [mol %] | weight | [g/mol] | [g/mol] | [g/mol] |
| Synthesis | polysiloxane | MeTMS | PhTMS | cyEpoTMS | TMOS | 50.0 | 4,500 | 360 | — | — |
| example 9 | (PS-1) | (30) | (50) | (10) | (10) | | | | | |

| | | monomer [mole ratio] | | | |
|---|---|---|---|---|---|
| | | polyfunctional | polyfunctional | | unsaturated |
| | | epoxy | carboxylic | carboxylic | carboxylic |
| | polymer | compound | dianhydride | anhydride | acid |
| Synthesis | resin containing | BGPF | ODPA | PHA | MAA |
| example 10 | polycyclic side | (100) | (90) | (20) | (200) |
| | chain (CR-1) | | | | |

| | polyfunctional | | | | |
|---|---|---|---|---|---|
| | carboxylic acid | | | acid equivalent | |
| | derivative structural | | | weight | double |
| | unit having aromatic | weight | phenol | (=carboxylic | bond |
| | group, and carboxylic | average | equivalent | acid equivalent | equivalent |
| | anhydride structural unit | molecular | weight | weight) | weight |
| | [mol %] | weight | [g/mol] | [g/mol] | [g/mol] |
| Synthesis | 100.0 | 4,700 | — | 470 | 470 |
| example 10 | | | | | |

| | | monomer [mole ratio] | | |
|---|---|---|---|---|
| | | | | unsaturated |
| | | polyfunctional epoxy | carboxylic | carboxylic |
| | polymer | compound | anhydride | acid |
| Synthesis | acid-modified | NC-3000-H | THPHA | MAA |
| example 11 | epoxy resin | (epoxy equivalent weight: 290 g/mol) | (0.18 mol) | (0.20 mol) |
| | (AE-1) | (epoxy group based: 0.2 mol) | (mole ratio: 90) | (mole ratio: 100) |
| | | (epoxy group based mole ratio: 100) | | |
| Synthesis | acid-modified | NC-3500 | THPHA | MAA |
| example 12 | epoxy resin | (epoxy equivalent weight: 210 g/mol) | (0.16 mol) | (0.20 mol) |
| | (AE-2) | (epoxy group based: 0.2 mol) | (mole ratio: 80) | (mole ratio: 100) |
| | | (epoxy group based mole ratio: 100) | | |

| | polyfunctional | | | | |
|---|---|---|---|---|---|
| | carboxylic acid | | | acid equivalent | |
| | derivative structural | | | weight | double |
| | unit having aromatic | weight | phenol | (=carboxylic | bond |
| | group, and carboxylic | average | equivalent | acid equivalent | equivalent |
| | anhydride structural unit | molecular | weight | weight) | weight |
| | [mol %] | weight | [g/mol] | [g/mol] | [g/mol] |
| Synthesis | 0.0 | 4,500 | — | 570 | 510 |
| example 11 | | | | | |
| Synthesis | 0.0 | 4,500 | — | 520 | 420 |
| example 12 | | | | | |

| | | monomer [mole ratio] | | | |
|---|---|---|---|---|---|
| | | acidic | aromatic | alicyclic | unsaturated |
| | | copolymerization | copolymerization | copolymerization | compound having |
| | polymer | component | component | component | epoxy group |
| Synthesis | acrylic resin | MAA | BnMA | TCDM | GMA |
| example 13 | (AC-1) | (50) | (45) | (5) | (20) |

| | | | | acid equivalent | |
|---|---|---|---|---|---|
| | structural units | | | weight | double |
| | having aromatic | weight | phenol | (=carboxylic | bond |
| | group in all | average | equivalent | acid equivalent | equivalent |
| | structural units | molecular | weight | weight) | weight |
| | [mol %] | weight | [g/mol] | [g/mol] | [g/mol] |
| Synthesis | 45.0 | 15,000 | — | 540 | 810 |
| example 13 | | | | | |

TABLE 1-4

| | | | | | | | | | acid | |
|---|---|---|---|---|---|---|---|---|---|---|
| | | monomer [mole ratio] | | | | | | | equivalent | |
| | | | | | | | compound | | weight | |
| | | | | | | | having | weight | (=phenol | double bond |
| | | | | | | | unsaturated | average | equivalent | equivalent |
| | | | | aldehyde compound | | | double bond | molecular | weight) | weight |
| | polymer | phenol compound | | bisalkoxymethyl compound | | | group | weight | [g/mol] | [g/mol] |
| Synthesis | phenol resin | XLN | — | SAD | BAD | HAD | — | 4,000 | 130 | — |
| example 14 | (PR-1) | (200) | | (100) | (25) | (75) | | | | |
| Synthesis | phenol resin | MCS | NPDL | — | BAD | HAD | — | 4,500 | 130 | — |
| example 15 | (PR-2) | (30) | (70) | | (75) | (25) | | | | |
| Synthesis | phenol resin | MCS | — | — | — | HAD | — | 3,000 | 120 | — |
| example 16 | (PR-3) | (100) | | | | (100) | | | | |
| Synthesis | phenol resin | MCS | — | SAD | BAD | — | GMA | 3,500 | 150 | 1,190 |
| example 17 | (PR-4) | (100) | | (75) | (25) | | (20) | | | |
| Synthesis | phenol resin | MCS | BPFL | — | BAD | HAD | — | 6,000 | 190 | — |
| example 18 | (PR-5) | (70) | (30) | | (75) | (25) | | | | |

TABLE 1-5

| | | | | | acid | |
|---|---|---|---|---|---|---|
| | | | | | equivalent | |
| | | | | | weight | |
| | | monomer [mole ratio] | | weight | (=phenol | double bond |
| | | hydroxystyrene | styrene | average | equivalent | equivalent |
| | | copolymerization | copolymerization | molecular | weight) | weight |
| | polymer | component | component | weight | [g/mol] | [g/mol] |
| Synthesis | polyhydroxystyrene | HST | STR | 9,500 | 150 | — |
| example 19 | (PHS-1) | (80) | (20) | | | |

| | | | | | | acid | |
|---|---|---|---|---|---|---|---|
| | | | | | | equivalent | |
| | | | | | | weight | |
| | | | | | weight | (=phenol | double bond |
| | | monomer [mole ratio] | | | average | equivalent | equivalent |
| | | polyfunctional epoxy | carboxy group-containing | | molecular | weight) | weight |
| | polymer | compound | phenol compound | | weight | [g/mol] | [g/mol] |
| Synthesis | phenol group | NC-3000-H | DHBA | MHBA | 5,500 | 290 | — |
| example 20 | modified epoxy | (epoxy equivalent weight: | (0.10 mol) | (0.10 mol) | | | |
| | resin | 290 g/mol) | (mole ratio: 50) | (mole ratio: 50) | | | |
| | (PE-1) | (epoxy group based: 0.2 mol) | | | | | |
| | | (epoxy group based mole | | | | | |
| | | ratio: 100) | | | | | |

| | | monomer [mole ratio] | | | | | | | | |
|---|---|---|---|---|---|---|---|---|---|---|
| | | | copoly- | | | | | | acid | |
| | | copoly- | merization | | | | compound | | equivalent | |
| | | merization | component | | | carboxy | having | | weight | double |
| | | component | having | aromatic | alicyclic | group- | unsaturated | weight | (=phenol | bond |
| | | having | phenolic | copoly- | copoly- | containing | double | average | equivalent | equivalent |
| | | epoxy | hydroxyl | merization | merization | phenol | bond | molecular | weight) | weight |
| | polymer | group | group | component | component | compound | group | weight | [g/mol] | [g/mol] |
| Synthesis | phenol group | GMA | — | STR | TCDM | DHBA | — | 13,000 | 310 | — |
| example 21 | modified | (30) | | (50) | (20) | (30) | | | | |
| | acrylic resin | | | | | | | | | |
| | (PAC-1) | | | | | | | | | |
| Synthesis | phenol group | — | HPMA | BnMA | — | — | GMA | 8,000 | 330 | 1,330 |
| example 22 | modified | | (75) | (25) | | | (15) | | | |
| | acrylic resin | | | | | | | | | |
| | (PAC-2) | | | | | | | | | |

For the resin prepared in each Synthesis example and the resin used in each Example, Reference example, and Comparative example, Table 2-1 summarizes the structural units and structures of these resins.

TABLE 2-1

| alkali soluble resin | |
|---|---|
| (A) | structural unit and structure present in alkali soluble resin (A) |
| (PI-1) | structural unit represented by general formula (1); structural unit having fluorine atom |
| (PI-2) | structural unit represented by general formula (1) |
| (PI-3) | structural unit represented by general formula (1); radical polymerizable group: methacryloyl group |
| (PIP-1) | structural unit represented by general formula (3); structural unit having fluorine atom; |
| | In total content of amide acid structural unit, amide acid ester structural unit, amide acid amide |
| | structural unit, and ring-closed imide structural unit, |
| | amide acid ester structural unit accounts for 65 mol %, |
| | amide acid structural unit accounts for 25 mol %, and |
| | ring-closed imide structural unit accounts for 10 mol %. |
| (PB-1) | structural unit represented by general formula (2); structural unit having fluorine atom |
| (PBP-1) | structural unit represented by general formula (4); structural unit having fluorine atom |
| (PAI-1) | structural unit represented by general formula (5); structural unit having fluorine atom |
| (PAI-2) | structural unit represented by general formula (5); structural unit having fluorine atom; radical |
| | polymerizable group: methacryloyl group |
| (PS-1) | structural unit represented by general formula (8); structural unit represented by general formula (9) |
| (CR-1) | condensed polycyclic structure: fluorene structure; radical polymerizable group: methacryloyl group |
| (AE-1) | structure containing at least two directly bonded aromatic ring backbones: biphenyl structure; radical |
| | polymerizable group: methacryloyl group |
| (AE-2) | structure containing at least two directly bonded aromatic ring backbones: biphenyl structure; radical |
| | polymerizable group: methacryloyl group |
| (AC-1) | backbone chain containing acrylic resin structure; radical polymerizable group: methacryloyl group |
| (PR-1) | structural unit represented by general formula (32) |
| (PR-2) | structural unit represented by general formula (35) |
| (PR-3) | structural unit represented by general formula (36) |
| (PR-4) | structural unit represented by general formula (31); radical polymerizable group: methacryloyl group |
| (PR-5) | structural unit represented by general formula (40) |
| (PHS-1) | backbone chain containing polyhydroxystyrene structure |
| (PE-1) | structure containing at least two directly bonded aromatic ring backbones: biphenyl structure |
| (PAC-1) | backbone chain containing acrylic resin structure |
| (PAC-2) | backbone chain containing acrylic resin structure; radical polymerizable group: methacryloyl group |

### <Examples of Preparation of Pigment Dispersions>

Preparation example 1 Preparation of pigment dispersion (Bk-1) A 35.0 g portion of ADP, used as dispersant, and 765.0 g of PGMEA, used as solvent, were weighed, mixed, and stirred for 10 minutes to ensure diffusion, and then 100.0 g of Bk-S0100CF, used as colorant, was weighed, mixed, and stirred for 30 minutes to prepare a preliminary stirred liquid. As a grinding medium, ceramic beads in which the pure content of the complex oxide of the zirconium element and the hafnium element (ZrO₂—HfO₂) is 90 mass % or more were prepared. The preliminary stirred liquid was fed to a vertical type bead mill with the vessel filled with the complex oxide grinding medium (zirconia (ZrO₂)/hafnium oxide (HfO₂)/yttrium oxide (Y₂O₃)/aluminum oxide (Al₂O₃)=93.3/1.5/4.9/0.3 (by mass)), which had a diameter of 0.40 mm, and the first wet media dispersion treatment was performed in a circulation type apparatus at a circumferential speed of 8 m/s for 3 hours. Then, it was fed to a vertical type bead mill with the vessel filled with the complex oxide grinding medium (zirconia (ZrO₂)/hafnium oxide (HfO₂)/yttrium oxide (Y₂O₃)/aluminum oxide (Al₂O₃)=93.3/1.5/4.9/0.3 (by mass)), which had a diameter of 0.05 mm, and the second wet media dispersion treatment was performed in a circulation type apparatus at a circumferential speed of 9 m/s so that the number average particle diameter would be 80 nm. Subsequently, it was filtered through a 0.80 μm filter, and a pigment dispersion (Bk-1) having a solid content of 15 mass % and a pigment/dispersant ratio of 100/35 (by mass) was obtained. The pigment in the resulting pigment dispersion had an average primary particle diameter of 80 nm.

The components of the dispersions prepared in Preparation examples 1 to 7, which are pigment dispersions, are summarized in Table 2-2. In Preparation examples 2 to 7, pigment dispersions were prepared by the same procedure as in Preparation example 1. Here, the surface-coated benzofuranone based black pigment (Bk-CBF1) used in Preparation example 6 was synthesized by a generally known method based on the synthesis method described in Coating example 1 given in paragraph [0503] to paragraph [0505] of International Publication WO 2019/087985. The surface-coated perylene based black pigment (Bk-CPR1) used in Preparation example 7 was synthesized by a generally known method based on the synthesis method described in Example 18 given in paragraph [0186] to paragraph [0188]

and paragraph of International Publication WO 2018/038083. Furthermore, the polyalkylene amine-polyoxyalkylene ether based dispersant (ADP) used in Preparation examples 1 to 7 was synthesized by a generally known method based on the method described in Synthesis example 2 given in paragraph [0138] to paragraph [0141] of Japanese Unexamined Patent Publication (Kokai) No. 2020-070352. Components and features of the colorant (D) and dispersant (E) used in each Example, Reference example, and Comparative example are also summarized in Table 2-2.

TABLE 2-2

| | | | | | | | average primary | average primary |
|---|---|---|---|---|---|---|---|---|
| | | constitution [parts by mass] | | | | | particle diameter in | particle diameter in |
| | pigment | (D) | | | (E) | | pigment dispersion | cured film |
| | dispersion | colorant | | | dispersant | solvent | [nm] | [nm] |
| Preparation | pigment | Bk-S0100CF | — | — | ADP | PGMEA | 80 | 60 |
| example 1 | dispersion | (100) | | | (35) | | | |
| | (Bk-1) | | | | | | | |
| Preparation | pigment | Bk-S0084 | — | — | ADP | PGMEA | 100 | 80 |
| example 2 | dispersion | (100) | | | (35) | | | |
| | (Bk-2) | | | | | | | |
| Preparation | pigment | Bk-FK4280 | — | — | ADP | PGMEA | 100 | 80 |
| example 3 | dispersion | (100) | | | (35) | | | |
| | (Bk-3) | | | | | | | |
| Preparation | pigment | Bk-A1103 | — | — | ADP | PGMEA | 100 | 80 |
| example 4 | dispersion | (100) | | | (35) | | | |
| | (Bk-4) | | | | | | | |
| Preparation | pigment | P.R.179 | P.Y.192 | P.B.60 | ADP | PGMEA | 100 | 80 |
| example 5 | dispersion | (30) | (30) | (40) | (35) | | | |
| | (Bk-5) | | | | | | | |
| Preparation | pigment | Bk-CBF1 | — | — | ADP | PGMEA | 60 | 60 |
| example 6 | dispersion | (100) | | | (35) | | | |
| | (Bk-6) | | | | | | | |
| Preparation | pigment | Bk-CPR1 | — | — | ADP | PGMEA | 80 | 80 |
| example 7 | dispersion | (100) | | | (35) | | | |
| | (Bk-7) | | | | | | | |

| colorant (D) | |
|---|---|
| dispersant (E) | Description of colorant (D), description of dispersant (E) |
| Bk-S0100CF | mixture of compound represented by general formula (161) and compound represented by general formula (162); |
| | IRGAPHOR (registered trademark) BLACK S0100CF |
| | (manufactured by BASF; benzofuranone based black pigment with primary particle diameter of 40 to 80 nm) |
| Bk-S0084 | compound represented by general formula (164); PALIOGEN (registered trademark) BLACK S0084 |
| | (manufactured by BASF; perylene based black pigment with primary particle diameter of 50 to 100 nm) |
| Bk-FK4280 | mixture of compound represented by general formula (165) and compound represented by general formula (166); |
| | LUMOGEN” (registered trademark) BLACK FK4280 |
| | (manufactured by BASF; perylene based black pigment with primary particle diameter of 50 to 100 nm) |
| Bk-A1103 | compound represented by general formula (168); CHROMOFINE (registered trademark) BLACK A1103 |
| | (manufactured by Dainichiseika Colour & Chemicals Mfg. Co., Ltd.; azo based black pigment with primary particle |
| | diameter of 50 to 100 nm) |
| P.R.179 | C.I. pigment red 179 (perylene based red pigment) |
| P.Y.192 | C.I. pigment yellow 192 (imidazolone based yellow pigment) |
| P.B.60 | C.I. pigment blue 60 (indanthrone based blue pigment) |
| Bk-CBF1 | mixture of compound represented by general formula (161) and compound represented by general formula (162); |
| | surface coated benzofuranone based black pigment ((DC-1) silica coated layer: silica (SiO₂-based content 10.0 |
| | parts by mass relative to 100 parts by mass of black pigment); (DC-2) metal oxide coated layer: alumina (Al₂O₃- |
| | based content 2.0 parts by mass relative to 100 parts by mass of black pigment); coated layer's average coating |
| | rate 97.5% in black pigment) |
| Bk-CPR1 | mixture of compound represented by general formula (165) and compound represented by general formula (166); |
| | surface coated perylene based black pigment ((DC-1) silica coated layer: silica + silica ((DC-1) two silica coated |
| | layers; |
| | SiO₂-based content 3.0 + 7.0 parts by mass relative to 100 parts by mass of black pigment); |
| | coated layer's average coating rate 84.5% in black pigment) |
| ADP | tertiary amino group, structure represented by general formula (26), structure represented by general formula (29), |
| | and dispersant having basic group (E1) having polyoxyalkylene structure (amine value: 20 mgKOH/g (solid |
| | content: 100 mass %)) |
| A.R.52 | C.I. acid red 52 (xanthene based red dye) |
| B.B.7 | C.I. basic blue 7 (triarylmethane based blue dye) |
| S.R.18 | C.I. solvent red 18 (azo based red dye) |
| D.Y.201 | C.I. disperse yellow 201 (methine based yellow dye) |

### Synthesis Example 23 Synthesis of Silica Particle (SP-1) Dispersion

In a three-neck flask, 104.5 g of MEK, used as solvent, 142.5 g of MEK-ST-40, used as silica particle dispersion containing the sodium element, and 0.01 g of MOP, used as polymerization inhibitor, were weighed, added, mixed, and stirred for 10 minutes, followed by heating the liquid to a temperature of 50° C. Then, a solution prepared by dissolving 3.0 g of KBM-503, used as surface modifier, in 50.0 g of MEK was added dropwise over 10 minutes. After the end of dropping, stirring was performed at 50° C. for 2 hours to dehydrate and condense the surface modifier. After the reaction, the reaction solution was cooled to room temperature to provide a silica particle (SP-1) dispersion. The resulting silica particle (SP-1) had a surface modification group containing a methacryloyl group as a radical polymerizable group.

Components and features of the silica particles used in each Example, Reference example, and Comparative example are summarized in Table 2-3. Here, for the dispersion (MSiP-1) of the silica particles (SP-2), MEK-ST-40 was used as silica particle dispersion containing the sodium element while KBM-13 was used as surface modifier. Without using MOP as polymerization inhibitor, silica particles having a surface modification group containing a methylsilyl group were synthesized and used. For the dispersion (MSiP-2) of the silica particles (SP-3), MEK-ST-L was used as silica particle dispersion containing the sodium element while KBM-13 was used as surface modifier. Without using MOP as polymerization inhibitor, silica particles having a surface modification group containing a methylsilyl group were synthesized and used.

TABLE 2-3

| | | physical properties of silica particles | | | | |
|---|---|---|---|---|---|---|
| | | distribution range of | average primary | | | |
| silica | silica particle | primary particle diameter | particle diameter | range of | average | content of |
| particles | dispersion | [nm] | [nm] | aspect ratio | aspect ratio | sodium element |
| SP-1 | Synthesis example 23 | 10 to 16 | 12 | 1.0 to 1.1 | 1.1 | 100 mass ppm |
| SP-2 | MSiP-1 | 10 to 15 | 12 | 1.0 to 1.1 | 1.1 | 100 mass ppm |
| SP-3 | MSiP-2 | 20 to 60 | 40 | 1.0 to 1.2 | 1.2 | 100 mass ppm |

### <Evaluation Methods Used in Examples, Reference Examples, and Comparative Examples>

The evaluation methods used in each Example, Reference example, and Comparative example are described below.

### (1) Weight Average Molecular Weight of Resin

Using a GPC analysis apparatus (HLC-8220; manufactured by Tosoh Corporation) and tetrahydrofuran or N-methyl-2-pyrrolidone as fluidized bed, the polystyrene based weight average molecular weight was determined according to JIS K7252-3 (2008) from measurements taken around room temperature.

### (2) Acid Equivalent Weight

Using an automatic potentiometric titration apparatus (AT-510; manufactured by Kyoto Electronics Manufacturing Co., Ltd.) along with a 0.1 mol/L sodium hydroxide/ethanol solution as titration reagent and a 1/1 (by mass) xylene/N, N-dimethyl formamide mixture as titration solvent, the acid values (in mgKOH/g) of the phenolic hydroxyl group and the carboxyl group were determined by potentiometric titration method according to JIS K2501 (2003). From the measured acid values of the phenolic hydroxyl group and the carboxyl group, the acid equivalent weights (in g/mol) of the phenolic hydroxyl group and the carboxyl group were calculated.

Here, the acid equivalent weight of the silanol group was calculated by the procedure described below. The silanol group was acetylated in a reaction using acetic anhydride as acetylating agent, imidazole and N,N′-dimethylaminopyridine as catalysts, and N,N-dimethylformamide as solvent. The potentiometric titration method was performed in the same way to measure the silanol value (in mgKOH/g). The measured silanol value was used to calculate the acid equivalent (weight in g/mol) of the silanol group.

### (3) Double Bond Equivalent Weight

Using an automatic potentiometric titration apparatus (AT-510; manufactured by Kyoto Electronics Manufacturing Co., Ltd.) along with an iodine monochloride solution (mixed solution of 7.9 g of iodine trichloride, 8.9 g of iodine, and 1,000 mL of acetic acid) as iodine supply source, 100 g/L of an aqueous potassium iodide solution as aqueous solution for capturing unreacted iodine, and 0.1 mol/L of an aqueous sodium thiosulfate solution as titration reagent, the iodine value of the resin was determined by the Wijs method according to “Item 6: Iodine Value” of JIS K0070 (1992) “Test Method for Acid Value, Saponification Value, Ester Value, Iodine Value, Hydroxyl Value, and Unsaponifiable Components of Chemical Products”. The measured iodine value (in gl/100 g) was used to calculate the double bond equivalent weight (in g/mol).

### (4) Average Primary Particle Diameter of Pigment in Pigment Dispersion

The median diameter (D50) was measured using a dynamic light scattering particle diameter distribution analyzer (SZ-100; manufactured by Horiba Ltd.) under the conditions of a laser wavelength of 532 nm, use of PGMEA as dilution solvent, a dilution ratio of 250 times (by mass), a solvent viscosity of 1.25, a solvent refractive index of 1.40, a measuring temperature of 25° C., a measuring mode of scattered light, and operation conditions set to “polydisperse” and “broad”. Two measurements were taken and their average was adopted as the average primary particle diameter of the pigment in the pigment dispersion.

### (5) Pre-Treatment of Substrate

The glass substrate used (manufactured by Geomatec Co., Ltd.; hereinafter referred to as ITO/Ag substrate) included a 100 nm film of APC (silver/palladium/copper=98.07/0.87/1.06 (by mass)) formed on a glass plate by sputtering and a 10 nm film of ITO formed by sputtering on the APC layer, and it was cleaned before use by subjecting it to UV-O₃ cleaning treatment for 100 seconds using a desktop type optical surface treatment apparatus (PL16-110; manufactured by Sen Lights Co., Ltd.). Tempax glass substrates (manufactured by AGC Techno Glass Co., Ltd.) were used without pretreatment.

### (6) Measurement of Film Thickness

A surface roughness/contour form measuring machine (SURFCOM 1400D, manufactured by Tokyo Seimitsu Co., Ltd.) was used for the measurement of film thickness under the conditions of a measuring magnification of 10,000 times, a measuring length of 1.0 mm, and a measuring speed of 0.30 mm/s.

### (7) Light Blocking Efficiency (Optical Density Value (Hereinafter Referred to as OD Value))

According to the method described in Example 1 given below, a cured film of a photosensitive composition was prepared on a Tempax glass substrate. A transmission density measuring device (X-Rite 361T (V); manufactured by X-Rite) was used to measure the incident light intensity (I₀) and transmitted light intensity (I) at three surface points on the cured film prepared above. As an indicator of light blocking efficiency, the OD value per μm of film thickness was calculated by the equation given below, and the average of the OD values measured at three surface points was calculated.

OD value=log₁₀(I₀/I)

(8) Ion Detection Intensity at 3 nm Depth from Surface of First Electrode

In an organic EL display produced by the method described in Example 1 given below, the ion detection intensity was measured by time-of-flight secondary ion mass spectrometry. An etching ion species accelerated by applying a bias is allowed to collide against a pixel part through the light emitting layer. An etching ion species accelerated by applying a bias is allowed to collide through the light emitting layer while etching is performed in the depth direction toward the first electrode. Secondary ions released at this time were observed to measure the depth profile in the depth direction from the light emitting layer toward the first electrode. In the depth profile, the point where the detection intensity of ion species of the elements present in the first electrode reached 100 or more was assumed to represent the surface of the first electrode. Here, in the case where a transparent conductive oxide film layer containing indium as the main constituent element was present as the outermost layer of the first electrode that faced the light emitting layer, the point where the detection intensity of the indium oxide ion (InO₂⁻) reached 100 or more was assumed to represent the surface of the first electrode. In addition, the position at 3 nm depth from the surface of the first electrode was identified by measuring the depth profile starting from the surface of the first electrode in contact with the organic layer containing a light emitting layer toward the interior of the first electrode and finishing at the bottom of the first electrode while measuring the thickness of the first electrode, followed by calculating the sputter rate of the first electrode from the above measurements. The measuring conditions used for time-of-flight secondary ion mass spectrometry were as described below. To determine the detection intensity of each ion, three measurements of time-of-flight secondary ion mass spectrometry were taken and their average was calculated.

### <Measuring Conditions>

Equipment: time-of-flight secondary ion mass spectrometer (TOF.SIMS5; manufactured by ION-TOF)
Etching ion species: Cs⁺
Etching ion acceleration energy: 0.25 keV
Etching ion current: 7 nA
Etching area: 150 μm
Measuring area: 30 μm
Number of pixels: 128×128 pixels
Primary ion species: Bi⁺
Primary ion energy: 25 keV
Primary ion current: 0.6 pA (cycle time: 50 μs)
Secondary ion polarity: negative
Mass resolution: high
Charge compensation: E-gun

### (9) Ratio of Ion Detection Intensity to Total Anion Detection Intensity on Surface of Pixel Separation Layer Part and Ratio of Ion Detection Intensity to Total Anion Detection Intensity on Surface of First Electrode

In an organic EL display produced by the method described in Example 1 given below, the ion detection intensity was measured by time-of-flight secondary ion mass spectrometry. The primary ion species accelerated by applying a bias was collided against the surface of the pixel separation layer part, and the secondary ions released at this time were examined. Similarly, the primary ion species accelerated by applying a bias was collided against the surface of the first electrode that was in a pixel part and in contact with the organic layer containing a light emitting layer, and the secondary ions released at this time were examined. The measuring conditions used for time-of-flight secondary ion mass spectrometry were as described below.

### <Measuring Conditions>

Equipment: time-of-flight secondary ion mass spectrometer (TOF.SIMS5; manufactured by ION-TOF)
Measuring area on surface of pixel separation layer part: 100 μm Measuring area on surface of transparent conductive oxide film layer: 50 μm
Number of scans: 8
Number of pixels: 256×256 pixels
Vacuum degree for measurement: 4×10⁻⁷ Pa (4×10⁻⁹ mbar) or less
Primary ion species: Bi₃⁺⁺
Primary ion accelerating voltage: 25 kV
Primary ion current: 0.1 pA (cycle time: 140 μs)
Pulse width: 13.3 ns
Bunching: enabled (high mass resolution)
Static neutralization: none
Post-acceleration: 10 kV

(10) Emission Characteristics of Light Emitting Element (Low Voltage Driving Characteristics, Light Emission Luminance, and Reliability of Light Emitting Element)

### <Low Voltage Driving Characteristics and Light Emission Luminance Evaluation (Current Density —Voltage Characteristics Evaluation)>

An organic EL display produced by the method described in Example 1 given below was caused to emit light by driving it with a direct current. The applied voltage was raised from a low value incrementally until the current density reached 30 mA/cm². The voltage and current density were plotted as the voltage was raised incrementally, and the drive voltage at a point where the current density reached 10 mA/cm² was determined to serve as an indicator of low voltage driving characteristics and light emission luminance. Evaluations were made as described below, and samples rated as A+, A, B+, B, C+, or C, which were able to be driven at voltages of 4.5 V or less, were judged to be acceptable.
A+: drive voltage 3.2 V or less
A: drive voltage more than 3.2 V and 3.5 V or less
B+: drive voltage more than 3.5 V and 3.7 V or less
B: drive voltage more than 3.7 V and 4.0 V or less
C+: drive voltage more than 4.0 V and 4.2 V or less
C: drive voltage more than 4.2 V and 4.5 V or less
D: drive voltage more than 4.5 V and 5.5 V or less
E: drive voltage more than 5.5 V or unmeasurable

### <Evaluation of Reliability of Light Emitting Element>

An organic EL display produced by the method described in Example 1 given below was caused to emit light by driving it with a direct current of 10 mA/cm² and observed to check for non-emitting regions or light emission failures such as uneven brightness. For durability test, a light emitting element was placed with the light extraction side facing up, heated to 80° C., irradiated with light having a wavelength of 365 nm and an intensity of 0.6 mW/cm², and maintained for 500 hours. After the 500 hour period, the organic EL display was caused to emit light by driving it with a direct current of 10 mA/cm² and observed to check for changes in light emission characteristics. As an indicator of the reliability of the light emitting element, the light emitting region area after the durability test was measured relative to the initial light emitting region area, which accounts for 100%, measured before the durability test. Evaluations were made as described below, and samples rated as A+, A, B+, B, C+, or C, which had a light emitting region area of 80% or more, were judged to be acceptable.
A+: having a light emitting region area of 100%
A: having a light emitting region area of 97% or more and less than 100%
B+: having a light emitting region area of 94% or more and less than 97%
B: having a light emitting region area of 90% or more and less than 94%
C+: having a light emitting region area of 85% or more and less than 90%
C: having a light emitting region area of 80% or more and less than 85%
D: having a light emitting region area of 60% or more and less than 80%
E: having a light emitting region area of less than 60%<

### Compounds Used in Examples, Reference Examples, and Comparative Examples

Components and features of the compound (F1) used in each Example, Reference example, and Comparative example are summarized in Table 2-4. Components and features of the surface active agent and ink repellent agent used in each Example, Reference example, and Comparative example are also summarized in Table 2-4.

TABLE 2-4

| | physical properties of compound (F1) | | | | | |
|---|---|---|---|---|---|---|
| | | | | | carbon atoms | carbon atoms |
| | | | acidic group | (I-f1) structure | contained and | contained and |
| compound | name of | | containing | (II-f1) structure | number of | number of |
| (F1) | compound | type of compound | phosphorus atom | present in compound (F1) | aliphatic groups | oxyalkylene groups |
| f-1 | n-octyl | aliphatic containing | phosphonic | n-octyl group | carbon atoms | — |
| | phosphonic | phosphonic acid | acid group | | contained: 8 | |
| | acid | | | | number: 1 | |
| f-2 | [lauryl- | phosphoric acid | phosphoric | lauryl group | carbon atoms | carbon atoms |
| | bis(oxyethylene)] | monoester | acid group | oxyethylene group | contained: 12 | contained: 2 |
| | phosphate | compound | | | number: 1 | number: 2 |

| surface active | |
|---|---|
| agent ink | |
| repellent agent | Description of surface active agent, description of ink repellent agent |
| SFT-1 | silicone based surface active agent having siloxane bond-containing structure (c) (backbone chain containing |
| | polydimethyl siloxane structure having 2 or more dimethyl siloxane bonds) and silyl group-containing structure |
| | (b) (side chain having two terminal structures containing trimethyl silyl groups and polyoxyalkylene structure) |
| SFT-2 | acrylic resin based surface active agent having fluorine-containing structure (a) (backbone chain containing |
| | acrylic resin structure, and side chain containing alkyl group with 2 or more fluorine atoms and alkylene group |
| | with 2 or more fluorine atoms) |
| RS-72-K | acrylic resin based surface active agent having fluorine-containing structure (a) (backbone chain containing |
| | acrylic resin structure, and side chain containing alkyl group with 2 or more fluorine atoms and alkylene group |
| | with 2 or more fluorine atoms) and side chain containing acryloyl group as radical polymerizable group; Megafac |
| | (registered trademark) RS-72-K (manufactured by DIC) |

A list of components and abbreviations used in Examples, Reference examples, and Comparative examples is given in Table 2-5. In addition, the structures of the compounds (b-1) to (b-7), (c-1) to (c-4), (f-1) and (f-2), (g-1) to (g-5), (v-1), and (NQD-1) used in Examples, Reference examples, and Comparative examples are shown below.

It should be noted that the compounds (s-1) and (s-2) are included in the glycol ether compounds having specific structures described above. The compound (v-1) is included in the polyoxyalkylene ether compounds described above and had a hydrophobic structure (a) (a phenyl group with 6 carbon atoms bonded to two ethylene groups with 2 carbon atoms having a phenyl group with 6 carbon atoms) and a hydrophilic structure (b) (twelve oxyethylene group with 2 carbon atoms), and a hydrophilic group (a hydroxy group bonded to the oxyethylene group). The compound (w-1) is included in the ink repellent agents described above. In addition, the compound (d-8) is a dye prepared by mixing and stirring A.R.52 and B.B.7 at a ratio of 1/1 (by mol), filtering the precipitated salt, washing it three times with water, and drying it. Furthermore, the compounds (u-1b) and (u-2b) are hafnium oxide and yttrium oxide, which are different from the components derived from pigment dispersions and were added separately.

TABLE 2-5

| Abbreviation | Name of substance | Abbreviation | Name of substance | Abbreviation | Name of substance |
|---|---|---|---|---|---|
| (d-1) | Bk-S0100CF | (S-1) | hexane thiol | (p-1) | pure water |
| (d-2) | Bk-S0084 | (S-2) | octane thiol | (q-1) | sodium dodecanoate |
| (d-3) | Bk-FK4280 | (S-3) | dodecane thiol | (q-2) | potassium dodecanoate |
| (d-4) | Bk-A1103 | (S-4) | benzyl thiol | (q-3) | magnesium dodecanoate |
| (d-5) | P.R.179 | (S-5) | 8-mercaptooctyl trimethoxysilane | (q-4) | calcium dodecanoate |
| | P.Y.192 | (S-6) | dioctyl sulfide | (r-1) | benzene |
| | P.B.60 | | | | |
| (d-6) | Bk-CBF1 | (S-7) | octanesulfonic acid | (r-2) | toluene |
| (d-7) | Bk-CPR1 | (S-I-1) | bis(butyltriethyl ammonium) sulfide | (r-3) | xylene |
| (d-8) | A.R.52-B.B.7 | (S-I-2) | bis(octyltriethyl ammonium) sulfide | (r-4) | naphthalene |
| (d-9) | S.R.18 | (S-I-3) | bis(benzyltriethyl ammonium) sulfide | (s-1) | 2-methoxy-1-propanol |
| (d-10) | D.Y.201 | (S-I-4) | bis(butyltriethyl ammonium) sulfate | (s-2) | 2-methoxy-1-propanol acetate |
| (e-1) | ADP | (CI-1) | octyl chloride | (t-1) | SFT-1 |
| — | — | (CI-2) | dodecyl chloride | (t-2) | SFT-2 |
| — | — | (CI-3) | benzyl chloride | (u-1) | hafnium oxide (derived from |
| | | | | | pigment dispersion) |
| — | — | (Br-1) | octyl bromide | (u-2) | yttrium oxide (derived from |
| | | | | | pigment dispersion) |
| — | — | (Br-2) | dodecyl bromide | (u-1b) | hafnium oxide (added separately) |
| — | — | (Br-3) | benzyl bromide | (u-2b) | oxidized yttrium (added separately) |
| — | — | (CI-1-1) | butyltriethyl ammonium chloride | (w-1) | RS-72-K |
| — | — | (CI-1-2) | octyltriethyl ammonium chloride | — | — |
| — | — | (CI-1-3) | benzyltriethyl ammonium chloride | — | — |
| — | — | (Br-1-1) | butyltriethyl ammonium bromide | — | — |
| — | — | (Br-1-2) | octyltriethyl ammonium bromide | — | — |
| — | — | (Br-1-3) | benzyltriethyl ammonium bromide | — | — |

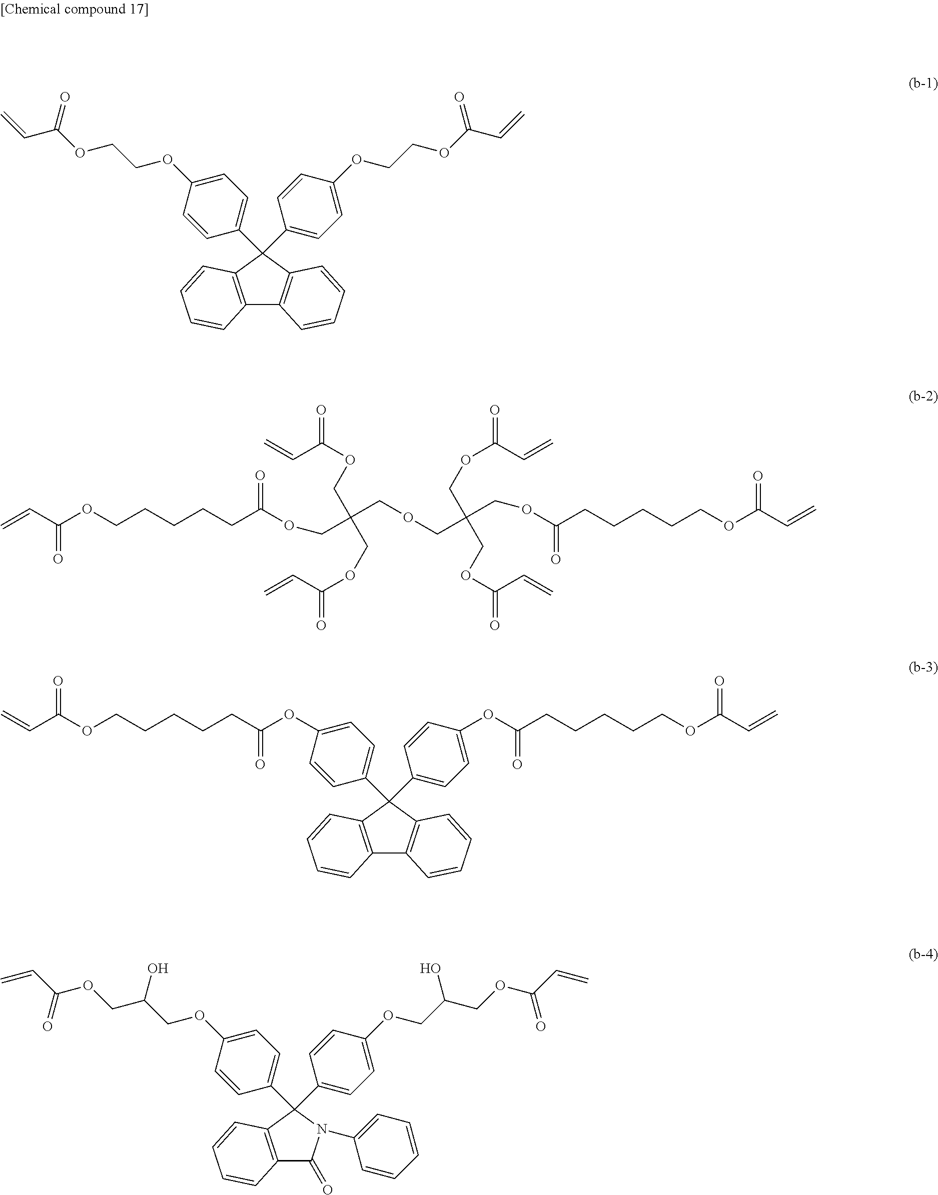

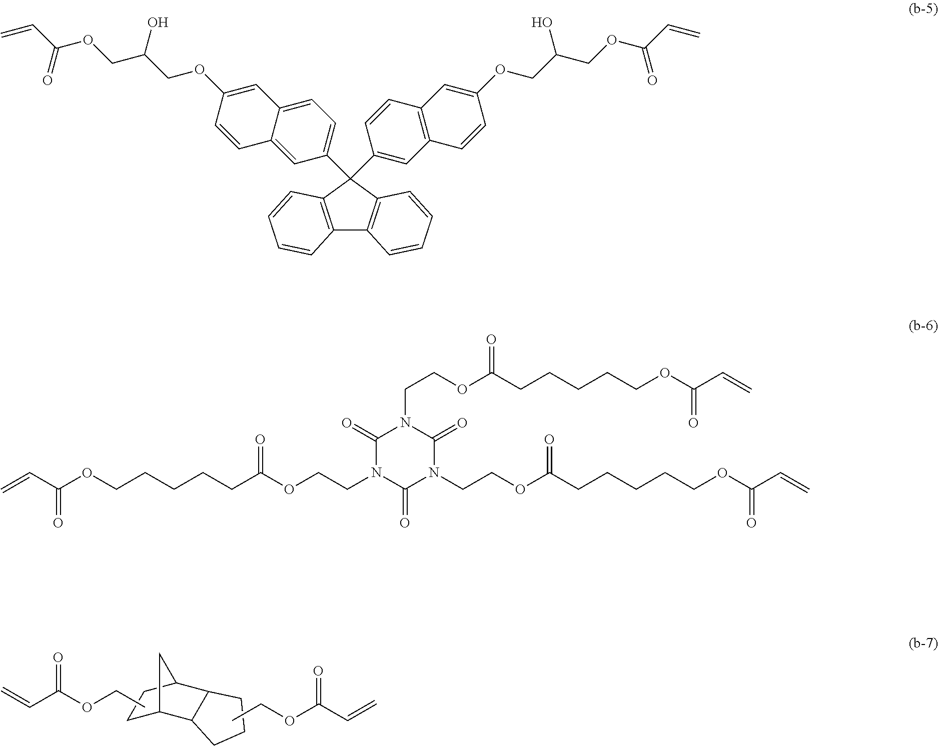

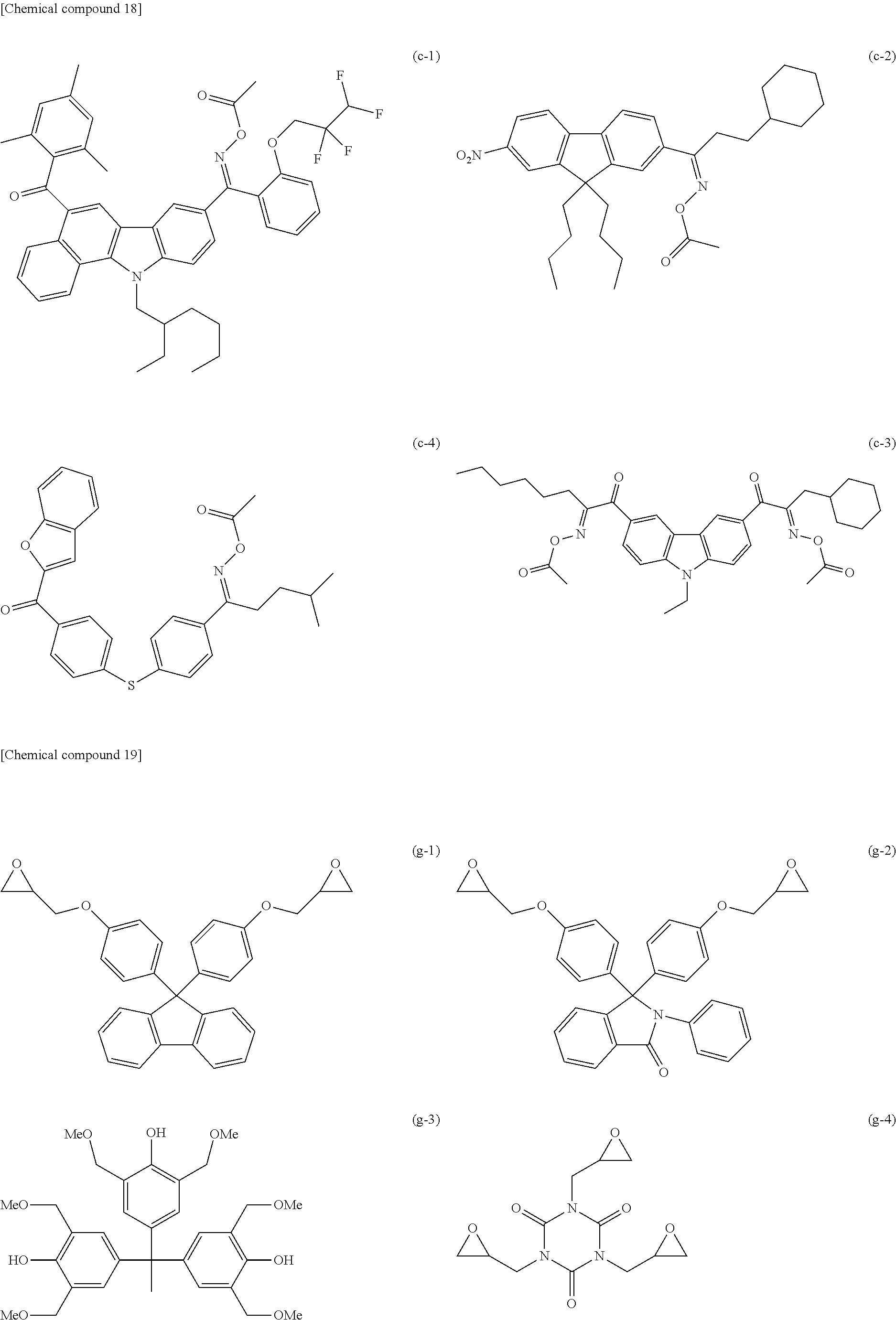

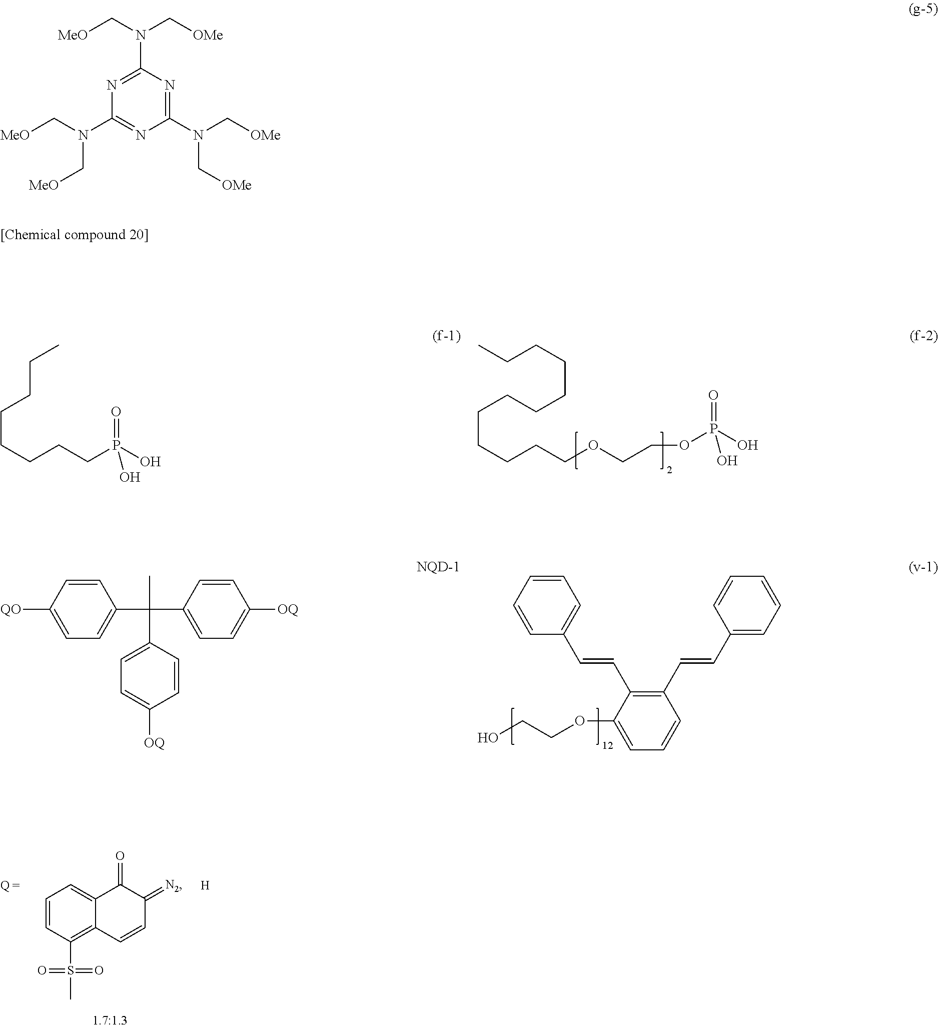

### Example 1

A photosensitive composition 1 was prepared using the components specified in Table 3-1. First, a formulation solution devoid of the colorant (D) was prepared, and then a pigment dispersion and the formulation solution were mixed to provide a photosensitive composition. Using a PGMEA/EDM/MBA mixture blended at a ratio of 70/20/10 (by mass) as solvent, the solid content of the photosensitive composition was adjusted to about 15 mass %. The resulting solution of the photosensitive composition was filtered through a 0.45 μm filter before use.

Here, the amount of the compound (I) added was adjusted appropriately so that the content of each element such as the sulfur element and the content of each ion such as sulfide ion in the photosensitive composition would be as specified in Table 3-1. Similarly, the content of water (hereinafter referred to as “water content”), the content of the sodium element etc., the content of benzene etc., the content of the glycol ether compound of a specific structure, the content of the surface active agent, the content of the polyoxyalkylene ether compound, and the content of the ink repellent were adjusted so that the constitution would be as specified in Table 3-1. Here, the hafnium oxide and yttrium oxide were components derived from the pigment dispersion, and accordingly, the contents of the hafnium element and the yttrium element were also attributed to the pigment dispersion.

In a similar way, a photosensitive composition X¹ was prepared using the components specified in Table 2-6.

TABLE 2-6

| | components | | | | | | | |
|---|---|---|---|---|---|---|---|---|
| | | resin (A1) | | | | S/Cl/Br etc. | | |
| | | resin (A2) | | | | elements and | other | |
| | | resin (A3) | | | | ions in | elements and | |
| | | (content/ | photosensitizer (C) | | compound (I) | composition | compounds in | |
| | pigment | parts by | (content/parts by | crosslinking agent (G) | other | (content/ | composition | solvent |
| | dispersion | mass) | mass) | (content/parts by mass) | compounds | mass ppm) | (content) | (mass ratio) |
| composition | — | PI-1 (40) | NQD-1 (20) | g-3 (3) | S-2 | S element | water content | PGMEA/EDM/ |
| X1 | | AE-1 (30) | | v-1 (1) | Cl-1 | (630) | (1.0 mass %) | MBA = |
| | | PR-1 (30) | | | p-1 | Cl element | surface active | 70/20/10 |
| | | | | | t-1 | (3) | agent | |
| | | | | | v-1 | | (200 mass ppm) | |
| | | | | | | | v-1 | |
| | | | | | | | (1,210 mass ppm) | |

### <Preparation of Cured Film of Photosensitive Composition>

First, the method used for producing cured films of photosensitive compositions is described below. The photosensitive composition 1 prepared above was spread on an ITO/Ag substrate by spin coating using a spin coater (MS-A100; manufactured by Mikasa Co., Ltd.) at an appropriate rotating speed, and then it was prebaked on a hot plate equipped with a buzzer (HPD-3000BZN; manufactured by AS ONE Corporation) at 120° C. for 120 seconds to produce a prebaked film having a thickness of about 1.8 μm. The prebaked film produced above was subjected to spray development with a 2.38 mass % aqueous TMAH solution using a small type development apparatus for photolithography (AD-1200; manufactured by Takizawa Sangyo Co., Ltd.) and the time period required for complete dissolution of the prebaked film (unexposed portions) (breaking point; hereinafter referred to as BP) was measured.

Another prebaked film was prepared by the same procedure as above, and then a double side alignment type single side exposure device (Mask Aligner PEM-6M; manufactured by Union Optical Co., Ltd.) was used to apply i-line (wavelength 365 nm), h-line (wavelength 405 nm), and g-line (wavelength 436 nm) beams emitted from an ultrahigh pressure mercury lamp to the resulting prebaked film through a gray scale mask designed for sensitivity measurement (MDRM MODEL 4000-5-FS; manufactured by Opto-Line International), thereby forming a light-exposed pattern. After the light exposure step, a small type development apparatus for photolithography (AD-1200; manufactured by Takizawa Sangyo Co., Ltd.) was used to develop the film with a 2.38 mass % aqueous TMAH solution, followed by rinsing with water for 30 seconds to provide a developed film of the photosensitive composition 1. The development time used was 1.3 times as long as the measured BP. The developed pattern was observed to determine the optimum exposure dose (reading on i-line illumination photometer) to form a 18 μm wide space pattern, which corresponds to the opening part, in a 20 μm line-and-space pattern. After light exposure with the optimal exposure dose, the developed pattern was heat-cured at 250° C. in a high temperature inert gas oven (INH-9CD-S; manufactured by Koyo Thermo Systems Co., Ltd.) to provide a cured film of the photosensitive composition 1 having a film thickness of about 1.2 μm. The heat-curing conditions used included heating to 250° C. at a heating rate of 3.5° C./min in a nitrogen atmosphere with an oxygen concentration of 20 mass ppm or less, subsequent heat treatment at 250° C. for 60 minutes, and cooling to 50° C.

The cured film was analyzed by means of nuclear magnetic resonance spectroscopy, infrared spectroscopy, time-of-flight secondary ion mass spectrometry, etc., to determine the structural units and compounds of resins present in the cured film. It was confirmed that the cured film produced by curing the photosensitive composition 1 by the procedure described above contained the resins and compounds specified below. Specifically, the cured film produced by curing the photosensitive composition 1 contained compounds having structures derived from the components initially present in the photosensitive composition 1. Resin (A1-DL): a resin having a structural unit as represented by the general formula (1) Resin (A2-DL): an acid modified epoxy resin having a structural unit as represented by the general formula (24) and a biphenyl structure
Resin (A3-DL): a resin having a structural unit as represented by the general formula (32) Compound (C1x-DL): a compound having a benzocarbazole structure, with an imino group bonded to the benzocarbazole structure
Colorant (D-DL): a compound having a benzofuranone based black pigment and a structure as represented by the general formula (161)
Compound having phosphoric acid based structure: a compound having a phosphonate structure
Compound (G2-DL): a compound having a 1,1,1-tris(4-hydroxyphenyl) propane structure Compound (I1a-DL): a compound having a thiol structure containing a monovalent octyl group having 8 carbon atoms
Compound (I2a-DL): a compound having an alkyl chloride structure containing a monovalent octyl group having 8 carbon atoms

### <Preparation of Organic EL Display (Including Pixel Separation Layer Part and Spacer Layer Part)>

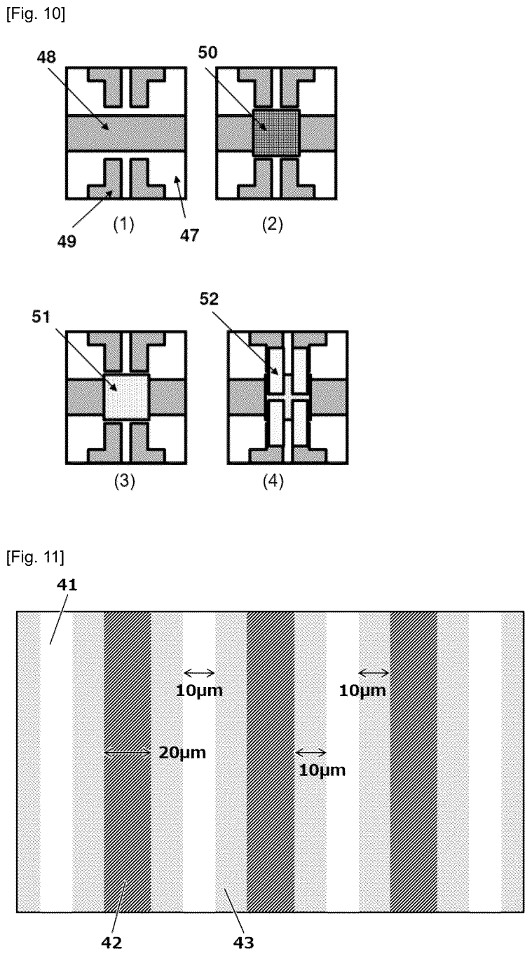

Next, described below is the method for producing an organic EL display. FIG. 10 shows a schematic diagram of the substrate used. First, APC (silver/palladium/copper=98.07/0.87/1.06 (by mass)) was sputtered to a thickness of 100 nm to form a non-transparent conductive metal layer on a non-alkali glass substrate 47 with a size of 38×46 mm and patterned by etching to form an APC layer. In addition, an amorphous ITO was sputtered to a thickness of 10 nm to form a transparent conductive oxide layer on the APC layer and etched to form a reflective electrode as the first electrode part 48. An auxiliary electrode part 49 to serve for the extraction of a second electrode was also formed simultaneously (FIG. 10 (step 1)). The resulting substrate was subjected to ultrasonic cleaning for 10 minutes using Semico Clean (registered trademark) 56 (manufactured by Furuuchi Chemical Corporation) and then rinsed with ultrapure water. Then, the photosensitive composition 1 was spread and prebaked on this substrate by the procedure described above and patterned by light exposure through a photomask having a predetermined pattern, followed by development, rinsing, and heating for heat-curing. The optimum exposure dose was applied, and development was performed for a period 1.3 times as long as BP. The heat-curing conditions used included heating to 250° C. at a heating rate of 3.5° C./min in a nitrogen atmosphere with an oxygen concentration of 20 mass ppm or less, subsequent heat treatment at 250° C. for 60 minutes, and cooling to 50° C. In this way, a pixel separation layer part 50 on which square opening parts, each with a width of 70 μm and a length of 70 μm, were aligned at intervals of 175 μm in the width direction and 175 μm in the length direction, wherein the first electrode was exposed in each opening part, was formed in a limited effective area of the substrate (FIG. 10 (step 2)). These opening parts would finally form light emitting pixels of an organic EL display. The limited effective area of the substrate had a square shape with a size of 16 mm×16 mm, and the pixel separation layer part 50 had a thickness of about 1.5 μm.

In addition, on top of the substrate that had the pixel separation layer part 50 formed thereon, the photosensitive composition X¹ specified in Table 2-6 was spread and prebaked by the procedure described above, and then it was patterned by light exposure through a photomask having a predetermined pattern, followed by development, rinsing, and heating for heat-curing. Here, the development time was 60 seconds, and light exposure was performed to a previously measured optimal exposure dose. Furthermore, the heat-curing conditions used included heating to 200° C. at a heating rate of 3.5° C./min in a nitrogen atmosphere with an oxygen concentration of 20 mass ppm or less, subsequent heat treatment at 200° C. for 60 minutes, and cooling to 50° C. In this way, spacer layer parts, each having a square shape with a size of 35 μm width and 35 μm length, were formed at multiple locations not adjacent to the opening parts on the pixel separation layer part 50. The spacer layer parts had thicknesses of about 1.5 μm.

Then, an organic EL display was produced using the substrate, which had a first electrode part 48, auxiliary electrode part 49, pixel separation layer part 50, and spacer layer parts formed thereon. After carrying out nitrogen plasma treatment as a pre-treatment step, an organic EL layer part 51 containing a light emitting layer was formed by vacuum deposition (FIG. 10 (step 3)). Here, the degree of vacuum used for vapor deposition was 1×10⁻³ Pa or less, and the substrate was rotated relative to the deposition source during the vapor deposition step. First, a compound (HT-1) was deposited to a thickness of 10 nm to form a hole injection layer and a compound (HT-2) was deposited to a thickness of 50 nm to form a hole transport layer. Then, a compound (GH-1) and the compound (GD-1) were deposited as host material and dopant material, respectively, on the light emitting layer to a thickness of 40 nm to ensure a doping concentration of 10 vol %. Subsequently, as electron transport materials, the compound (ET-1) and the compound (LiQ) were deposited with a ratio of 1:1 by volume to a thickness of 40 nm. Here, the compounds used in the organic EL layer (i.e., compound (HT-1), compound (HT-2), compound (GH-1), compound (GD-1), compound (ET-1), and compound (LiQ)) were the same compounds as described in paragraph to paragraph of International Publication WO 2017/057281.

Then, after depositing the compound (LiQ) to a thickness of 2 nm, MgAg (magnesium/silver=10/1 (by volume)) was deposited to a thickness of 10 nm to form a second electrode 52, thereby providing a transparent electrode (FIG. 10 (step 4)). Subsequently, in a low humidity nitrogen atmosphere, a cap-shaped glass plate was adhered with an epoxy resin based adhesive to ensure sealing, thus producing four 5 mm×5 mm top emission type organic EL displays on one substrate. It should be noted that the film thickness referred to here is the reading on a crystal oscillation type film thickness monitor.

The spacer layer parts were analyzed by means of nuclear magnetic resonance spectroscopy, infrared spectroscopy, time-of-flight secondary ion mass spectrometry, etc., to determine the structural units and compounds of resins present in the spacer layer parts. It was confirmed that the spacer layer parts produced by curing the photosensitive composition X¹ by the procedure described above contained the resins and compounds specified below. Specifically, the spacer layer parts produced by curing the photosensitive composition X¹ contained the same compounds having structures derived from the components initially present in the photosensitive composition X1. In addition, the spacer layer parts produced by curing the photosensitive composition X1 do not contain the colorant (D-DL).
Resin (A1-DL): a resin having a structural unit as represented by the general formula (1) Resin (A2-DL): an acid modified epoxy resin having a structural unit as represented by the general formula (24) and a biphenyl structure
Resin (A3-DL): a resin having a structural unit as represented by the general formula (32) Compound (C2x-DL): a compound having a 1H-indene-3-carboxylate-7-arylsulfonate structure
Compound (G2-DL): a compound having a 1,1,1-tris(4-hydroxyphenyl) propane structure Compound (I1a-DL): a compound having a thiol structure containing a monovalent octyl group having 8 carbon atoms
Compound (I2a-DL): a compound having an alkyl chloride structure containing a monovalent octyl group having 8 carbon atoms

### Examples 2 to 76, Comparative Examples 1 to 6, Examples 36A to 61A, 81A to 89A, 105A, and 106A, and Comparative Examples 1A and 5A

According to the same procedure as in Example 1, photosensitive compositions 2 to 78 and photosensitive compositions 36A to 61A, 81A to 89A, 105A, 106A, 110A, and 114A were prepared using the components specified in Table 3-1 to Table 8-2. In Table 3-1 to Table 8-2, the numerals in parentheses show the solid content of each component in number of parts by mass. Using each of the photosensitive compositions prepared, a film of the photosensitive composition was formed on a substrate and evaluated for photosensitive characteristics, cured film characteristics, and light emission characteristics in the same way as in Example 1. Results of these evaluations are summarized in Table 3-1 to Table 8-2.

In Table 3-1 to Table 3-3, various characteristics of photosensitive compositions containing different compounds as the compound (I) are evaluated at different ion detection intensities at a depth of 3 nm from the surface of the first electrode. In Table 3-4 and Table 3-5, various characteristics of photosensitive compositions containing different other compounds are evaluated at different contents of other elements and different contents of other compounds in the photosensitive compositions.

Table 7-2 shows the maximum surface roughness and the difference in maximum surface roughness between the pixel separation layer and the spacer layer in Example 1. Table 7-2 also shows the ratio of the ion detection intensity to the total anion detection intensity and the ratio between the first electrode part and the pixel separation layer part in Example 1.

In Table 8-1, various characteristics of a photosensitive composition devoid of the compound (I), various photosensitive compositions that differ in the content of each element and the content of each ion in the photosensitive compositions are evaluated at different ion detection intensities at a depth of 3 nm from the surface of the first electrode. In Table 8-2, various characteristics of a photosensitive composition devoid of the compound (I) and photosensitive compositions that had undesirable contents of elements or undesirable contents of ions in the photosensitive compositions are evaluated.

### Example 77; Preparation of Cured Film of Photosensitive Composition (Cured Film Having Thick Part and Thin Part)

First, the method used for producing a cured film of a photosensitive composition is described below. By the procedure described in Example 1 given above, a prebaked film with a thickness of about 5.0 μm of the photosensitive composition 1 was formed on an ITO/Ag substrate. The prebaked film produced above was subjected to spray development with a 2.38 mass % aqueous TMAH solution by a small type development apparatus for photolithography (AD-1200; manufactured by Takizawa Sangyo Co., Ltd.), and the time period required for complete dissolution of the prebaked film (unexposed parts) (breaking point; hereinafter referred to as BP) was measured.

Another prebaked film was prepared by the same procedure as above, and then the resulting prebaked film was patterned by light exposure using a double side alignment type single side exposure device (Mask Aligner PEM-6M; manufactured by Union Optical Co., Ltd.) to apply i-line (wavelength 365 nm), h-line (wavelength 405 nm), and g-line (wavelength 436 nm) beams emitted from an ultrahigh pressure mercury lamp through a halftone photomask designed for evaluation of halftone characteristics. The halftone photomask used had transparent portions, light blocking portions, and translucent portions that were located between the transparent portions and the light blocking portions. It had regions where the transmittance (% T_{HT}) of the translucent portions was 20%, 25%, or 30% of the transmittance (% T_{FT}) of the transparent portions. Each transparent portion is adjacent to a translucent portion and each translucent portion is adjacent to a light blocking portion. FIG. 11 shows a typical arrangement and sizes of transparent portions, light blocking portions, and translucent portions in a typical halftone photomask. After the light exposure step, a small type development device for photolithography (AD-1200; manufactured by Takizawa Sangyo Co., Ltd.) was used to develop the film with a 2.38 mass % aqueous TMAH solution, followed by rinsing with water for 30 seconds to provide a developed film of the photosensitive composition 1 having a step shape. The development time used was 1.3 times as long as the measured BP. The developed pattern was observed to determine the optimum exposure dose (reading on i-line illumination photometer) for the transparent portions and translucent portions to form a 22 μm wide space pattern that corresponds to the opening part in a 20 μm space pattern that was defined by thin parts made of the translucent portions and had opening parts made of light blocking portions. After light exposure with the optimum exposure dose, the developed pattern was heat-cured at 250° C. in a high temperature inert gas oven (INH-9CD-S; manufactured by Koyo Thermo Systems Co., Ltd.) to provide a cured film of the photosensitive composition 1 having a step shape including thick parts with thicknesses of about 3.0 μm and thin parts with thicknesses of about 1.5 μm. The heat-curing conditions used included heating to 250° C. at a heating rate of 3.5° C./min in a nitrogen atmosphere with an oxygen concentration of 20 mass ppm or less, subsequent heat treatment at 250° C. for 60 minutes, and cooling to 50° C.

The cured film was analyzed by means of nuclear magnetic resonance spectroscopy, infrared spectroscopy, time-of-flight secondary ion mass spectrometry, etc., to determine the structural units and compounds of resins present in the cured film. It was confirmed that in the step shape of the cured film produced by curing the photosensitive composition 1 by the procedure described above, the thick parts and the thin parts contained resins and compounds having the same structures as in the cured film produced by curing the photosensitive composition 1 in Examples 1 given above. Specifically, the thick parts and the thin parts in the step shape of the cured film produced by curing the photosensitive composition 1 contained the same compounds having structures derived from the components initially present in the photosensitive composition 1. For the thick parts and the thin parts in the step shape of the cured film produced by curing the photosensitive composition 1, the OD value per μm of film thickness, which is an indicator of light blocking efficiency, was 1.1.

### Example 77; Preparation of Organic EL Display (Including Pixel Separation Layer Part Having Thick Part and Thin Part)

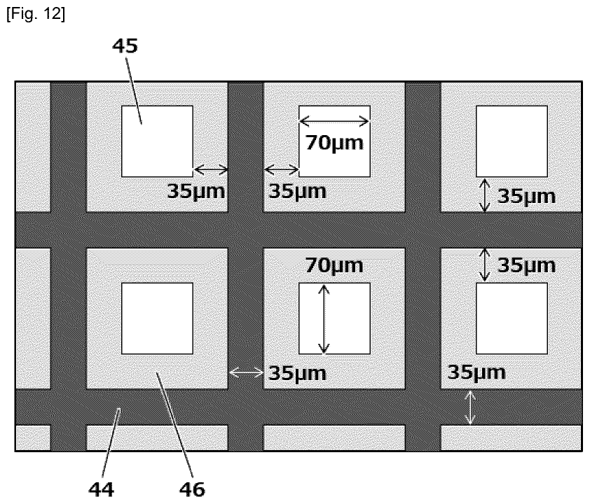

Next, described below is the method for producing an organic EL display. An organic EL display was produced by the method described in Example 1 given above. A cured film containing a step-shaped pattern of the photosensitive composition 1, which was designed to work as the pixel separation layer part 50, was formed by using a halftone photomask having a predetermined pattern and also having transparent portions, light blocking portions, and translucent portions that were located between transparent portions and light blocking portions, thereby producing an organic EL display. The pixel separation layer part 50, which had a step-shaped pattern of the photosensitive composition 1, was produced in such a manner that it had thick parts with thicknesses of about 3.0 μm and thin parts with thicknesses of about 1.5 μm. The pattern having a step shape has thick parts, opening parts, and thin parts, wherein square opening parts, each with a width of 70 μm and a length of 70 μm, are aligned at intervals of 175 μm in the width direction and 175 μm in the length direction. In regard to the thin parts and thick parts, the space with a width of 105 μm between two opening parts, each having a width of 70 μm, (interval 175 μm-width 70 μm=105 μm) includes a 35 μm thick part and two 35 μm thin parts that are located adjacent to the opening parts and on two sides of the thick part. Also, the space with a length of 105 μm of between two opening parts, each having a length of 70 μm, (interval 175 μm-length 70 μm=105 μm) includes a 35 μm thick part and two 35 μm thin parts that are located adjacent to the opening parts and on two sides of the thick part. FIG. 12 gives a schematic diagram illustrating the arrangement and sizes of thick parts, opening parts, and thin parts in the organic EL display produced above. Evaluations for various characteristics were made in the same way as in Example 1. Results of these evaluations are summarized in Table 7-3.

### Comparative Example 7

Except for using the compound (S-2) as the compound (I) instead of the compound (S-4) used in Comparative Example 2, the same procedure as in Comparative example 2 was carried out to prepare a photosensitive composition 79. Here, the preparation of the photosensitive composition 79 was performed so that the content of the S element in the photosensitive composition would be 500 mass ppm. The resulting photosensitive composition was stored at 25° C. for one week. After storage, a film of the photosensitive composition was formed on a substrate in the same way as in Example 1. Foreign substances were generated in large amounts, indicating that the photosensitive composition was poor in storage stability.

### Example 78

A photosensitive composition 1 that included the compound (S-2) as the compound (I) and had an S element content of 3 mass ppm in the photosensitive composition was stored in the same way at 25° C. for one week. After storage, a film of the photosensitive composition was formed on a substrate in the same way as in Example 1. Foreign substance generation did not occur, indicating that the photosensitive composition was high in storage stability.

### Example 79

The photosensitive composition 79 prepared above was stored at 25° C. for one week, and the photosensitive composition after being stored was designated as the photosensitive composition 79′. Except for filtering the photosensitive composition 79′ through a 0.45 μm filter before spreading it on a substrate, the same procedure as in Example 1 was carried out to form a film of the photosensitive composition on a substrate, followed by making evaluations for photosensitive characteristics, cured film characteristics, and light emission characteristics. It had an OD value per μm of film thickness of 1.1. and it was rated as C+ for the light emission region area after durability test and rated as B for the drive voltage at which the current density reached 10 mA/cm².

In each of the examples given above, a photosensitive composition with positive type sensitivity was used and development was performed for 60 seconds, 90 seconds, or 120 seconds. Using a gray scale mask designed for sensitivity measurement (MDRM MODEL 4000-5-FS; manufactured by Opto-Line International), test was performed to determine the optimum exposure dose (reading on i-line illumination photometer) to form a 20 μm wide space pattern, which corresponds to the opening part, in a 20 μm line-and-space pattern. In the case where a photosensitive composition with positive type sensitivity was used, furthermore, the heat-curing conditions used included heating to 200° C. at a heating rate of 3.5° C./min in a nitrogen atmosphere with an oxygen concentration of 20 mass ppm or less, subsequent heat treatment at 200° C. for 60 minutes, and cooling to 50° C.

The water content was measured by volumetric titration using a Karl Fischer reagent. The contents of the sodium element, potassium element, magnesium element, calcium element, hafnium element, and yttrium element were measured by inductively coupled plasma-mass spectrometry and inductively coupled plasma-atomic emission spectroscopy using calibration curves prepared with standard substances. The contents of benzene, toluene, xylene, naphthalene, glycol ether compounds having specific structures, surface active agents, polyoxyalkylene ether compounds, and ink repellents were measured by gas chromatography-mass spectrometry and liquid chromatography-mass spectrometry using calibration curves prepared with standard substances.

The contents of the sulfur element, chlorine element, and bromine element were measured by combustion ion chromatography. A photosensitive composition sample was burned and decomposed in a combustion tube of an analytical device, and the generated gas was absorbed in an absorption solution, followed by analyzing a part of the absorption solution by ion chromatography. The absence of a measured element content indicates that the element was not detected.

### <Combustion and Absorption Conditions>

System: AQF-2100H, GA-210 (manufactured by Mitsubishi Chemical Corporation)
Electric furnace temperature: inlet 900° C., outlet 1,000° C.
Gas: Ar/O₂ 200 mL/min, O₂ 400 mL/min
Absorption solution: H2O₂ 0.1 mass %
Volume of absorption solution: 5 mL

### <Ion Chromatographic—Anion Analysis Conditions>

System: ICS1600 (manufactured by DIONEX)
Mobile phase: 2.7 mmol/L Na₂CO₃, 0.3 mmol/L NaHCO₃
Flow rate: 1.50 mL/min
Detector: electric conductivity detector
Injection volume: 100 μL

Furthermore, the contents of sulfide ions, hydrogen sulfide ions, sulfate ions, hydrogen sulfate ions, chloride ions, and bromide ions were measured by ion chromatography. A photosensitive composition sample was added to a 10 mmol/L aqueous solution of potassium hydroxide and shaken for 2 hours to extract ion components. The extract liquid was filtered under the conditions given below, and anion components were analyzed by ion chromatography. The absence of a measured ion content indicates that the element was not detected.

### <Filtering Conditions>

Membrane filter: 0.22 μm, PVDF (manufactured by Merck Millipore)
Solid phase extraction cartridge: InertSep Slim-J PLS-3 (manufactured by GL Sciences Inc.)
Cation exchange cartridge: OnGuard II H (manufactured by Thermo Fisher Scientific)

### <Ion Chromatography Analysis Conditions>

Equipment: ICS-5000+ (manufactured by Thermo Fisher Scientific)
Separation column: 2 mm diameter x 250 mm, IonPac AS11-HC-4 μm
Eluent: potassium hydroxide/gradient
Detector: electric conductivity detector
Specimen Injection volume: 100 μL

TABLE 3-1

| | | | | | | | | | components |
|---|---|---|---|---|---|---|---|---|---|
| | | constitution | | | | | | | of cured film |
| | | | | | | S etc. | Cl/Br etc. | | S etc. |
| | | | constituent | | | elements and | elements and | other | elements and |
| | | | components | | | ions in | ions in | elements and | ions in |
| | | | (content/ | | | composition | composition | compounds in | cured film |
| | | pigment | parts by | | other | (content/ | (content/ | composition | (content/ |
| | composition | dispersion | mass) | compound (I) | compounds | mass ppm) | mass ppm) | (content) | mass ppm) |
| Example | 1 | Bk-1 | PI-1 (30) | S-2 | p-1 | S element | Cl element | water content | S element |
| 1 | | | AE-1 (25) | Cl-1 | t-1 | (3) | (3) | (1.0 mass %) | (3) |
| Example | 2 | | PR-1 (15) | S-1 | u-1 | | | surface active | |
| 2 | | | b-1 (10) | Cl-1 | u-2 | | | agent | |
| Example | 3 | | b-2 (20) | S-3 | | | | (200 mass ppm) | |
| 3 | | | c-1 (10) | Cl-1 | | | | Hf element | |
| Example | 4 | | d-1 (41.0) | S-4 | | | | (0.7 mass ppm) | |
| 4 | | | e-1 (14.4) | Cl-1 | | | | Y element | |
| Example | 5 | | f-1 (0.5) | S-5 | | | | (2.3 mass ppm) | |
| 5 | | | g-3 (5) | Cl-1 | | | | | |
| Example | 6 | | | S-6 | | | | | |
| 6 | | | | Cl-1 | | | | | |
| Example | 7 | | | S-7 | | | | | |
| 7 | | | | Cl-1 | | | | | |
| Example | 8 | | | S—I-1 | | S element | | | S element |
| 8 | | | | Cl-1 | | (3) | | | (3) |
| Example | 9 | | | S—I-2 | | sulfide ion | | | sulfide ion |
| 9 | | | | Cl-1 | | (3) | | | (3) |
| Example | 10 | | | S—I-3 | | | | | |
| 10 | | | | Cl-1 | | | | | |
| Example | 11 | | | S—I-4 | | S element | | | S element |
| 11 | | | | Cl-1 | | (1) | | | (1) |
| | | | | | | sulfuric acid | | | sulfuric acid |
| | | | | | | ion | | | ion |
| | | | | | | (3) | | | (3) |
| Example | 12 | | | S-2 | | S element | | | S element |
| 12 | | | | Cl-1 | | (0.5) | | | (0.5) |
| Example | 13 | | | | | S element | | | S element |
| 13 | | | | | | (40) | | | (40) |
| Example | 14 | | | S—I-1 | | S element | | | S element |
| 14 | | | | Cl-1 | | (0.5) | | | (0.5) |
| | | | | | | sulfide ion | | | sulfide ion |
| | | | | | | (0.5) | | | (0.5) |
| Example | 15 | | | | | S element | | | S element |
| 15 | | | | | | (40) | | | (40) |
| | | | | | | sulfide ion | | | sulfide ion |
| | | | | | | (40) | | | (40) |

| | components | | | | | | | | |
|---|---|---|---|---|---|---|---|---|---|
| | of cured film | | | | | | | light emission | |
| | Cl/Br etc. | | | | | | | characteristics | |
| | elements and | | | | | | | | low voltage |
| | ions in | ion detection intensity | | | | | OD for | reliability | driving |
| | cured film | | | indium | | | light | of light | characteristics |
| | (content/ | sulfur | chlorine | oxide | carbon | cyanide | blocking | emitting | light emission |
| | mass ppm) | ion | ion | ion | ion | ion | efficiency | element | luminance |
| Example | Cl element | 20.0 | 19.0 | 1,518 | 904 | 1,355 | 1.1 | A | A |
| 1 | (3) | | | | | | | | |
| Example | | 17.5 | 19.0 | 1,488 | 911 | 1,338 | 1.1 | B+ | A |
| 2 | | | | | | | | | |
| Example | | 17.4 | 18.9 | 1,492 | 909 | 1,362 | 1.1 | B+ | A |
| 3 | | | | | | | | | |
| Example | | 17.0 | 19.1 | 1,480 | 900 | 1,350 | 1.1 | B | B+ |
| 4 | | | | | | | | | |
| Example | | 22.1 | 19.0 | 1,492 | 706 | 1,134 | 1.1 | A | A |
| 5 | | | | | | | | | |
| Example | | 20.5 | 19.0 | 1,520 | 905 | 1,360 | 1.1 | A | A |
| 6 | | | | | | | | | |
| Example | | 20.3 | 19.0 | 1,515 | 907 | 1,345 | 1.1 | A | A |
| 7 | | | | | | | | | |
| Example | | 20.1 | 18.9 | 1,511 | 903 | 1,351 | 1.1 | A | A |
| 8 | | | | | | | | | |
| Example | | 17.5 | 18.9 | 1,492 | 909 | 1,362 | 1.1 | B+ | A |
| 9 | | | | | | | | | |
| Example | | 17.1 | 19.0 | 1,480 | 900 | 1,350 | 1.1 | B | B+ |
| 10 | | | | | | | | | |
| Example | | 20.3 | 19.1 | 1,515 | 907 | 1,345 | 1.1 | A | A |
| 11 | | | | | | | | | |
| Example | | 23.1 | 19.0 | 1,500 | 910 | 1,361 | 1.1 | A+ | A |
| 12 | | | | | | | | | |
| Example | | 41.0 | 19.0 | 1,531 | 915 | 1,367 | 1.1 | B+ | A |
| 13 | | | | | | | | | |
| Example | | 23.0 | 19.1 | 1,502 | 907 | 1,362 | 1.1 | A+ | A |
| 14 | | | | | | | | | |
| Example | | 41.2 | 19.0 | 1,533 | 913 | 1,362 | 1.1 | B+ | A |
| 15 | | | | | | | | | |

TABLE 3-2

| | | constitution | | | | | | |
|---|---|---|---|---|---|---|---|---|
| | | | | | | S etc. | Cl/Br etc. | |
| | | | | | | elements and | elements and | other |
| | | | constituent | | | ions in | ions in | elements and |
| | | | components | | | composition | composition | compounds in |
| | | pigment | (content/parts by | | other | (content/ | (content/ | composition |
| | composition | dispersion | mass) | compound (I) | compounds | mass ppm) | mass ppm) | (content) |
| Example | 1 | Bk-1 | PI-1 (30) | S-2 | p-1 | S element | Cl element | water content |
| 1 | | | AE-1 (25) | Cl-1 | t-1 | (3) | (3) | (1.0 mass %) |
| Example | 16 | | PR-1 (15) | S-2 | u-1 | | | surface active |
| 16 | | | b-1 (10) | Cl-2 | u-2 | | | agent |
| Example | 17 | | b-2 (20) | S-2 | | | | (200 mass ppm) |
| 17 | | | c-1 (10) | Cl-3 | | | | Hf element |
| Example | 18 | | d-1 (41.0) | S-2 | | | Br element | (0.7 mass ppm) |
| 18 | | | e-1 (14.4) | Br-1 | | | (3) | Y element |
| Example | 19 | | f-1 (0.5) | S-2 | | | | (2.3 mass ppm) |
| 19 | | | g-3 (5) | Br-2 | | | | |
| Example | 20 | | | S-2 | | | | |
| 20 | | | | Br-3 | | | | |
| Example | 21 | | | S-2 | | | Cl element | |
| 21 | | | | Cl—I-1 | | | (3) | |
| Example | 22 | | | S-2 | | | chloride ion | |
| 22 | | | | Cl—I-2 | | | (3) | |
| Example | 23 | | | S-2 | | | | |
| 23 | | | | Cl—I-3 | | | | |
| Example | 24 | | | S-2 | | | Br element | |
| 24 | | | | Br—-I-1 | | | (3) | |
| Example | 25 | | | S-2 | | | bromide ion | |
| 25 | | | | Br—I-2 | | | (3) | |
| Example | 26 | | | S-2 | | | | |
| 26 | | | | Br—I-3 | | | | |
| Example | 27 | | | S-2 | | | Cl element | |
| 27 | | | | Cl-1 | | | (0.5) | |
| Example | 28 | | | | | | Cl element | |
| 28 | | | | | | | (40) | |
| Example | 29 | | | S-2 | | | Cl element | |
| 29 | | | | Cl—I-1 | | | (0.5) | |
| | | | | | | | chloride ion | |
| | | | | | | | (0.5) | |
| Example | 30 | | | | | | Cl element | |
| 30 | | | | | | | (40) | |
| | | | | | | | chloride ion | |
| | | | | | | | (40) | |

| | components | | | | | | | | | | |
|---|---|---|---|---|---|---|---|---|---|---|---|
| | of cured film | | | | | | | | | light emission | |
| | S etc. | Cl/Br etc. | | | | | | | | characteristics | |
| | elements | elements | | | | | | | | | low voltage |
| | and ions in | and ions in | ion detection intensity | | | | | | OD for | reliability | driving |
| | cured film | cured film | | | | indium | | | light | of light | characteristics |
| | (content/ | (content/ | sulfur | chlorine | bromine | oxide | carbon | cyanide | blocking | emitting | light emission |
| | mass ppm) | mass ppm) | ion | ion | ion | ion | ion | ion | efficiency | element | luminance |
| Example | S element | Cl element | 20.0 | 19.0 | — | 1,518 | 904 | 1,355 | 1.1 | A | A |
| 1 | (3) | (3) | | | | | | | | | |
| Example | | | 20.0 | 16.4 | — | 1,488 | 911 | 1,338 | 1.1 | B+ | A |
| 16 | | | | | | | | | | | |
| Example | | | 19.9 | 16.0 | — | 1,492 | 909 | 1,362 | 1.1 | B | B+ |
| 17 | | | | | | | | | | | |
| Example | | Br element | 20.1 | — | 18.9 | 1,515 | 907 | 1,345 | 1.1 | A | A |
| 18 | | (3) | | | | | | | | | |
| Example | | | 20.0 | — | 16.3 | 1,488 | 911 | 1,338 | 1.1 | B+ | A |
| 19 | | | | | | | | | | | |
| Example | | | 20.0 | — | 16.0 | 1,480 | 900 | 1,350 | 1.1 | B | B+ |
| 20 | | | | | | | | | | | |
| Example | | Cl element | 19.9 | 19.1 | — | 1,511 | 903 | 1,351 | 1.1 | A | A |
| 21 | | (3) | | | | | | | | | |
| Example | | chloride ion | 19.9 | 16.5 | — | 1,492 | 909 | 1,362 | 1.1 | B+ | A |
| 22 | | (3) | | | | | | | | | |
| Example | | | 20.0 | 16.1 | — | 1,480 | 900 | 1,350 | 1.1 | B | B+ |
| 23 | | | | | | | | | | | |
| Example | | Br element | 20.1 | — | 19.1 | 1,511 | 903 | 1,351 | 1.1 | A | A |
| 24 | | (3) | | | | | | | | | |
| Example | | bromide ion | 20.0 | — | 16.5 | 1,492 | 909 | 1,362 | 1.1 | B+ | A |
| 25 | | (3) | | | | | | | | | |
| Example | | | 20.0 | — | 16.1 | 1,480 | 900 | 1,350 | 1.1 | B | B+ |
| 26 | | | | | | | | | | | |
| Example | | Cl element | 20.1 | 22.1 | — | 1,500 | 910 | 1,361 | 1.1 | A+ | A |
| 27 | | (0.5) | | | | | | | | | |
| Example | | Cl element | 20.0 | 40.5 | — | 1,531 | 915 | 1,367 | 1.1 | B+ | A |
| 28 | | (40) | | | | | | | | | |
| Example | | Cl element | 20.0 | 22.0 | — | 1,502 | 907 | 1,362 | 1.1 | A+ | A |
| 29 | | (0.5) | | | | | | | | | |
| | | chloride ion | | | | | | | | | |
| | | (0.5) | | | | | | | | | |
| Example | | Cl element | 20.1 | 40.7 | — | 1,533 | 913 | 1,362 | 1.1 | B+ | A |
| 30 | | (40) | | | | | | | | | |
| | | chloride ion | | | | | | | | | |
| | | (40) | | | | | | | | | |

TABLE 3-3

| | | | | | | | | | components |
|---|---|---|---|---|---|---|---|---|---|
| | | constitution | | | | | | | of cured film |
| | | | | | | S etc. | Cl/Br etc. | | S etc. |
| | | | constituent | | | elements and | elements and | | elements and |
| | | | components | | | ions in | ions in | other elements | ions in |
| | | | (content/ | | | composition | composition | and compounds | cured film |
| | | pigment | parts by | | other | (content/ | (content/ | in composition | (content/ |
| | composition | dispersion | mass) | compound (I) | compounds | mass ppm) | mass ppm) | (content) | mass ppm) |
| Example | 1 | Bk-1 | PI-1 (30) | S-2 | p-1 | S element | Cl element | water content | S element |
| 1 | | | AE-1 (25) | Cl-1 | t-1 | (3) | (3) | (1.0 mass %) | (3) |
| Example | 31 | | PR-1 (15) | S-2 | u-1 | | — | surface active | |
| 31 | | | b-1 (10) | | u-2 | | | agent | |
| Example | 32 | | b-2 (20) | S-2 | | S element | — | (200 mass ppm) | S element |
| 32 | | | c-1 (10) | S—I-1 | | (6) | | Hf element | (6) |
| | | | d-1 (41.0) | | | sulfide ion | | (0.7 mass ppm) | sulfide ion |
| | | | e-1 (14.4) | | | (3) | | Y element | (3) |
| Example | 33 | | f-1 (0.5) | Cl-1 | | — | Cl element | (2.3 mass ppm) | — |
| 33 | | | g-3 (5) | | | | (3) | | |
| Example | 34 | | | Cl-1 | | — | Cl element | | — |
| 34 | | | | Cl—I-1 | | | (6) | | |
| | | | | | | | chloride ion | | |
| | | | | | | | (3) | | |
| Example | 35 | | | S-2 | | S element | Cl element | | S element |
| 35 | | | | Cl-1 | | (3) | (3) | | (3) |
| | | | | Br-1 | | | Br element | | |
| | | | | | | | (3) | | |

| | components | | | | | | | | | |
|---|---|---|---|---|---|---|---|---|---|---|
| | of cured film | | | | | | | | light emission | |
| | Cl/Br etc. | | | | | | | | characteristics | |
| | elements and | | | | | | | | | low voltage |
| | ions in | ion detection intensity | | | | | | OD for | reliability | driving |
| | cured film | | | | indium | | | light | of light | characteristics |
| | (content/ | sulfur | chlorine | bromine | oxide | carbon | cyanide | blocking | emitting | light emission |
| | mass ppm) | ion | ion | ion | ion | ion | ion | efficiency | element | luminance |
| Example | Cl element | 20.0 | 19.0 | — | 1,518 | 904 | 1,355 | 1.1 | A | A |
| 1 | (3) | | | | | | | | | |
| Example | — | 20.1 | — | — | 1,518 | 903 | 1,352 | 1.1 | A | B+ |
| 31 | | | | | | | | | | |
| Example | — | 26.6 | — | — | 1,436 | 644 | 1,004 | 1.1 | A | A |
| 32 | | | | | | | | | | |
| Example | Cl element | — | 19.1 | — | 1,519 | 905 | 1,360 | 1.1 | B+ | B+ |
| 33 | (3) | | | | | | | | | |
| Example | Cl element | — | 25.5 | — | 1,441 | 650 | 1,007 | 1.1 | B+ | A |
| 34 | (6) | | | | | | | | | |
| | chloride ion | | | | | | | | | |
| | (3) | | | | | | | | | |
| Example | Cl element | 20.0 | 14.9 | 14.5 | 1,490 | 710 | 1,098 | 1.1 | A | A+ |
| 35 | (3) | | | | | | | | | |
| | Br element | | | | | | | | | |
| | (3) | | | | | | | | | |

TABLE 3-4

| | | constitution | | | | | |
|---|---|---|---|---|---|---|---|
| | | | | compound (B) | | | |
| | | | | photosensitizer (C) | | | |
| | | | resin (A1) | colorant (D) | | | S/Cl/Br etc. |
| | | | resin (A2) | dispersant (E) | | | elements and |
| | | | resin (A3) | compound (F) | | | ions in |
| | | | (content/ | crosslinking agent (G) | compound (I) | | composition |
| | | pigment | parts by | inorganic particles (H) | other | other | (content/ |
| | composition | dispersion | mass) | (content/parts by mass) | compounds | compounds | mass ppm) |
| Example 1 | 1 | Bk-1 | PI-1 (30) | b-1 (10) | S-2 | q-1 | S element |
| Example 36A | 36A | | AE-1 (25) | b-2 (20) | Cl-1 | q-2 | (3) |
| Example 37A | 37A | | PR-1 (15) | c-1 (10) | p-1 | q-3 | Cl element |
| Example 38A | 38A | | | d-1 (41.0) | t-1 | q-4 | (3) |
| Example 39A | 39A | | | e-1 (14.4) | u-1 | q-1 | |
| Example 40A | 40A | | | f-1 (0.5) | u-2 | | |
| Example 41A | 41A | | | g-3 (5) | | r-1 | |
| Example 42A | 42A | | | | | r-2 | |
| Example 43A | 43A | | | | | r-3 | |
| Example 44A | 44A | | | | | r-4 | |
| Example 45A | 45A | | | | | r-2 | |
| Example 46A | 46A | | | | | | |
| Example 47A | 47A | | | | | s-1 | |
| Example 48A | 48A | | | | | s-2 | |
| Example 49A | 49A | | | | | | |
| Example 50A | 50A | | | | | | |
| Example 51A | 51A | | | | | w-1 | |

| | | | components | | light emission | |
|---|---|---|---|---|---|---|
| | | | of cured | | characteristics | |
| | constitution | | film elements | | reliability | |
| | other elements | | and ions in | OD for | of light | low voltage |
| | and compounds in | | cured film | light | emitting | driving |
| | composition | | (content/ | blocking | element | characteristics |
| | (content) | | mass ppm) | efficiency | luminance | light emission |
| Example 1 | water content | Na element | S element | 1.1 | A | A+ |
| | (1.0 mass %) | (3 mass ppm) | (2) | | | |
| Example 36A | surface active agent | K element | Cl element | 1.1 | A | A+ |
| | (200 mass ppm) | (3 mass ppm) | (2) | | | |
| Example 37A | Hf element | Mg element | | 1.1 | A | A+ |
| | (0.7 mass ppm) | (3 mass ppm) | | | | |
| Example 38A | Y element | Ca element | | 1.1 | A | A+ |
| | (2.3 mass ppm) | (3 mass ppm) | | | | |
| Example 39A | | Na element | | 1.1 | A+ | A+ |
| | | (0.5 mass ppm) | | | | |
| Example 40A | | Na element | | 1.1 | B+ | A+ |
| | | (40 mass ppm) | | | | |
| Example 41A | | r-1 | | 1.1 | A | A+ |
| | | (3 mass ppm) | | | | |
| Example 42A | | r-2 | | 1.1 | A | A+ |
| | | (3 mass ppm) | | | | |
| Example 43A | | r-3 | | 1.1 | A | A+ |
| | | (3 mass ppm) | | | | |
| Example 44A | | r-4 | | 1.1 | A | A+ |
| | | (3 mass ppm) | | | | |
| Example 45A | | r-2 | | 1.1 | A+ | A+ |
| | | (0.5 mass ppm) | | | | |
| Example 46A | | r-2 | | 1.1 | B+ | A+ |
| | | (40 mass ppm) | | | | |
| Example 47A | | s-1 | | 1.1 | A | A+ |
| | | (0.05 mass %) | | | | |
| Example 48A | | s-2 | | 1.1 | A | A+ |
| | | (0.05 mass %) | | | | |
| Example 49A | | s-2 | | 1.1 | A+ | A+ |
| | | (0.01 mass %) | | | | |
| Example 50A | | s-2 | | 1.1 | B+ | A+ |
| | | (0.1 mass %) | | | | |
| Example 51A | | w-1 | | 1.1 | A | A+ |
| | | (4,264 mass ppm) | | | | |

TABLE 3-5

| | | constitution | | | | | |
|---|---|---|---|---|---|---|---|
| | | | | compound (B) | | | |
| | | | | photosensitizer (C) | | | |
| | | | resin (A1) | colorant (D) | | | S/Cl/Br etc. |
| | | | resin (A2) | dispersant (E) | | | elements and |
| | | | resin (A3) | compound (F) | | | ions in |
| | | | (content/ | crosslinking agent (G) | compound (I) | | composition |
| | | pigment | parts by | inorganic particles (H) | other | other | (content/ |
| | composition | dispersion | mass) | (content/parts by mass) | compounds | compounds | mass ppm) |
| Example | 1 | Bk-1 | PI-1 (30) | b-1 (10) | S-2 | t-1 | S element |
| 1 | | | AE-1 (25) | b-2 (20) | Cl-1 | | (3) |
| Example | 52A | | PR-1 (15) | c-1 (10) | p-1 | | Cl element |
| 52A | | | | d-1 (41.0) | u-1 | | (3) |
| Example | 53A | | | e-1 (14.4) | u-2 | | |
| 53A | | | | f-1 (0.5) | | | |
| Example | 54A | | | g-3 (5) | | | |
| 54A | | | | | | | |
| Example | 55A | | | | | t-2 | |
| 55A | | | | | | | |
| Example | 56A | | | | | t-1 | |
| 56A | | | | | | | |
| Example | 57A | | | | | | |
| 57A | | | | | | | |
| Example | 58A | | | | | t-1 | |
| 58A | | | | | | u-1b | |
| Example | 59A | | | | | | |
| 59A | | | | | | | |
| Example | 60A | | | | | t-1 | |
| 60A | | | | | | u-2b | |
| Example | 61A | | | | | | |
| 61A | | | | | | | |

| | | | components | | light emission | |
|---|---|---|---|---|---|---|
| | | | of cured | | characteristics | |
| | constitution | | film elements | | reliability | |
| | other elements | | and ions in | OD for | of light | low voltage |
| | and compounds in | | cured film | light | emitting | driving |
| | composition | | (content/ | blocking | element | characteristics |
| | (content) | | mass ppm) | efficiency | luminance | light emission |
| Example | surface active agent | water content | S element | 1.1 | A | A |
| 1 | (200 mass ppm) | (1.0 mass %) | (2) | | | |
| Example | Hf element | water content | Cl element | 1.1 | A | A+ |
| 52A | (0.7 mass ppm) | (0.1 mass %) | (2) | | | |
| Example | Y element | water content | | 1.1 | A+ | A+ |
| 53A | (2.3 mass ppm) | (0.5 mass %) | | | | |
| Example | | water content | | 1.1 | B+ | A+ |
| 54A | | (1.5 mass %) | | | | |
| Example | water content | surface active agent | | 1.1 | A | A |
| 55A | (1.0 mass %) | (200 mass ppm) | | | | |
| Example | Hf element | surface active agent | | 1.1 | A | B+ |
| 56A | (0.7 mass ppm) | (50 mass ppm) | | | | |
| Example | Y element | surface active agent | | 1.1 | B+ | A |
| 57A | (2.3 mass ppm) | (500 mass ppm) | | | | |
| Example | water content | Hf element | | 1.1 | A | A |
| 58A | (1.0 mass %) | (10 mass ppm) | | | | |
| Example | surface active agent | Hf element | | 1.1 | B+ | A+ |
| 59A | (200 mass ppm) | (40 mass ppm) | | | | |
| | Y element | | | | | |
| | (2.3 mass ppm) | | | | | |
| Example | water content | Y element | | 1.1 | A | A |
| 60A | (1.0 mass %) | (10 mass ppm) | | | | |
| Example | surface active agent | Y element | | 1.1 | B+ | A+ |
| 61A | (200 mass ppm) | (40 mass ppm) | | | | |
| | Hf element | | | | | |
| | (0.7 mass ppm) | | | | | |

TABLE 4-1

| | | constitution | | | | | | | |
|---|---|---|---|---|---|---|---|---|---|
| | | | | | | constituent | | | |
| | | | resin (A1) | resin (A2) | resin (A3) | components | | | other elements |
| | | | (content/ | (content/ | (content/ | (content/ | | | and compounds |
| | | pigment | parts by | parts by | parts by | parts by | | other | in composition |
| | composition | dispersion | mass) | mass) | mass) | mass) | compound (I) | compounds | (content) |
| Example | 1 | Bk-1 | PI-1 (30) | AE-1 (25) | PR-1 (15) | b-1 (10) | S-2 | p-1 | S element |
| 1 | | | | | | b-2 (20) | Cl-1 | t-1 | (3 mass ppm) |
| Example | 36 | | PI-1 (30) | AE-1 (25) | PHS-1 (15) | c-1 (10) | | u-1 | Cl element |
| 36 | | | | | | d-1 (41.0) | | u-2 | (3 mass ppm) |
| Example | 37 | | PI-2 (30) | AE-1 (25) | PR-1 (15) | e-1 (14.4) | | | water content |
| 37 | | | | | | f-1 (0.5) | | | (1.0 mass %) |
| Example | 38 | | PIP-1 (30) | AE-1 (25) | PR-1 (15) | g-3 (5) | | | surface active |
| 38 | | | | | | | | | agent |
| Example | 39 | | PB-1 (30) | AE-1 (25) | PR-1 (15) | | | | (200 mass ppm) |
| 39 | | | | | | | | | Hf element |
| Example | 40 | | PBP-1 (30) | AE-1 (25) | PR-1 (15) | | | | (0.7 mass ppm) |
| 40 | | | | | | | | | Y element |
| Example | 41 | | PAI-1 (30) | AE-1 (25) | PR-1 (15) | | | | (2.3 mass ppm) |
| 41 | | | | | | | | | |
| Example | 42 | | PI-1 (30) | PI-3 (15) | PR-1 (15) | | | | |
| 42 | | | | AE-1 (10) | | | | | |
| Example | 43 | | PAI-1 (30) | PAI-2 (15) | PR-1 (15) | | | | |
| 43 | | | | AE-1 (10) | | | | | |
| Example | 44 | | PS-1 (30) | AE-1 (25) | PR-1 (15) | | | | |
| 44 | | | | | | | | | |
| Example | 45 | | PI-1 (30) | CR-1 (25) | PR-1 (15) | | | | |
| 45 | | | | | | | | | |
| Example | 46 | | PI-1 (30) | AE-2 (25) | PR-1 (15) | | | | |
| 46 | | | | | | | | | |
| Example | 47 | | PI-1 (30) | AC-1 (25) | PR-1 (15) | | | | |
| 47 | | | | | | | | | |

| | components | | | | | | | light emission | |
|---|---|---|---|---|---|---|---|---|---|
| | of cured film | | | | | | | characteristics | |
| | elements | | | | | | | | low voltage |
| | and ions in | ion detection intensity | | | | | OD for | reliability | driving |
| | cured film | | | indium | | | light | of light | characteristics |
| | (content/ | sulfur | chlorine | oxide | carbon | cyanide | blocking | emitting | light emission |
| | mass ppm) | ion | ion | ion | ion | ion | efficiency | element | luminance |
| Example | S element | 20.0 | 19.0 | 1,518 | 904 | 1,355 | 1.1 | A | A |
| 1 | (2) | | | | | | | | |
| Example | Cl element | 16.0 | 15.0 | 1,550 | 971 | 1,390 | 1.1 | B+ | B+ |
| 36 | (2) | | | | | | | | |
| Example | | 17.2 | 16.4 | 1,542 | 922 | 1,372 | 1.1 | B+ | B+ |
| 37 | | | | | | | | | |
| Example | | 19.3 | 18.1 | 1,532 | 943 | 1,385 | 1.1 | B+ | A |
| 38 | | | | | | | | | |
| Example | | 18.8 | 18.0 | 1,545 | 914 | 1,399 | 1.1 | A | B+ |
| 39 | | | | | | | | | |
| Example | | 19.2 | 18.0 | 1,554 | 928 | 1,384 | 1.1 | B+ | A |
| 40 | | | | | | | | | |
| Example | | 19.9 | 19.0 | 1,551 | 911 | 1,376 | 1.1 | A | A |
| 41 | | | | | | | | | |
| Example | | 21.0 | 19.9 | 1,491 | 871 | 1,310 | 1.1 | A+ | A |
| 42 | | | | | | | | | |
| Example | | 21.1 | 19.9 | 1,490 | 875 | 1,311 | 1.1 | A+ | A |
| 43 | | | | | | | | | |
| Example | | 16.3 | 15.0 | 1,494 | 1,034 | 1,424 | 1.1 | B+ | A |
| 44 | | | | | | | | | |
| Example | | 19.9 | 19.1 | 1,515 | 909 | 1,362 | 1.1 | A | A |
| 45 | | | | | | | | | |
| Example | | 20.1 | 19.0 | 1,510 | 900 | 1,350 | 1.1 | A | A |
| 46 | | | | | | | | | |
| Example | | 12.6 | 11.1 | 1,489 | 1,051 | 1,437 | 1.1 | B | A |
| 47 | | | | | | | | | |

TABLE 4-2

| | | constitution | | | | | | | |
|---|---|---|---|---|---|---|---|---|---|
| | | | | | | constituent | | | |
| | | | resin (A1) | resin (A2) | resin (A3) | components | | | other elements |
| | | | (content/ | (content/ | (content/ | (content/ | | | and compounds |
| | | pigment | parts by | parts by | parts by | parts by | | other | in composition |
| | composition | dispersion | mass) | mass) | mass) | mass) | compound (I) | compounds | (content) |
| Example | 1 | Bk-1 | PI-1 (30) | AE-1 (25) | PR-1 (15) | b-1 (10) | S-2 | p-1 | S element |
| 1 | | | | | | | Cl-1 | t-1 | (3 mass ppm) |
| Example | 48 | | PI-1 (30) | AE-1 (25) | PR-2 (15) | b-2 (20) | | u-1 | Cl element |
| 48 | | | | | | | | u-2 | (3 mass ppm) |
| Example | 49 | | PI-1 (30) | AE-1 (25) | PR-3 (15) | c-1 (10) | | | water content |
| 49 | | | | | | | | | (1.0 mass %) |
| Example | 50 | | PI-1 (30) | AE-1 (25) | PR-4 (15) | d-1 (41.0) | | | surface active |
| 50 | | | | | | | | | agent |
| Example | 51 | | PI-1 (30) | AE-1 (25) | PR-5 (15) | e-1 (14.4) | | | (200 mass ppm) |
| 51 | | | | | | | | | Hf element |
| Example | 52 | | PI-1 (30) | AE-1 (25) | PE-1 (15) | f-1 (0.5) | | | (0.7 mass ppm) |
| 52 | | | | | | | | | Y element |
| Example | 53 | | PI-1 (30) | AE-1 (25) | PAC-1 (15) | g-3 (5) | | | (2.3 mass ppm) |
| 53 | | | | | | | | | |
| Example | 54 | | PI-1 (30) | AE-1 (25) | PAC-2 (15) | | | | |
| 54 | | | | | | | | | |

| | components | | | | | | | light emission | |
|---|---|---|---|---|---|---|---|---|---|
| | of cured film | | | | | | | characteristics | |
| | elements | | | | | | | | low voltage |
| | and ions in | | | | | | OD for | reliability | driving |
| | cured film | ion detection intensity | | | | | light | of light | characteristics |
| | (content/ | sulfur | chlorine | indium | carbon | cyanide | blocking | emitting | light emission |
| | mass ppm) | ion | ion | oxide ion | ion | ion | efficiency | element | luminance |
| Example | S element | 20.0 | 19.0 | 1,518 | 904 | 1,355 | 1.1 | A | A |
| 1 | (2) | | | | | | | | |
| Example | Cl element | 21.0 | 19.9 | 1,499 | 888 | 1,316 | 1.1 | A+ | A |
| 48 | (2) | | | | | | | | |
| Example | | 16.5 | 15.4 | 1,543 | 957 | 1,381 | 1.1 | B+ | B+ |
| 49 | | | | | | | | | |
| Example | | 21.0 | 19.9 | 1,495 | 880 | 1,315 | 1.1 | A+ | A |
| 50 | | | | | | | | | |
| Example | | 21.1 | 20.0 | 1,491 | 875 | 1,316 | 1.1 | A+ | A |
| 51 | | | | | | | | | |
| Example | | 20.1 | 19.0 | 1,515 | 902 | 1,360 | 1.1 | A | A |
| 52 | | | | | | | | | |
| Example | | 16.1 | 15.1 | 1,549 | 968 | 1,395 | 1.1 | B+ | B+ |
| 53 | | | | | | | | | |
| Example | | 17.2 | 16.0 | 1,520 | 938 | 1,389 | 1.1 | A | B+ |
| 54 | | | | | | | | | |

TABLE 5-1

| | | constitution | | | | | | |
|---|---|---|---|---|---|---|---|---|
| | | | | | | | | S/Cl/Br etc. |
| | | | constituent | | | | | elements |
| | | | components | | | | | and ions in |
| | | | (content/ | compound (F) | | | | composition |
| | | pigment | parts by | crosslinking agent (G) | inorganic particles (H) | | other | (content/ |
| | composition | dispersion | mass) | (content/parts by mass) | (content/parts by mass) | compound (I) | compounds | mass ppm) |
| Example | 1 | Bk-1 | PI-1 (30) | f-1 (0.5) | — | S-2 | p-1 | S element |
| 1 | | | AE-1 (25) | g-3 (5) | | Cl-1 | t-1 | (3) |
| Example | 55 | | PR-1 (15) | f-2 (0.5) | — | | u-1 | Cl element |
| 55 | | | b-1 (10) | g-3 (5) | | | u-2 | (3) |
| Example | 56 | | b-2 (20) | f-1 (0.5) | — | | | |
| 56 | | | c-1 (10) | g-1 (5) | | | | |
| Example | 57 | | d-1 (41.0) | f-1 (0.5) | — | | | |
| 57 | | | e-1 (14.4) | g-2 (5) | | | | |
| Example | 58 | | | f-1 (0.5) | — | | | |
| 58 | | | | g-4 (5) | | | | |
| Example | 59 | | | f-1 (0.5) | — | | | |
| 59 | | | | g-5 (5) | | | | |
| Example | 60 | | | f-1 (0.5) | SP-1 (20.0) | | | |
| 60 | | | | g-3 (5) | | | | |
| Example | 61 | | | | SP-2 (20.0) | | | |
| 61 | | | | | | | | |
| Example | 62 | | | | SP-3 (20.0) | | | |
| 62 | | | | | | | | |

| | | components | | | | | | | light emission | |
|---|---|---|---|---|---|---|---|---|---|---|
| | constitution | of cured film | | | | | | | characteristics | |
| | other | elements | | | | | | | | low voltage |
| | elements and | and ions in | ion detection intensity | | | | | OD for | reliability | driving |
| | compounds in | cured film | | | indium | | | light | of light | characteristics |
| | composition | (content/ | sulfur | chlorine | oxide | carbon | cyanide | blocking | emitting | light emission |
| | (content) | mass ppm) | ion | ion | ion | ion | ion | efficiency | element | luminance |
| Example | water content | S element | 20.0 | 19.0 | 1,518 | 904 | 1,355 | 1.1 | A | A |
| 1 | (1.0 mass %) | (2) | | | | | | | | |
| Example | surface active | Cl element | 20.0 | 19.0 | 1,519 | 908 | 1,359 | 1.1 | A | A |
| 55 | agent | (2) | | | | | | | | |
| Example | (200 mass ppm) | | 19.9 | 18.9 | 1,520 | 908 | 1,371 | 1.1 | A+ | B+ |
| 56 | Hf element | | | | | | | | | |
| Example | (0.7 mass ppm) | | 19.9 | 19.0 | 1,515 | 904 | 1,359 | 1.1 | A+ | B+ |
| 57 | Y element | | | | | | | | | |
| Example | (2.3 mass ppm) | | 21.1 | 20.0 | 1,514 | 908 | 1,354 | 1.1 | B+ | A+ |
| 58 | | | | | | | | | | |
| Example | | | 21.1 | 20.1 | 1,504 | 899 | 1,341 | 1.1 | B+ | A+ |
| 59 | | | | | | | | | | |
| Example | water content | | 23.4 | 22.2 | 1,495 | 710 | 1,111 | 1.0 | A+ | A+ |
| 60 | (1.0 mass %) | | | | | | | | | |
| Example | Na element | | 22.5 | 21.1 | 1,491 | 811 | 1,231 | 1.0 | A+ | A |
| 61 | (2 mass ppm) | | | | | | | | | |
| Example | surface active | | 21.4 | 20.0 | 1,490 | 875 | 1,311 | 1.0 | A+ | A |
| 62 | agent | | | | | | | | | |
| | (200 mass ppm) | | | | | | | | | |
| | Hf element | | | | | | | | | |
| | (0.7 mass ppm) | | | | | | | | | |
| | Y element | | | | | | | | | |
| | (2.3 mass ppm) | | | | | | | | | |

TABLE 5-2

| | | constitution | | | | | |
|---|---|---|---|---|---|---|---|
| | | | resin (A1) | | | colorant (D) | |
| | | | resin (A2) | | | dispersant (E) | |
| | | | resin (A3) | compound (B) | | compound (F) | |
| | | | (content/ | (content/ | | crosslinking agent (G) | compound (I) |
| | | pigment | parts by | parts by | photosensitizer (C) | inorganic particles (H) | other |
| | composition | dispersion | mass) | mass) | (content/parts by mass) | (content/parts by mass) | compounds |
| Example | 1 | Bk-1 | PI-1 (30) | b-1 (10) | c-1 (10) | d-1 (41.0) | S-2 |
| 1 | | | AE-1 (25) | b-2 (20) | | e-1 (14.4) | Cl-1 |
| Example | 81A | | PR-1 (15) | b-3 (10) | | f-1 (0.5) | p-1 |
| 81A | | | | b-2 (20) | | g-3 (5) | t-1 |
| Example | 82A | | | b-4 (10) | | | u-1 |
| 82A | | | | b-2 (20) | | | u-2 |
| Example | 83A | | | b-5 (10) | | | |
| 83A | | | | b-2 (20) | | | |
| Example | 84A | | | b-1 (10) | | | |
| 84A | | | | b-6 (20) | | | |
| Example | 85A | | | b-1 (10) | | | |
| 85A | | | | b-2 (15) | | | |
| | | | | b-7 (5) | | | |
| Example | 86A | | | b-1 (10) | c-2 (10) | | |
| 86A | | | | b-2 (20) | | | |
| Example | 87A | | | | c-3 (10) | | |
| 87A | | | | | | | |
| Example | 88A | | | | c-4 (10) | | |
| 88A | | | | | | | |
| Example | 89A | | | | c-1 (10) | | |
| 89A | | | | | NQD-1 (5) | | |

| | constitution | | components | | light emission | |
|---|---|---|---|---|---|---|
| | S/Cl/Br etc. | | of cured film | | characteristics | |
| | elements and | other | elements | | | low voltage |
| | ions in | elements and | and ions in | OD for | reliability | driving |
| | composition | compounds in | cured film | light | of light | characteristics |
| | (content/ | composition | (content/ | blocking | emitting | light emission |
| | mass ppm) | (content) | mass ppm) | efficiency | element | luminance |
| Example | S element | water content | S element | 1.1 | A | A |
| 1 | (3) | (1.0 mass %) | (2) | | | |
| Example | Cl element | surface active | Cl element | 1.1 | A+ | A |
| 81A | (3) | agent | (2) | | | |
| Example | | (200 mass ppm) | | 1.1 | A | A |
| 82A | | Hf element | | | | |
| Example | | (0.7 mass ppm) | | 1.1 | A+ | A |
| 83A | | Y element | | | | |
| Example | | (2.3 mass ppm) | | 1.1 | A | A+ |
| 84A | | | | | | |
| Example | | | | 1.1 | A+ | A |
| 85A | | | | | | |
| Example | | | | 1.1 | A | A |
| 86A | | | | | | |
| Example | | | | 1.1 | A | B+ |
| 87A | | | | | | |
| Example | S element | | | 1.1 | B+ | B+ |
| 88A | (583) | | | | | |
| | Cl element | | | | | |
| | (3) | | | | | |
| Example | S element | | | 1.1 | A | A+ |
| 89A | (114) | | | | | |
| | Cl element | | | | | |
| | (3) | | | | | |

TABLE 6-1

| | | constitution | | | | | | | |
|---|---|---|---|---|---|---|---|---|---|
| | | | resin (A1) | | | | | S/Cl/Br etc. | |
| | | | resin (A2) | | | | | elements and | other |
| | | | resin (A3) | constituent | | | | ions in | elements and |
| | | | (content/ | components | | | | com position | compounds in |
| | | pigment | parts by | (content/ | | | other | (content/ | composition |
| | composition | dispersion | mass) | parts by mass) | | compound (I) | compounds | mass ppm) | (content) |
| Example | 1 | Bk-1 | PI-1 (30) | b-1 (10) | d-1 (41.0) | S-2 | p-1 | S element | water content |
| 1 | | | AE-1 (25) | b-2 (20) | e-1 (14.4) | Cl-1 | t-1 | (3) | (1.0 mass %) |
| Example | 63 | Bk-2 | PR-1 (15) | c-1 (10) | d-2 (41.0) | | u-1 | Cl element | surface active |
| 63 | | | | f-1 (0.5) | e-1 (14.4) | | u-2 | (3) | agent |
| Example | 64 | Bk-3 | | g-3 (5) | d-3 (41.0) | | | | (200 mass ppm) |
| 64 | | | | | e-1 (14.4) | | | | Hf element |
| Example | 65 | Bk-4 | | | d-4 (41.0) | | | | (0.7 mass ppm) |
| 65 | | | | | e-1 (14.4) | | | | Y element |
| Example | 66 | Bk-5 | | | d-5 (71.8) | | | | (2.3 mass ppm) |
| 66 | | | | | e-1 (25.1) | | | | |
| Example | 67 | Bk-6 | | | d-6 (41.0) | | | | |
| 67 | | | | | e-1 (14.4) | | | | |
| Example | 68 | Bk-7 | | | d-7 (41.0) | | | | |
| 68 | | | | | e-1 (14.4) | | | | |
| Example | 69 | — | | b-1 (10) | — | | p-1 | | water content |
| 69 | | | | b-2 (20) | | | t-1 | | (1.0 mass %) |
| | | | | c-1 (5) | | | v-1 | | surface active |
| | | | | f-1 (0.5) | | | | | agent |
| | | | | g-3 (3) | | | | | (200 mass ppm) |
| | | | | | | | | | v-1 |
| | | | | | | | | | (1,370 mass ppm) |

| | components | | | | | | | light emission | |
|---|---|---|---|---|---|---|---|---|---|
| | of cured film | | | | | | | characteristics | |
| | elements and | | | | | | | | low voltage |
| | ions in | ion detection intensity | | | | | OD for | reliability | driving |
| | cured film | | | indium | | | light | of light | characteristics |
| | (content/ | sulfur | chlorine | oxide | carbon | cyanide | blocking | emitting | light emission |
| | mass ppm) | ion | ion | ion | ion | ion | efficiency | element | luminance |
| Example | S element | 20.0 | 19.0 | 1,518 | 904 | 1,355 | 1.1 | A | A |
| 1 | (2) | | | | | | | | |
| Example | Cl element | 16.5 | 15.4 | 1,543 | 957 | 1,381 | 0.9 | B+ | B+ |
| 63 | (2) | | | | | | | | |
| Example | | 19.3 | 18.1 | 1,532 | 943 | 1,385 | 0.9 | B+ | A |
| 64 | | | | | | | | | |
| Example | | 16.0 | 15.0 | 1,550 | 971 | 1,390 | 1.0 | B+ | B+ |
| 65 | | | | | | | | | |
| Example | | 9.3 | 8.1 | 1,329 | 1,473 | 1,514 | 1.1 | B | B+ |
| 66 | | | | | | | | | |
| Example | | 23.5 | 22.1 | 1,492 | 704 | 1,102 | 1.0 | A+ | A+ |
| 67 | | | | | | | | | |
| Example | | 22.5 | 21.1 | 1,491 | 811 | 1,231 | 0.8 | A | A+ |
| 68 | | | | | | | | | |
| Example | | 12.7 | 11.2 | 1,440 | 1,205 | 1,500 | — | B+ | B |
| 69 | | | | | | | | | |

TABLE 6-2

| | | constitution | | | | | |
|---|---|---|---|---|---|---|---|
| | | | resin (A1) | | | | |
| | | | resin (A2) | photosensitizer (C) | colorant (D) | compound (B) | |
| | | | resin (A3) | compound (F) | dispersant (E) | crosslinking agent (G) | compound (I) |
| | | pigment | (content/ | (content/ | (content/ | inorganic particles (H) | other |
| | composition | dispersion | parts by mass) | parts by mass) | parts by mass) | (content/parts by mass) | compounds |
| Example | 1 | Bk-1 | PI-1 (30) | c-1 (10) | d-1 (41.0) | b-1 (10) | S-2 |
| 1 | | | AE-1 (25) | f-1 (0.5) | e-1 (14.4) | b-2 (20) | Cl-1 |
| Example | 63 | Bk-2 | PR-1 (15) | | d-2 (41.0) | g-3 (5) | p-1 |
| 63 | | | | | e-1 (14.4) | | t-1 |
| Example | 64 | Bk-3 | | | d-3 (41.0) | | u-1 |
| 64 | | | | | e-1 (14.4) | | u-2 |
| Example | 65 | Bk-4 | | | d-4 (41.0) | | |
| 65 | | | | | e-1 (14.4) | | |
| Example | 66 | Bk-5 | | | d-5 (71.8) | | |
| 66 | | | | | e-1 (25.1) | | |
| Example | 67 | Bk-6 | | | d-6 (41.0) | | |
| 67 | | | | | e-1 (14.4) | | |
| Example | 68 | Bk-7 | | | d-7 (41.0) | | |
| 68 | | | | | e-1 (14.4) | | |
| Example | 69 | — | | c-1 (5) | — | b-1 (10) | S-2 |
| 69 | | | | f-1 (0.5) | | b-2 (20) | Cl-1 |
| Example | 105A | — | | | — | g-3 (3) | p-1 |
| 105A | | | | | | | t-1 |
| Example | 106A | — | | | — | | v-1 |
| 106A | | | | | | | |

| | constitution | | components | | light emission | |
|---|---|---|---|---|---|---|
| | S/Cl/Br etc. | | of cured film | | characteristics | |
| | elements and | other | elements and | | | low voltage |
| | ions in | elements and | ions in | OD for | | driving |
| | composition | compounds in | cured film | light | reliability of | characteristics |
| | (content/ | composition | (content/ | blocking | light emitting | light emission |
| | mass ppm) | (content) | mass ppm) | efficiency | element | luminance |
| Example | S element | water content | S element | 1.1 | A | A |
| 1 | (3) | (1.0 mass %) | (2) | | | |
| Example | Cl element | surface active agent | Cl element | 0.9 | B+ | B+ |
| 63 | (3) | (200 mass ppm) | (2) | | | |
| Example | | Hf element | | 0.9 | B+ | A |
| 64 | | (0.7 mass ppm) | | | | |
| Example | | Y element | | 1.0 | B+ | B+ |
| 65 | | (2.3 mass ppm) | | | | |
| Example | | | | 1.1 | B | B+ |
| 66 | | | | | | |
| Example | | | | 1.0 | A+ | A+ |
| 67 | | | | | | |
| Example | | | | 0.8 | A | A+ |
| 68 | | | | | | |
| Example | | water content | | — | B+ | B |
| 69 | | (1.0 mass %) | | | | |
| | | surface active agent | | | | |
| | | (200 mass ppm) | | | | |
| | | V-1 | | | | |
| | | (1,370 mass ppm) | | | | |
| Example | | water content | | — | B+ | B |
| 105A | | (1.0 mass %) | | | | |
| | | surface active agent | | | | |
| | | (200 mass ppm) | | | | |
| | | V-1 | | | | |
| | | (2,740 mass ppm) | | | | |
| Example | | water content | | — | B | B+ |
| 106A | | (1.0 mass %) | | | | |
| | | surface active agent | | | | |
| | | (200 mass ppm) | | | | |
| | | V-1 | | | | |
| | | (4,110 mass ppm) | | | | |

TABLE 6-3

| | | constitution | | | | | | |
|---|---|---|---|---|---|---|---|---|
| | | | | | | | S/Cl/Br etc. | |
| | | | constituent | colorant (D) | | | elements and | other |
| | | | components | dispersant (E) | | | ions in | elements and |
| | | | (content/ | (content/ | | | composition | compounds in |
| | | pigment | parts by | parts by | | other | (content/ | composition |
| | composition | dispersion | mass) | mass) | compound (I) | compounds | mass ppm) | (content) |
| Example | 70 | Bk-1 | PI-1 (40) | d-1 (41.0) | S-2 | p-1 | S element | water content |
| 70 | | | AE-1 (30) | e-1 (14.4) | Cl-1 | t-1 | (437) | (1.0 mass %) |
| | | | PR-1 (30) | | | u-1 | Cl element | surface active agent |
| | | | NQD-1 (20) | | | u-2 | (3) | (200 mass ppm) |
| | | | g-3 (3) | | | v-1 | | Hf element |
| | | | | | | | | (0.7 mass ppm) |
| | | | | | | | | Y element |
| | | | | | | | | (2.3 mass ppm) |
| | | | | | | | | v-1 |
| | | | | | | | | (836 mass ppm) |
| Example | 71 | — | | d-8 (35.9) | | p-1 | S element | water content |
| 71 | | | | d-9 (14.4) | | t-1 | (2,102) | (1.0 mass %) |
| | | | | d-10 (21.5) | | v-1 | Cl element | surface active agent |
| | | | | | | | (3) | (200 mass ppm) |
| | | | | | | | | v-1 |
| | | | | | | | | (766 mass ppm) |
| Example | 72 | — | | — | | | S element | water content |
| 72 | | | | | | | (630) | (1.0 mass %) |
| | | | | | | | Cl element | surface active agent |
| | | | | | | | (3) | (200 mass ppm) |
| | | | | | | | | v-1 |
| | | | | | | | | (1,210 mass ppm) |

| | components | | | | | | | light emission | |
|---|---|---|---|---|---|---|---|---|---|
| | of cured film | | | | | | | characteristics | |
| | elements and | | | | | | | | low voltage |
| | ions in | ion detection intensity | | | | | OD for | reliability | driving |
| | cured film | | | indium | | | light | of light | characteristics |
| | (content/ | sulfur | chlorine | oxide | carbon | cyanide | blocking | emitting | light emission |
| | mass ppm) | ion | ion | ion | ion | ion | efficiency | element | luminance |
| Example | S element | 56.7 | 15.6 | 1,548 | 962 | 1,386 | 1.0 | B | A |
| 70 | (280) | | | | | | | | |
| | Cl element | | | | | | | | |
| | (2) | | | | | | | | |
| Example | S element | 56.1 | 16.1 | 1,551 | 972 | 1,391 | 1.0 | B | A |
| 71 | (1,400) | | | | | | | | |
| | Cl element | | | | | | | | |
| | (2) | | | | | | | | |
| Example | S element | 72.6 | 11.1 | 1,489 | 1,198 | 1,530 | — | B | B+ |
| 72 | (400) | | | | | | | | |
| | Cl element | | | | | | | | |
| | (2) | | | | | | | | |

TABLE 7-1

| | | constitution | | | | | components of |
|---|---|---|---|---|---|---|---|
| | | | constituent | | | other | non-transparent |
| | | | components | | | elements and | conductive |
| | | | (content/ | | | compounds in | metal layer in |
| | | pigment | parts by | | other | composition | first electrode |
| | composition | dispersion | mass) | compound (I) | compounds | (content) | [mass %] |
| Example | 1 | Bk-1 | PI-1 (30) | S-2 | p-1 | S element | Ag/Pd/Cu = |
| 1 | | | AE-1 (25) | Cl-1 | t-1 | (3 mass ppm) | 98.07/0.87/ |
| | | | PR-1 (15) | | u-1 | Cl element | 1.06 |
| Example | 1 | | b-1 (10) | | u-2 | (3 mass ppm) | Ag/Pd/Cu/In = |
| 73 | | | b-2 (20) | | | water content | 97.07/0.87/ |
| | | | c-1 (10) | | | (1.0 mass %) | 1.06/1.00 |
| Example | 1 | | d-1 (41.0) | | | surface active | Ag/Pd/Cu/Na = |
| 74 | | | e-1 (14.4) | | | agent | 97.07/0.87/ |
| | | | f-1 (0.5) | | | (200 mass ppm) | 1.06/1.00 |
| Example | 1 | | g-3 (5) | | | Hf element | Ag/Pd/Cu/Ca = |
| 75 | | | | | | (0.7 mass ppm) | 97.07/0.87/ |
| | | | | | | Y element | 1.06/1.00 |
| Example | 1 | | | | | (2.3 mass ppm) | Ag/Pd/Cu/Si = |
| 76 | | | | | | | 97.07/0.87/ |
| | | | | | | | 1.06/1.00 |

| | | | | | | | light emission | |
|---|---|---|---|---|---|---|---|---|
| | | | | | | | characteristics | |
| | | | | | | | | low voltage |
| | ion detection intensity | | | | | OD for | reliability | driving |
| | | | indium | | | light | of light | characteristics |
| | sulfur | chlorine | oxide | carbon | cyanide | blocking | emitting | light emission |
| | ion | ion | ion | ion | ion | efficiency | element | luminance |
| Example | 20.0 | 19.0 | 1,518 | 904 | 1,355 | 1.1 | A | A |
| 1 | | | | | | | | |
| Example | 22.1 | 21.0 | 1,465 | 703 | 1,091 | 1.1 | A | A+ |
| 73 | | | | | | | | |
| Example | 22.5 | 21.3 | 1,481 | 710 | 1,121 | 1.1 | A | A+ |
| 74 | | | | | | | | |
| Example | 22.4 | 21.1 | 1,477 | 713 | 1,103 | 1.1 | A | A+ |
| 75 | | | | | | | | |
| Example | 22.2 | 21.2 | 1,469 | 707 | 1,117 | 1.1 | A | A+ |
| 76 | | | | | | | | |

TABLE 7-2

| | | constitution | | | | | | |
|---|---|---|---|---|---|---|---|---|
| | | | | | | S/Cl/Br etc. | | |
| | | | | | | elements and | other | |
| | | | constituent | | | ions in | elements and | different in |
| | | | components | | | composition | compounds in | maximum |
| | | pigment | (content/ | | other | (content/ | composition | surface |
| | composition | dispersion | parts by mass) | compound (I) | compounds | mass ppm) | (content) | roughness |
| Example | 1 | Bk-1 | Pl-1 (30) | S-2 | p-1 | S element | water content | pixel separation |
| 1 | | | AE-1 (25) | Cl-1 | t-1 | (3) | (1.0 mass %) | layer surface = |
| | | | PR-1 (15) | | u-1 | Cl element | surface active agent | 11.0 nm |
| | | | b-1 (10) | | u-2 | (3) | (200 mass ppm) | spacer layer |
| | | | b-2 (20) | | | | Hf element | surface = |
| | | | c-1 (10) | | | | (0.7 mass ppm) | 0.5 nm |
| | | | d-1 (41.0) | | | | Y element | difference in |
| | | | e-1 (14.4) | | | | (2.3 mass ppm) | maximum surface |
| | | | f-1 (0.5) | | | | | roughness = |
| | | | g-3 (5) | | | | | 10.5 nm |

| | | | | | | | light emission | |
|---|---|---|---|---|---|---|---|---|
| | | | | | | | characteristics | |
| | | | | | | | | low voltage |
| | | | | | | OD for | reliability | driving |
| | ion detection intensity at depth of 3 nm from surface | | | | | light | of light | characteristics |
| | sulfur | chlorine | indium oxide | carbon | cyanide | blocking | emitting | light emission |
| | ion | ion | ion | ion | ion | efficiency | element | luminance |
| Example | 20.0 | 19.0 | 1,518 | 904 | 1,355 | 1.1 | A | A |
| 1 | | | | | | | | |

| | | constitution | | | | | |
|---|---|---|---|---|---|---|---|
| | | | | | | S/Cl/Br etc. | |
| | | | | | | elements and | other |
| | | | constituent | | | ions in | elements and |
| | | | components | | | composition | compounds in |
| | | pigment | (content/ | | other | (content/ | composition |
| | composition | dispersion | parts by mass) | compound (I) | compounds | mass ppm) | (content) |
| Example | 1 | Bk-1 | PI-1 (30) | S-2 | p-1 | S element | water content |
| 1 | | | AE-1 (25) | Cl-1 | t-1 | (3) | (1.0 mass %) |
| | | | PR-1 (15) | | u-1 | Cl element | surface active |
| | | | b-1 (10) | | u-2 | (3) | agent |
| | | | b-2 (20) | | | | (200 mass ppm) |
| | | | c-1 (10) | | | | Hf element |
| | | | d-1 (41.0) | | | | (0.7 mass ppm) |
| | | | e-1 (14.4) | | | | Y element |
| | | | f-1 (0.5) | | | | (2.3 mass ppm) |
| | | | g-3 (5) | | | | |

| | ratio of ion detection intensity to total anion detection intensity | | | | | light emission | |
|---|---|---|---|---|---|---|---|
| | sulfur ion | | chlorine ion | | | characteristics | |
| | | ratio between | | ratio between | | | low voltage |
| | | first electode | | first electode | OD for | reliability | driving |
| | ratio of | part and pixel | ratio of | part and pixel | light | of light | characteristics |
| | detection | separation layer | detection | separation layer | blocking | emitting | light emission |
| | intensity | part | intensity | part | efficiency | element | luminance |
| Example | (a) surface of | 4.9 | (a) surface of | 6.8 | 1.1 | A | A |
| 1 | first electrode | | first electrode | | | | |
| | part in pixel | | part in pixel | | | | |
| | part = | | part = | | | | |
| | 0.00103 | | 0.00226 | | | | |
| | (b) surface | | (b) surface | | | | |
| | of pixel | | of pixel | | | | |
| | separation | | separation | | | | |
| | layer part = | | layer part = | | | | |
| | 0.00021 | | 0.00033 | | | | |

TABLE 7-3

| | | constitution | | | | | | |
|---|---|---|---|---|---|---|---|---|
| | | | | | | S/Cl/Br etc. | | |
| | | | constituent | | | elements and | other | |
| | | | components | | | ions in | elements and | difference |
| | | | (content/ | | | composition | compounds in | in maximum |
| | | pigment | parts by | | other | (content/ | composition | surface |
| | composition | dispersion | mass) | compound (I) | compounds | mass ppm) | (content) | roughness |
| Example | 1 | Bk-1 | PI-1 (30) | S-2 | p-1 | S element | water content | surface of thin |
| 77 | | | AE-1 (25) | Cl-1 | t-1 | (3) | (1.0 mass %) | part in pixel |
| | | | PR-1 (15) | | u-1 | Cl element | surface active | separation |
| | | | b-1 (10) | | u-2 | (3) | agent | layer = |
| | | | b-2 (20) | | | | (200 mass ppm) | 19.0 nm |
| | | | c-1 (10) | | | | Hf element | surface of thick |
| | | | d-1 (41.0) | | | | (0.7 mass ppm) | part in pixel |
| | | | e-1 (14.4) | | | | Y element | separation |
| | | | f-1 (0.5) | | | | (2.3 mass ppm) | layer = |
| | | | g-3 (5) | | | | | 8.5 nm |
| | | | | | | | | difference in |
| | | | | | | | | maximum surface |
| | | | | | | | | roughness = |
| | | | | | | | | 10.5 nm |

| | | | | | | | light emission | |
|---|---|---|---|---|---|---|---|---|
| | | | | | | | characteristics | |
| | | | | | | | | low voltage |
| | ion detection intensity at depth of 3 nm from surface | | | | | OD for | reliability | driving |
| | | | indium | | | light | of light | characteristics |
| | sulfur | chlorine | oxide | carbon | cyanide | blocking | emitting | light emission |
| | ion | ion | ion | ion | ion | efficiency | element | luminance |
| Example | 23.5 | 22.2 | 1,494 | 709 | 1,110 | 1.1 | A+ | A+ |
| 77 | | | | | | | | |

TABLE 8-1

| | | constitution | | | | | | | components |
|---|---|---|---|---|---|---|---|---|---|
| | | | resin (A1) | | | | S/Cl/Br etc. | | of cured film |
| | | | resin (A2) | constituent | | | elements and | other | elements and |
| | | | resin (A3) | components | | | ions in | elements and | ions in |
| | | | (content/ | (content/ | | | composition | compounds in | cured film |
| | | pigment | parts by | parts by | | other | (content/ | composition | (content/ |
| | composition | dispersion | mass) | mass) | compound (I) | compounds | mass ppm) | (content) | mass ppm) |
| Comparative | 73 | Bk-1 | PI-1 (30) | b-1 (10) | — | p-1 | — | water content | — |
| example 1 | | | AE-1 (25) | b-2 (20) | | t-1 | | (1.0 mass %) | |
| Comparative | 74 | | PR-1 (15) | c-1 (10) | S-4 | u-1 | S element | surface active | S element |
| example 2 | | | | d-1 (41.0) | Cl-3 | u-2 | (500) | agent | (1,000) |
| | | | | e-1 (14.4) | | | Cl element | (200 mass ppm) | Cl element |
| | | | | g-3 (5) | | | (500) | Hf element | (1,000) |
| Comparative | 75 | | | | S—I-3 | | S element | (0.7 mass ppm) | S element |
| example 3 | | | | | Cl—I-3 | | (1,000) | Y element | (2,000) |
| | | | | | | | sulfide ion | (2.3 mass ppm) | sulfide ion |
| | | | | | | | (1,000) | | (2,000) |
| | | | | | | | Cl element | | Cl element |
| | | | | | | | (1,000) | | (2,000) |
| | | | | | | | chloride ion | | chloride ion |
| | | | | | | | (1,000) | | (2,000) |
| Comparative | 76 | — | | b-1 (10) | — | p-1 | — | water content | — |
| example 4 | | | | b-2 (20) | | t-1 | | (1.0 mass %) | |
| Comparative | 77 | — | | c-1 (5) | S-4 | v-1 | S element | surface active | S element |
| example 5 | | | | g-3 (3) | Cl-3 | | (500) | agent | (1,000) |
| | | | | | | | Cl element | (200 mass ppm) | Cl element |
| | | | | | | | (500) | v-1 | (1,000) |
| Comparative | 78 | — | | | S—I-3 | | S element | (1,370 mass ppm) | S element |
| example 6 | | | | | Cl—I-3 | | (1,000) | | (2,000) |
| | | | | | | | sulfide ion | | sulfide ion |
| | | | | | | | (1,000) | | (2,000) |
| | | | | | | | Cl element | | Cl element |
| | | | | | | | (1,000) | | (2,000) |
| | | | | | | | chloride ion | | chloride ion |
| | | | | | | | (1,000) | | (2,000) |

| | | | | | | | light emission | |
|---|---|---|---|---|---|---|---|---|
| | | | | | | | characteristics | |
| | | | | | | | | low voltage |
| | ion detection intensity | | | | | OD for | reliability | driving |
| | | | indium | | | light | of light | characteristics |
| | sulfur | chlorine | oxide | carbon | cyanide | blocking | emitting | light emission |
| | ion | ion | ion | ion | ion | efficiency | element | luminance |
| Comparative | — | — | 562 | 4,614 | 4,579 | 1.1 | B | D |
| example 1 | | | | | | | | |
| Comparative | 231 | 215 | 1,318 | 1,460 | 1,501 | 1.1 | D | C |
| example 2 | | | | | | | | |
| Comparative | 242 | 228 | 1,325 | 1,469 | 1,512 | 1.1 | D | C |
| example 3 | | | | | | | | |
| Comparative | — | — | 702 | 4,372 | 4,290 | — | C+ | D |
| example 4 | | | | | | | | |
| Comparative | 251 | 233 | 1,329 | 1,473 | 1,514 | — | E | C |
| example 5 | | | | | | | | |
| Comparative | 263 | 241 | 1,338 | 1,481 | 1,525 | — | E | C |
| example 6 | | | | | | | | |

TABLE 8-2

| | constitution composition | | | | | | |
|---|---|---|---|---|---|---|---|
| | | | | compound (B) | | | |
| | | | | photosensitizer (C) | | | |
| | | | resin (A1) | colorant (D) | | | S/Cl/Br etc. |
| | | | resin (A2) | dispersant (E) | | | elements |
| | | | resin (A3) | compound (F) | | | and ions in |
| | | | (content/ | crosslinking agent (G) | | | composition |
| | | pigment | parts by | inorganic particles (H) | | other | (content/ |
| | | dispersion | mass) | (content/parts by mass) | compound (I) | compounds | mass ppm) |
| Comparative | 110A | Bk-1 | PI-1 (30) | b-1 (10) | — | u-1 | — |
| example 1A | | | AE-1 (25) | b-2 (20) | | u-2 | |
| Comparative | 73 | | PR-1 (15) | c-1 (10) | — | p-1 | — |
| example 1 | | | | d-1 (41.0) | | t-1 | |
| Comparative | 74 | | | e-1 (14.4) | S-4 | u-1 | S element |
| example 2 | | | | g-3 (5) | Cl-3 | u-2 | (500) |
| | | | | | | | Cl element |
| | | | | | | | (500) |
| Comparative | 75 | | | | S—I-3 | | S element |
| example 3 | | | | | Cl—I-3 | | (1,000) |
| | | | | | | | sulfide ion |
| | | | | | | | (1,000) |
| | | | | | | | Cl element |
| | | | | | | | (1,000) |
| | | | | | | | chloride ion |
| | | | | | | | (1,000) |
| Comparative | 114A | — | | b-1 (10) | — | v-1 | — |
| example 5A | | | | b-2 (20) | | | |
| Comparative | 76 | — | | c-1 (5) | — | p-1 | — |
| example 4 | | | | g-3 (3) | | t-1 | |
| Comparative | 77 | — | | | S-4 | v-1 | S element |
| example 5 | | | | | Cl-3 | | (500) |
| | | | | | | | Cl element |
| | | | | | | | (500) |
| Comparative | 78 | — | | | S—I-3 | | S element |
| example 6 | | | | | Cl—I-3 | | (1,000) |
| | | | | | | | sulfide ion |
| | | | | | | | (1,000) |
| | | | | | | | Cl element |
| | | | | | | | (1,000) |
| | | | | | | | chloride ion |
| | | | | | | | (1,000) |

| | | | components | | light emission | |
|---|---|---|---|---|---|---|
| | | | of cured film | | characteristics | |
| | constitution | | elements and | | | low voltage |
| | other elements | | ions in | OD for | reliability | driving |
| | and compounds | | cured film | light | of light | characteristics |
| | in composition | | (content/ | blocking | emitting | light emission |
| | (content) | | mass ppm) | efficiency | element | luminance |
| Comparative | — | Hf element | — | 1.1 | B | D |
| example 1A | | (0.7 mass ppm) | | | | |
| Comparative | water content | Y element | — | 1.1 | B | D |
| example 1 | (1.0 mass %) | (2.3 mass ppm) | | | | |
| Comparative | surface active | | S element | 1.1 | D | C |
| example 2 | agent | | (1,000) | | | |
| | (200 mass ppm) | | Cl element | | | |
| | | | (1,000) | | | |
| Comparative | | | S element | 1.1 | D | C |
| example 3 | | | (2,000) | | | |
| | | | sulfide ion | | | |
| | | | (2,000) | | | |
| | | | Cl element | | | |
| | | | (2,000) | | | |
| | | | chloride ion | | | |
| | | | (2,000) | | | |
| Comparative | — | v-1 | — | — | C+ | D |
| example 5A | | (1,370 mass ppm) | | | | |
| Comparative | water content | | — | — | C+ | D |
| example 4 | (1.0 mass %) | | | | | |
| Comparative | surface active | | S element | — | E | C |
| example 5 | agent | | (1,000) | | | |
| | (200 mass ppm) | | Cl element | | | |
| | | | (1,000) | | | |
| Comparative | | | S element | — | E | C |
| example 6 | | | (2,000) | | | |
| | | | sulfide ion | | | |
| | | | (2,000) | | | |
| | | | Cl element | | | |
| | | | (2,000) | | | |
| | | | chloride ion | | | |
| | | | (2,000) | | | |

### EXPLANATION OF NUMERALS

34: thick part
35a, 35b, 35c: thin parts
36a, 36b, 36c, 36d, 36e: inclined sides in cross section of cured pattern
37: horizontal side of underlying substrate
41: transparent portion
42: light blocking portion
43: translucent portion
44: thick part
45: opening part
46: thin part
47: non-alkali glass substrate
48: first electrode part
49: auxiliary electrode part
50: pixel separation layer part
51: organic EL layer part containing light emitting layer
52: second electrode part
100A: display device including pixel separation layer having step shape
100B: display device having pixel separation layer and spacer layer
100E: display device including step-shaped pixel separation layer and polarizing film
200A: display device including step-shaped pixel separation layer and pixel size control layer
101, 201: substrate
102, 202: electrically conductive layer/metal wiring
103, 203: TFT element layer
104, 204: interlayer insulation layer
105, 205: TFT planarization layer/TFT protection layer
106A, 206A: pixel separation layer having step shape
106B: pixel separation layer
107, 207: first electrode
108, 208: organic layer containing light emitting layer
109, 209: second electrode
110, 210: sealing layer
111, 211: touch panel wiring/touch panel electrode
112, 212: color filter layer
113, 213: black matrix layer
114, 214: overcoat layer
115, 215: substrate
116, 216: thick part in pixel separation layer
117A: spacer layer
218A: pixel size control layer
123: polarizing film
100x, 200x: cross sectional axis in plan view
106Aa, 206Aa: opening part in pixel separation layer part having step shape
106Ba: opening part in pixel separation layer part
112a, 212a: color filter layer part
113a, 213a: opening part in black matrix layer part
116a, 216a: thick part in pixel separation layer part
117Aa: spacer layer part
218Aa: opening part in pixel size control layer part
124a: pixel part
124a1: pixel part of first color
124a2: pixel part of second color
124a3: pixel part of third color

1. A display device comprising a substrate, a first electrode, a second electrode, a pixel separation layer, and an organic layer containing a light emitting layer,
wherein the pixel separation layer contains a colorant (D-DL) and has an optical density of 0.5 to 3.0 in the visible light wavelength range per μm of the thickness of the pixel separation layer,
has a plurality of pixel parts in a plan view, and
satisfies the relationship represented by the general formula (SA-1) and/or the relationship represented by the general formula (XA-1):
$$2 \leq ( {S}_{Dep / Anode} ) \leq 200 \qquad ( SA - 1 )$$
$$and$$
$$2 \leq ( {X}_{Dep / Anode} ) \leq 200 , \qquad ( XA - 1 )$$
wherein:
(S_{Dep/Anode}) counts represents the detection intensity of the sulfur ion (S⁻);
(X_{Dep/Anode}) counts represents the sum of (Cl_{Dep/Anode}) and (Br_{Dep/Anode});
(Cl_{Dep/Anode}) counts represents the detection intensity of the chlorine ion (Cl⁻); and
(Br_{Dep/Anode}) counts represents the detection intensity of the bromine ion (Br⁻);
all measured by time-of-flight secondary ion mass spectrometry at a position 3 nm deep in each pixel part from the surface of the first electrode, the surface being in contact with the organic layer containing a light emitting layer.

2. The display device according to claim 1, satisfying the relationships represented by the general formula (SA-1) and the general formula (XA-1).

3. The display device according to claim 1, wherein:
the first electrode is a non-transparent electrode having a multilayer structure;
the first electrode has a non-transparent conductive metal layer; and
at least one of the layers other than the outermost layer of the first electrode that faces the light emitting layer includes a non-transparent conductive metal layer containing silver or copper as the main constituent element.

4. The display device according to claim 3, wherein the first electrode has a transparent conductive oxide film layer and a non-transparent conductive metal layer and has, as the outermost layer of the first electrode that faces the light emitting layer, a transparent conductive oxide film layer containing indium as the main constituent element.

5. The display device according to claim 4, satisfying the relationship represented by the general formula (SA-1) given above and further satisfying the relationships represented by the general formula (SA-2) and the general formula (InSA-1), and/or
satisfying the relationship represented by the general formula (XA-1) given above and further satisfying the relationships represented by the general formula (XA-2) and the general formula (InXA-1), wherein:
(InO_{Dep/Anode}) counts is the detection intensity of the indium oxide ion (InO₂⁻), measured by time-of-flight secondary ion mass spectrometry at a position 3 nm deep in each pixel part from the surface of the transparent conductive oxide film layer, the surface being in contact with the organic layer containing a light emitting layer:
$$0.00001 \leq ( {S}_{Dep / Anode} ) / ( {In O}_{Dep / Anode} ) \leq 0.1 , \qquad ( SA - 2 )$$
$$1 , 000 \leq ( {In O}_{Dep / Anode} ) \leq 40 , 000 , \qquad ( InSA - 1 )$$
$$0.00001 \leq ( {X}_{Dep / Anode} ) / ( {In O}_{Dep / Anode} ) \leq 0.1 , \qquad ( XA - 2 )$$
$$and$$
$$1 , 000 \leq ( {In O}_{Dep / Anode} ) \leq 40 , 0. \qquad ( InXA - 1 )$$

6. The display device according to any one of claims 1 to 5, further satisfying the relationship represented by the general formula (SA-1a) and/or the relationship represented by the general formula (XA-1a):
$$2 \leq ( {S}_{Dep / Anode} ) \leq 100 , \qquad ( SA - 1 a )$$
$$and$$
$$2 \leq ( {X}_{Dep / Anode} ) \leq 100. \qquad ( XA - 1 a )$$

7. The display device according to any one of claims 1 to 5, satisfying the relationship represented by the general formula (SD-1) and/or the relationship represented by the general formula (XD-1):
$$0.1 \leq ( {S}_{Anode} ) / ( {S}_{PDL} ) \leq 20 , \qquad ( SD - 1 )$$
$$and$$
$$0.1 \leq ( {X}_{Anode} ) / ( {X}_{PDL} ) \leq 20 , \qquad ( XD - 1 )$$
wherein:
(SP_{DL}) is the ratio of the ion detection intensity of the sulfur ion (S⁻);
(X_{PDL}) is the total of (Cl_{PDL}) and (Br_{PDL});
(Cl_{PDL}) is the ratio of the ion detection intensity of the chlorine ion (Cl⁻);
(Br_{PDL}) is the ratio of the ion detection intensity of the bromine ion (Br⁻);
the ratios being relative to the total anion detection intensities measured by time-of-flight secondary ion mass spectrometry on the surface of the pixel separation layer part that is in contact with the second electrode part or is exposed in the opening part in the second electrode part, in the region not overlapping with the region including the organic layer part containing a light emitting layer on the pixel separation layer part;
(S_{Anode}) is the ratio of the ion detection intensity of the sulfur ion (S⁻);
(X_{Anode}) is the total of (Cl_{Anode}) and (Br_{Anode});
(Cl_{Anode}) is the ratio of the ion detection intensity of the chlorine ion (Cl⁻); and
(Br_{Anode}) is the ratio of the ion detection intensity of the bromine ion (Br⁻);
the ratios being relative to the total anion detection intensities measured by time-of-flight secondary ion mass spectrometry on the surface of the first electrode part that is in contact with the organic layer containing a light emitting layer in the pixel part.

8. The display device according to any one of claims 1 to 5, wherein:
the pixel separation layer contains an organic black pigment and/or a mixture of two or more color pigments,
the organic black pigment containing one or more selected from the group consisting of benzofuranone based black pigments, perylene based black pigments, and azo based black pigments, and
the mixture of two or more color pigments containing two or more pigments selected from the group consisting of red, orange, yellow, green, blue, and purple.

9. The display device according to any one of claims 1 to 5, wherein the pixel separation layer contains a resin (A1-DL) and/or a resin (A3-DL) as specified below:
resin (A1-DL): a resin having one or more structural units selected from the group consisting of imide structure, amide structure, oxazole structure, and siloxane structure, and resin (A3-DL): a resin having a structural unit containing a phenolic hydroxyl group.

10. The display device according to any one of claims 1 to 5, wherein the pixel separation layer contains a compound (C1x-DL) and/or a compound (C2x-DL) as specified below:
compound (C1x-DL): a compound having a fluorene structure, benzofluorene structure, dibenzofluorene structure, carbazole structure, benzocarbazole structure, indole structure, benzoinole structure, or diphenyl sulfide structure and having a structure including an imino group bonded to these structures and/or a structure including a carbonyl group bonded to these structures, and
compound (C2x-DL): a compound having a carboxylate structure containing an indene structure and/or an aryl sulfonate structure containing an indene structure.

11. The display device according to any one of claims 1 to 5, wherein the non-transparent conductive metal layer containing silver or copper as the main constituent element in the first electrode further contains one or more selected from the group consisting of In, Sn, Zn, Al, Ga, Bi, Nd, Ni, Mn, Na, K, Mg, Ca, C, and Si, as elements different from the main constituent element.

12. The display device according to any one of claims 1 to 5, in the form of a flexible display device further comprising:
a flexible substrate,
a structure in which the pixel separation layer is disposed on the flexible substrate, none of linear polarizing plates, quarter wave plates, or circular polarizing plates on the light extraction side of the organic layer containing a light emitting layer, and
a curved display part, a display part having a plane bending outward, or a display part having a plane bending inward.

13. The display device according to any one of claims 1 to 5, wherein:
the pixel separation layer has a step shaped cured pattern, and
the thickness difference of (ΔT_{FT-HT}) μm between the thickness of (T_{FT}) μm and the thickness of (T_{HT}) μm is 0.5 to 10.0 μm where (T_{FT}) μm is the thickness of the thick parts and (T_{HT}) μm is the thickness of the thin parts in the step shaped cured pattern of the pixel separation layer.

14. The display device according to claim 13, wherein:
the thick parts and the thin parts in the step shaped cured pattern of the pixel separation layer contain the same colorant (D-DL), and
the optical density per μm of the thickness of the thick parts and the thin parts is 0.5 to 3.0 in the visible light wavelength range.

15. The display device according to any one of claims 1 to 5, wherein the pixel separation layer has a cured pattern and has a spacer layer disposed on a part of the pixel separation layer, the spacer layer having a thickness (T_{SP}) μm of 0.5 to 10.0 μm, and
the spacer layer satisfying at least one of the requirements (1) to (3) given below:
(1) the spacer layer does not contain the colorant (D-DL),
(2) the spacer layer contains the colorant (D-DL) and has an optical density of 0.0 to 0.3 in the visible light wavelength range per μm of the thickness of the spacer layer, and
(3) the spacer layer includes a compound (C2x-DL) having a carboxylate structure containing an indene structure and/or an aryl sulfonate structure containing an indene structure.

16. A display device comprising a substrate, a first electrode, a second electrode, a pixel separation layer, and an organic layer containing a light emitting layer, wherein:
the pixel separation layer contains a colorant (D-DL) and has an optical density of 0.5 to 3.0 in the visible light wavelength range per μm of the thickness of the pixel separation layer;
the pixel separation layer contains one or more selected from the group consisting of a compound (I1a-DL), compound (I1b-DL), compound (I2a-DL), and compound (I2b-DL) as specified below;
the compound (I1a-DL) and the compound (I2a-DL) have structures (I-Ia) as specified below;
the compound (I1b-DL) and the compound (I2b-DL) have structures (I-Ib) as specified below; and
one or more of the requirements (1a-DL) and (1b-DL) or one or more of the requirements (2a-DL) and (2b-DL) specified below are satisfied:
compound (I1a-DL): one or more compounds selected from the group consisting of thiol structure-containing compounds, sulfide structure-containing compounds, disulfide structure-containing compounds, sulfoxide structure-containing compounds, sulfone structure-containing compounds, sultone structure-containing compounds, thiophene structure-containing compounds, and sulfonic acid structure-containing compounds,
compound (I1b-DL): a compound having, as anion species, one or more selected from the group consisting of sulfide ion structures, hydrogen sulfide ion structures, sulfate ion structures, and hydrogen sulfate ion structures, and
also having, as cation species, an ammonium ion structure, primary ammonium ion structure, secondary ammonium ion structure, tertiary ammonium ion structure, or quaternary ammonium ion structure,
compound (I2a-DL): one or more compounds selected from the group consisting of alkyl chloride structure-containing compounds, cycloalkyl chloride structure-containing compounds, aryl chloride structure-containing compounds, alkyl bromide structure-containing compounds, cycloalkyl bromide structure-containing compounds, and aryl bromide structure-containing compounds,
compound (I2b-DL): a compound having, as anion species, a chloride ion structure and/or a bromide ion structure, and
also having, as cation species, an ammonium ion structure, primary ammonium ion structure, secondary ammonium ion structure, tertiary ammonium ion structure, or quaternary ammonium ion structure,
structure (I-Ia): a structure containing one or more selected from the group consisting of monovalent or divalent aliphatic groups having 4 to 30 carbon atoms, alkylaryl groups having 10 to 30 carbon atoms, arylalkyl groups having 10 to 30 carbon atoms, and aryl groups having 7 to 15 carbon atoms,
structure (I-Ib): a structure containing one or more selected from the group consisting of monovalent or divalent aliphatic groups having 1 to 6 carbon atoms, alkylaryl groups having 10 to 30 carbon atoms, arylalkyl groups having 10 to 30 carbon atoms, and aryl group having 7 to 15 carbon atoms,
(1a-DL) the content of the sulfur element in the pixel separation layer is 0.01 to 500 mass ppm,
(1b-DL) the total content of the sulfide ion, hydrogen sulfide ion, sulfate ion, and hydrogen sulfate ion in the pixel separation layer is 0.01 to 1,000 mass ppm,
(2a-DL) the total content of the chlorine element and the bromine element in the pixel separation layer is 0.01 to 500 mass ppm, and
(2b-DL) the total content of chloride ions and bromide ions in the pixel separation layer is 0.01 to 1,000 mass ppm.

17. A photosensitive composition comprising an alkali soluble resin (A), a photosensitizer (C), and a colorant (D) and satisfying the requirement (I) and/or the requirement (II) given below:
(I) further including one or more selected from the group consisting of components containing the sulfur element, components containing the chlorine element, and components containing the bromine element and satisfying the requirement (1a) and/or the requirement (2a) given below,
(1a) the content of the sulfur element in the photosensitive composition is 0.01 to 100 mass ppm, and
(2a) the total content of the chlorine element and the bromine element in the photosensitive composition is 0.01 to 100 mass ppm,
(II) further comprising one or more selected from the group consisting of components containing a sulfur based anion as given below and components containing a halogen anion as given below and satisfying the requirement (1b) and/or the requirement (2b) given below, sulfur based anion: one or more ions selected from the group consisting of sulfide ions, hydrogen sulfide ions, sulfate ions, and hydrogen sulfate ions, halogen anion: a chloride ion and/or a bromide ion,
(1b) the total content of sulfide ions, hydrogen sulfide ions, sulfate ions, and hydrogen sulfate ions in the photosensitive composition is 0.01 to 500 mass ppm, and
(2b) the total content of chloride ions and bromide ions in the photosensitive composition is 0.01 to 500 mass ppm.

18. The photosensitive composition according to claim 17, comprising the component containing the sulfur element and also satisfying the requirement (1a), and/or comprising the component containing a sulfur based anion and also satisfying the requirement (1b).

19. The photosensitive composition according to claim 17, comprising the component containing the sulfur element and also satisfying the requirement (1a) and/or comprising the component containing a sulfur based anion and also satisfying the requirement (1b), and further comprising one or more selected from the group consisting of components containing the chlorine element and components containing the bromine element and also satisfying the requirement (2a), and/or comprising the component containing a halogen anion and also satisfying the requirement (2b).

20. The photosensitive composition according to any one of claims 17 to 19, further comprising water and satisfying the requirement (3) given below:
(3) the content of water in the photosensitive composition is 0.01 to 2.0 mass %.
